(19) United States
(12) Patent Application Publication
(10) Pub. No.: US 2024/0284780 A1
(43) Pub. Date: Aug. 22, 2024

(54) ORGANOMETALLIC COMPOUND AND ORGANIC LIGHT-EMITTING DIODE INCLUDING THE SAME

(71) Applicant: LG Display Co., Ltd., Seoul (KR)

(72) Inventors: Hansol Park, Goyang-si (KR); Misang Yoo, Seoul (KR); Yoojeong Jeong, Seoul (KR); Kusun Choung, Seoul (KR); Soonjae Hwang, Seoul (KR); Kyoungjin PARK, Hwaseong-si (KR); Hyun KIM, Hwaseong-si (KR); Soo-Yong LEE, Cheonan-si (KR); Samuel KIM, Cheonan-si (KR)

(73) Assignee: LG Display Co., Ltd., Seoul (KR)

(21) Appl. No.: 18/425,395

(22) Filed: Jan. 29, 2024

(30) Foreign Application Priority Data
Jan. 30, 2023 (KR) 10-2023-0012112

(51) Int. Cl. H10K 85/30; C07F 15/00; C09K 11/06; H10K 50/12

(52) U.S. Cl. CPC H10K 85/342; C07F 15/0033; C09K 11/06; C07B 2200/05; C09K 2211/1033; C09K 2211/185; H10K 50/12

(57) ABSTRACT

An organometallic compound represented by Chemical Formula 1, and an organic light-emitting diode containing the same. In the Chemical Formula 1, Z represents one of O (oxygen), S (sulfur) or Se (selenium), m is 1 or 2, n is an integer from 0 to 2, and X Y is a bidentate ligand.

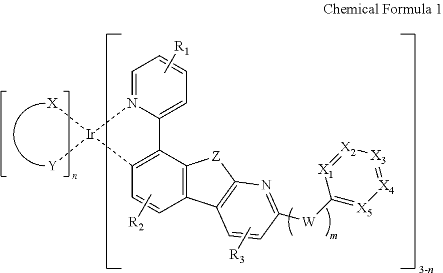

### CROSS-REFERENCE TO RELATED APPLICATION

This application claims the benefit of and the priority to Korean Patent Application No. 10-2023-0012112 filed on Jan. 30, 2023 in the Korean Intellectual Property Office, the disclosure of which is hereby incorporated by reference in its entirety.

### BACKGROUND

### 1. Technical Field

The present disclosure relates to an organometallic compound, and more particularly, to an organometallic compound having phosphorescent properties and an organic light-emitting diode including the same.

### 2. Description of the Related Art

Display devices are ubiquitous, and interest in such devices is increasing. One of the display devices is an organic light-emitting display device including an organic light-emitting diode (OLED) which is rapidly developing.

In the organic light-emitting diode, when electric charges are injected into a light-emitting layer formed or disposed between a positive electrode and a negative electrode, an electron and a hole may be recombined with each other in the light-emitting layer to form an exciton. The energy of the exciton may be converted to light that will be emitted by the organic light-emitting diode. Compared to conventional display devices, the organic light-emitting diode may operate at a lower voltage, consume relatively little power, render excellent colors, and may be used in a variety of ways when the organic light-emitting diode includes a flexible substrate. Further, a size of the organic light-emitting diode may be adjustable.

The organic light-emitting diode (OLED) may have superior viewing angle and contrast ratio compared to a liquid crystal display (LCD), and may be lightweight and ultra-thin because the OLED may not require a backlight. The organic light-emitting diode may include a plurality of organic layers between a negative electrode (electron injection electrode; cathode) and a positive electrode (hole injection electrode; anode). The plurality of organic layers may include a hole injection layer, a hole transport layer, a hole transport auxiliary layer, an electron blocking layer, and a light-emitting layer, an electron transport layer, etc.

In this organic light-emitting diode structure, when a voltage is applied across the two electrodes, electrons and holes are injected from the negative and positive electrodes, respectively, into the light-emitting layer. Excitons are generated in the light-emitting layer and then fall to a ground state to emit light.

Organic materials used in the organic light-emitting diode may be largely classified into light-emitting materials and charge-transporting materials. The light-emitting material may be an important factor in determining luminous efficiency of the organic light-emitting diode. The luminescent material may have high quantum efficiency, excellent electron and hole mobility, and may exist uniformly and stably in the light-emitting layer. The light-emitting materials may be classified into light-emitting materials emitting blue, red, and green colors based on colors of the light. A color-generating material may include a host and dopants to increase the color purity and luminous efficiency through energy transfer.

When a fluorescent material is used, singlets, which make up about 25% of excitons generated in the light-emitting layer, are used to emit light, while most of triplets, which make up 75% of the excitons generated in the light-emitting layer, are dissipated as heat. However, when a phosphorescent material is used, both singlets and triplets may emit light.

Conventionally, an organometallic compound may be used as the phosphorescent material in the organic light-emitting diode. The performance of an organic light-emitting diode may be improved by deriving a high-efficiency phosphorescent dopant material and applying a host material that may have optimal or desirable photophysical properties. The diode efficiency and lifetime may be improved compared to a conventional organic light-emitting diode.

### SUMMARY

Accordingly, an object of the present disclosure is to provide an organometallic compound capable of lowering operation voltage of an organic light-emitting diode, and improving efficiency and lifespan thereof, and an organic light-emitting diode including an organic light-emitting layer containing the same.

Objects of the present disclosure are not limited to the above-mentioned objects. Other objects and advantages of the present disclosure that are not mentioned may be understood based on following description, and may be more clearly understood based on aspects of the present disclosure. Further, it may be easily understood that the objects and advantages of the present disclosure may be realized using means shown in the claims and combinations thereof.

To achieve these and other advantages and in accordance with objects of the disclosure, as embodied and broadly described herein, an organometallic compound has a structure represented by Chemical Formula 1:

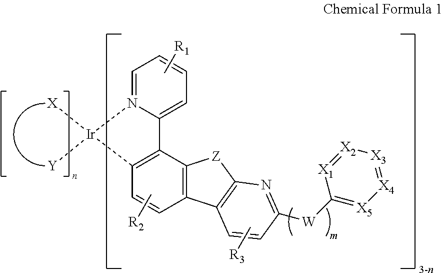

wherein in the Chemical Formula 1,
Z may represent one of O (oxygen), S (sulfur) or Se (selenium),
each W may independently represent C(R₄)₂,
m may be an integer of 1 to 5,
each of X₁, X₂, X₃, X₄, and X₅ may independently represent N or CR₅,
R₁, when present, may represent mono-substitution, di-substitution, tri-substitution or tetra-substitution (i.e., (R₁)ₚ, where p is 0 to 4),
R₂, when present, and R₃, when present, may each independently represent mono-substitution, or di-substitution (i.e., (R₂)_{q}, where q is 0 to 2, (R₃)ᵣ, where r is 0 to 2),
each of R₁ to R₃ may independently represent one selected from the group consisting of deuterium, halogen, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, and phosphino,
each R₄ may independently represent one selected from the group consisting of hydrogen, deuterium, halogen, and a C1 to C20 linear or branched alkyl group,
each R₅ may independently represent one selected from the group consisting of hydrogen, deuterium, halogen, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, and phosphino,
optionally, two adjacent R₁ groups, when present, may bind to each other to form a cycloalkyl, cycloalkenyl, aryl or arylalkyl,
two adjacent R₂ groups, when present, optionally bind to each other to form a cycloalkyl, cycloalkenyl, aryl or arylalkyl,
two adjacent R₃ groups, when present, optionally bind to each other to form a cycloalkyl, cycloalkenyl, aryl or arylalkyl,
two adjacent R₅ groups, when present, optionally bind to each other to form a cycloalkyl, cycloalkenyl, aryl or arylalkyl, n may be an integer from 0 to 2,

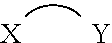

may be a bidentate ligand.

In some embodiments,

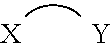

may have a structure represented by one of Chemical Formula 2 or Chemical Formula 3.

In some embodiments, n in the Chemical Formula 1 may be 0.

In some embodiments, n in the Chemical Formula 1 may be 1.

In some embodiments, n in the Chemical Formula 1 may be 2.

In some embodiments, Z may be O (oxygen).

In some embodiments, the organometallic compound represented by the Chemical Formula 1 may be include at least one selected from the group consisting of following compounds 1 to 372.

In some embodiments, the organometallic compound represented by the Chemical Formula 1 may be a green phosphorescent material.

According to another aspect of the present disclosure, an organic light-emitting diode may include a first electrode; a second electrode facing the first electrode; and an organic layer including a light-emitting layer that includes the organometallic compound according to an aspect of the present disclosure as a dopant, wherein the organic layer is between the first electrode and the second electrode.

In some embodiments, the organometallic compound represented by the Chemical Formula 1 may be a green phosphorescent material.

In some embodiments, the organic layer may further include at least one selected from the group consisting of a hole injection layer, a hole transport layer, an electron transport layer, and an electron injection layer.

According to yet another aspect of the present disclosure, an organic light-emitting display device may include a substrate; a driving element located on the substrate; and the organic light-emitting diode according to an aspect of the present disclosure, wherein the organic light-emitting diode is on the substrate and connected to the driving element.

The organometallic compound according to example embodiments of the present disclosure may be used as the dopant of the light-emitting layer of the organic light-emitting diode. The operation voltage of the organic light-emitting diode may be lowered, and the efficiency and lifespan characteristics of the organic light-emitting diode may be improved. Thus, a low power display device may be realized.

Effects of the present disclosure are not limited to the above-mentioned effects, and other effects not mentioned may be clearly understood by those skilled in the art from following description.

It is to be understood that both the foregoing general description and the following detailed description of the present disclosure are merely by way of example and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 is a schematic cross-sectional view of an organic light-emitting diode according to an embodiment of the present disclosure.

FIG. 2 is a cross-sectional view schematically showing an organic light-emitting diode having a tandem structure having two light-emitting stacks according to an embodiment of the present disclosure.

FIG. 3 is a cross-sectional view schematically showing an organic light-emitting diode of a tandem structure having three light-emitting stacks according to an embodiment of the present disclosure.

FIG. 4 is a cross-sectional view schematically illustrating an organic light-emitting display device including an organic light-emitting diode according to an illustrative embodiment of the present disclosure.

### DETAILED DESCRIPTION

Reference will now be made in detail to some of the examples and embodiments of the disclosure illustrated in the accompanying drawings. Wherever possible, the same reference numbers will be used throughout the drawings to refer to the same or like parts.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and may be embodied in various different forms. Thus, these example embodiments are set forth to make the present disclosure sufficiently complete, and to assist those skilled in the art to fully understand the scope of the present disclosure. The protected scope of the present disclosure is defined by claims and their equivalents.

For convenience of description, a scale in which each of elements is illustrated in the accompanying drawings may differ from an actual scale. Thus, the illustrated elements are not limited to the specific scale in which they are illustrated in the drawings. The same reference numbers in different drawings represent the same or similar elements, which may perform similar functionality. Further, where the detailed description of the relevant known steps and elements may obscure an important point of the present disclosure, a detailed description of such known steps and elements may be omitted. Furthermore, in the following detailed description of the present disclosure, numerous specific details are set forth to provide a sufficiently thorough understanding of the present disclosure. However, it will be understood that the present disclosure may be practiced without these specific details. In other instances, known methods, procedures, components, and circuits have not been described in detail so as not to unnecessarily obscure aspects of the present disclosure.

Although example embodiments of the present disclosure are described in detail with reference to the accompanying drawings, the present disclosure is not limited thereto.

Therefore, example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. The same or similar elements are designated by the same reference numerals throughout the specification unless otherwise specified.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In the present specification, where the terms “comprise,” “have,” “include,” and the like are used, one or more other elements may be added unless the term, such as “only,” is used. As used herein, the term “and/or” includes a single associated listed item and any and all of the combinations of two or more of the associated listed items. An expression such as “at least one of” when preceding a list of elements may modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

In construing an element or numerical value, the element or the numerical value is to be construed as including an error or tolerance range even where no explicit description of such an error or tolerance range is provided.

It will be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present. In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used.

Further, as used herein, when a layer, film, region, plate, or the like may be disposed “on” or “on a top” of another layer, film, region, plate, or the like, the former may directly contact the latter or another layer, film, region, plate, or the like may be disposed between the former and the latter. As used herein, when a layer, film, region, plate, or the like is directly disposed “on” or “on a top” of another layer, film, region, plate, or the like, the former directly contacts the latter and another layer, film, region, plate, or the like is not disposed between the former and the latter. Further, as used herein, when a layer, film, region, plate, or the like may be disposed “below” or “under” another layer, film, region, plate, or the like, the former may directly contact the latter or another layer, film, region, plate, or the like may be disposed between the former and the latter. As used herein, when a layer, film, region, plate, or the like is directly disposed “below” or “under” another layer, film, region, plate, or the like, the former directly contacts the latter and another layer, film, region, plate, or the like is not disposed between the former and the latter.

In descriptions of temporal relationships, for example, temporal precedent relationships between two events such as “after”, “subsequent to”, “before”, “next,” etc., another event may occur therebetween unless a more limiting term, “just,” “immediate(ly),” or “direct(ly)” (“directly after”, “directly subsequent”, “directly before”) is indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or overall combined with each other, and may be variously inter-operated with each other and driven technically as those skilled in the art can sufficiently understand. The embodiments may be implemented independently of each other and may be implemented together in an co-dependent relationship.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term “or” means “inclusive or” rather than “exclusive or”. That is, unless otherwise stated or clear from the context, the expression that “x uses a or b” means any one of natural inclusive permutations.

The terms used in the description below may be general and universal in the relevant art. However, there may be other terms depending on the development and/or change of technology, convention, preference of technicians, etc. Therefore, the terms used in the description below should not be understood as limiting the disclosure, and should be understood as examples of the terms for describing embodiments.

Further, in some example embodiments, a term may be arbitrarily selected by the applicant, and in this case, the detailed meaning thereof will be described in a corresponding description section. Therefore, such terms used in the description below may be understood based on the name of the terms, and the meaning of the terms and the contents throughout the Detailed Description.

As used herein, the term “halo” or “halogen” includes fluorine, chlorine, bromine, and iodine.

As used herein, the term “alkyl group” refers to both linear alkyl radicals and branched alkyl radicals. Unless otherwise specified, the alkyl group contains 1 to 20 carbon atoms, and includes methyl, ethyl, propyl, isopropyl, butyl, isobutyl, tert-butyl, etc. Further, the alkyl group may be optionally substituted.

As used herein, the term “cycloalkyl group” refers to a cyclic alkyl radical. Unless otherwise specified, the cycloalkyl group contains 3 to 20 carbon atoms, and includes cyclopropyl, cyclopentyl, cyclohexyl, and the like. Further, the cycloalkyl group may be optionally substituted.

As used herein, the term “alkenyl group” refers to both linear alkene radicals and branched alkene radicals. Unless otherwise specified, the alkenyl group contains 2 to 20 carbon atoms. Additionally, the alkenyl group may be optionally substituted.

As used herein, the term “cycloalkenyl group” refers to a cyclic alkenyl radical. Unless otherwise specified, the cycloalkenyl group contains 3 to 20 carbon atoms. Additionally, the cycloalkenyl group may be optionally substituted.

As used herein, the term “alkynyl group” refers to both linear alkyne radicals and branched alkyne radicals. Unless otherwise specified, the alkynyl group contains 2 to 20 carbon atoms. Additionally, the alkynyl group may be optionally substituted.

The terms “aralkyl group” and “arylalkyl group” as used herein are used interchangeably with each other and refer to an alkyl group having an aromatic group as a substituent. Further, the arylalkyl group may be optionally substituted.

The terms “aryl group” and “aromatic group” as used herein are used in the same meaning. The aryl group includes both a monocyclic group and a polycyclic group. The polycyclic group may include a “fused ring” in which two or more rings are fused with each other such that two carbons are common to two adjacent rings. Unless otherwise specified, the aryl group contains 6 to 60 carbon atoms. Further, the aryl group may be optionally substituted.

The term “heterocyclic group” as used herein means that at least one of carbon atoms constituting an aryl group, a cycloalkyl group, or an aralkyl group (arylalkyl group) is substituted by a heteroatom such as oxygen (O), nitrogen (N), sulfur (S), etc. Further, the heterocyclic group may be optionally substituted.

The term “carbon ring” as used herein may be used as a term including both “cycloalkyl group” as an alicyclic group and “aryl group” an aromatic group unless otherwise specified.

The terms “heteroalkyl group” and “heteroalkenyl group” as used herein mean that at least one of carbon atoms constituting an alkyl or an alkenyl group is substituted by a heteroatom such as oxygen (O), nitrogen (N), or sulfur (S). In addition, the heteroalkyl group and the heteroalkenyl group may be optionally substituted.

As used herein, the term “substituted” means that a substituent other than hydrogen (H) binds to corresponding carbon.

In some embodiments, a substituent may contain 1 to 30 carbon atoms unless there is a particular limitation on the number of carbon atoms. The carbon chain, if present in the substituent, may be linear or branched.

Unless specifically limited herein, the substituent may be deuterium, halogen, an alkyl group, a heteroalkyl group, an alkoxy group, an aryloxy group, an alkynyl group, an aryl group, a heteroaryl group, an acyl group, a carbonyl group, a carboxylic acid group, a nitrile group, a cyano group, an amino group, an alkylsilyl group, an arylsilyl group, a sulfonyl group, a phosphino group, and combinations thereof.

Subjects and substituents as defined in the present disclosure may be the same as or different from each other unless otherwise specified.

As used herein, “n substitution (n≥1)”, for example, “mono-substitution”, “di-substitution”, “tri-substitution”, and “tetra-substitution”, refers to the number of substitution site(s) where the substituent instead of hydrogen binds to the carbon atom in a specific compound or a portion of the compound. Even when “unsubstituted” may not be specified herein, this may be interpreted as hydrogen binding to a carbon atom unless a substituent binds thereto.

Hereinafter, example embodiments of an organometallic compound according to the present disclosure and of an organic light-emitting diode including the same will be described in detail.

An organometallic compound represented by Chemical Formula 1 of the present disclosure includes an arylalkyl moiety as compared to conventional phenyl-pyridine metal complex or benzofuropyridine-pyridine metal complex. The present disclosure has been completed by experimentally confirming that when the organometallic compound represented by the Chemical Formula 1 is used as a dopant material of a phosphorescent light-emitting layer of the organic light-emitting diode, the light-emitting efficiency and lifetime of the organic light-emitting diode may be improved, and an operation voltage thereof may be lowered.

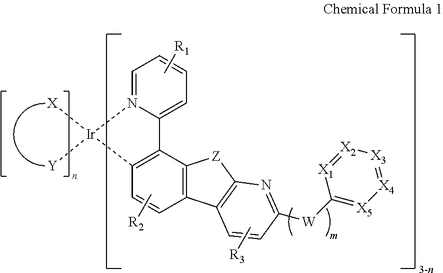

wherein in the Chemical Formula 1,
Z may represent one of O (oxygen), S (sulfur) or Se (selenium), each W may independently represent C(R₄)₂,
m may be an integer of 1 to 5,
each of X₁, X₂, X₃, X₄, and X₅ may independently represent N or CR₅.

In the above Chemical Formula 1, each of R₁, R₂, and R₃ represents a substituent that may bind to a moiety. As used herein, the definitions of R₁, R₂, and R₃ are applied to a case where R₁, R₂, and R₃ are present. When R₁, R₂, and R₃ are not present, the moiety is unsubstituted (e.g., without the substituent), and hydrogen basically binds thereto.

R₁ may represent mono-substitution, di-substitution, tri-substitution or tetra-substitution (i.e., (R₁)ₚ, where p is 0 to 4). Each of R₂ and R₃ may independently represent mono-substitution, or di-substitution (i.e., (R₂)_{q}, where q is 0 to 2, (R₃)ᵣ, where r is 0 to 2).

Each of R₁ to R₃ may independently represent one selected from the group consisting of deuterium, halogen, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, and phosphino.

Each R₄ may independently represent one selected from the group consisting of hydrogen, deuterium, halogen, and a C1 to C20 linear or branched alkyl group.

Each R₅ may independently represent one selected from the group consisting of hydrogen, deuterium, halogen, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, and phosphino,
optionally, two adjacent R₁ groups, when present, may bind to each other to form a cycloalkyl, cycloalkenyl, aryl or arylalkyl,
   two adjacent R₂ groups, when present, optionally bind to each other to form a cycloalkyl, cycloalkenyl, aryl or arylalkyl,
   two adjacent R₃ groups, when present, optionally bind to each other to form a cycloalkyl, cycloalkenyl, aryl or arylalkyl,
   two adjacent R₅ groups, when present, optionally bind to each other to form a cycloalkyl, cycloalkenyl, aryl or arylalkyl.
   n may be an integer from 0 to 2.

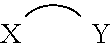

may be a bidentate ligand.

According to an example embodiment of the present disclosure,

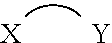

is an auxiliary ligand, and may have a structure represented by one of Chemical Formula 2 or Chemical Formula 3. In some embodiments,

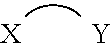

may be a bidentate ligand having a phenyl-pyridine structure represented by the Chemical Formula 2:

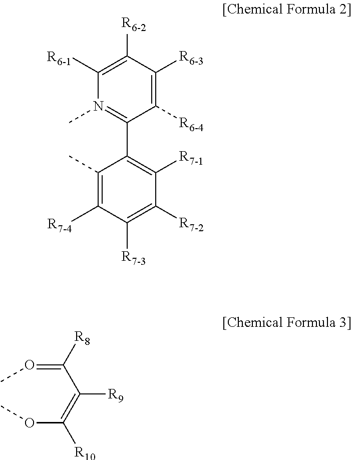

In the Chemical Formula 2, each of R₆₋₁, R₆₋₂, R₆₋₃, R₆₋₄, R₇₋₁, R₇₋₂, R₇₋₃, and R₇₋₄ may independently represent one selected from the group consisting of hydrogen, deuterium, a C1 to C5 linear alkyl group, a C1 to C5 branched alkyl group, a C6 to C20 aryl group, and a C7 to C30 arylalkyl group. At least one hydrogen of the C1 to C5 linear alkyl group, the C1 to C5 branched alkyl group, the C6 to C20 aryl group, or the C7 to C30 arylalkyl group selected as R₆₋₁, R₆₋₂, R₆₋₃, R₆₋₄, R₇₋₁, R₇₋₂, R₇₋₃ or R₇₋₄ may be substituted by deuterium or halogen.

Optionally, two adjacent groups among R₆₋₁, R₆₋₂, R₆₋₃, and R₆₋₄ may bind to each other to form a ring structure. Two adjacent groups among R₇₋₁, R₇₋₂, R₇₋₃, and R₇₋₄ may bind to each other to form a ring structure.

In the Chemical Formula 3, each of R₈, R₉, and R₁₀ may independently represent one selected from the group consisting of hydrogen, deuterium, a C1 to C5 linear alkyl group and a C1 to C6 branched alkyl group. At least one hydrogen of the C1 to C5 linear alkyl group or the C1 to C5 branched alkyl group selected as R₈, R₉ or R₁₀ may be substituted by deuterium or a halogen.

Optionally, two adjacent groups among R₈, R₉, and R₁₀ may bind to each other to form a ring structure.

According to an example embodiment of the present disclosure, n in the Chemical Formula 1 may be one of integers from 0 to 2. In some embodiments, for example, the compound represented by the above Chemical Formula 1 may have a heteroleptic structure where n in the Chemical Formula 1 is 1. For example, the compound represented by the above Chemical Formula 1 may have a heteroleptic structure where n in the Chemical Formula 1 is 2.

According to an example embodiment of the present disclosure, R₁ may not be present or, when present, R₁ may be or represent mono-substitution or di-substitution.

According to an example embodiment of the present disclosure, when R₁ is present, each R₁ may independently represent one of a C1 to C10 linear alkyl group, a C1 to C10 branched alkyl group, a C6 to C20 aryl group, and a C7 to C30 arylalkyl group. In this regard, optionally, at least one hydrogen of the C1 to C10 linear alkyl group, the C1 to C10 branched alkyl group, the C6 to C20 aryl group or the C7 to C30 arylalkyl group selected as R₁ may be substituted by deuterium.

According to an example embodiment of the present disclosure, when R₁ represents di-substitution and two R₁s are adjacent to each other, the two R₁s may bind to each other to form a ring structure, for example, a 5-membered or 6-membered cycloalkyl group. Optionally, at least one hydrogen of the cycloalkyl group may be substituted by deuterium.

According to an example embodiment of the present disclosure, R₂ may be absent.

According to an example embodiment of the present disclosure, R₃ may be absent.

According to an example embodiment of the present disclosure, at least three of X₁, X₂, X₃, X₄, and X₅ may be CR₅. In some embodiments, at least four thereof may be CR₅. In some embodiments, all of X₁, X₂, X₃, X₄, and X₅ may be CR₅. In some embodiments, R₅ may be hydrogen, deuterium, or a C1 to C10 linear or branched alkyl group. Optionally, at least two R₅s may be present and two adjacent R₅s may be fused with each other to form an alicyclic or aromatic ring structure. Optionally, one or more hydrogens of R₅ may be substituted by deuterium.

According to an example embodiment of the present disclosure, Z may be O (oxygen).

According to an example embodiment of the present disclosure, the compound represented by the Chemical Formula 1 may be used as a green phosphorescent material. However, the present disclosure is not necessarily limited thereto.

A specific example of the compound represented by the Chemical Formula 1 of the present disclosure may include or may be at least one selected from the group consisting of following Compound 1 to Compound 372. However, the specific example of the compound represented by the Chemical Formula 1 of the present disclosure is not limited thereto as long as it meets the above definition of the Chemical Formula 1:

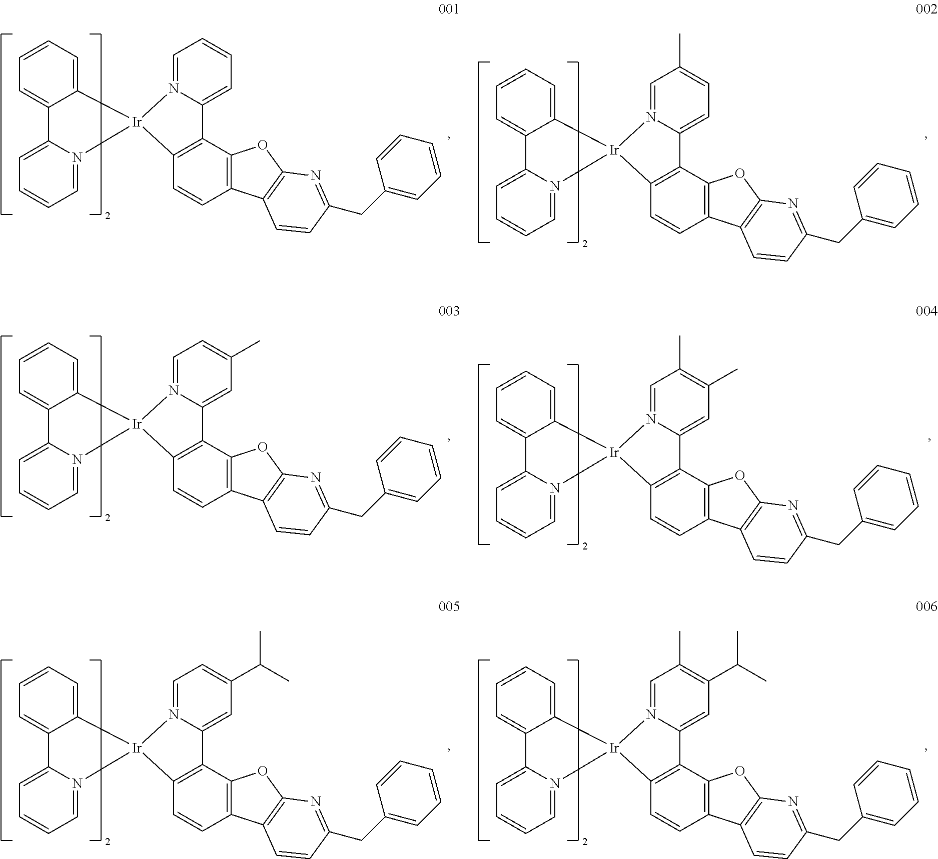

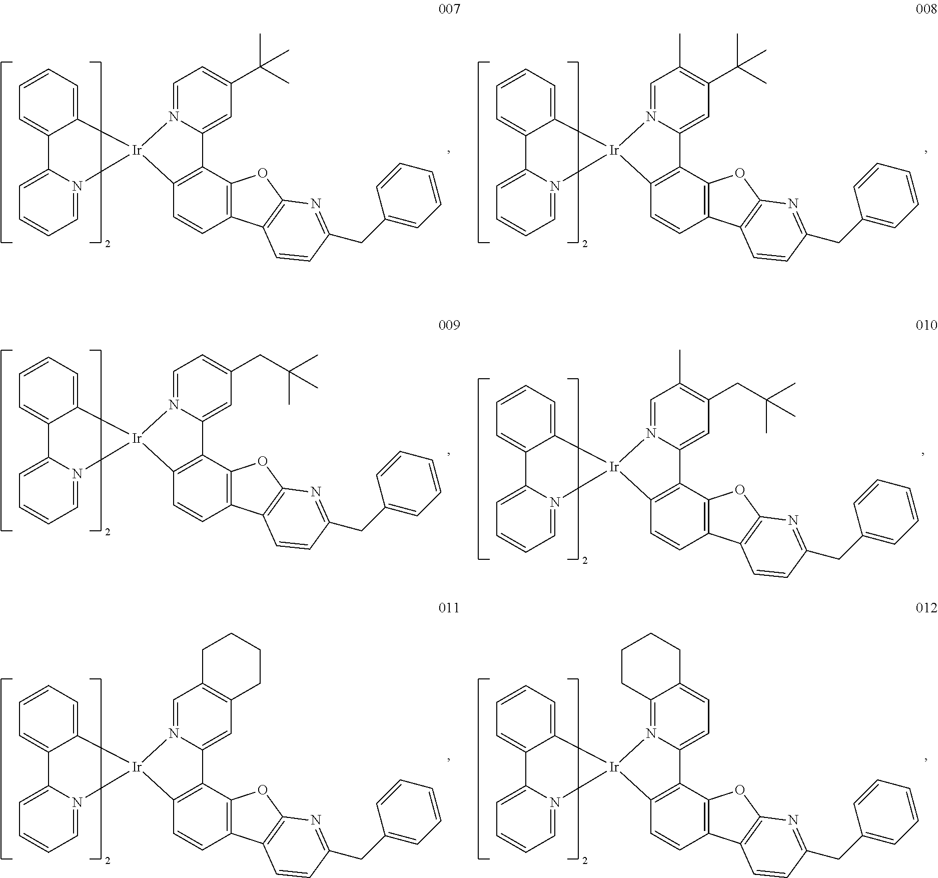

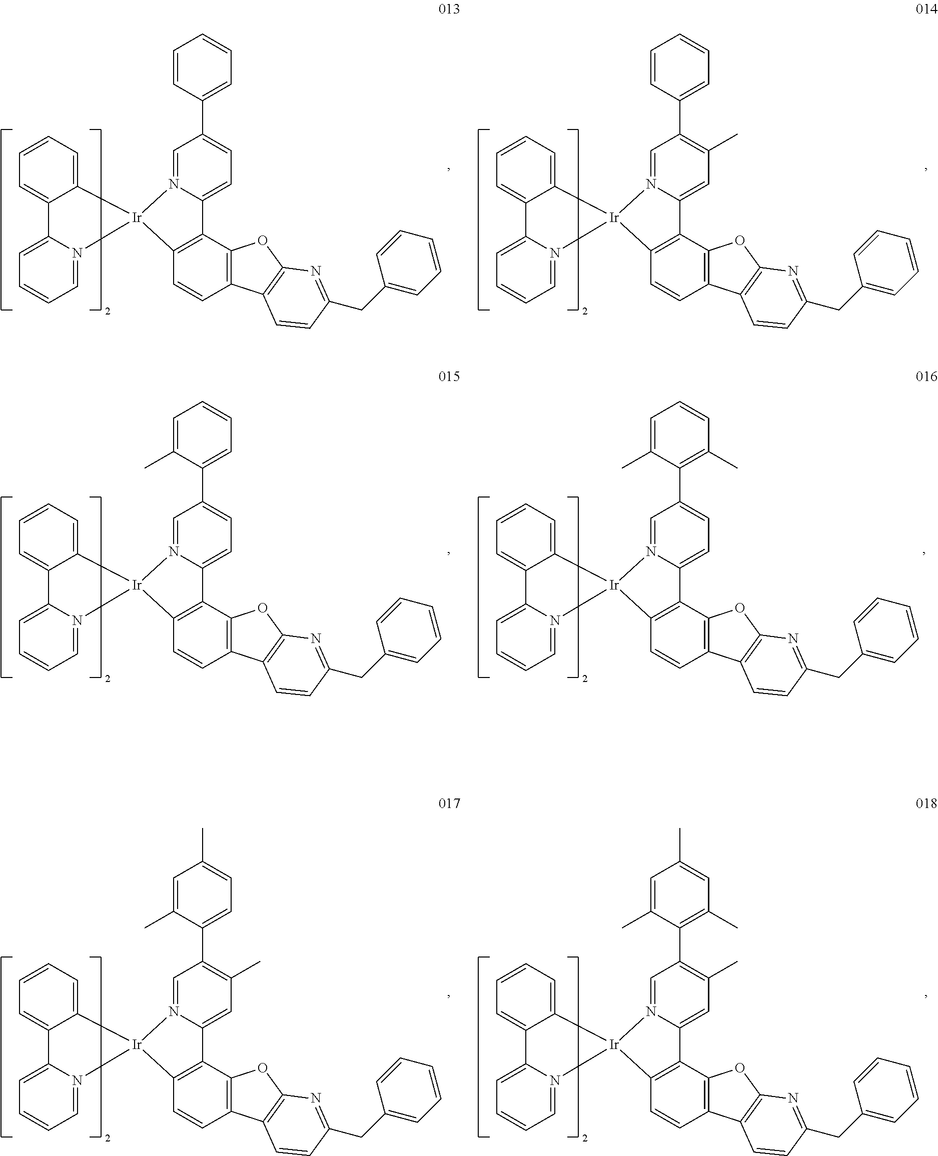

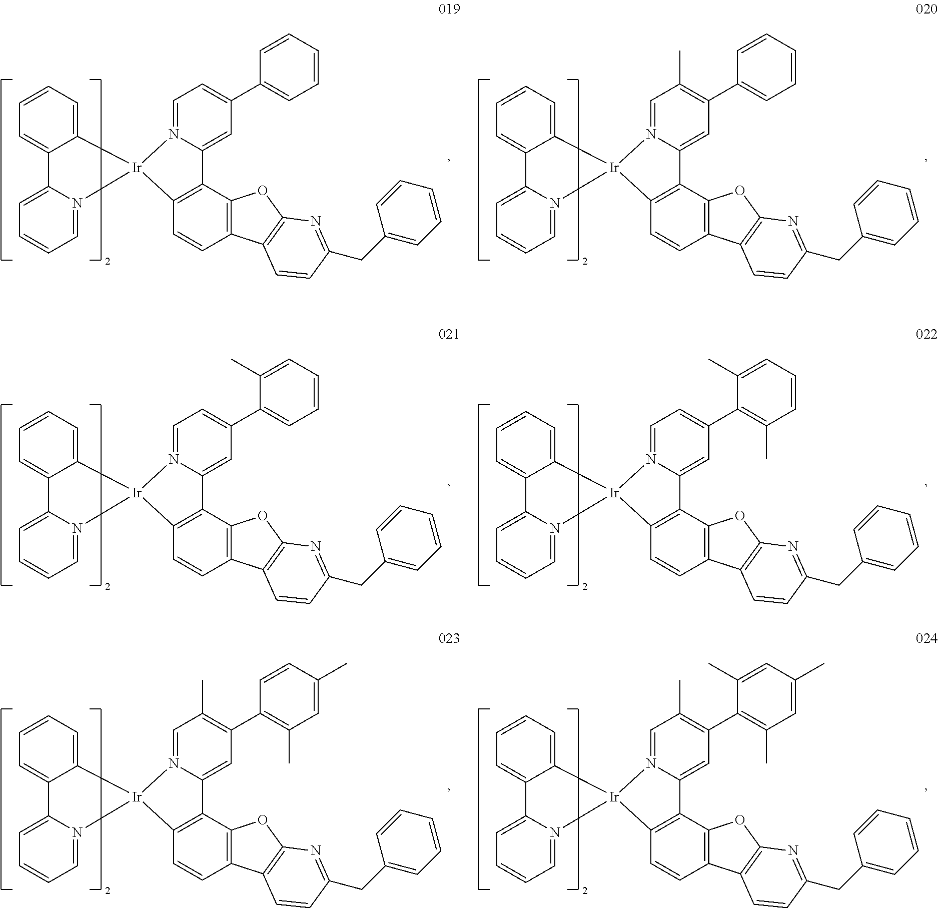

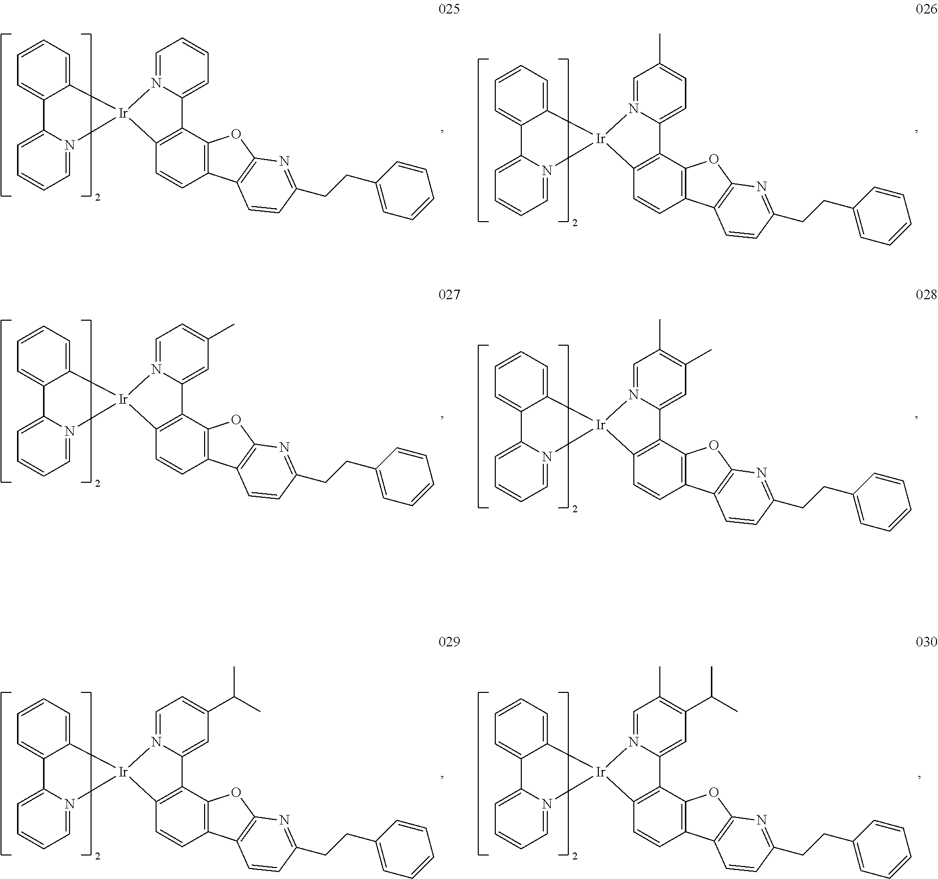

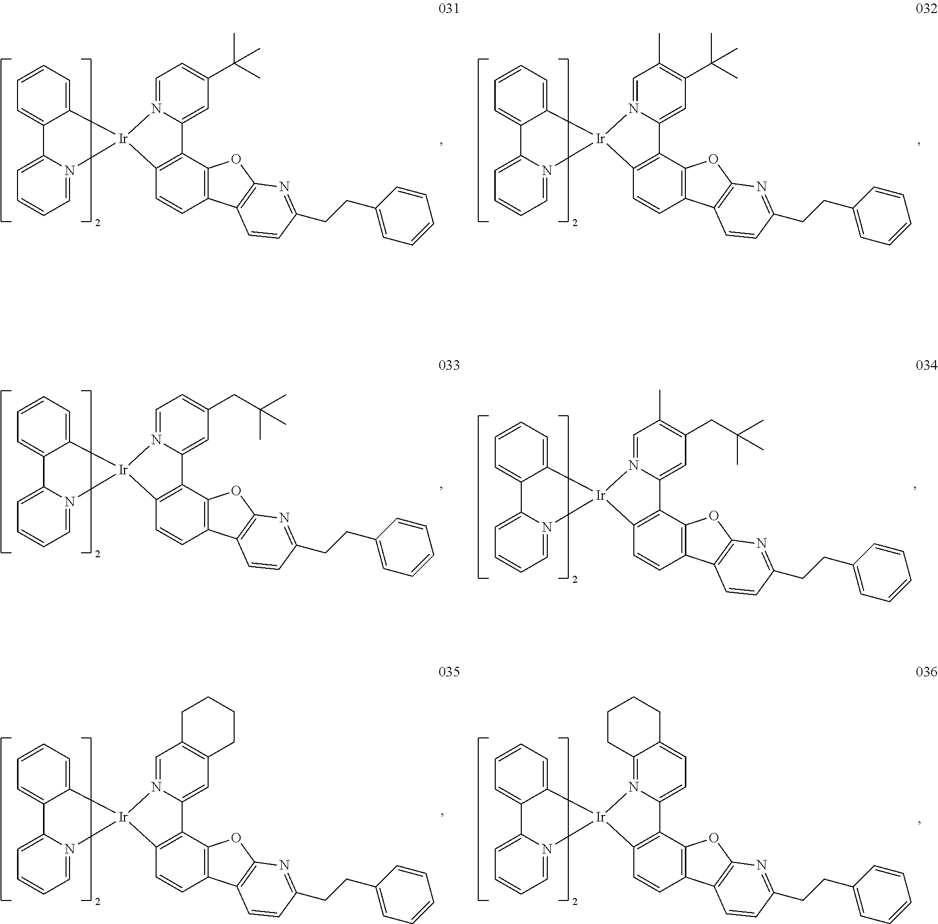

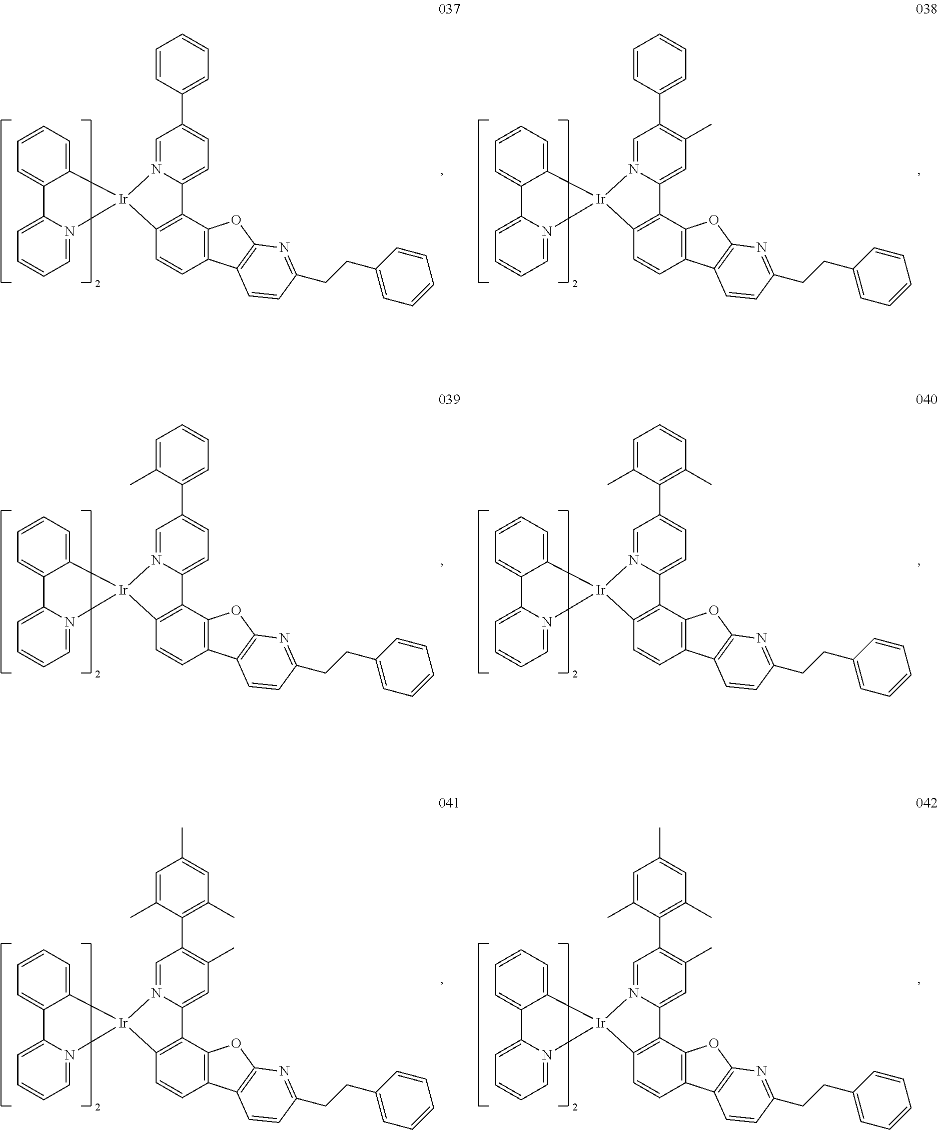

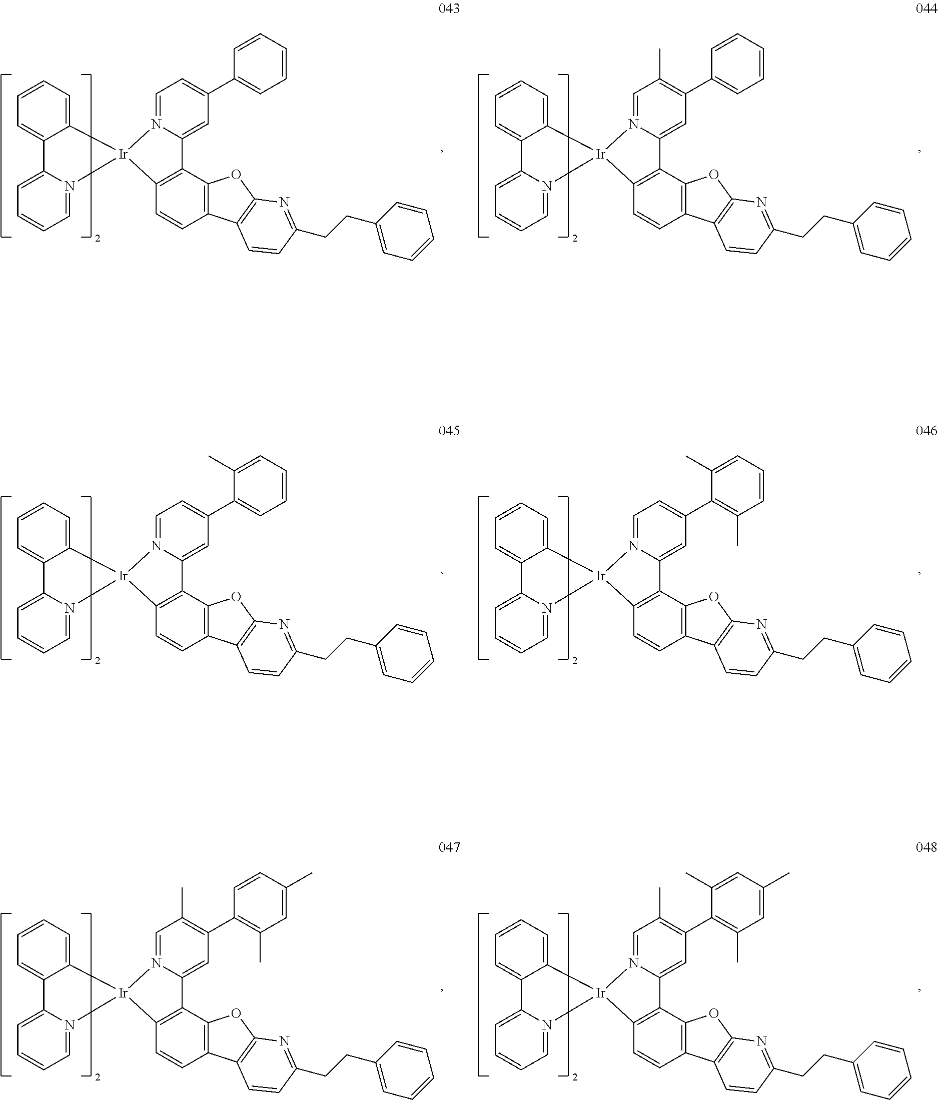

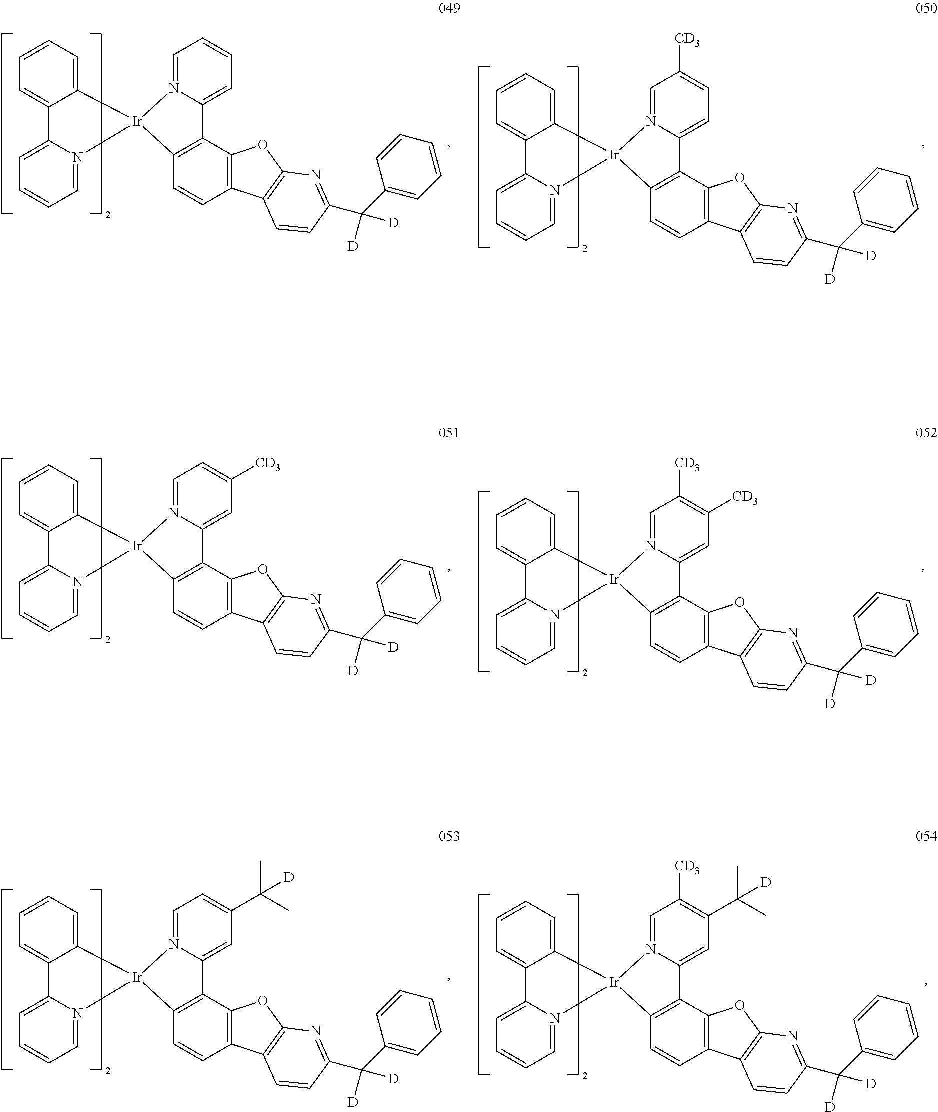

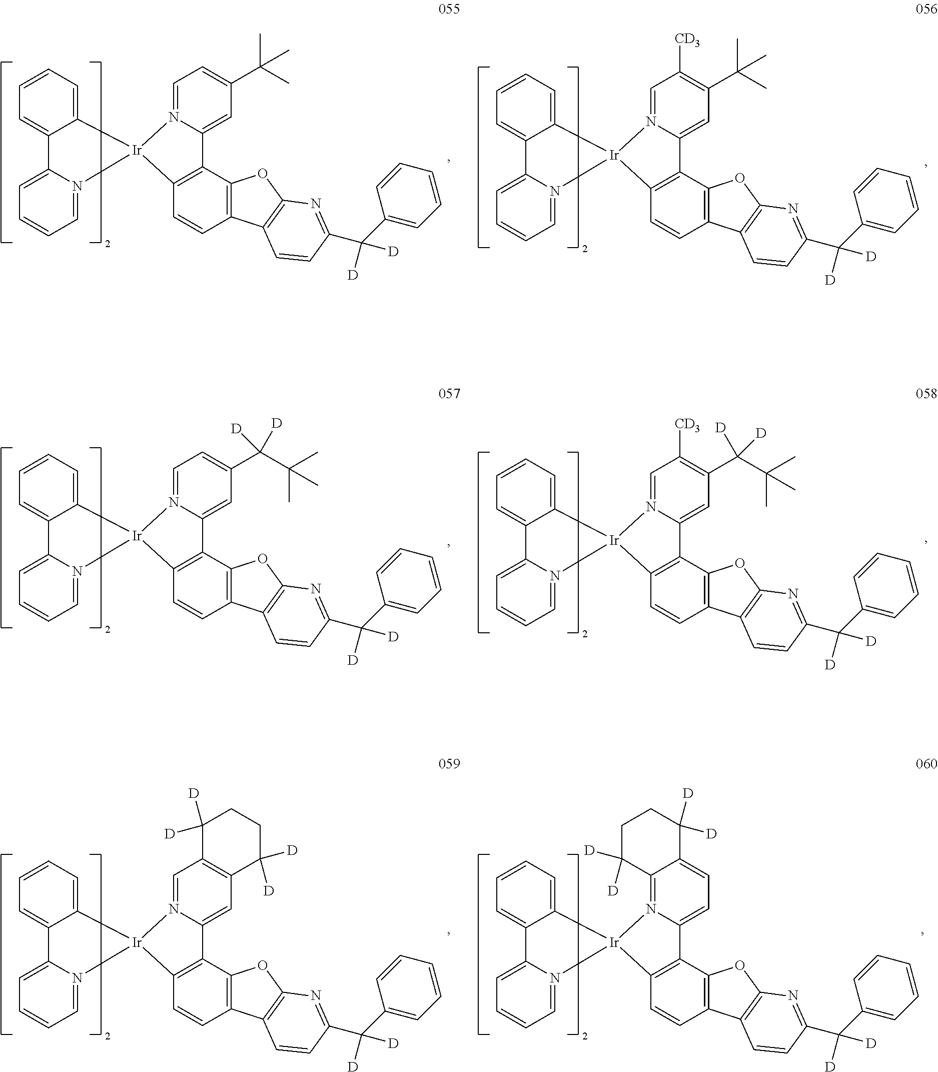

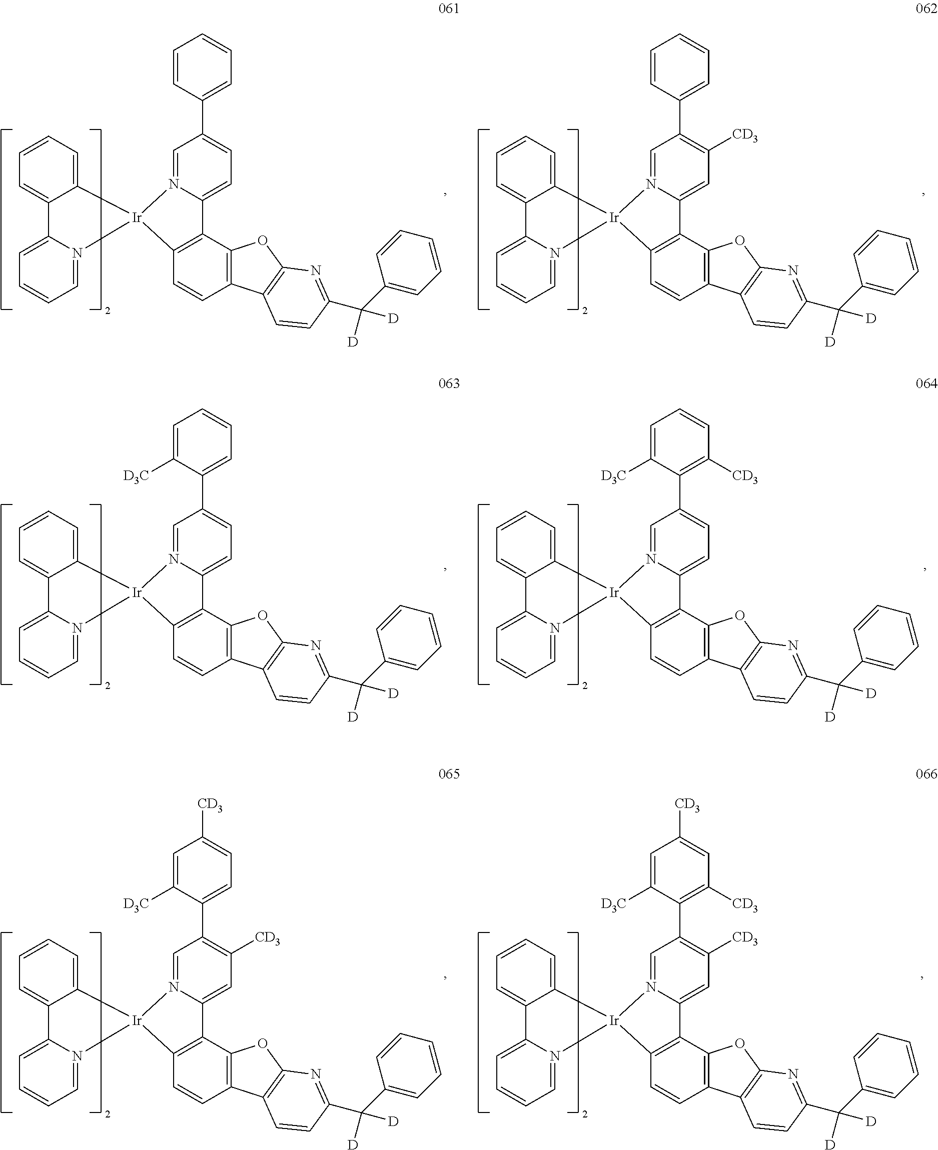

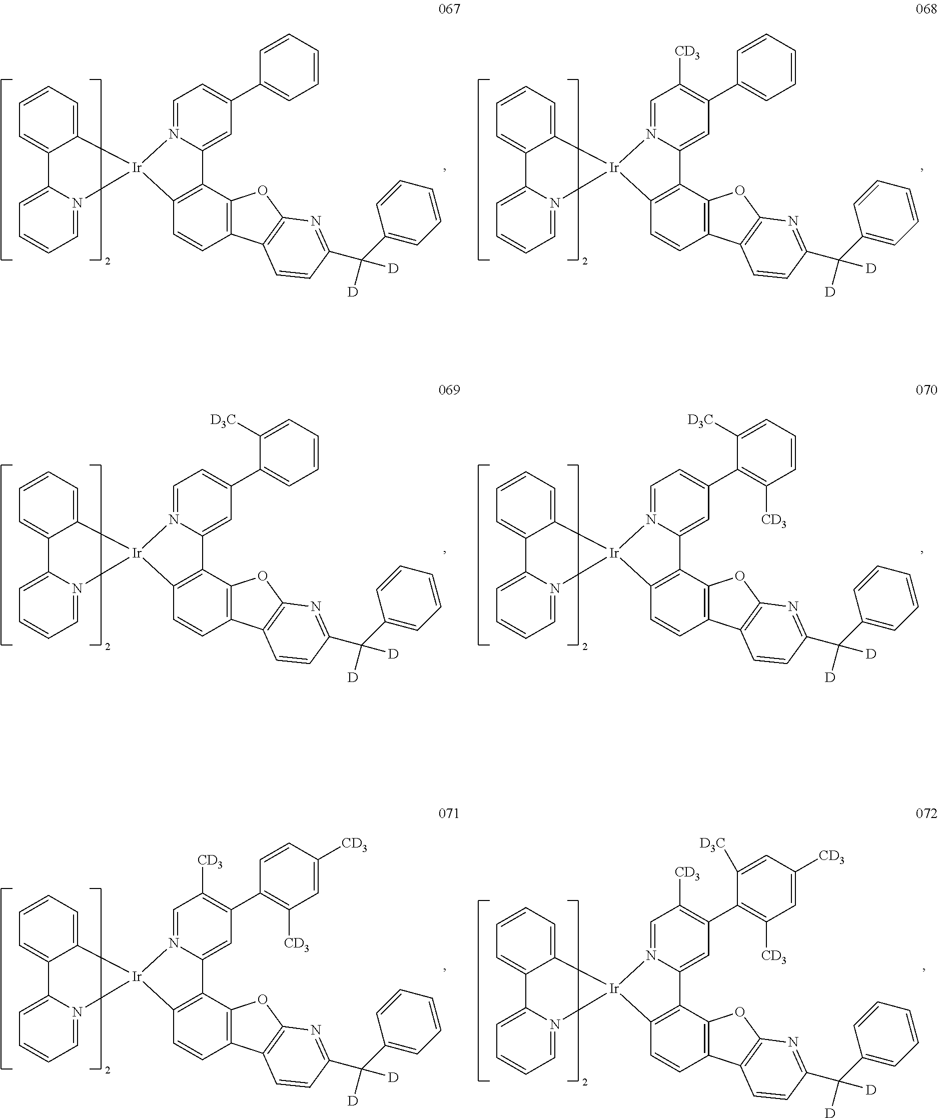

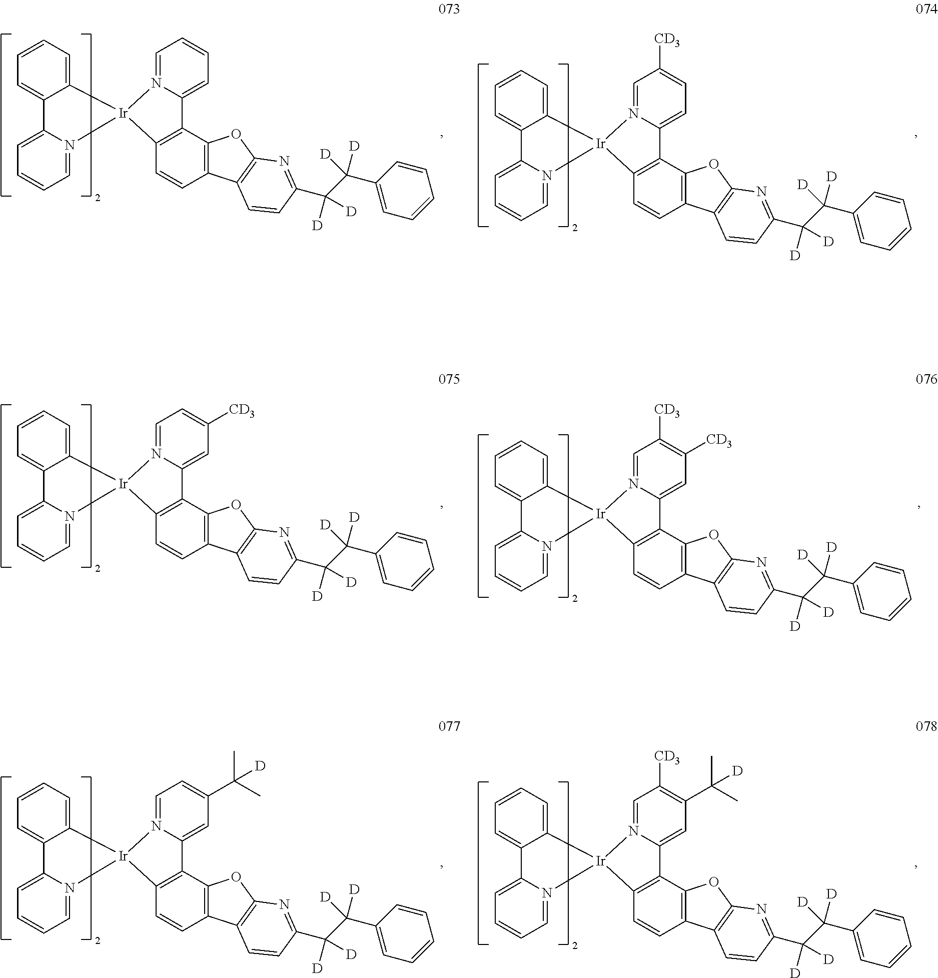

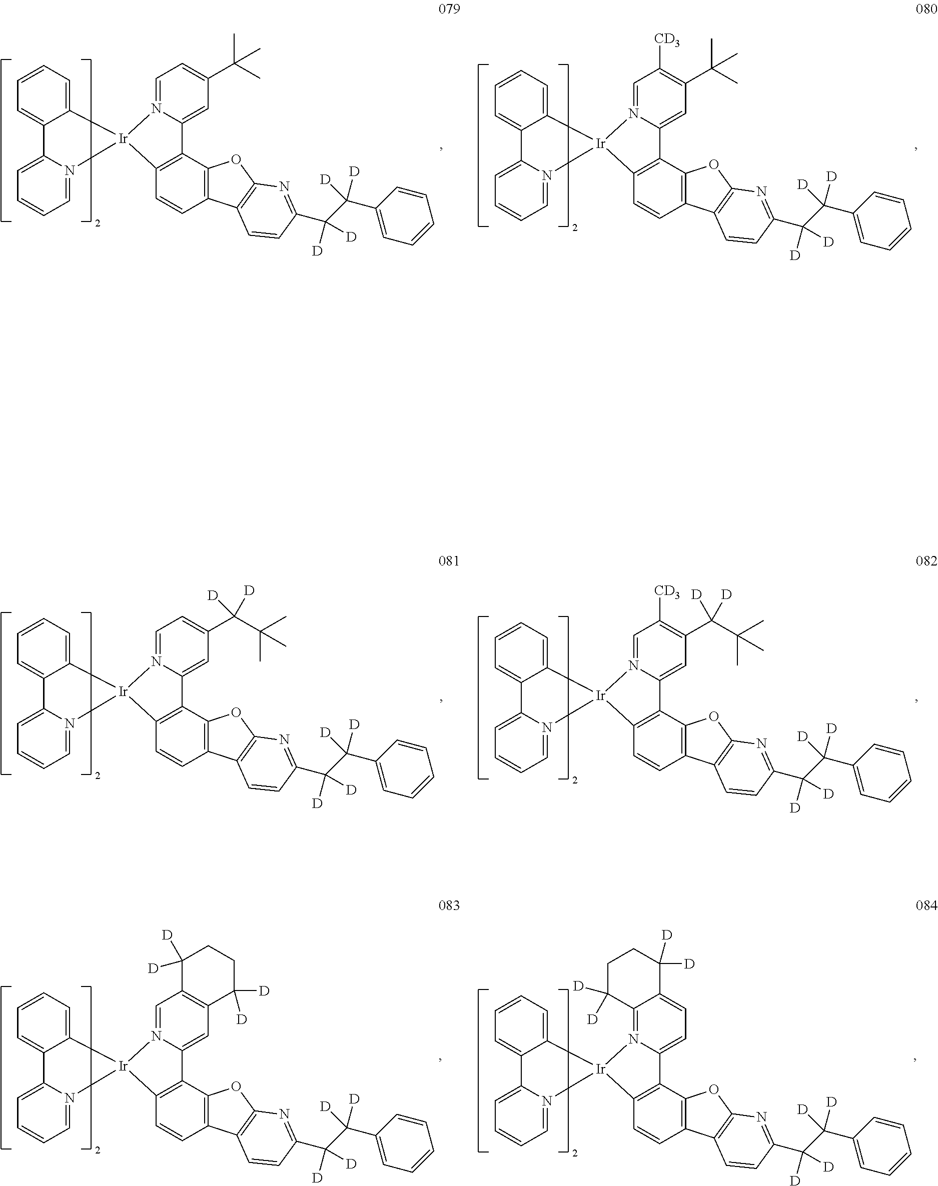

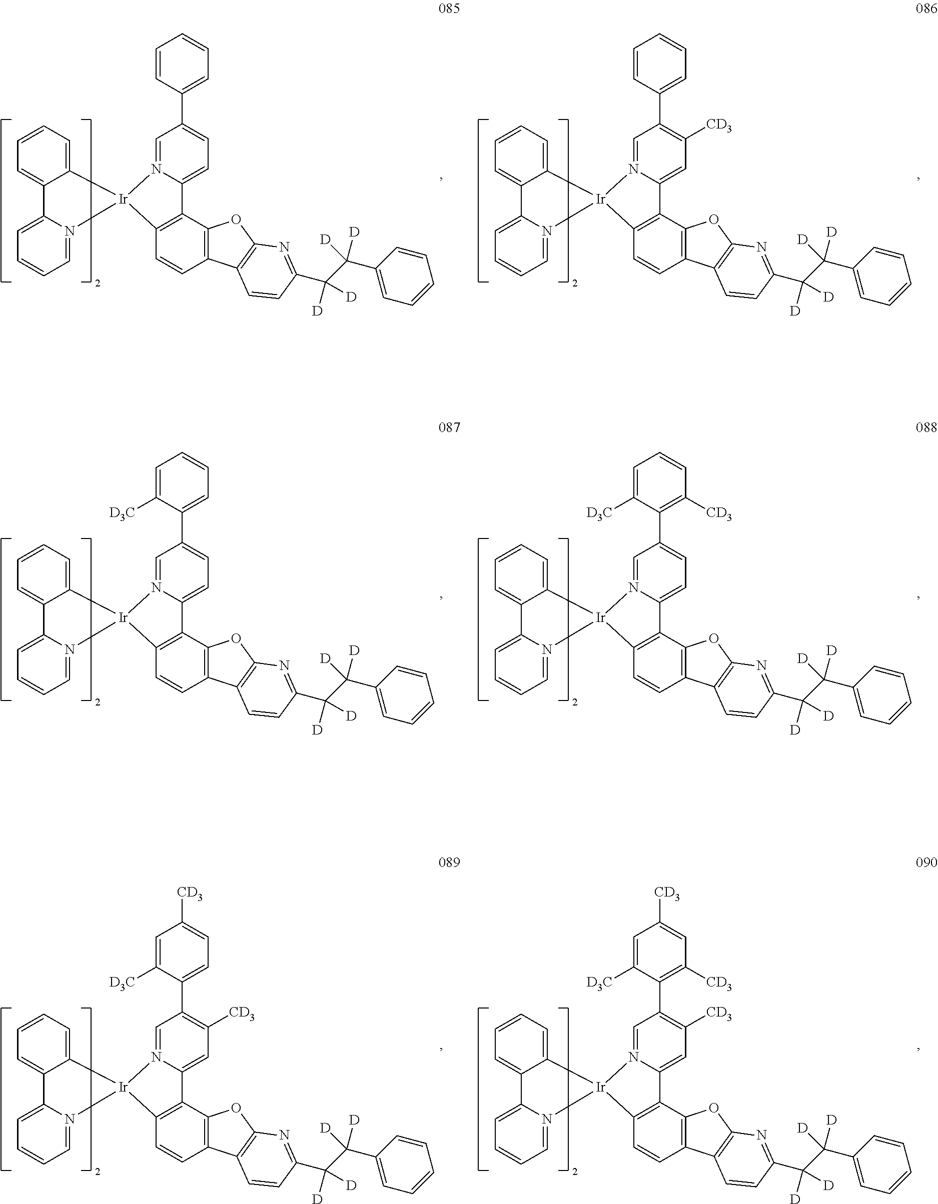

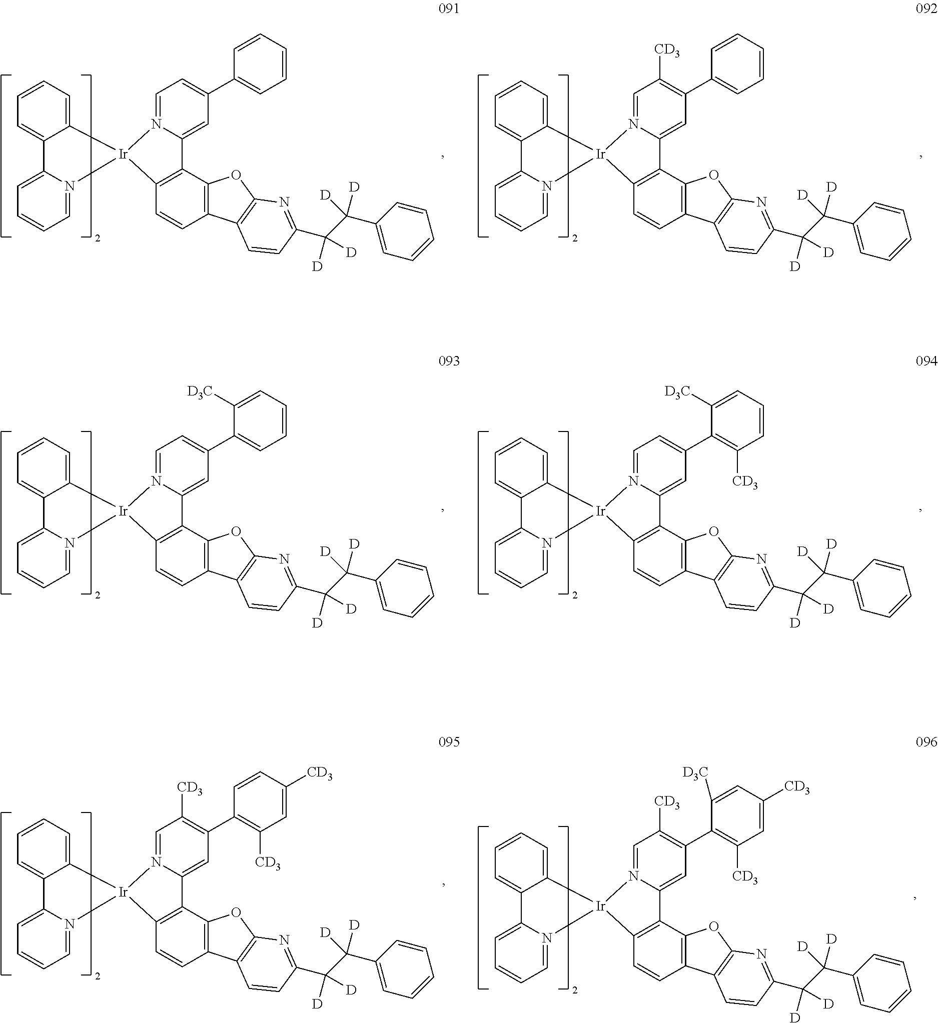

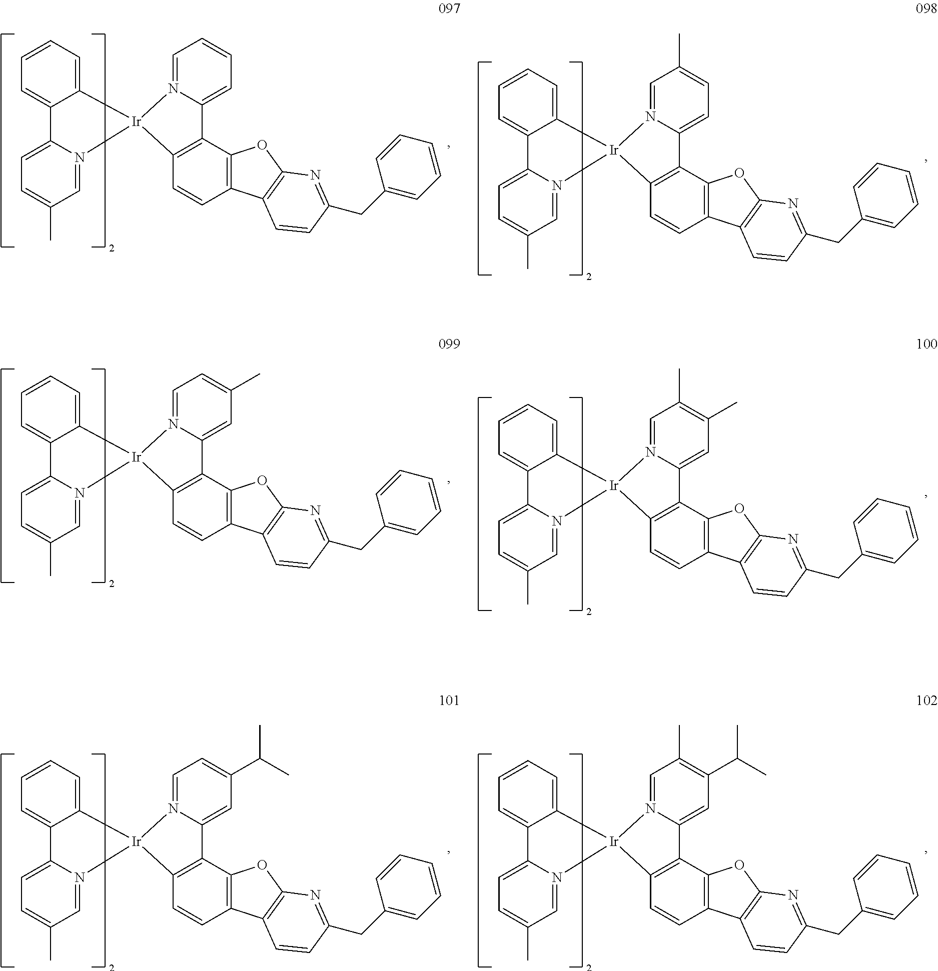

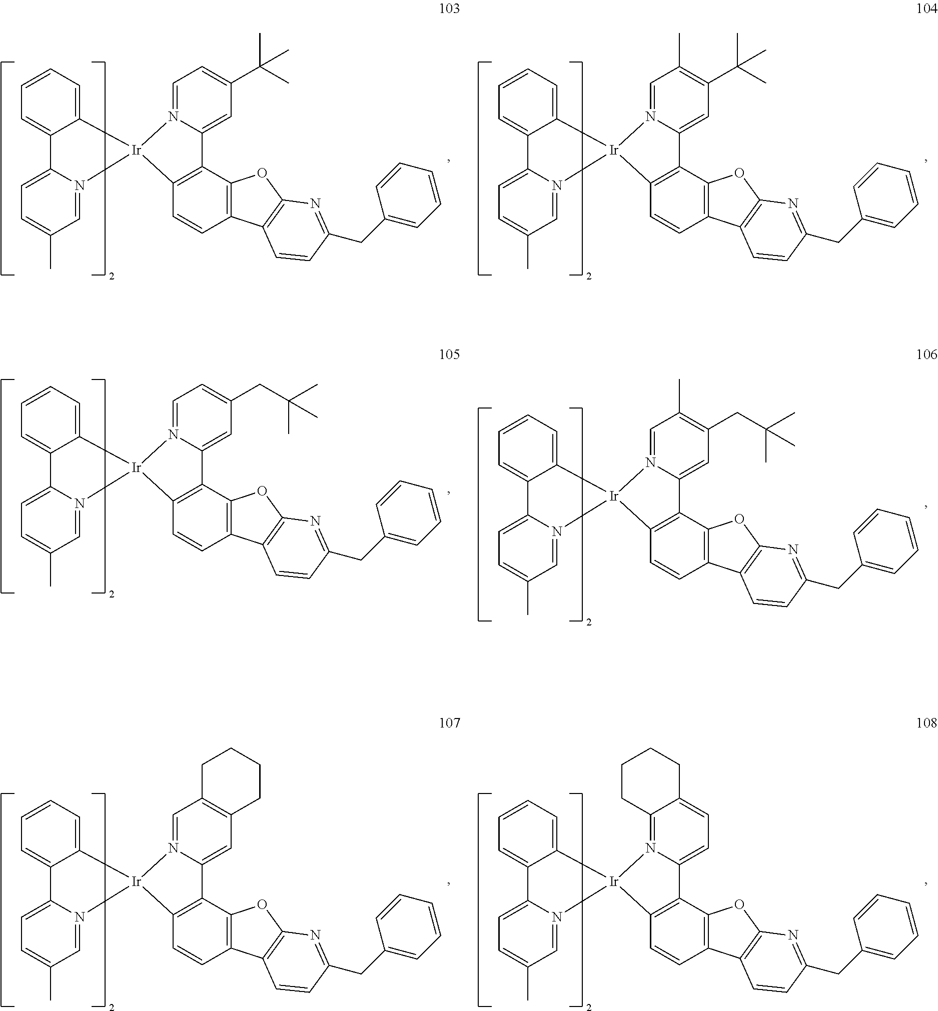

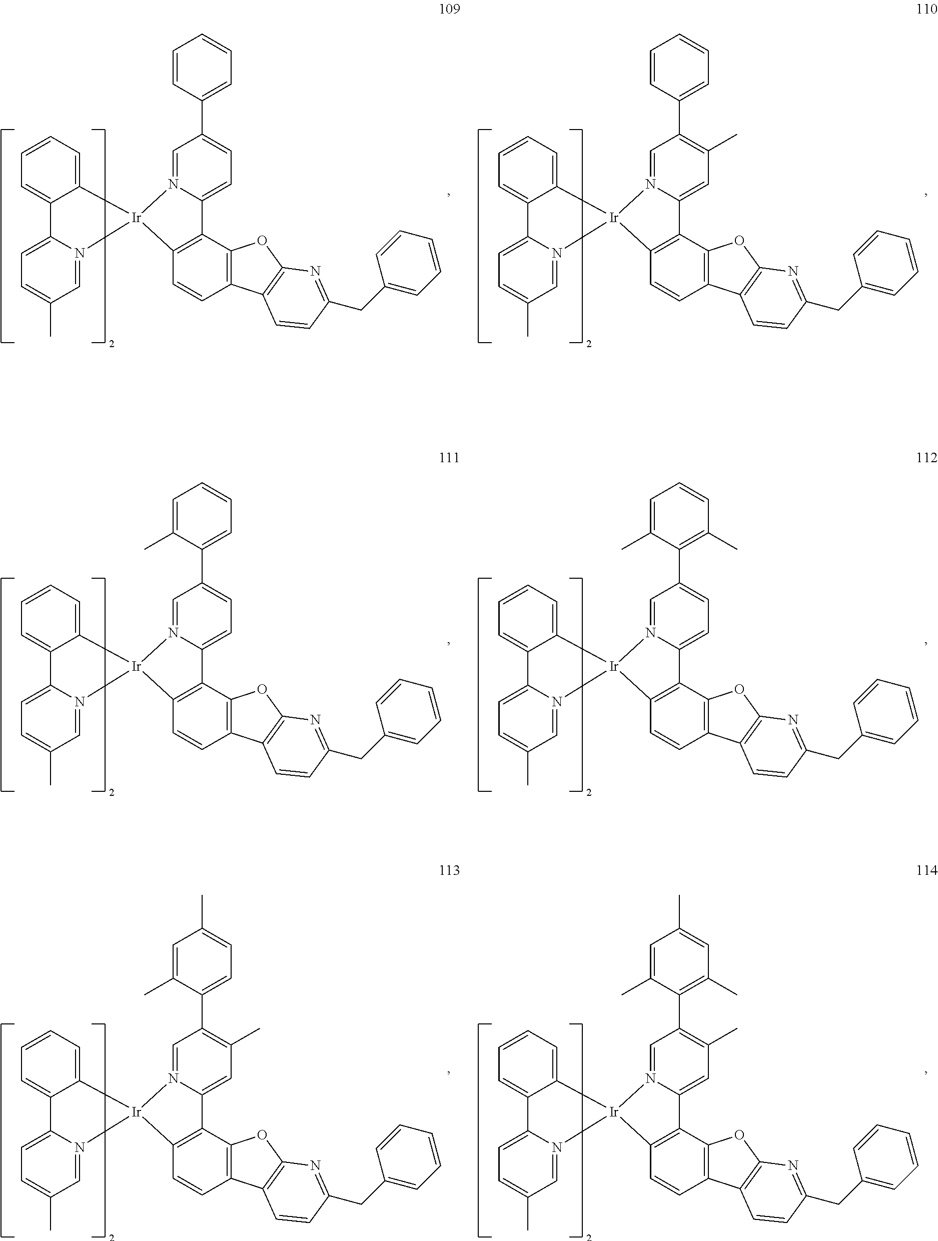

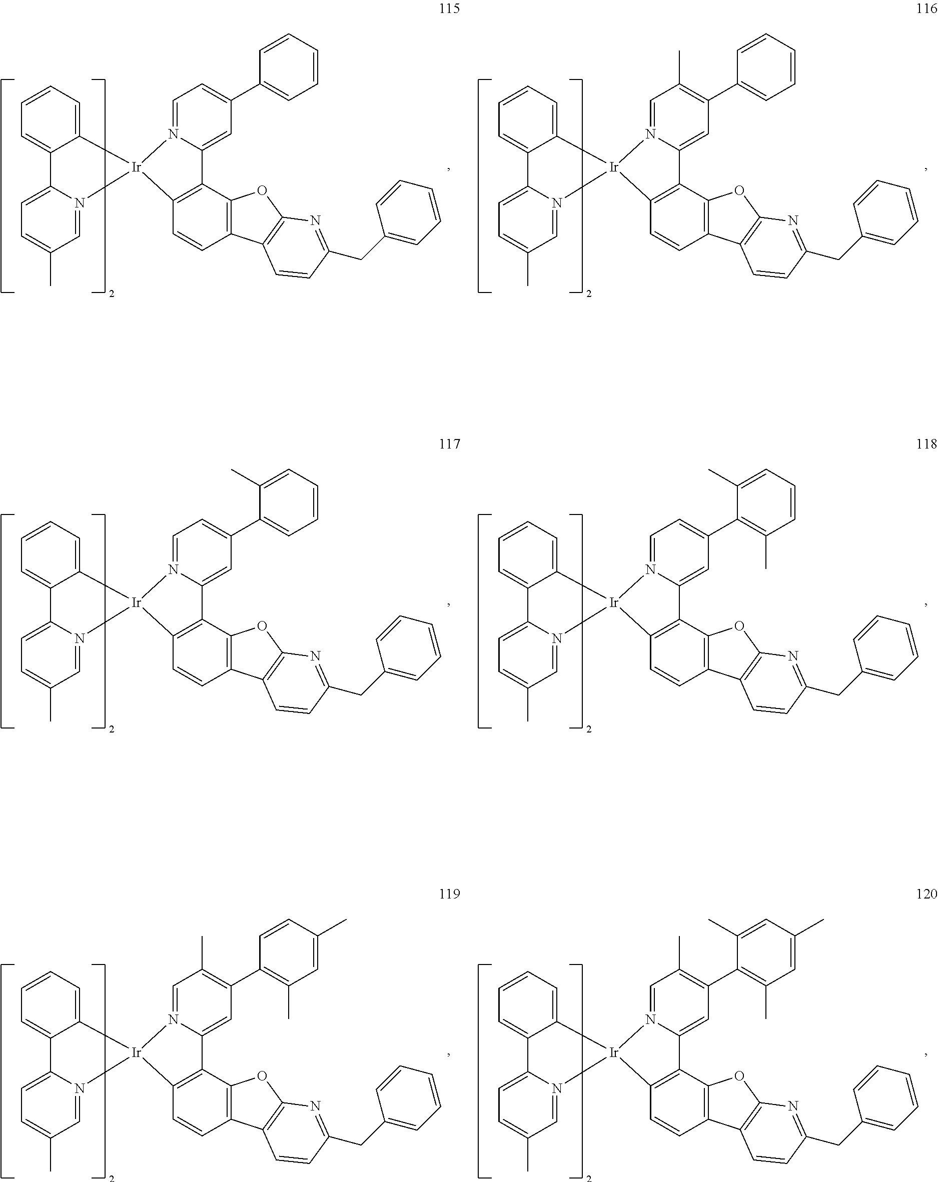

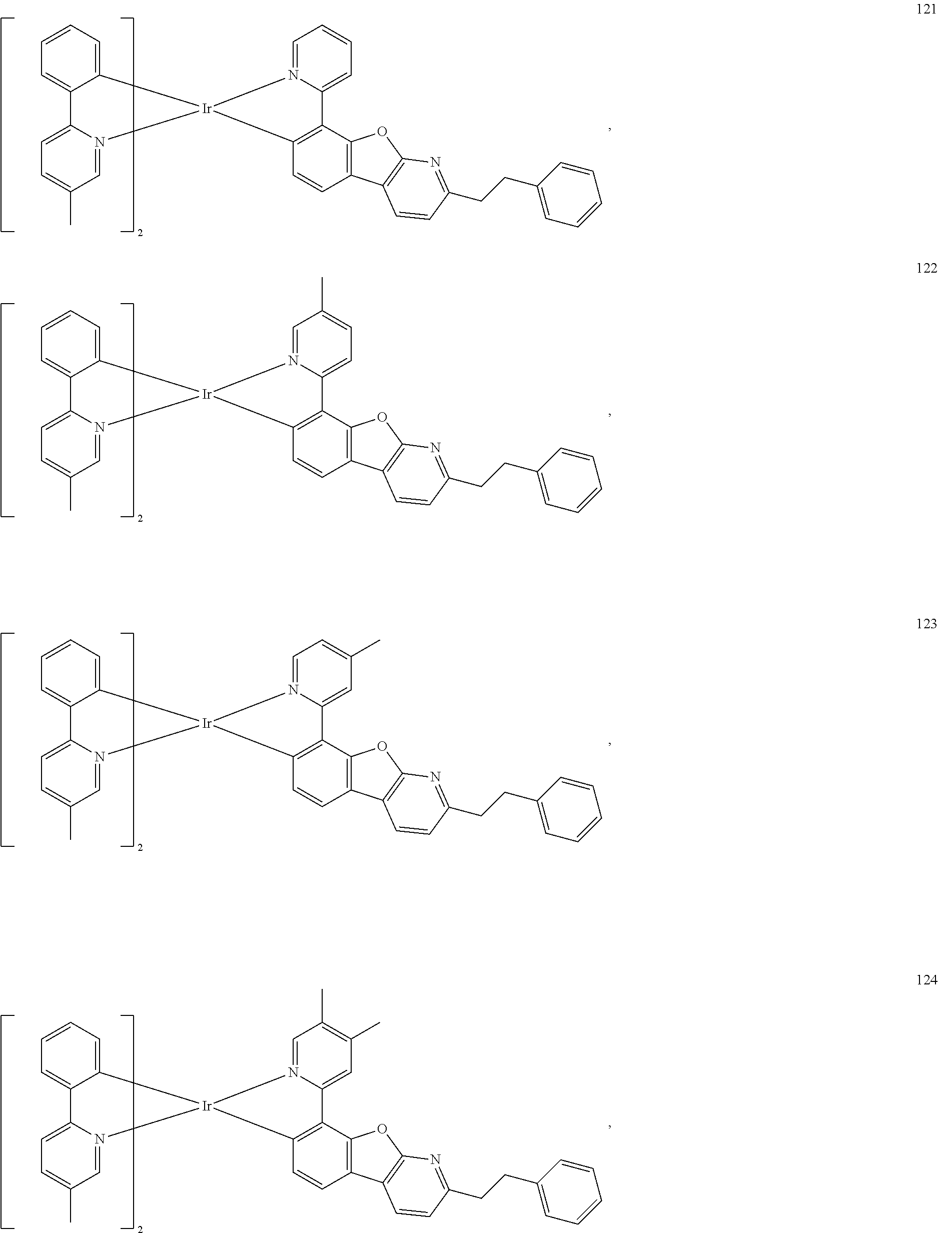

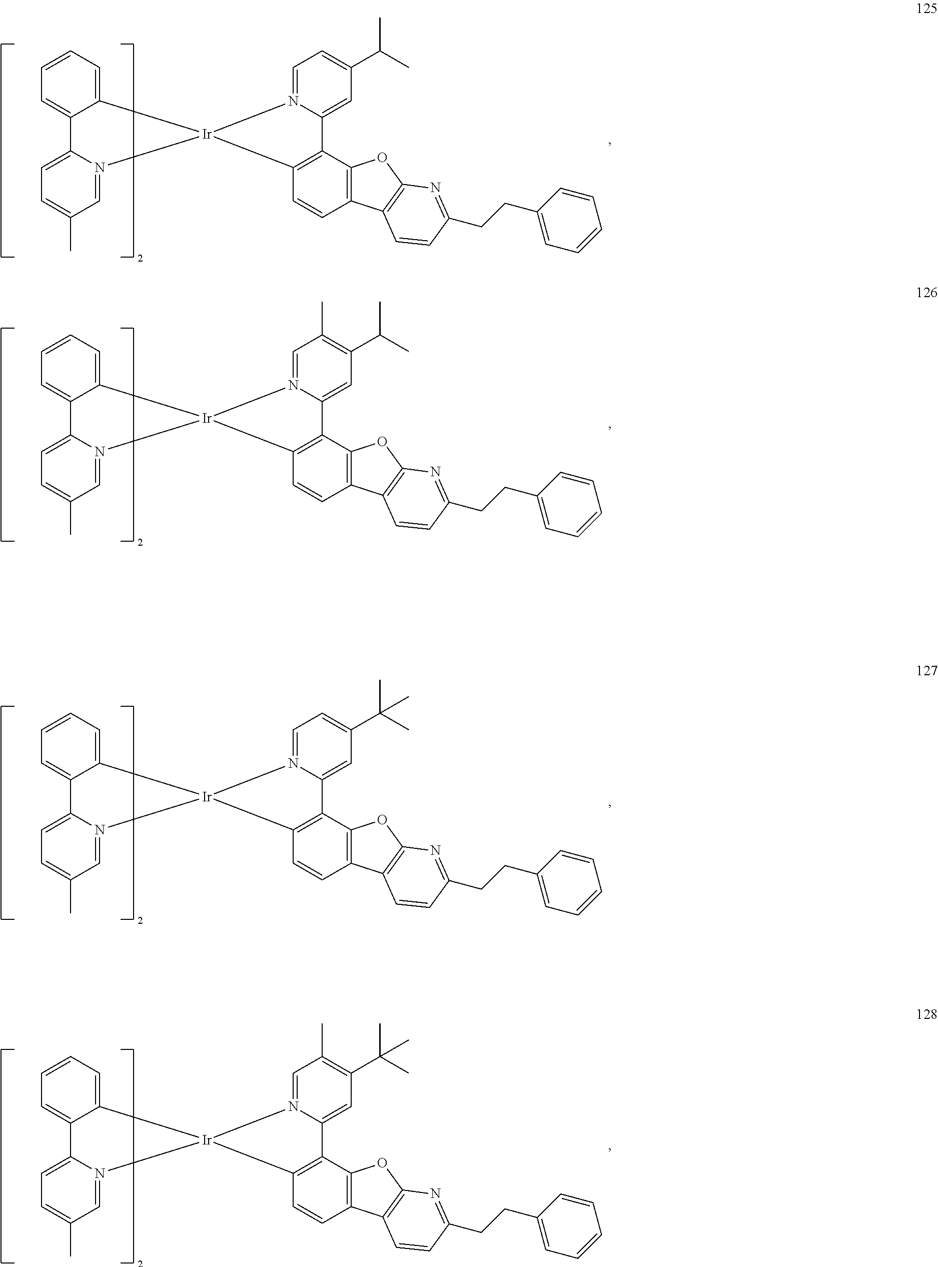

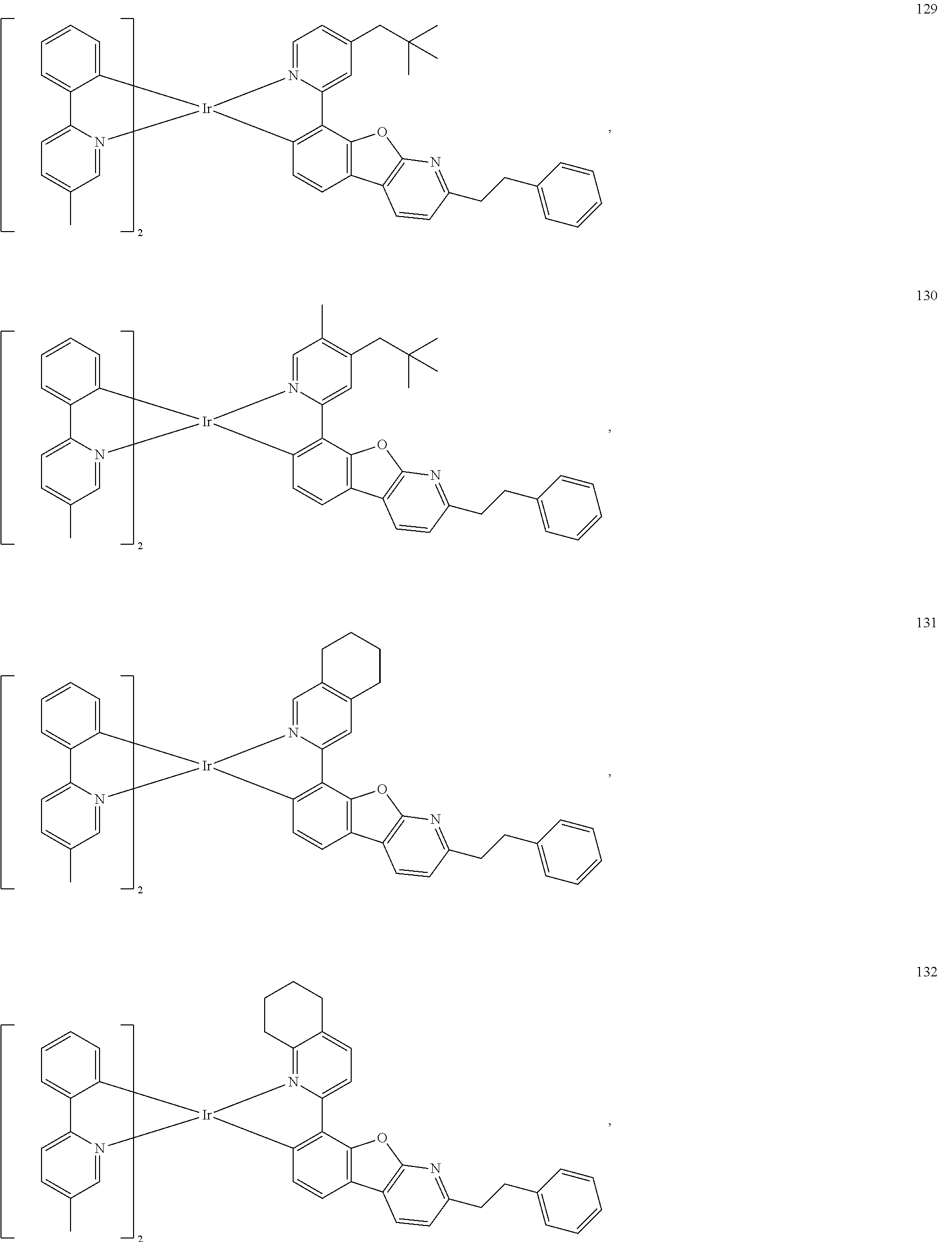

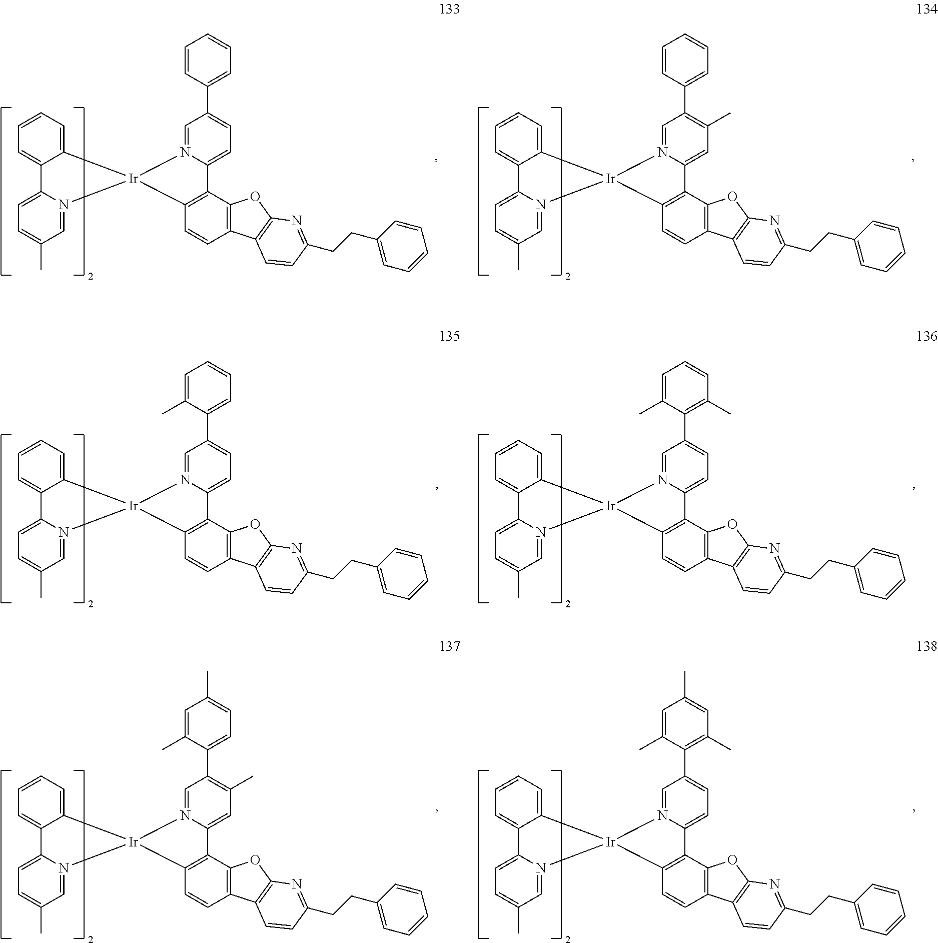

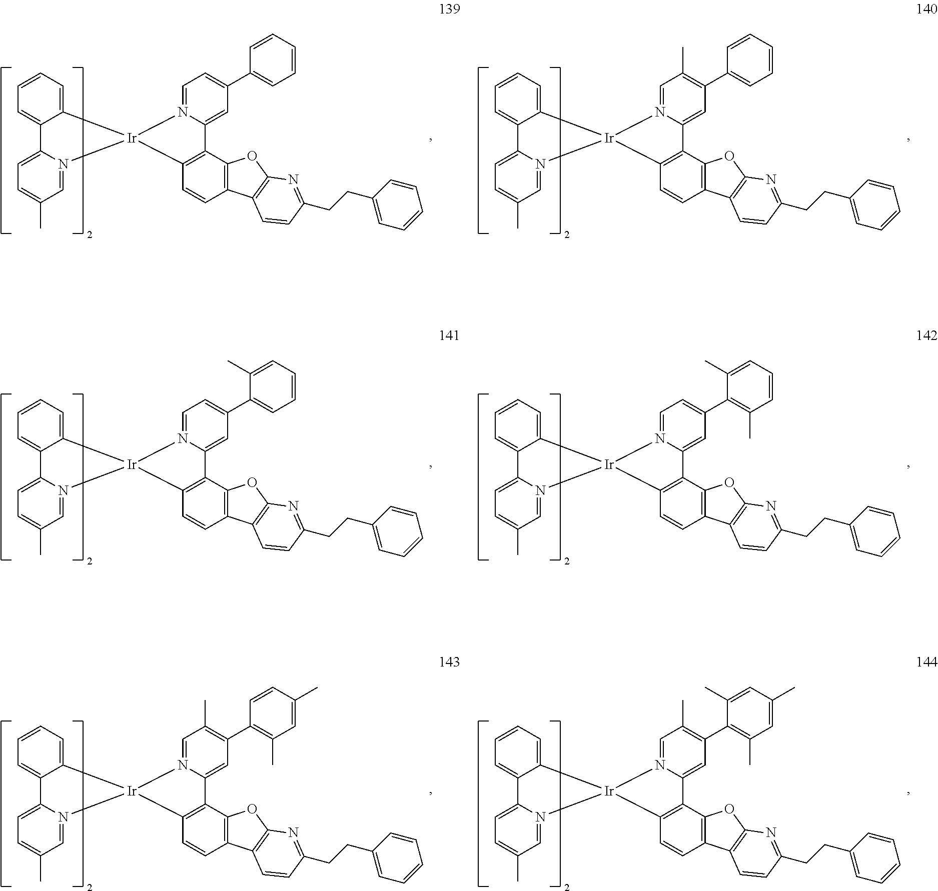

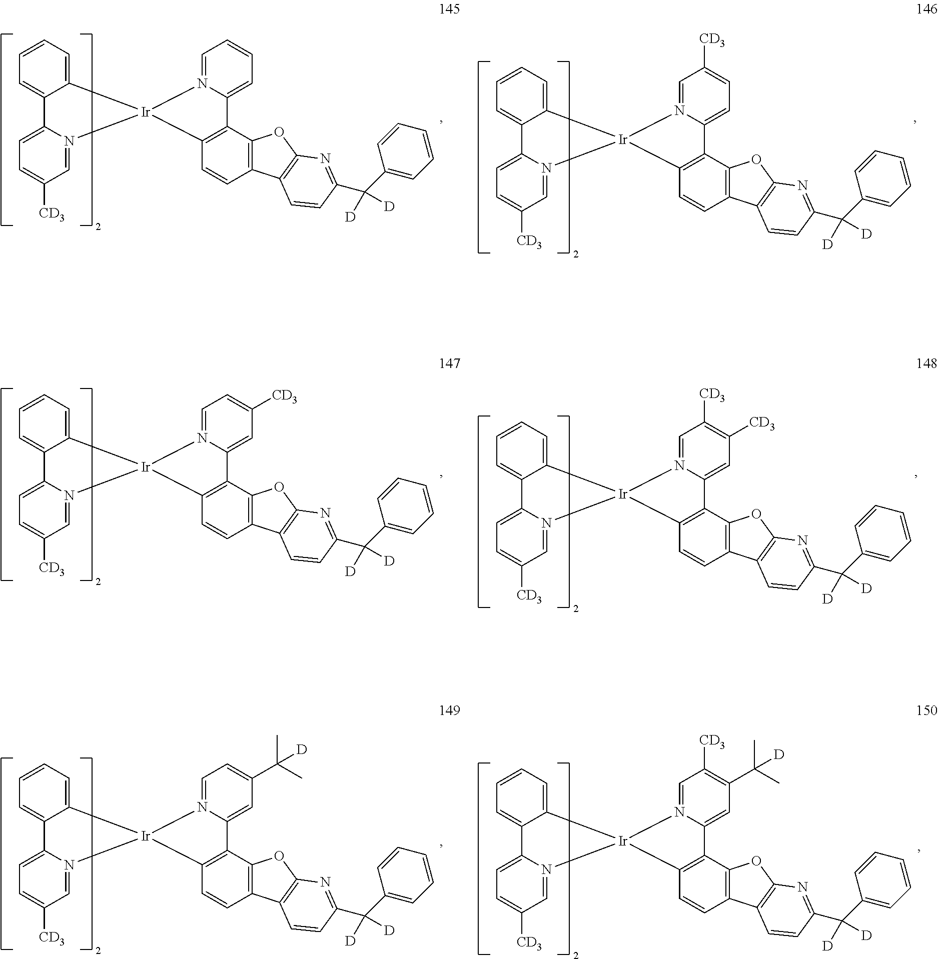

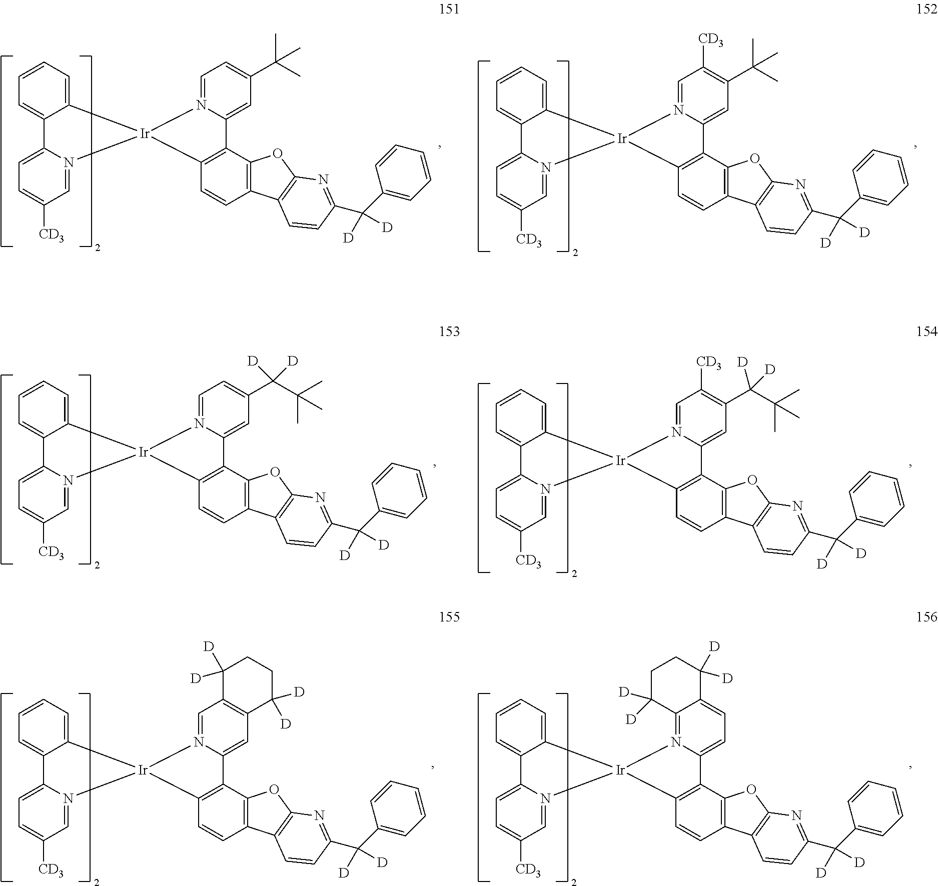

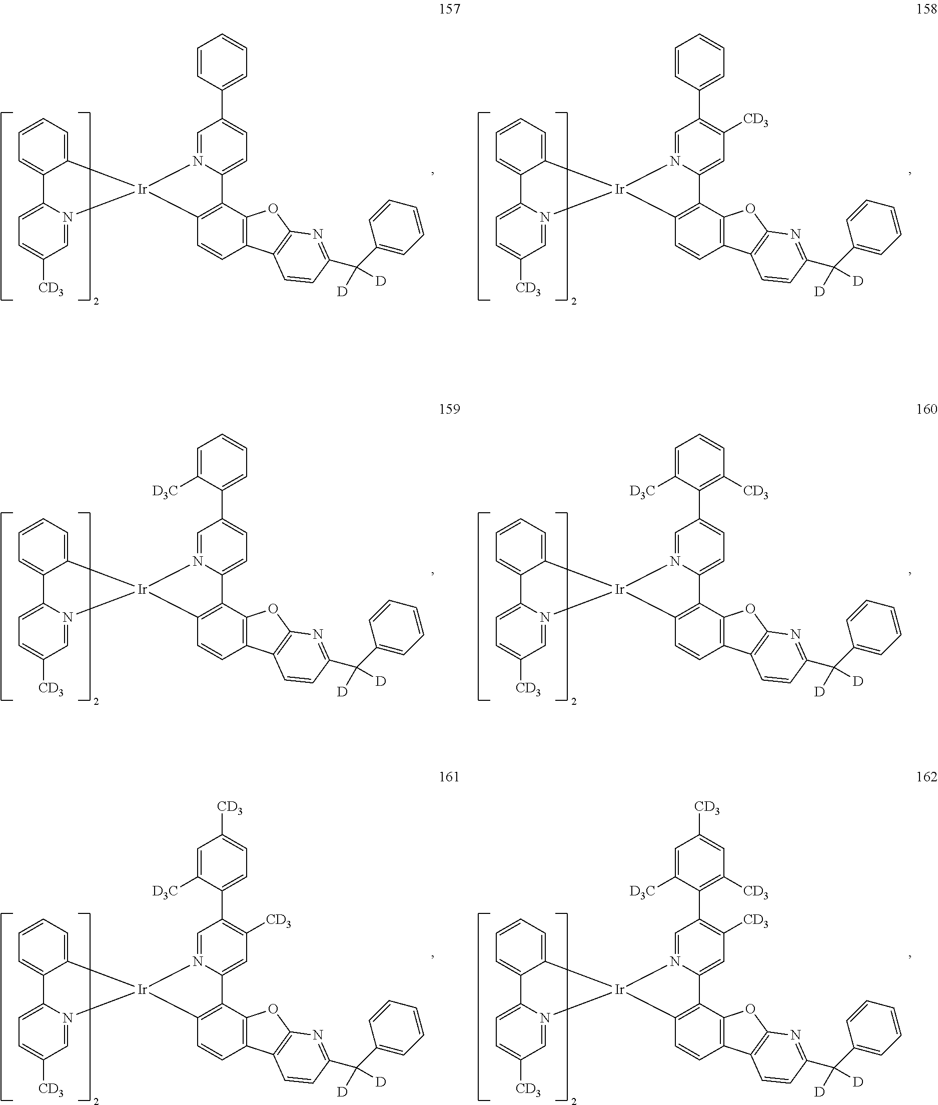

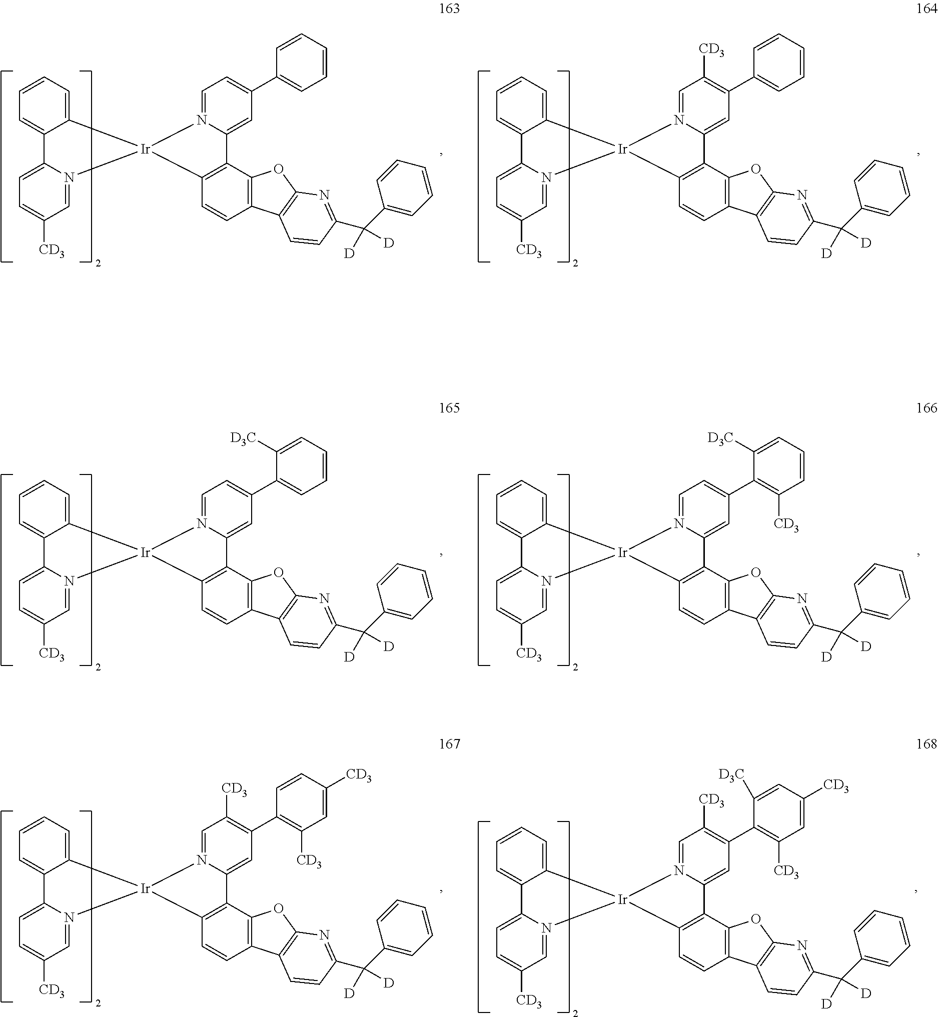

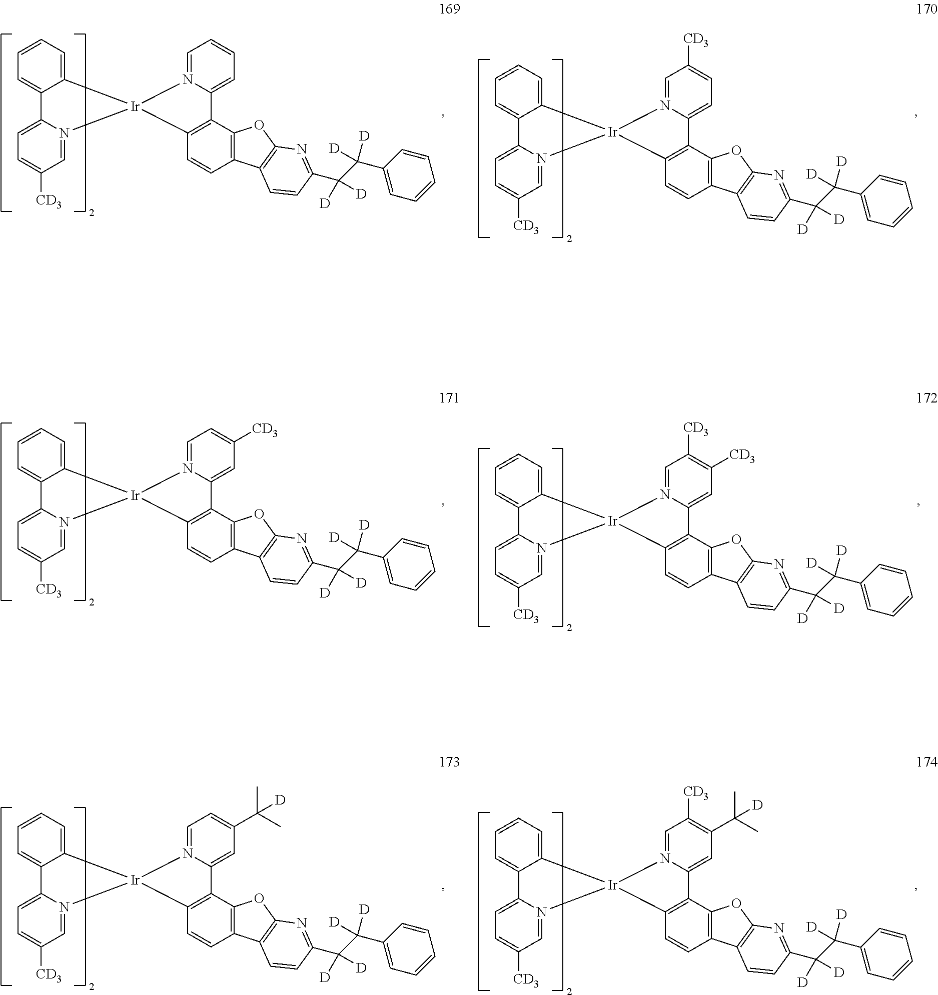

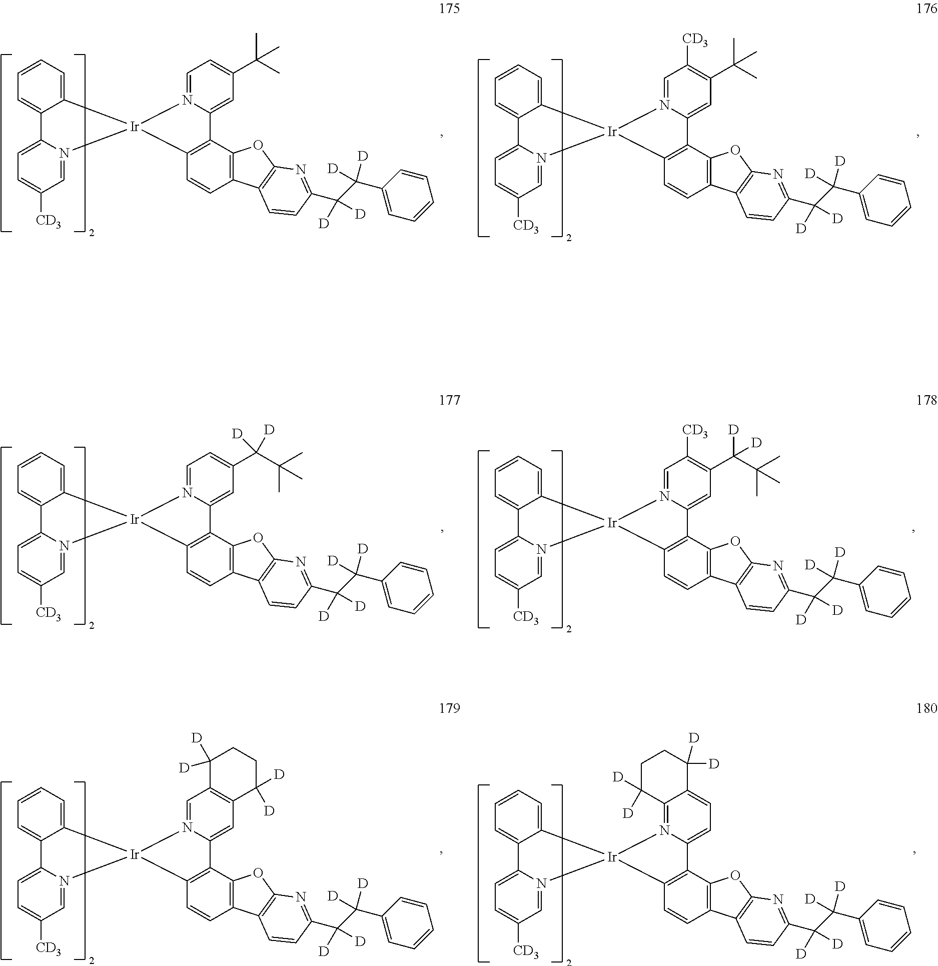

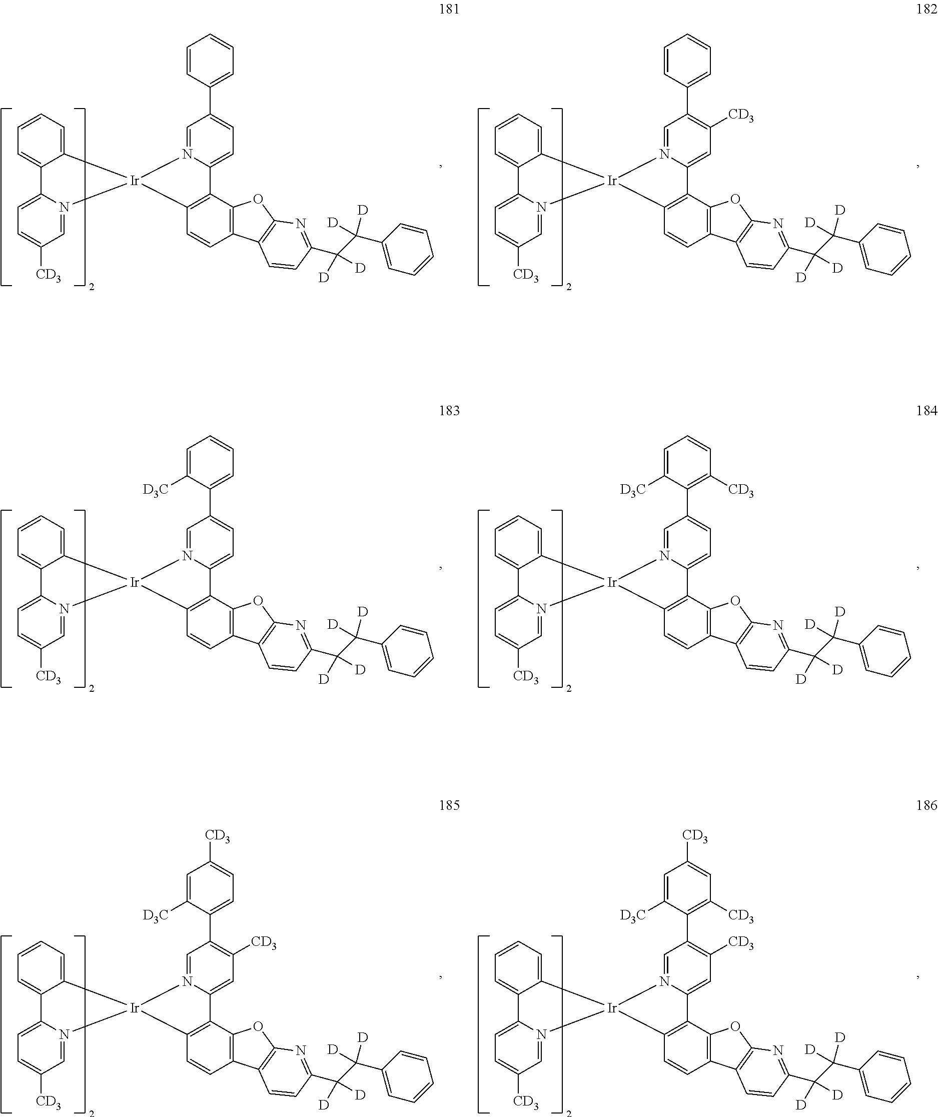

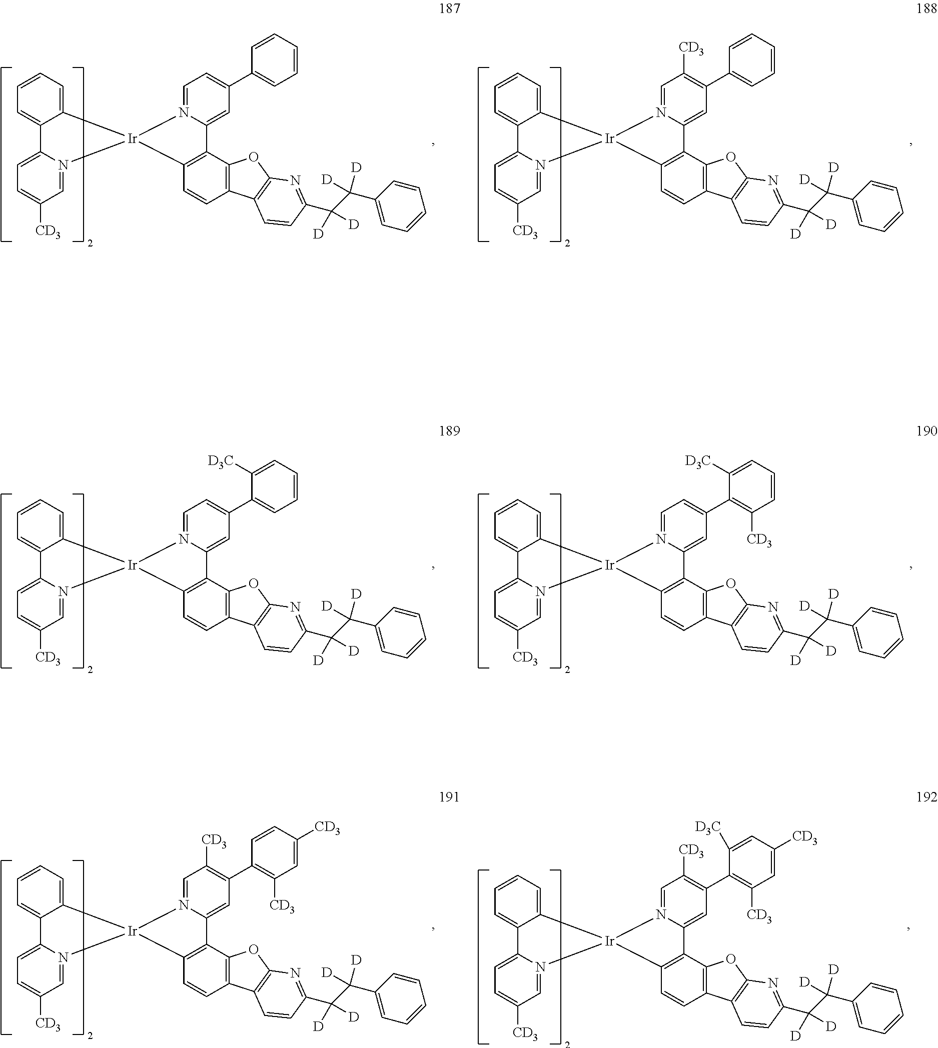

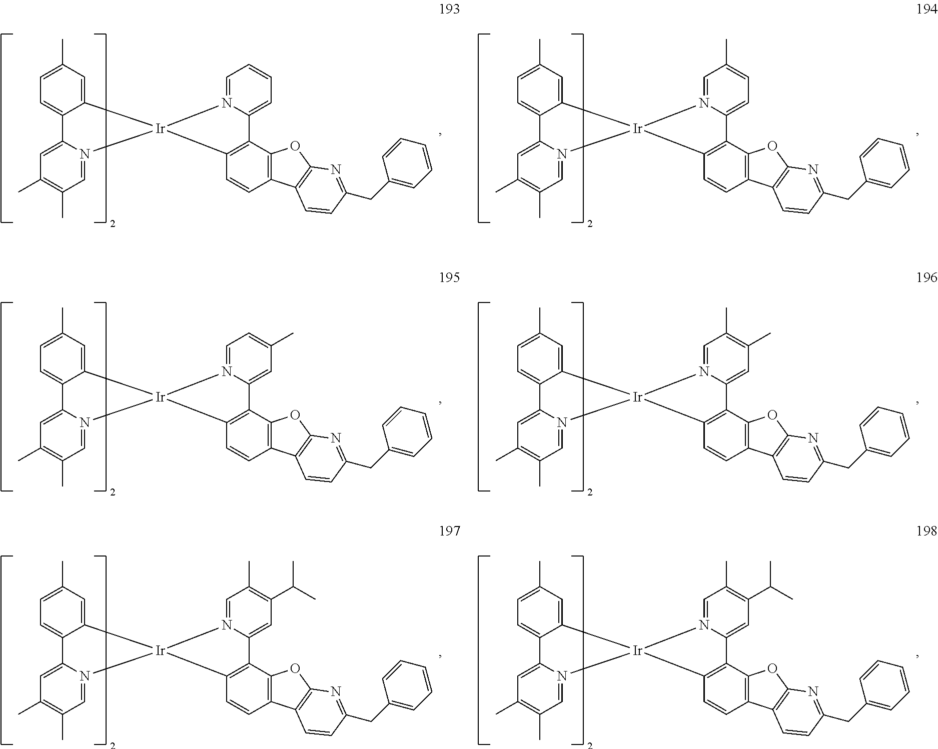

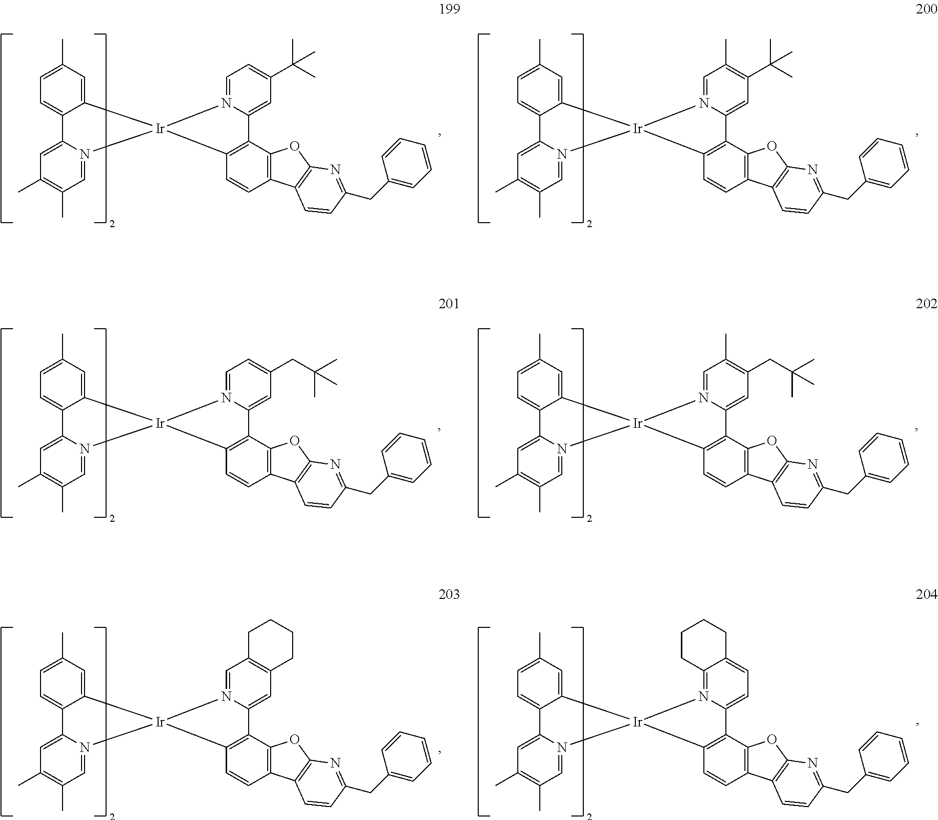

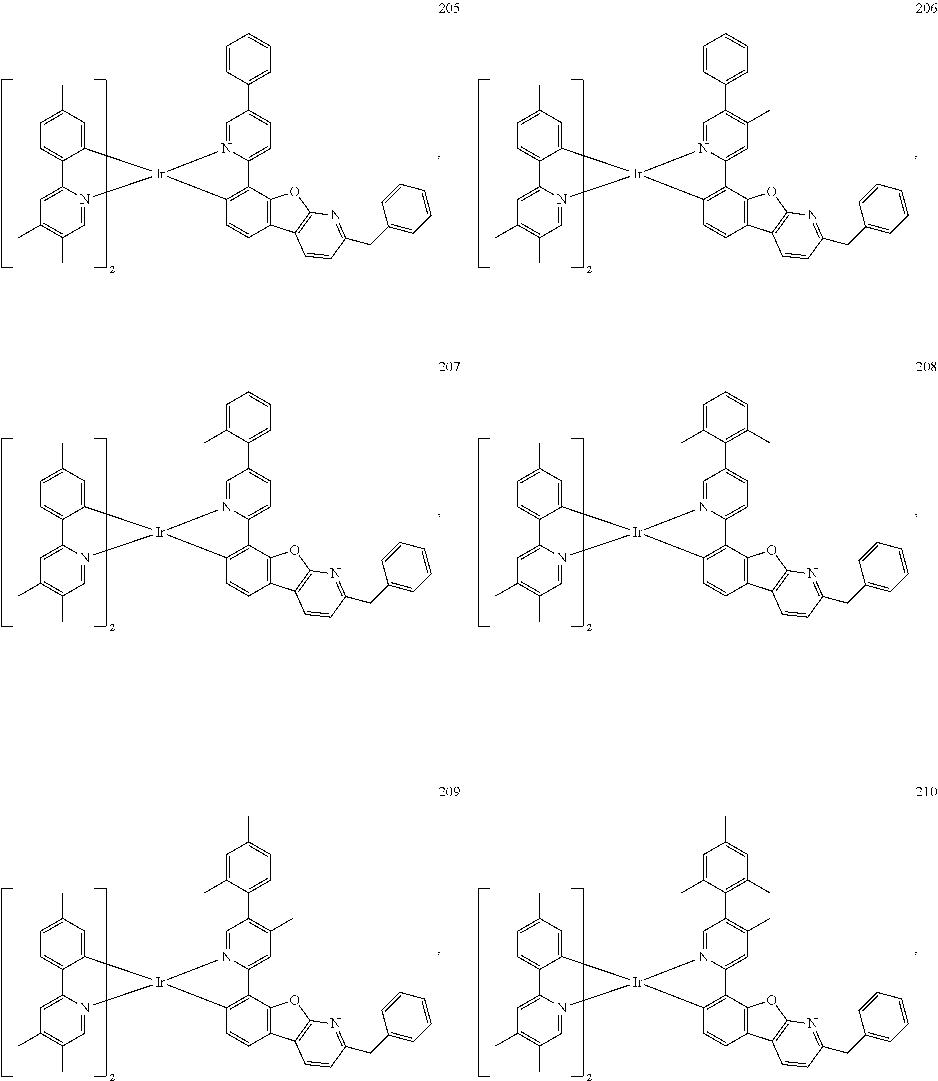

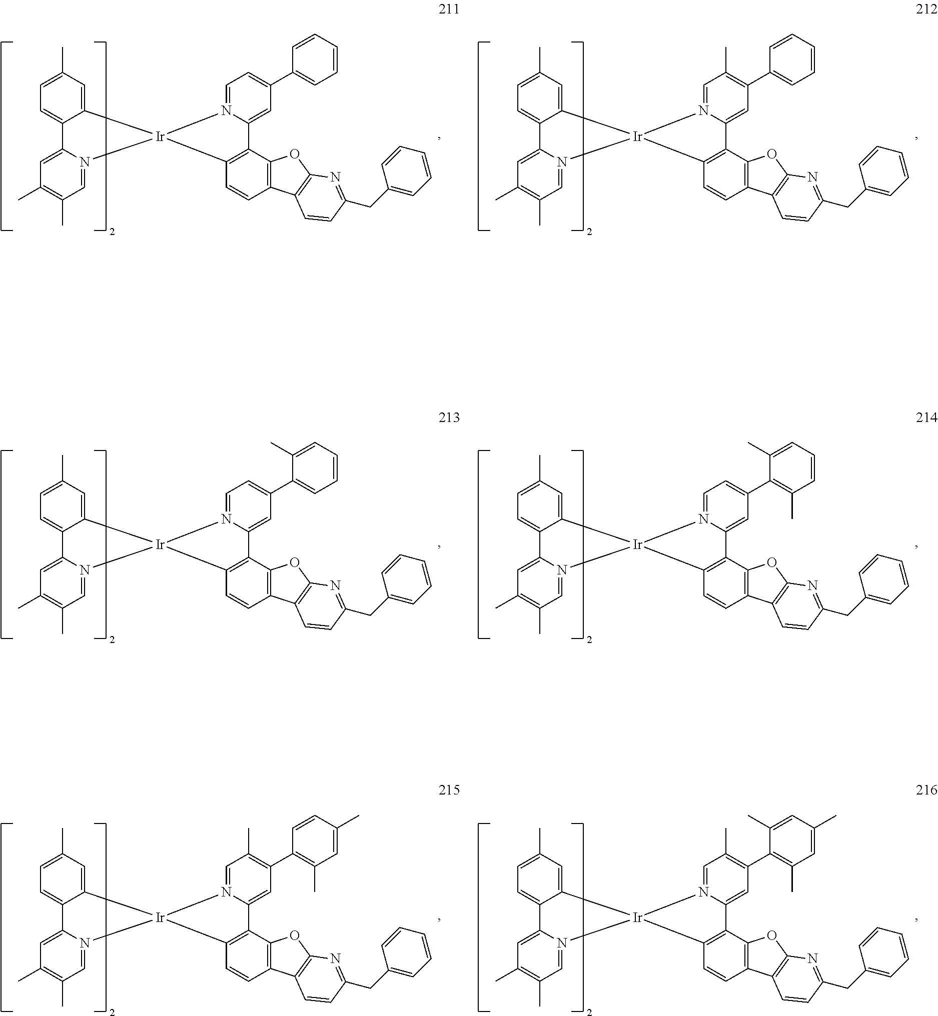

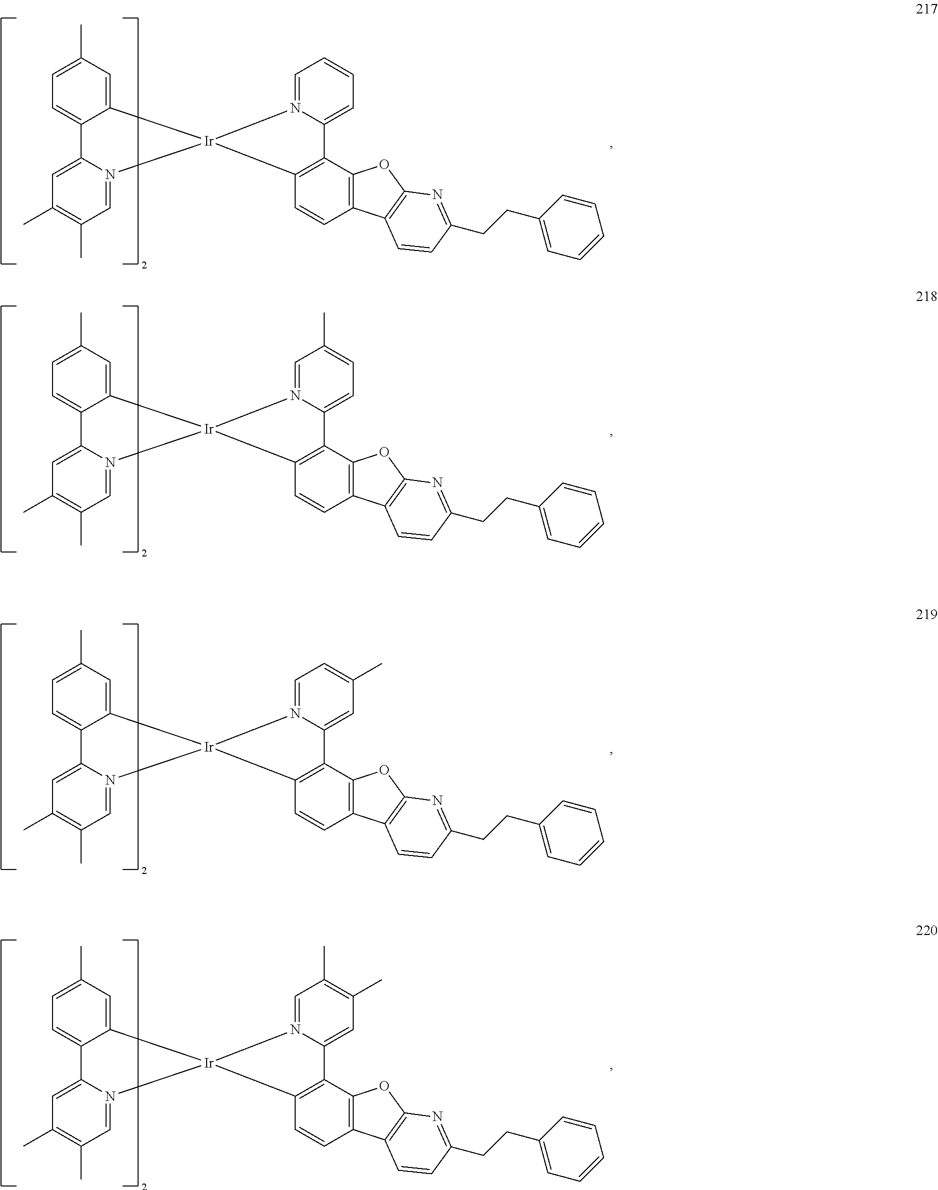

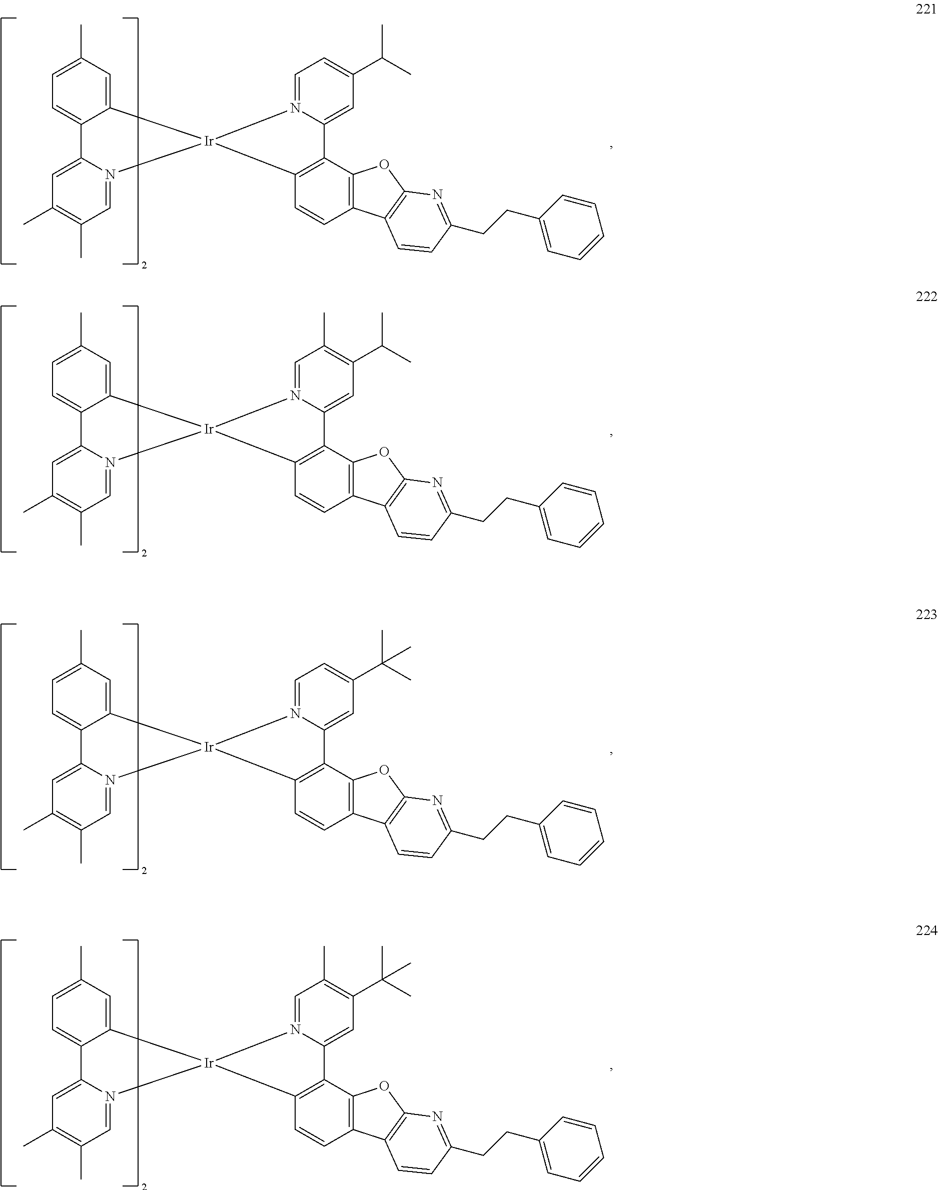

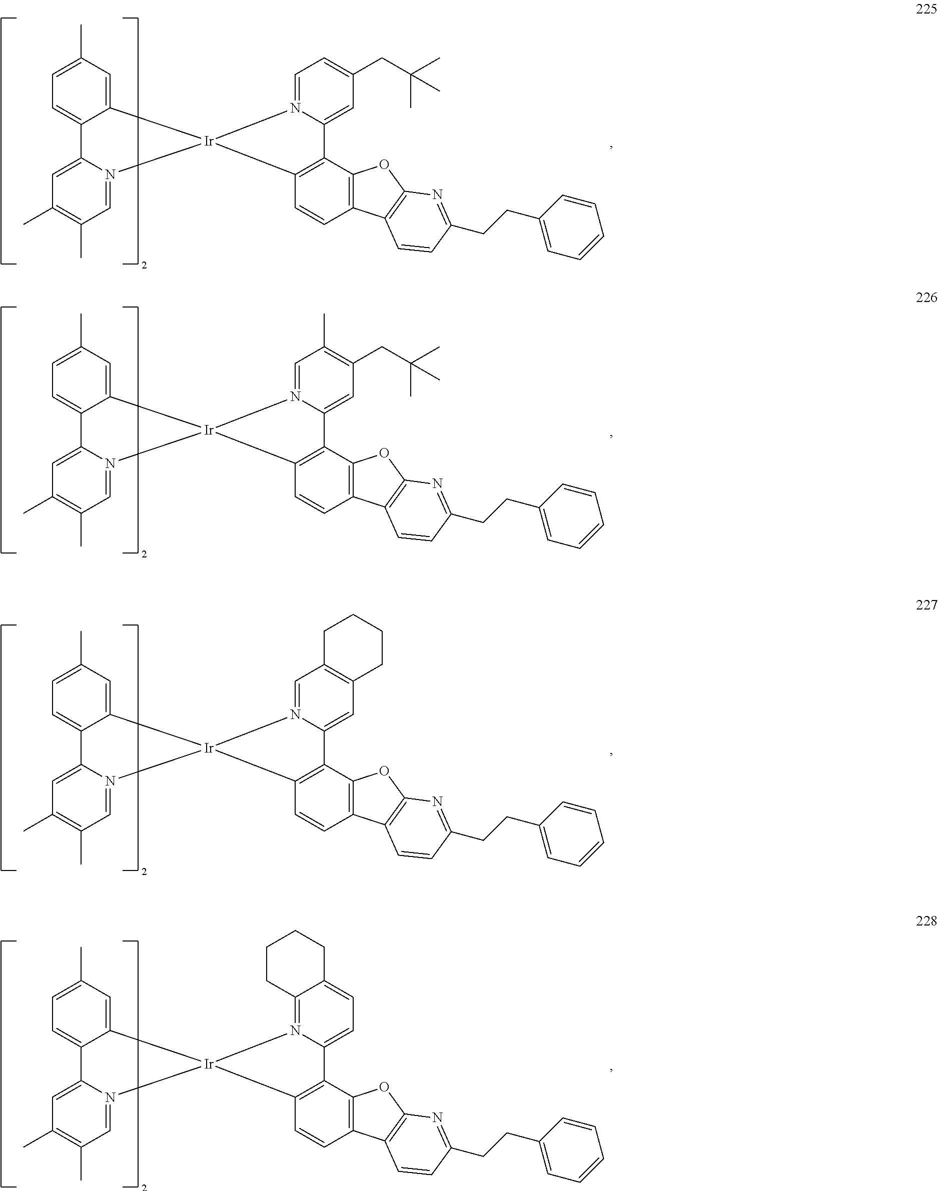

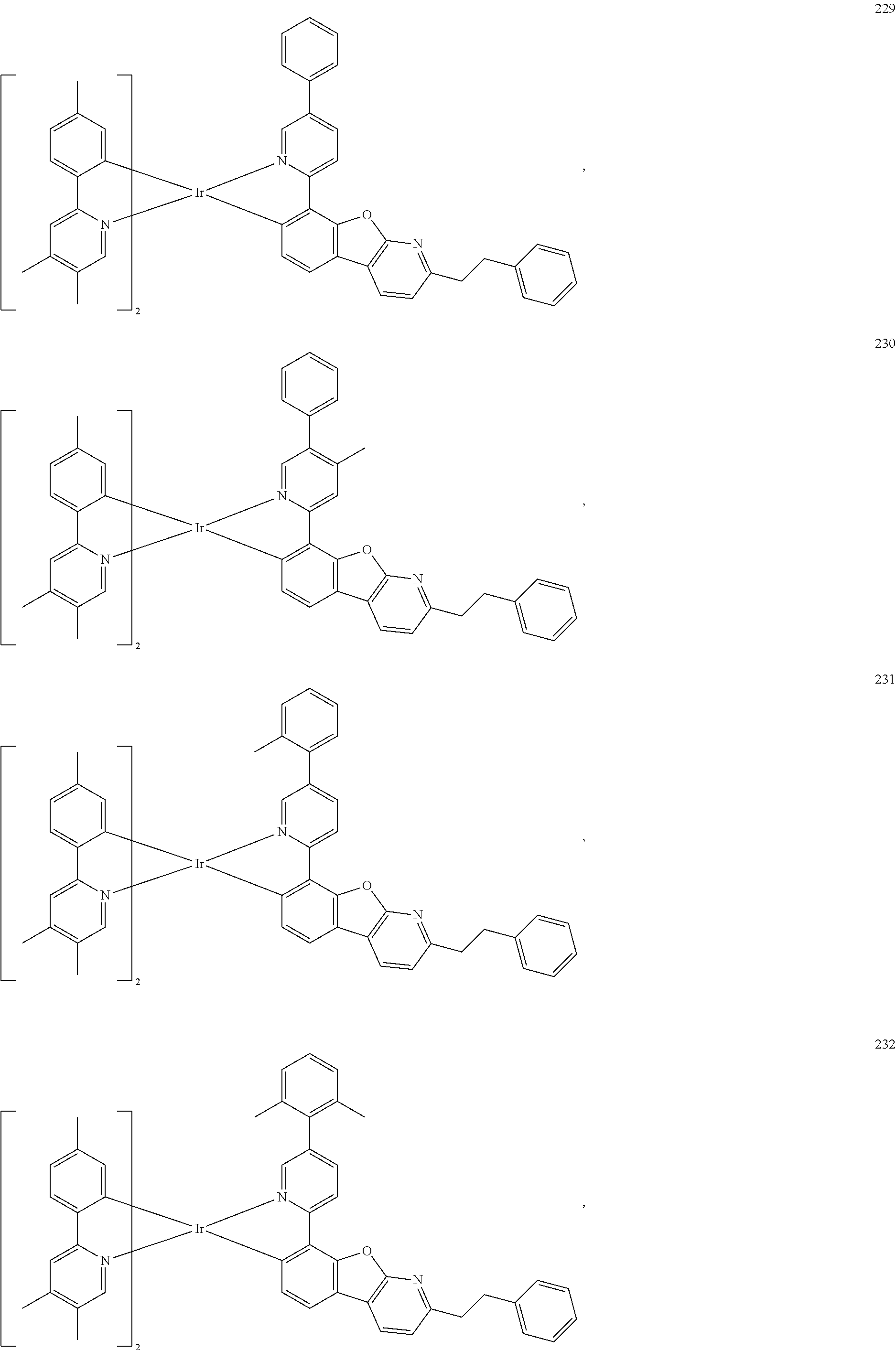

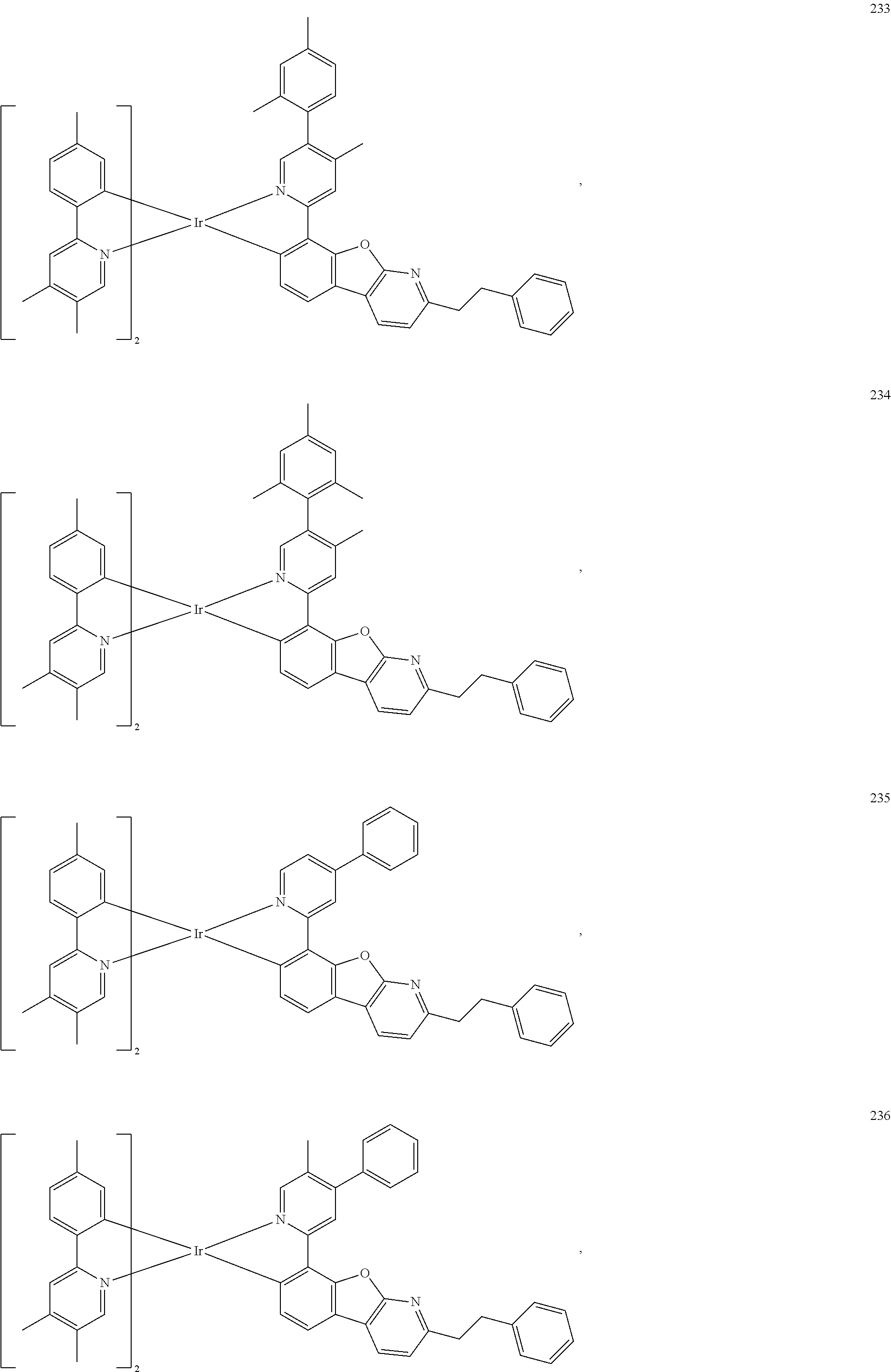

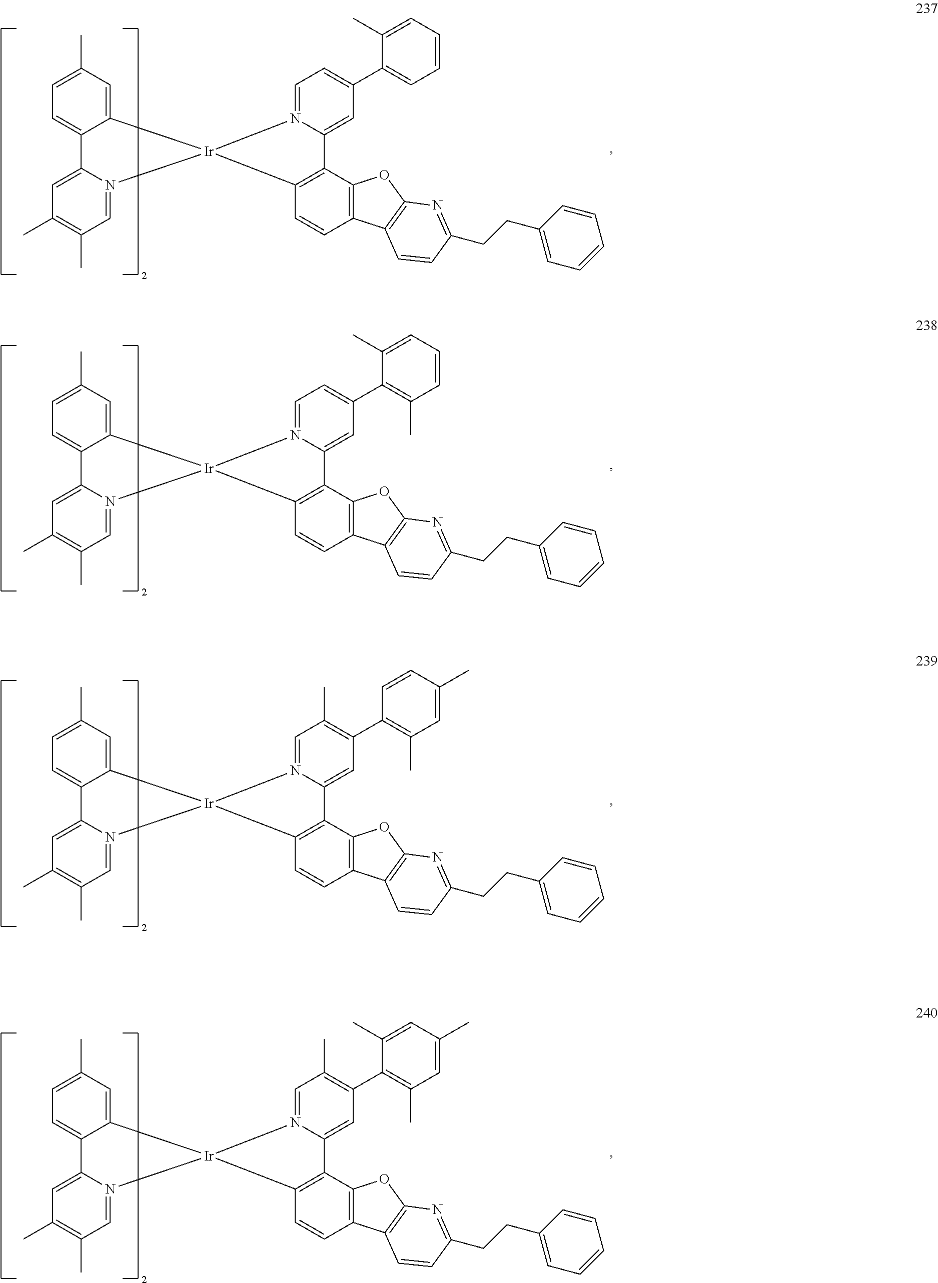

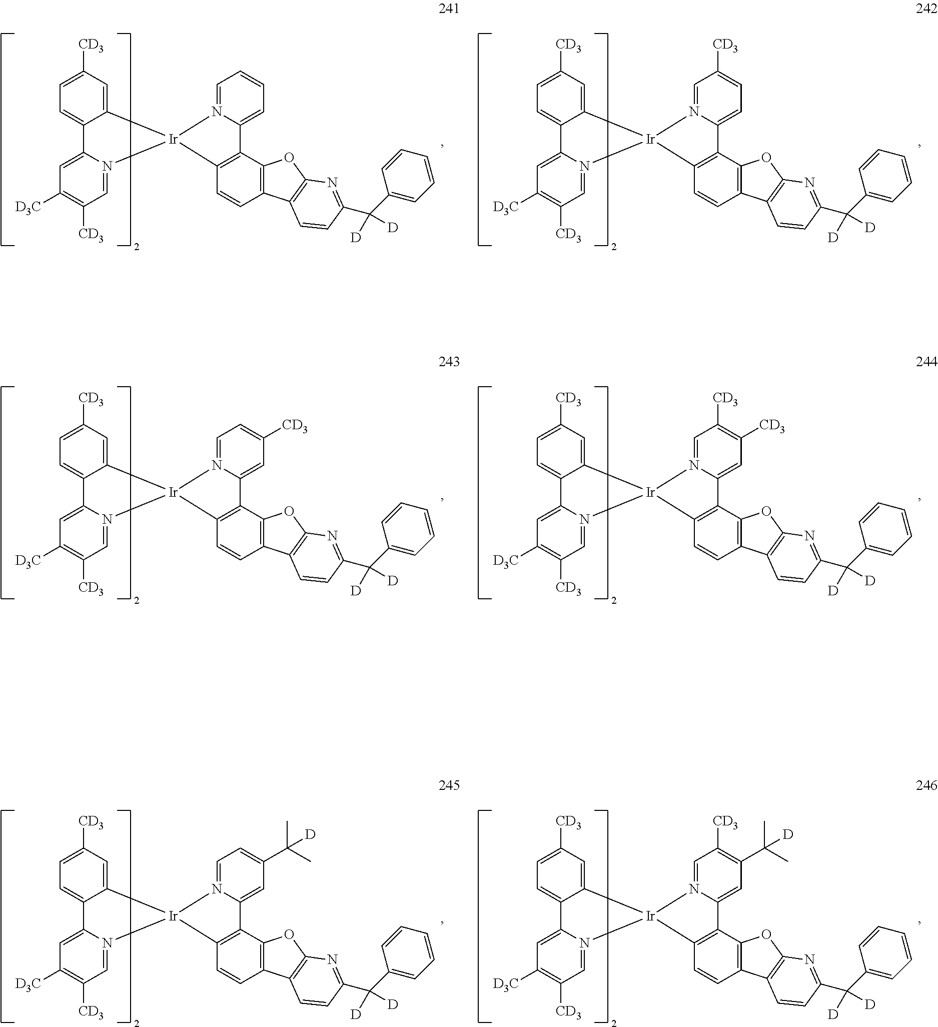

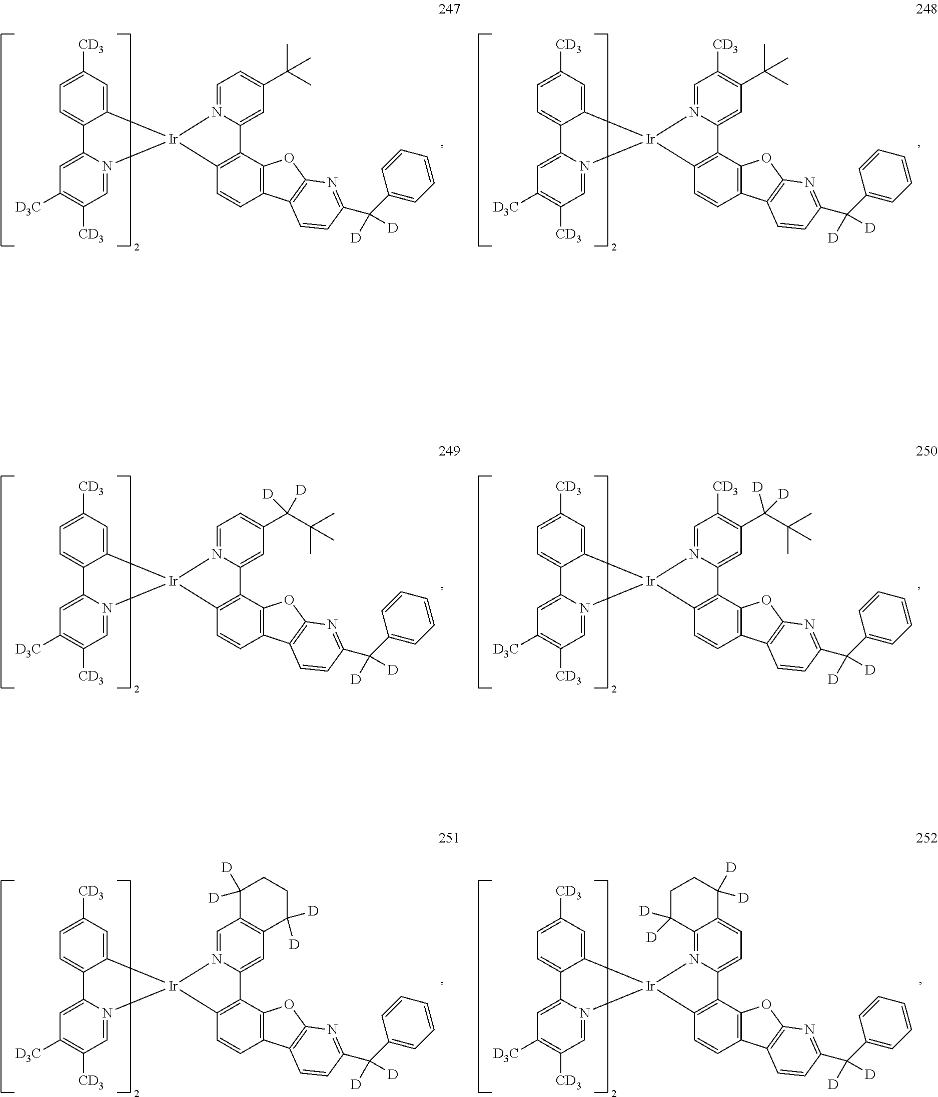

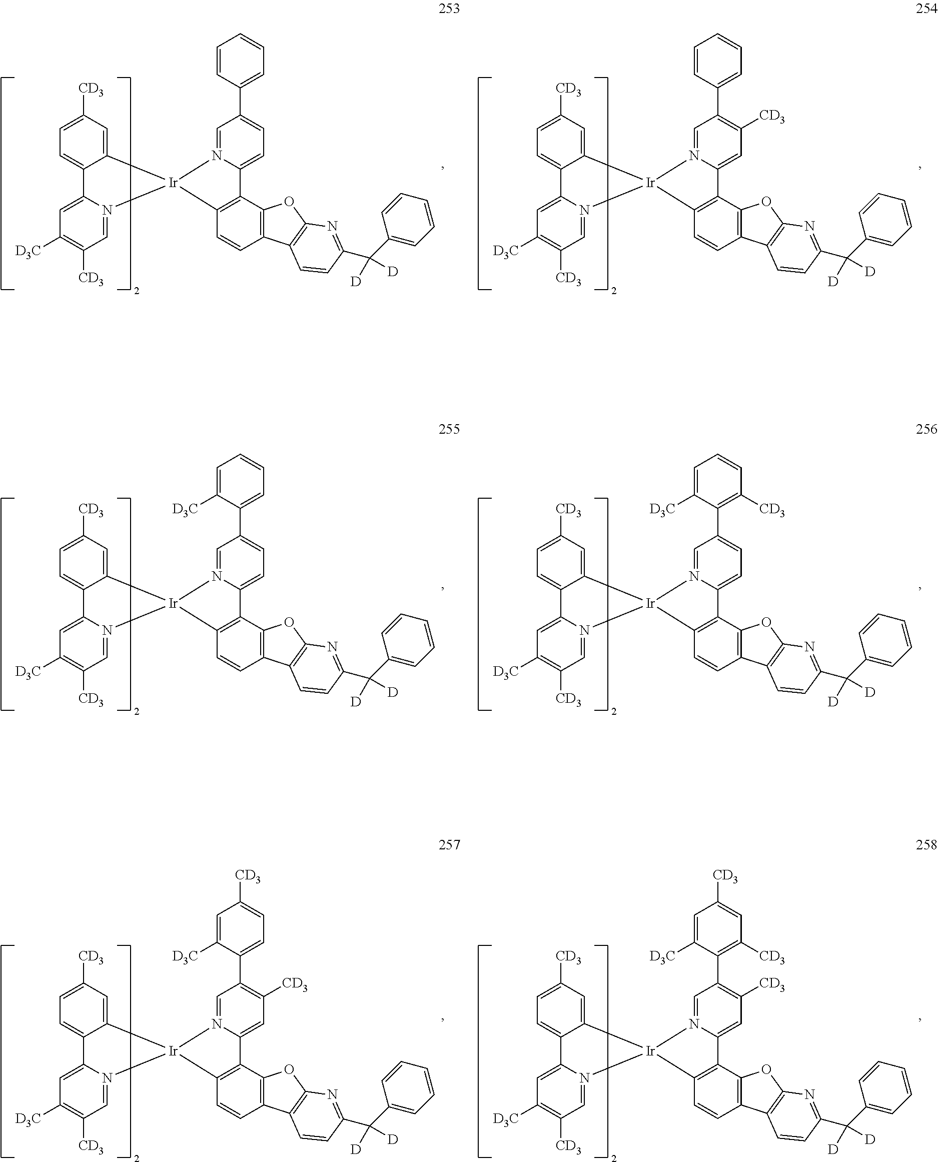

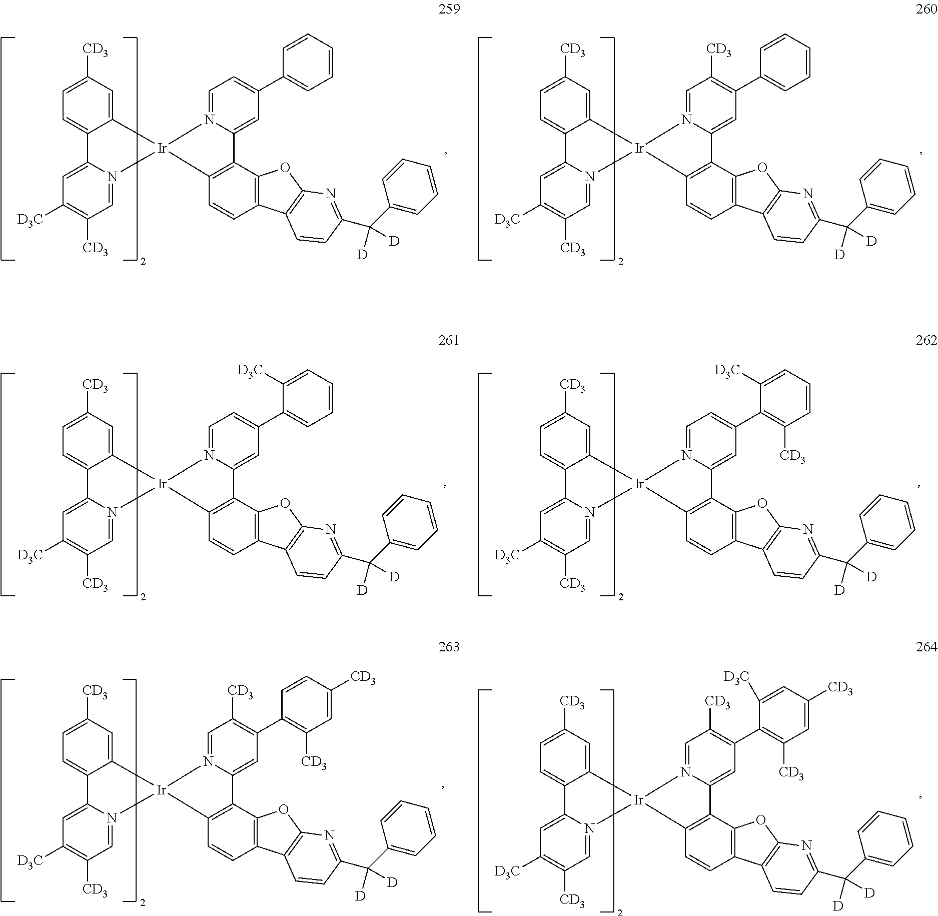

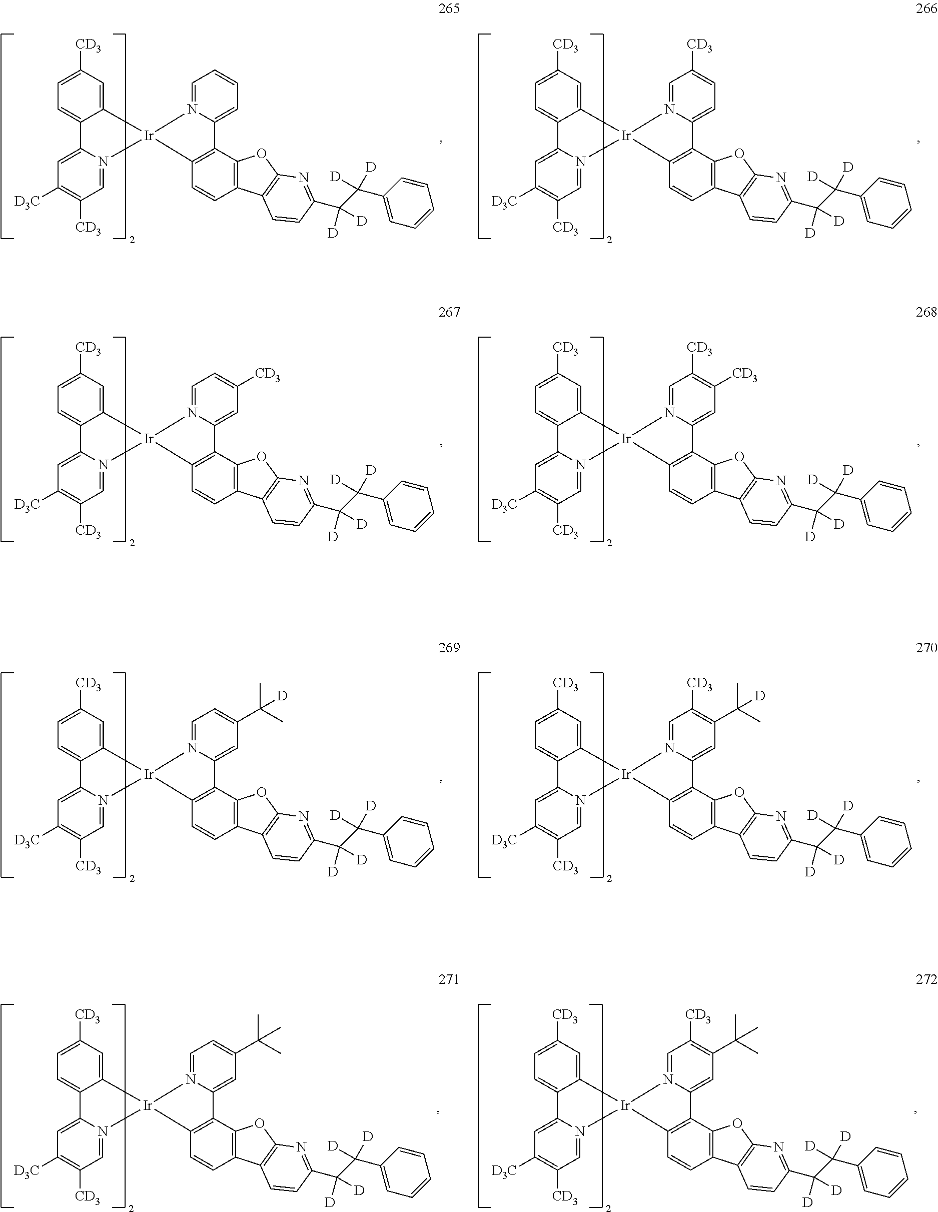

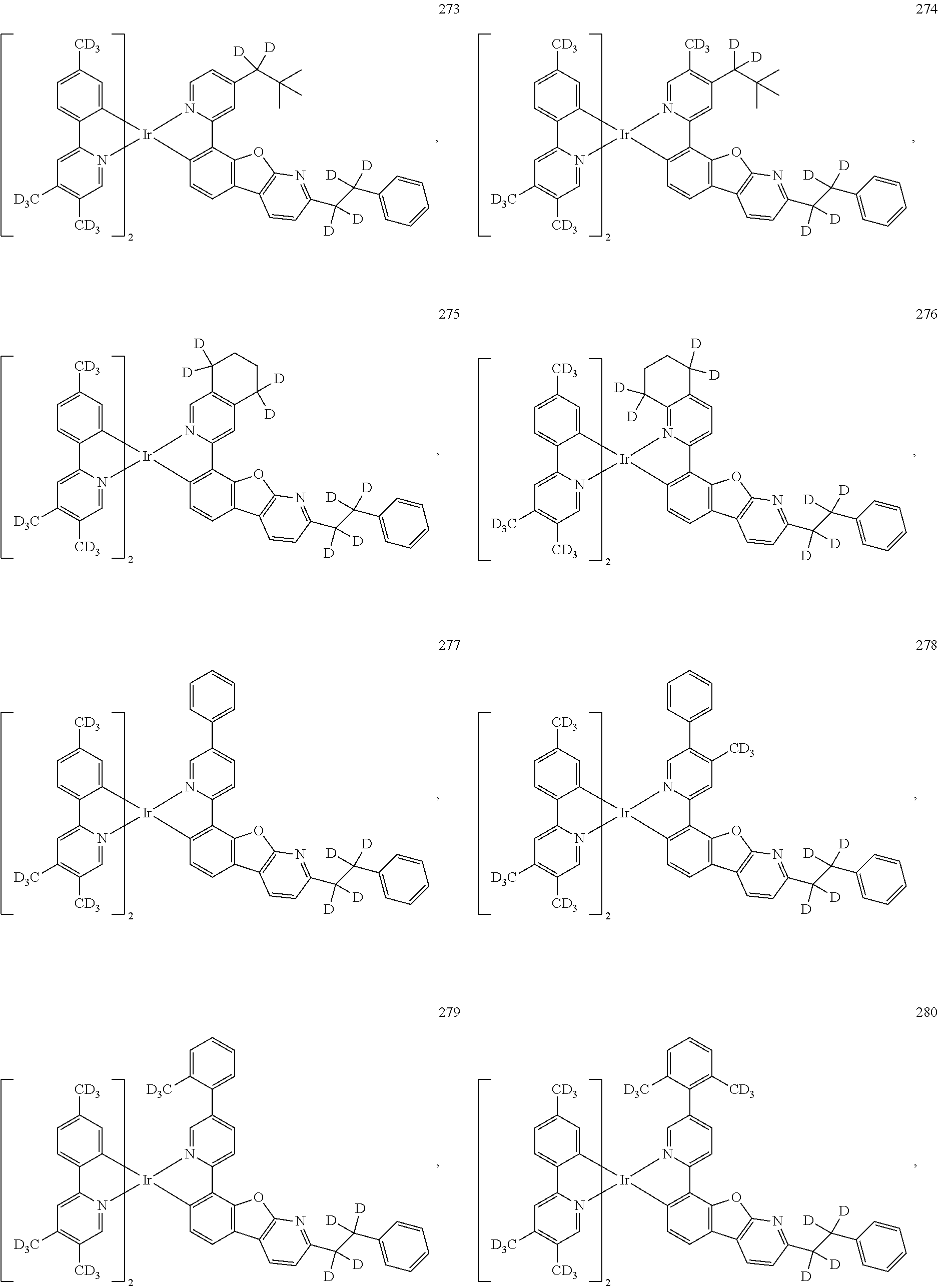

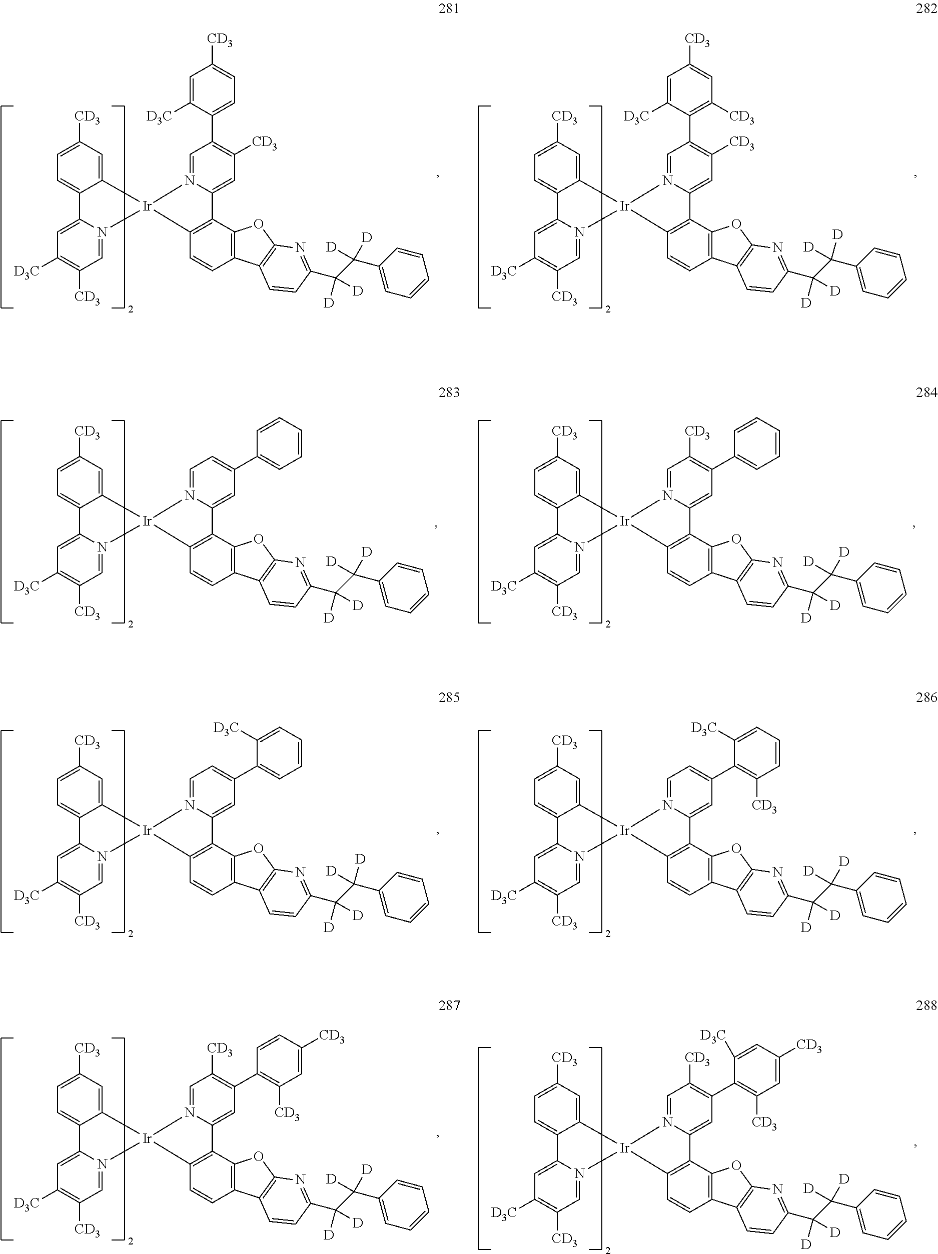

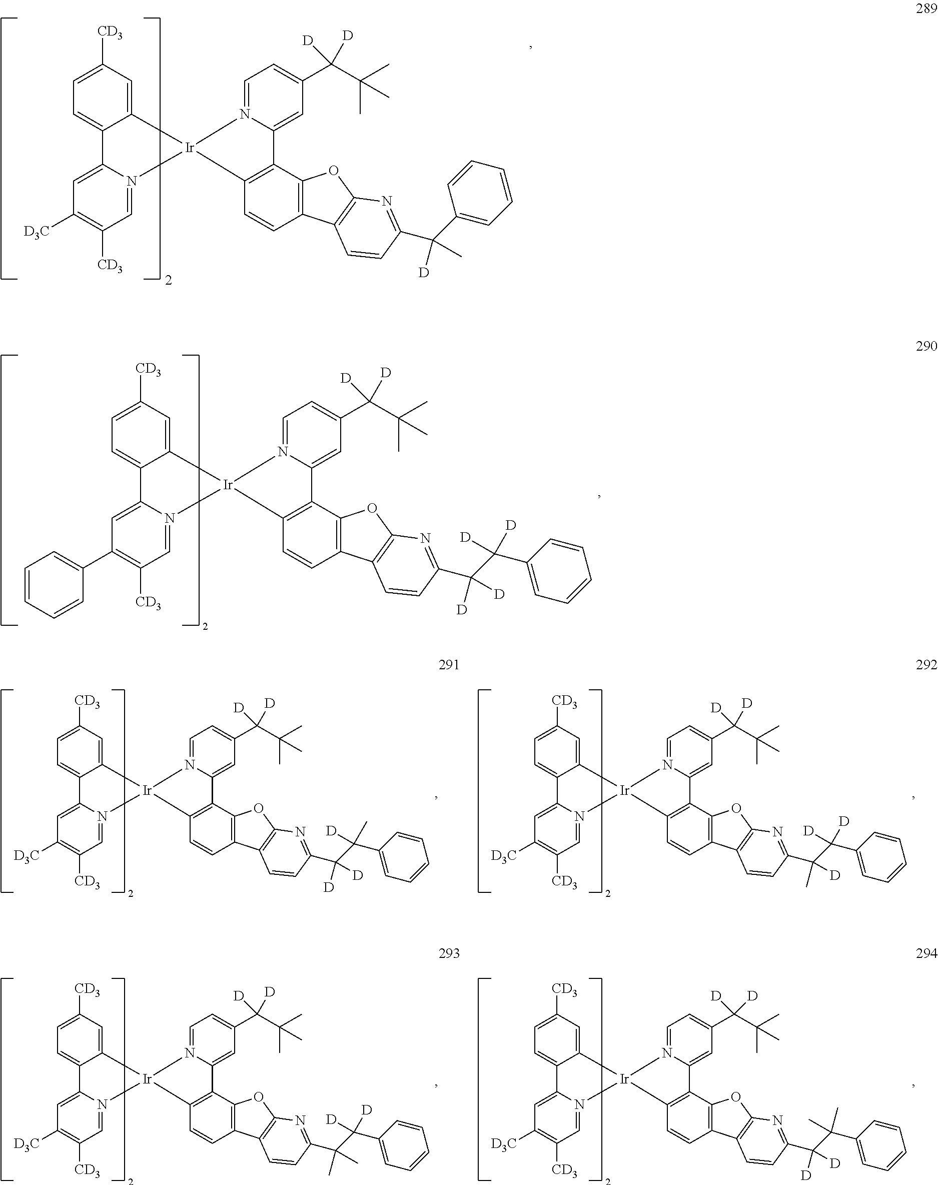

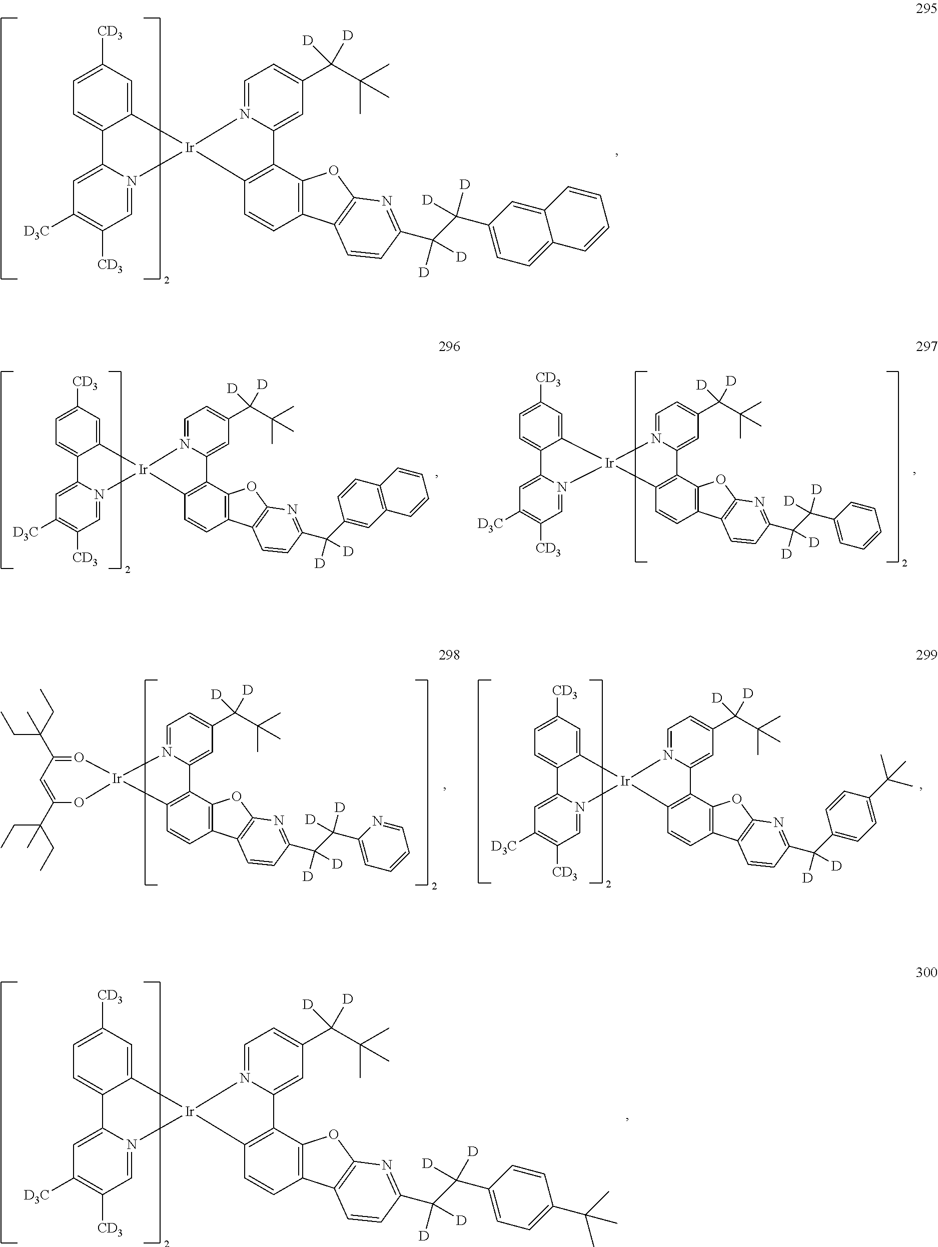

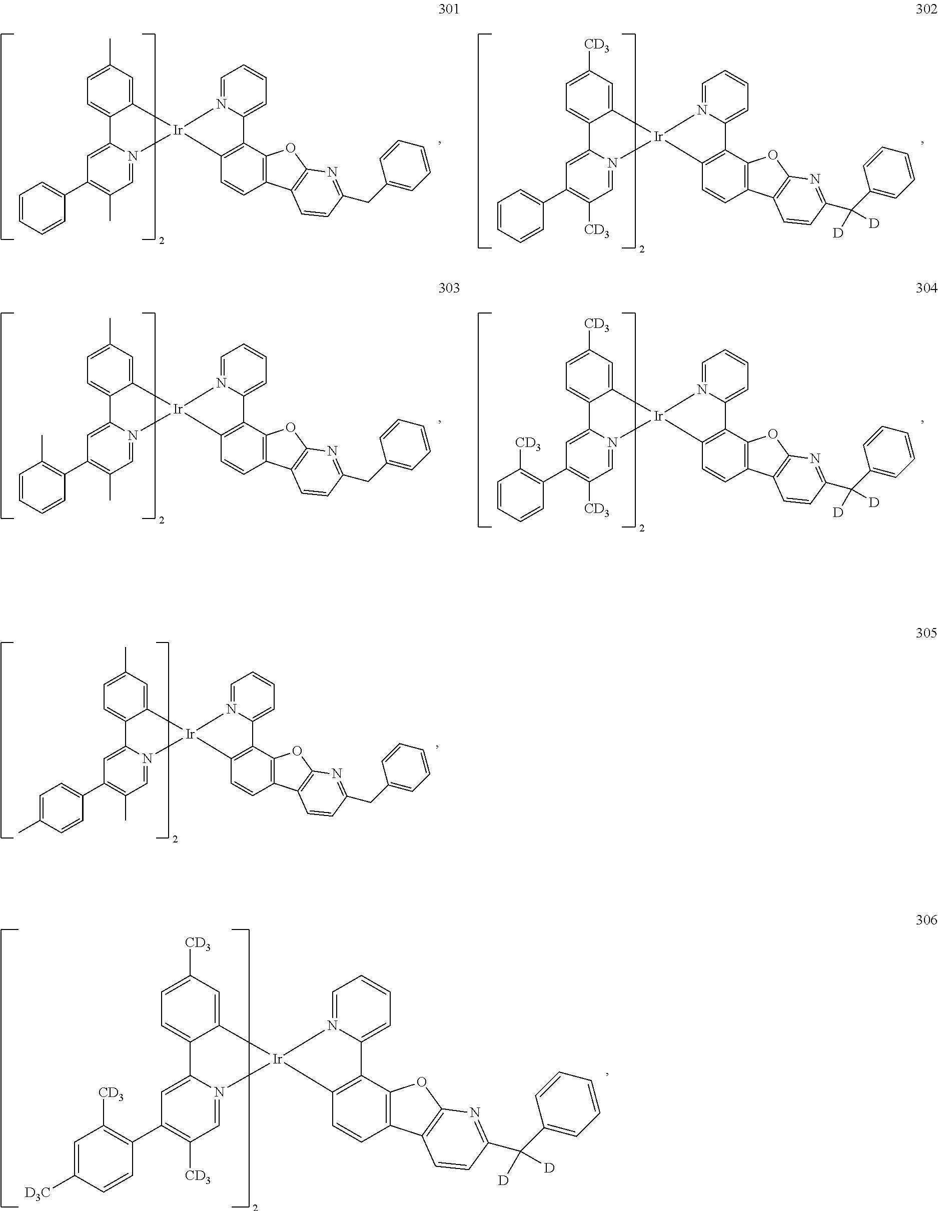

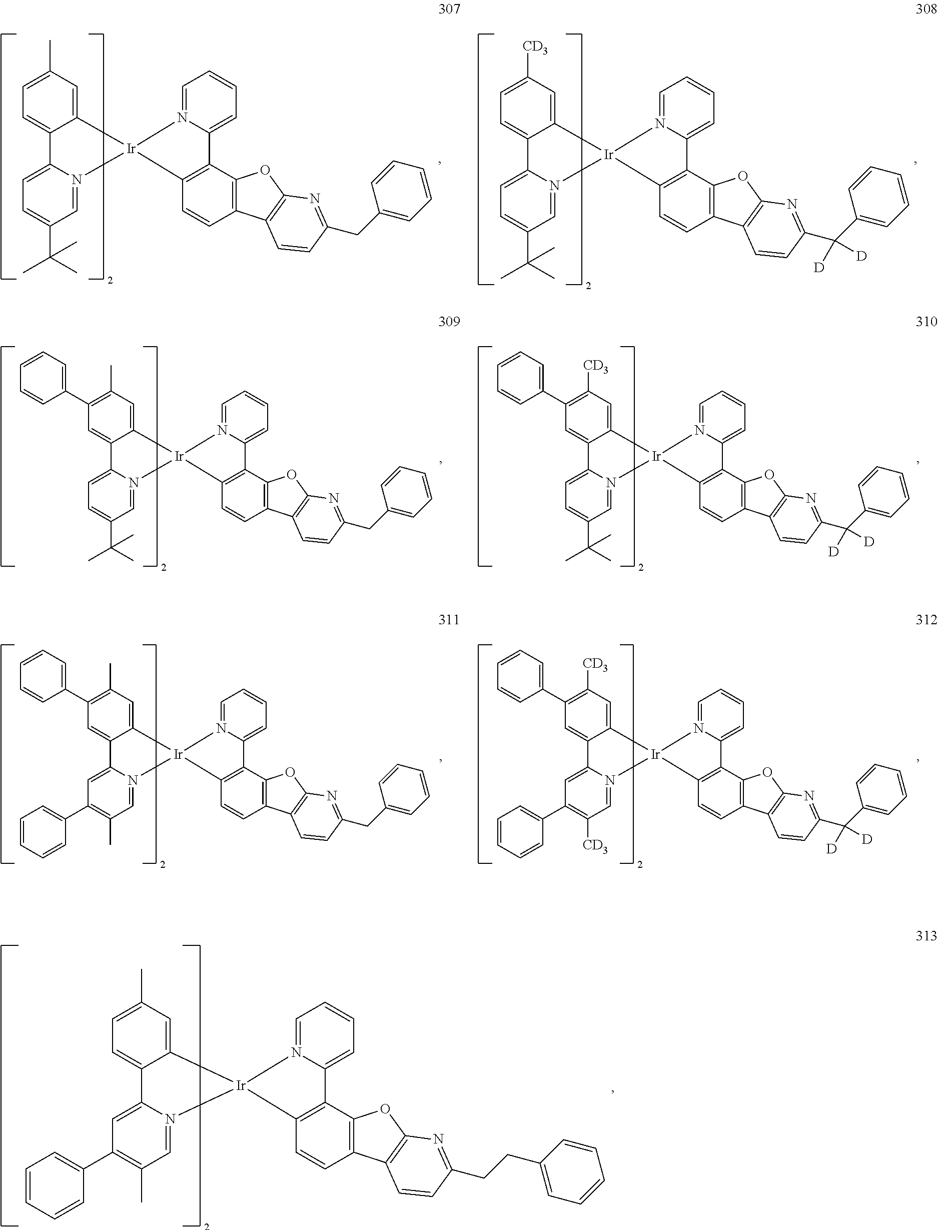

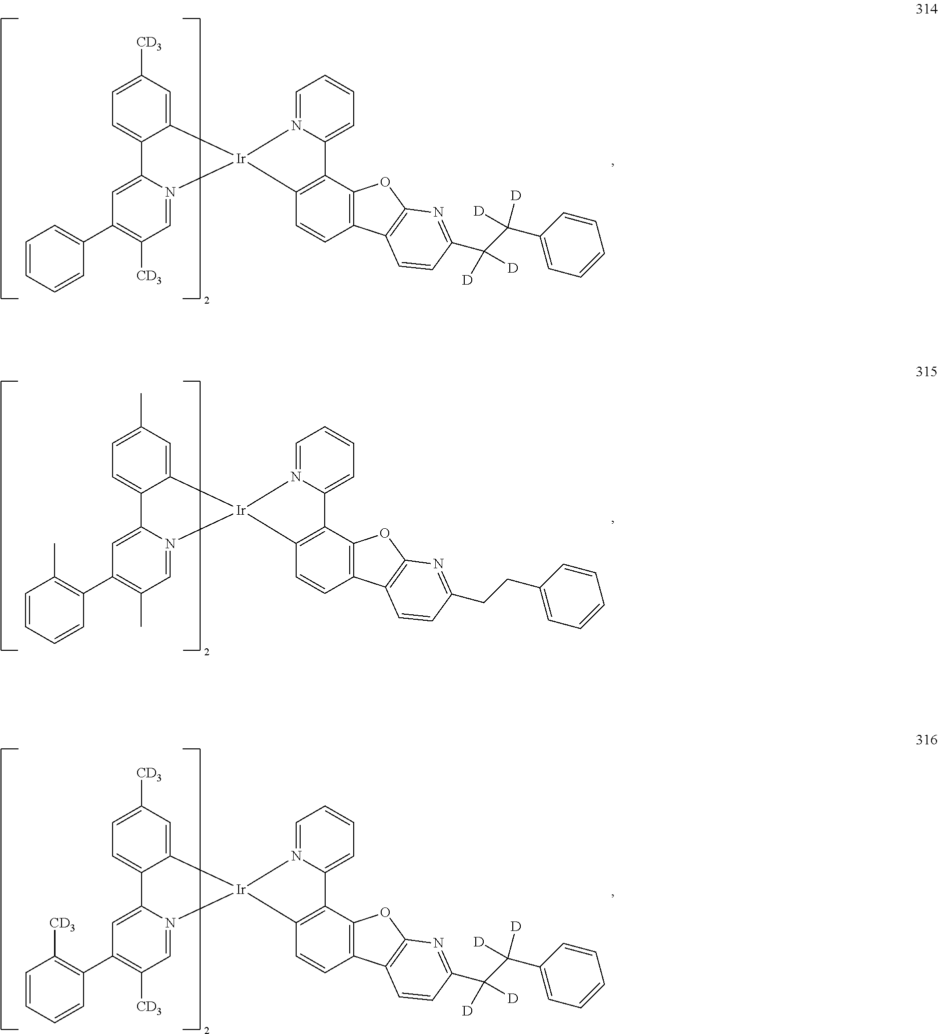

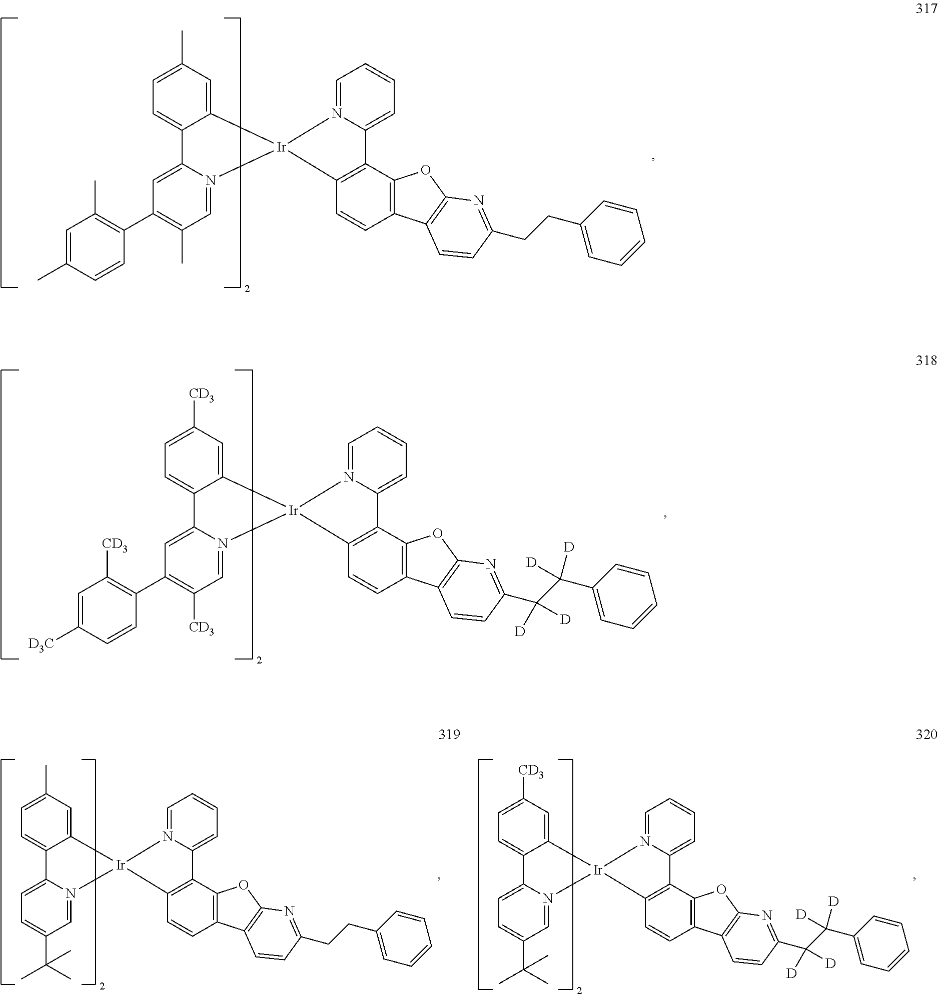

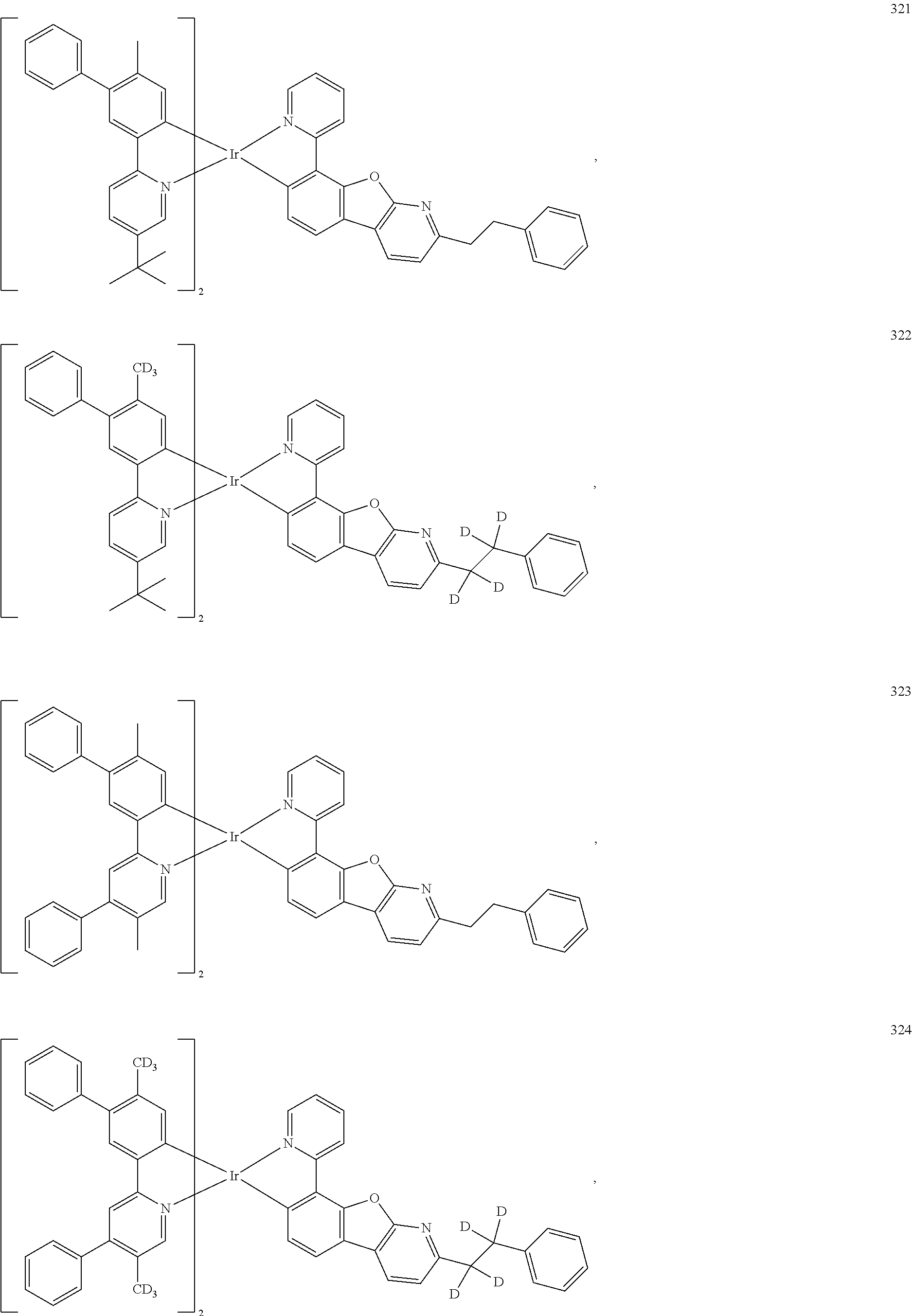

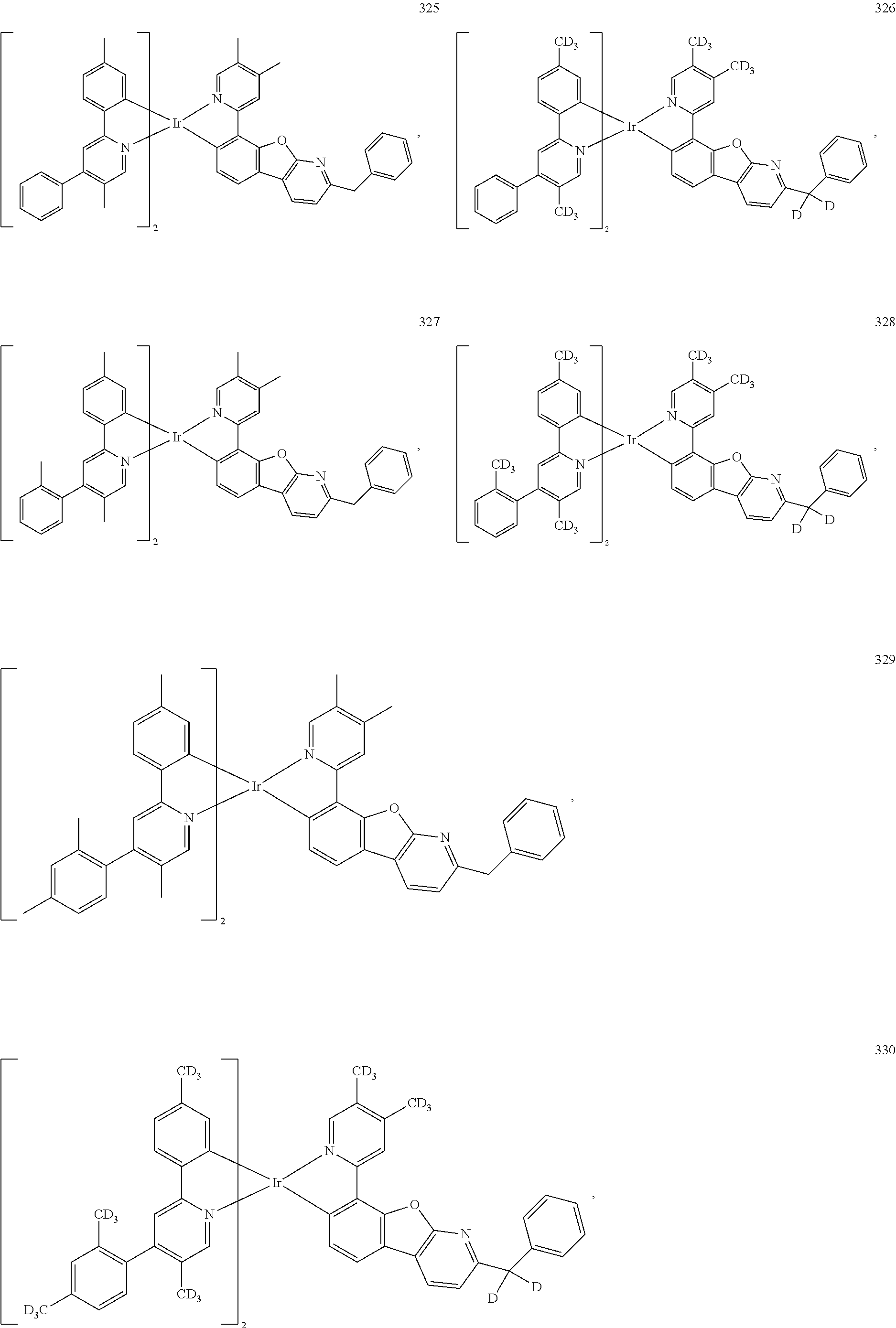

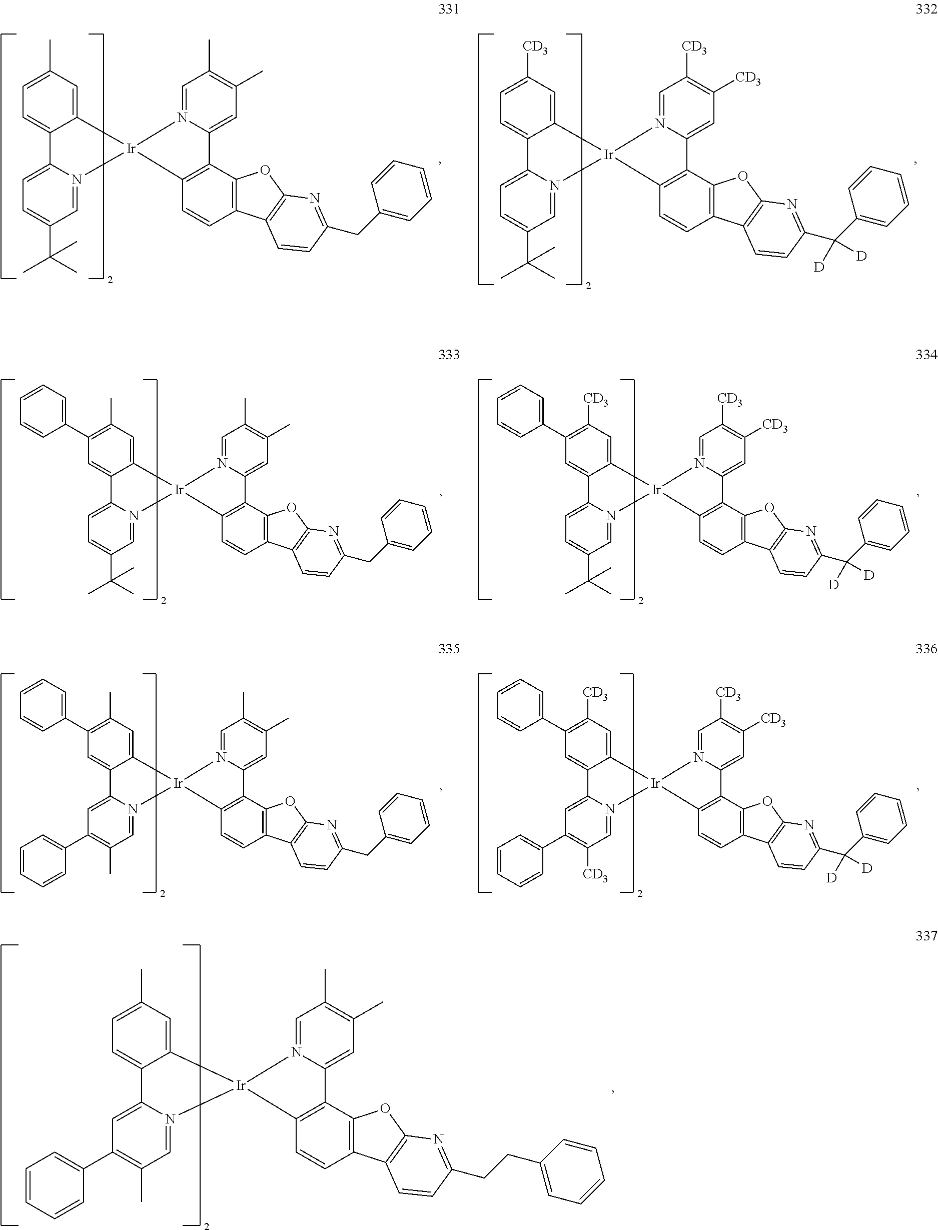

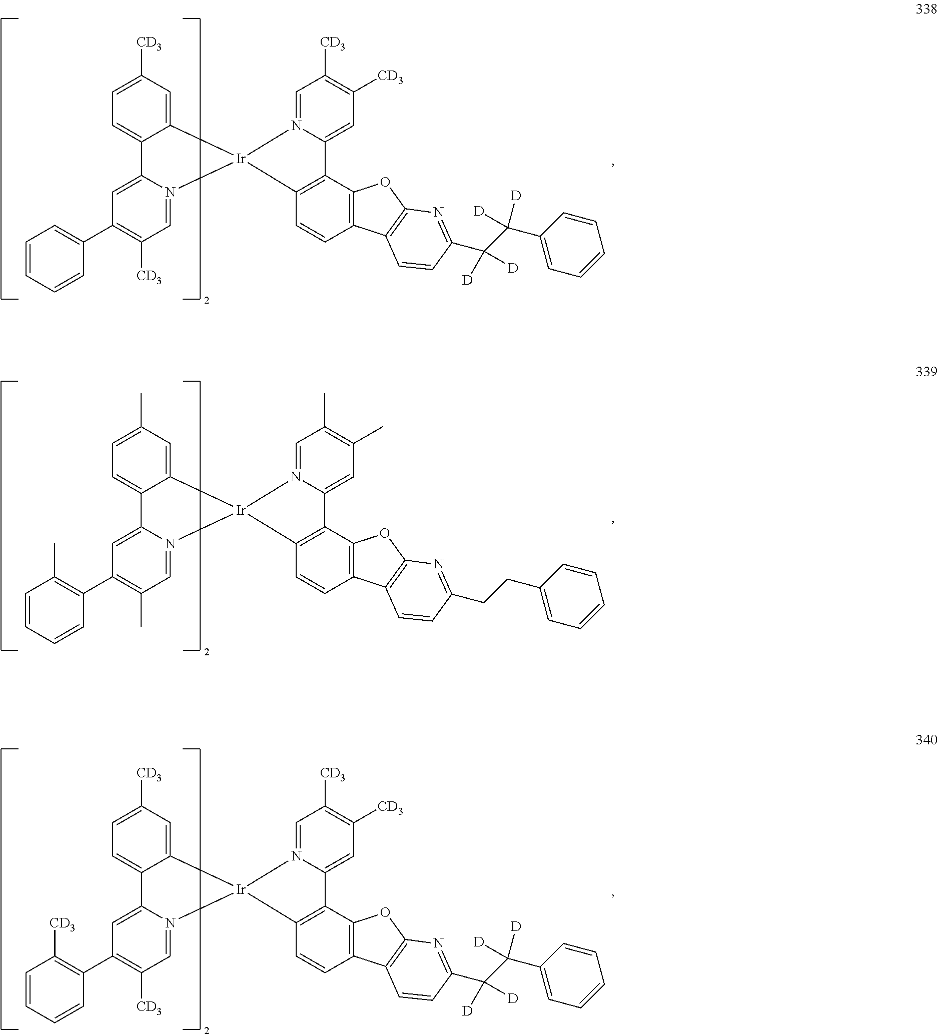

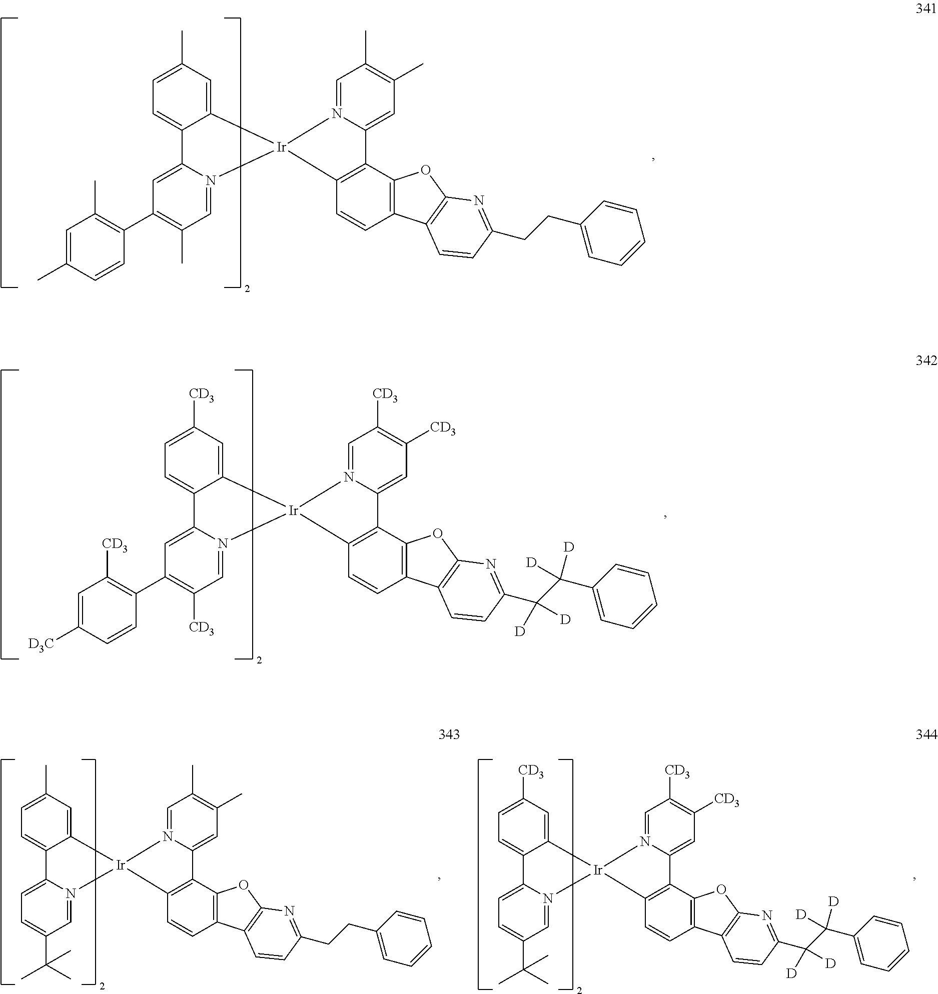

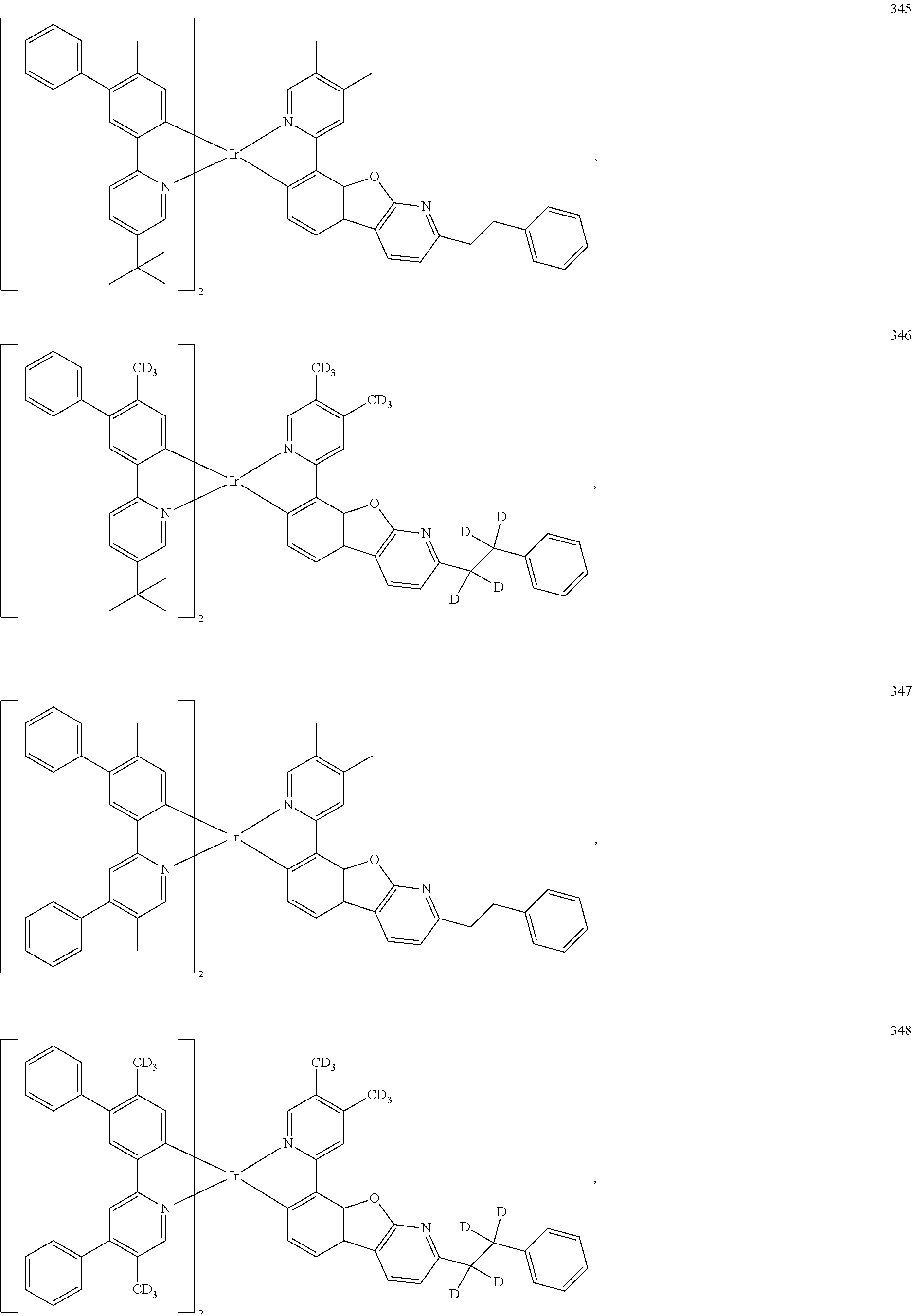

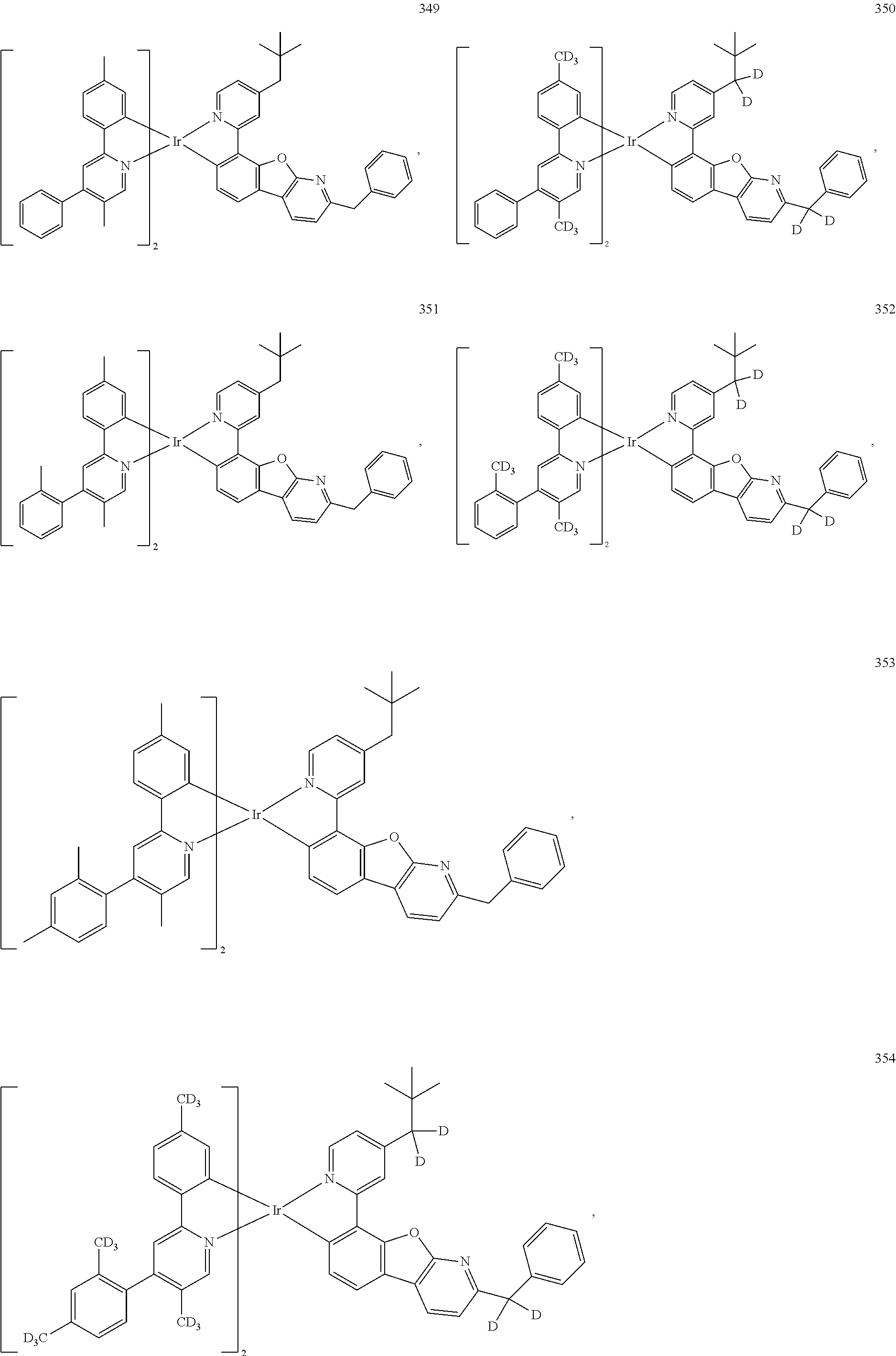

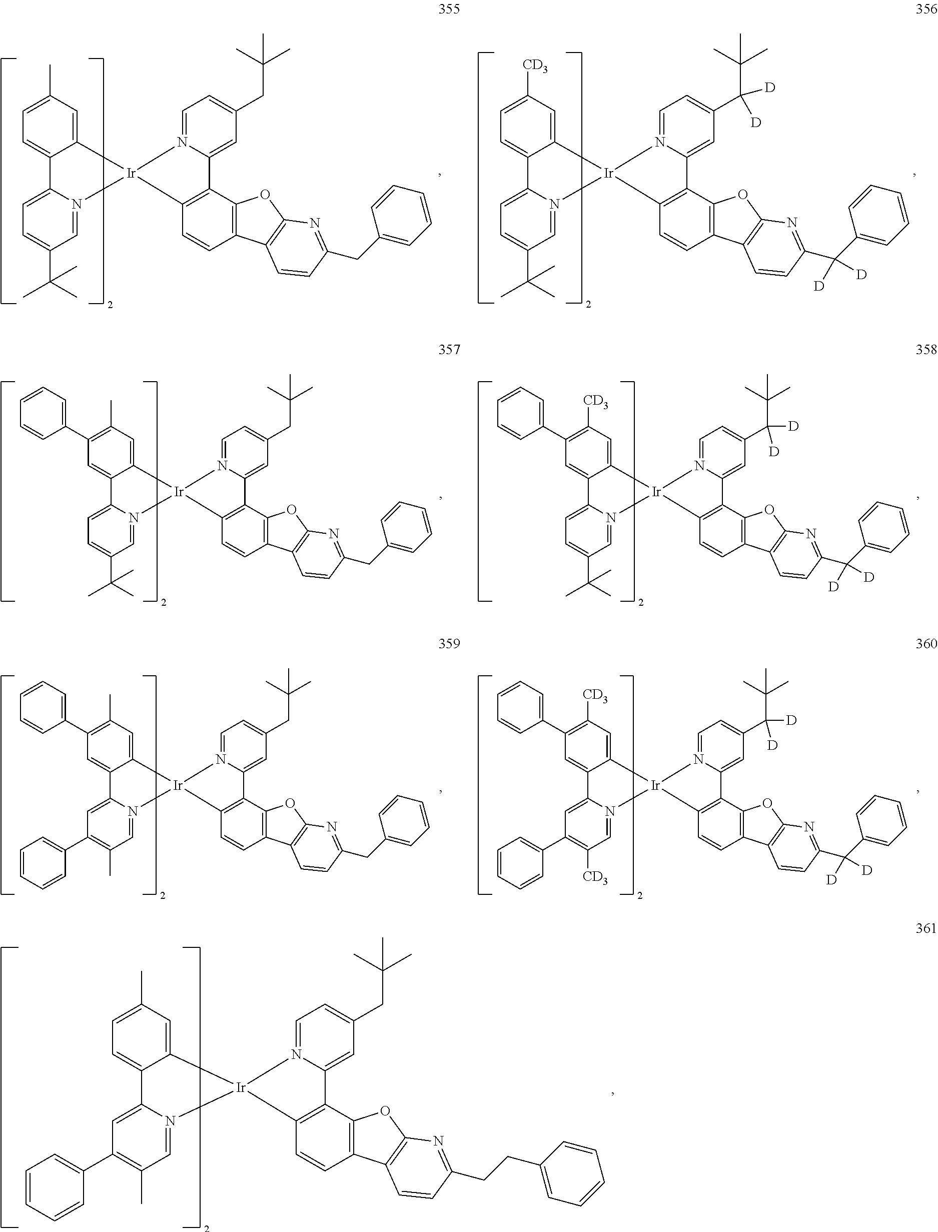

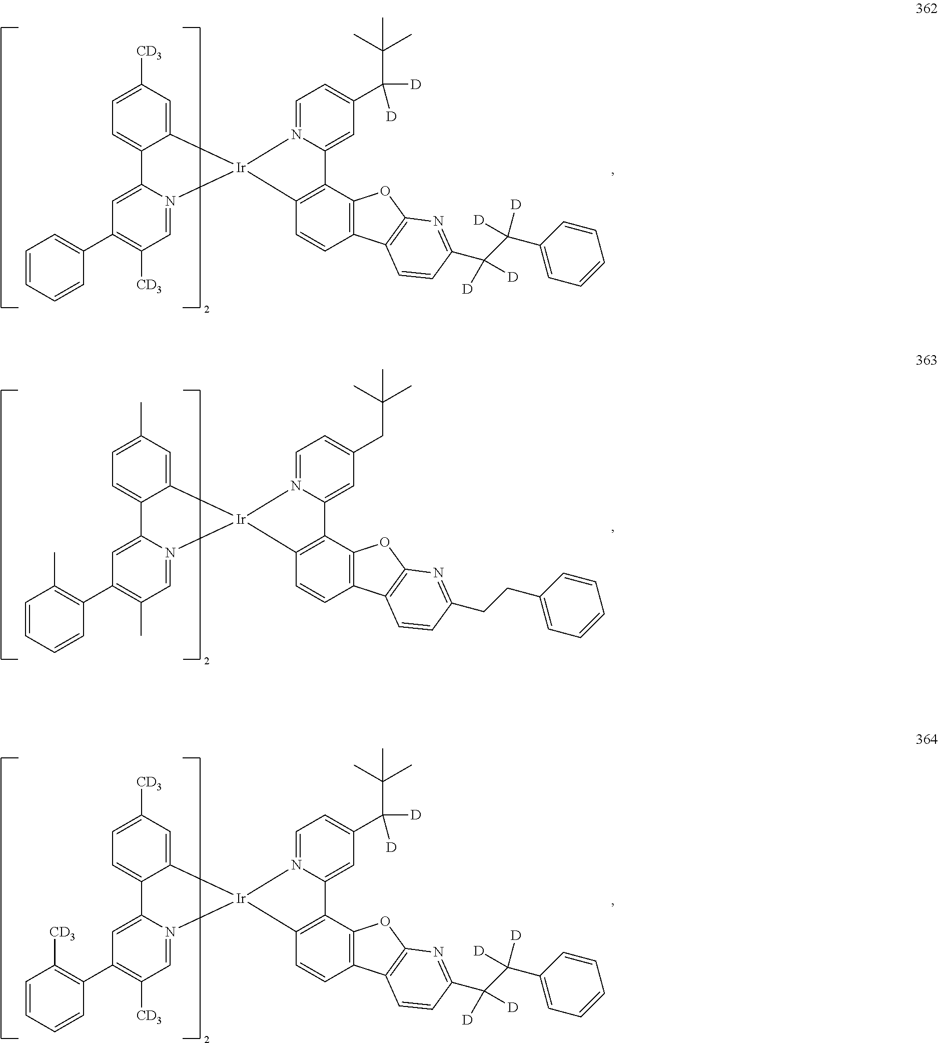

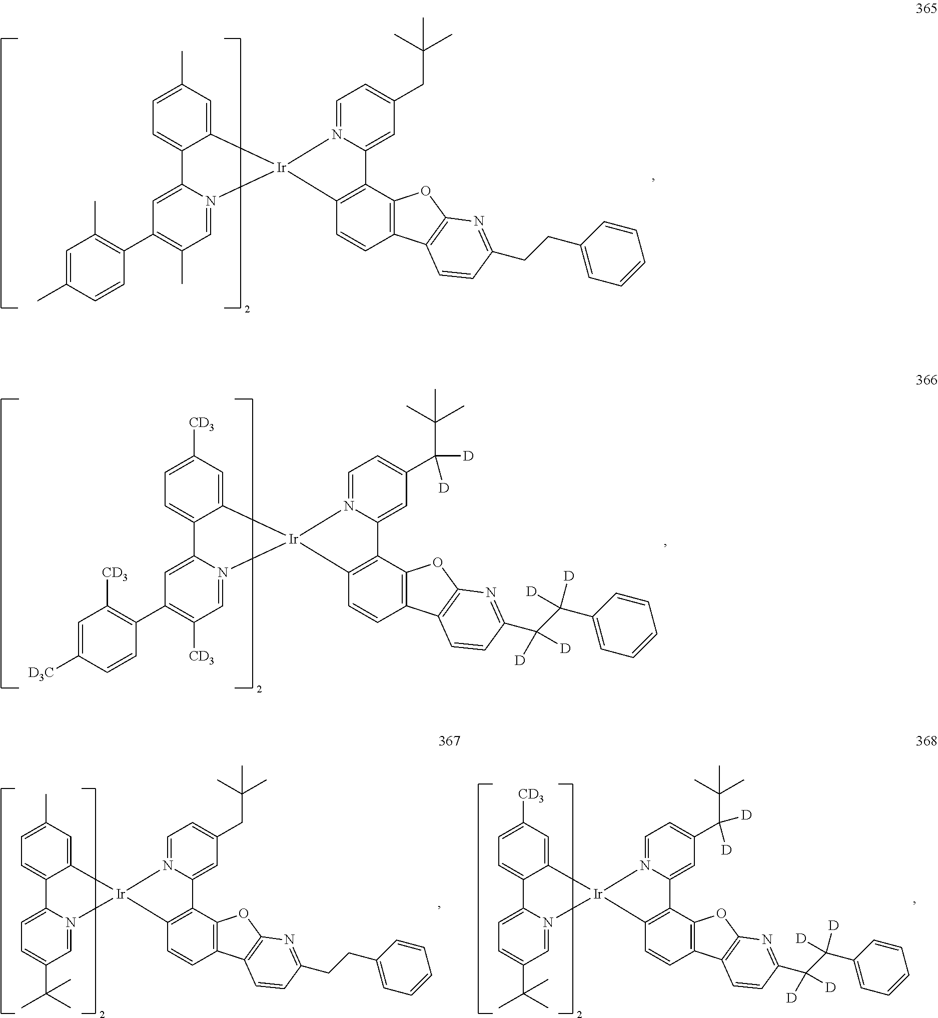

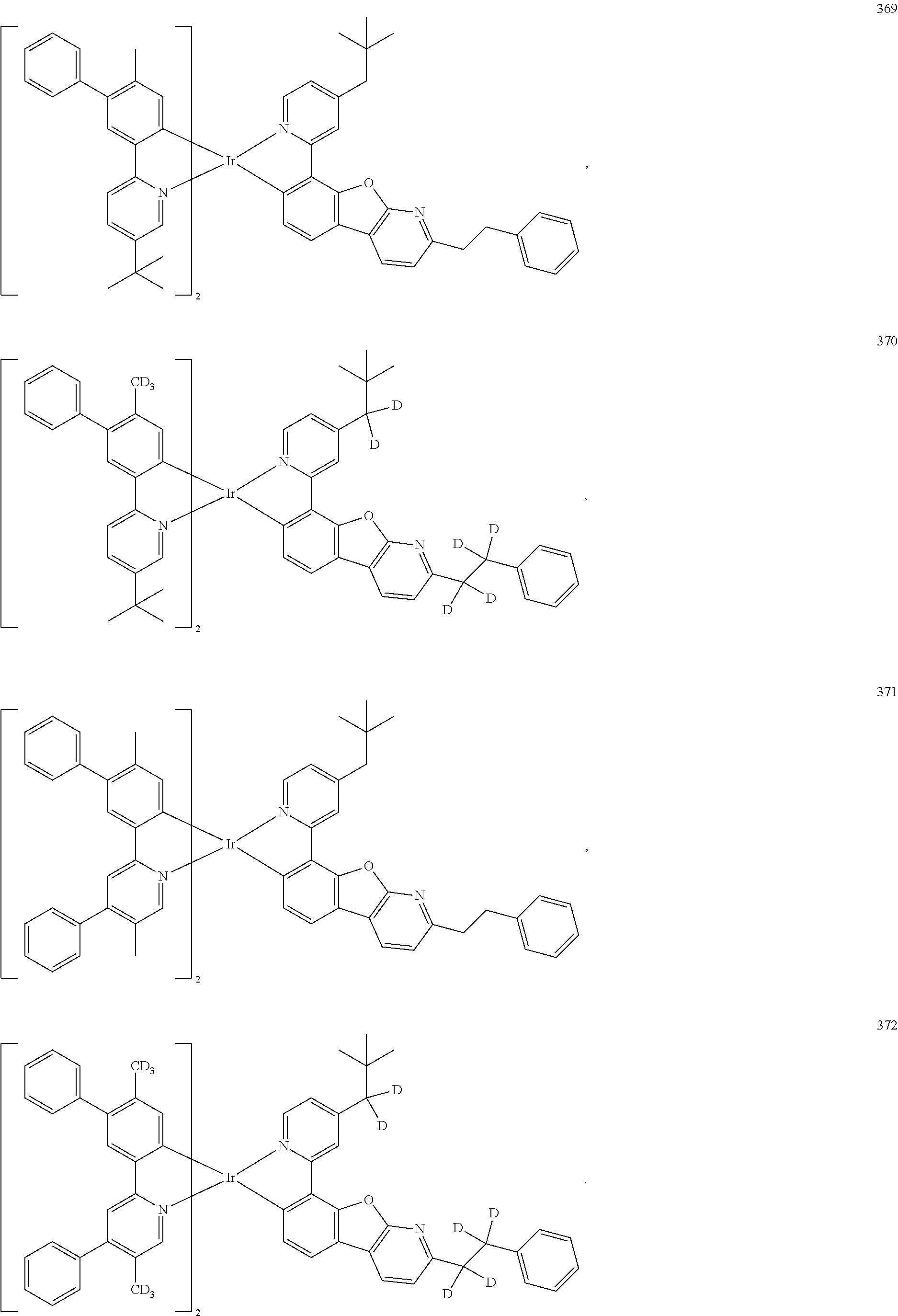

According to an example embodiment of the present disclosure, the organometallic compound represented by Chemical Formula 1 of the present disclosure may be used as a green phosphorescent dopant material.

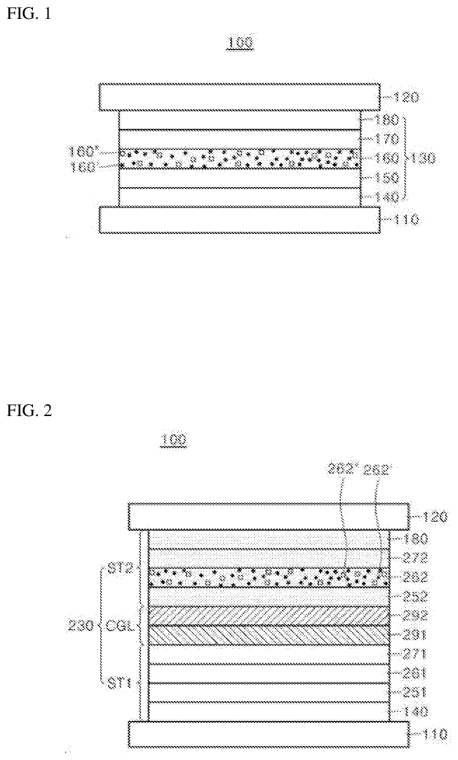

Referring to FIG. 1 according to an example embodiment of the present disclosure, an organic light-emitting diode 100 may include a first electrode 110; a second electrode 120 facing the first electrode 110; and an organic layer 130 disposed between the first electrode 110 and the second electrode 120. The organic layer 130 may include a light-emitting layer 160, and the light-emitting layer 160 may include a host material 160″ and a dopant material 160′. The dopant 160′ may be made of or include the organometallic compound represented by the Chemical Formula 1. In addition, in the organic light-emitting diode 100, the organic layer 130 disposed between the first electrode 110 and the second electrode 120 may be formed by sequentially stacking a hole injection layer 140 (HIL), a hole transport layer 150 (HTL), a light-emitting layer 160 (EML), an electron transport layer 170 (ETL) and an electron injection layer 180 (EIL) on the first electrode 110. The second electrode 120 may be formed or disposed on the electron injection layer 180, and a protective layer (not illustrated) may be formed or disposed thereon.

The first electrode 110 may act as a positive electrode, and may be made of or include ITO, IZO, tin-oxide, or zinc-oxide as a conductive material having a relatively large work function value. However, the present disclosure is not limited thereto.

The second electrode 120 may act as a negative electrode, and may include Al, Mg, Ca, or Ag as a conductive material having a relatively small work function value, or an alloy or combinations thereof. However, the present disclosure is not limited thereto.

The hole injection layer 140 may be positioned between the first electrode 110 and the hole transport layer 150. The hole injection layer 140 may include a compound selected from the group consisting of MTDATA, CuPc, TCTA, NPB(NPD), HATCN, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB (N,N′-diphenyl-N,N′-di[4-(N,N-diphenyl-amino)phenyl]benzidine), etc. In some embodiments, the hole injection layer 140 may include NPNPB. However, the present disclosure is not limited thereto.

The hole transport layer 150 may be positioned adjacent to the light-emitting layer and between the first electrode 110 and the light-emitting layer 160. A material of the hole transport layer 150 may include a compound selected from the group consisting of TPD, NPD, CBP, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl)-4-amine, etc. However, the present disclosure is not limited thereto.

According to the present disclosure, the light-emitting layer 160 may be formed by doping the host material 160″ with the organometallic compound represented by the Chemical Formula 1 as the dopant 160′ to improve luminous efficiency of the diode 100. The organometallic compound represented by the Chemical Formula 1 may be used as a green or red light-emitting material. In some embodiments, the organometallic compound represented by the Chemical Formula 1 may be a green phosphorescent material.

In an example embodiment of the present disclosure, a doping concentration of the dopant 160′ according to the present disclosure may be adjusted to be within a range of 1 to 30% by weight based on a total weight of the host material 160″. However, the disclosure is not limited thereto. For example, the doping concentration may be in a range of 2 to 20 wt %, for example, 3 to 15 wt %, for example, 5 to 10 wt %, for example, 3 to 8 wt %, for example, 2 to 7 wt %, for example, 5 to 7 wt %, or for example, 5 to 6 wt %.

The light-emitting layer 160 according to the present disclosure contains the host material 160′ which may be known in the art and may achieve an effect of the present disclosure when the layer 160 contains the organometallic compound represented by the Chemical Formula 1 as the dopant 160′. For example, in accordance with the present disclosure, the host material 160′ may include a host material selected from the group consisting of CBP (carbazole biphenyl), mCP (1,3-bis(carbazol-9-yl), and the like. However, the disclosure is not limited thereto.

Further, the electron transport layer 170 and the electron injection layer 180 may be sequentially stacked between the light-emitting layer 160 and the second electrode 120. A material of the electron transport layer 170 may have high electron mobility such that electrons may be stably supplied to the light-emitting layer under smooth electron transport.

For example, the material of the electron transport layer 170 may include a compound selected from the group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4-oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzothiazole, and ZADN (2-[4-(9,10-Di-2-naphthalen2-yl-2-anthracen-2-yl)phenyl]-1-phenyl-1H-benzoimidazole). In some embodiments, the material of the electron transport layer 170 may include ZADN. However, the present disclosure is not limited thereto.

The electron injection layer 180 may facilitate electron injection. A material of the electron injection layer may include a compound selected from the group consisting of Alq3 (tris(8-hydroxyquinolino)aluminum), PBD, TAZ, spiro-PBD, BAlq, SAlq, etc. However, the present disclosure is not limited thereto. In some embodiments, the electron injection layer 180 may be made of or include a metal compound. The metal compound may include, for example, one or more selected from the group consisting of Liq, LiF, NaF, KF, RbF, CsF, FrF, BeF₂, MgF₂, CaF₂, SrF₂, BaF₂ and RaF₂. However, the present disclosure is not limited thereto.

The organic light-emitting diode according to the present disclosure may be embodied as a white light-emitting diode having a tandem structure. The tandem organic light-emitting diode according to an illustrative embodiment of the present disclosure may be formed or disposed in a structure including adjacent stacks among two or more light-emitting stacks are connected to each other via a charge generation layer (CGL). The organic light-emitting diode may include the first and the second electrodes on a substrate, facing each other, and at least two light-emitting stacks each of which has a light-emitting layer being disposed between the first and the second electrodes so as to emit light in a specific wavelength band. The plurality of light-emitting stacks may emit light of the same color or different colors. In addition, one or more light-emitting layers may be included in one light-emitting stack, and the plurality of light-emitting layers may emit light of the same color or different colors.

In an example embodiment, the light-emitting layer included in at least one of the plurality of light-emitting stacks may contain the organometallic compound represented by the Chemical Formula 1 according to the present disclosure as the dopant. Adjacent stacks among the plurality of light-emitting stacks in the tandem structure may be connected to each other via the charge generation layer CGL including an N-type charge generation layer and a P-type charge generation layer.

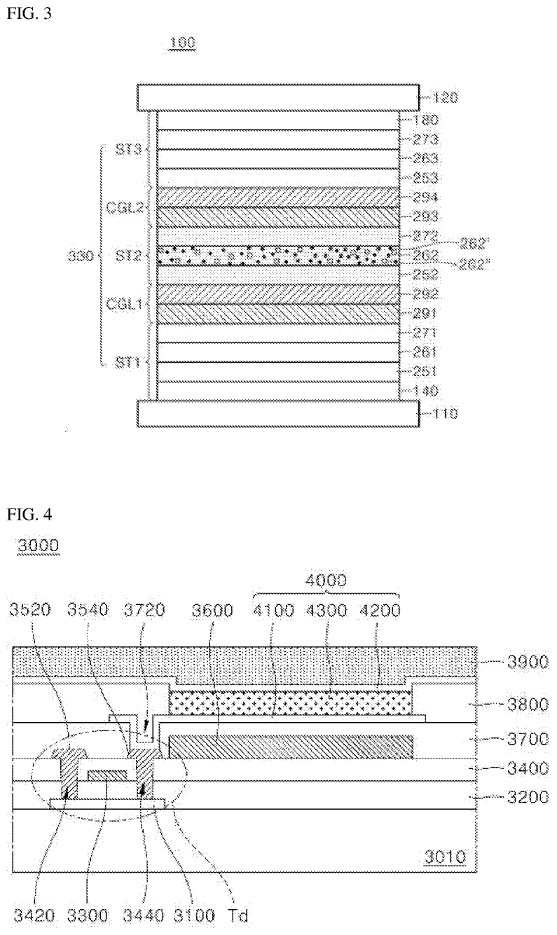

FIG. 2 and FIG. 3 are cross-sectional views schematically showing an organic light-emitting diode in a tandem structure having two light-emitting stacks and an organic light-emitting diode in a tandem structure having three light-emitting stacks, respectively, according to some example embodiments of the present disclosure.

As illustrated in FIG. 2, an organic light-emitting diode 100 according to the present disclosure may include a first electrode 110 and a second electrode 120 facing each other, and an organic layer 230 may be positioned between the first electrode 110 and the second electrode 120. The organic layer 230 may include a first light-emitting stack ST1 including a first light-emitting layer 261, a second light-emitting stack ST2 positioned between the first light-emitting stack ST1 and the second electrode 120 and including a second light-emitting layer 262, and the charge generation layer CGL positioned between the first and second light-emitting stacks ST1 and ST2. The charge generation layer CGL may include an N-type charge generation layer 291 and a P-type charge generation layer 292. At least one of the first light-emitting layer 261 and the second light-emitting layer 262 may contain the organometallic compound represented by the Chemical Formula 1 according to the present disclosure as the dopant 262′. For example, as illustrated in FIG. 2, the second light-emitting layer 262 of the second light-emitting stack ST2 may contain a host material 262″, and the dopant 262′ made of or include the organometallic compound represented by the Chemical Formula 1 doped into the host material. Although not illustrated in FIG. 2, each of the first and second light-emitting stacks ST1 and ST2 may further include, in addition to each of the first light-emitting layer 261 and the second light-emitting layer 262, an additional light-emitting layer. The descriptions as set forth above with respect to the hole transport layer 150 illustrated in the example embodiment in FIG. 1 may be applied in the same or similar manner to each of the first hole transport layer 251 and the second hole transport layer 252 illustrated in the example embodiment in FIG. 2. Moreover, the descriptions as set forth above with respect to the electron transport layer 170 illustrated in the example embodiments in FIG. 1 may be applied in the same or similar manner to each of the first electron transport layer 271 and the second electron transport layer 272 illustrated in the example embodiments in FIG. 2.

As illustrated in FIG. 3, the organic light-emitting diode 100 according to the present disclosure may include the first electrode 110 and the second electrode 120 facing each other, and an organic layer 330 positioned between the first electrode 110 and the second electrode 120. The organic layer 330 may be positioned between the first electrode 110 and the second electrode 120 and may include the first light-emitting stack ST1 including the first light-emitting layer 261, the second light-emitting stack ST2 including the second light-emitting layer 262, a third light-emitting stack ST3 including a third light-emitting layer 263, a first charge generation layer CGL1 positioned between the first and second light-emitting stacks ST1 and ST2, and a second charge generation layer CGL2 positioned between the second and third light-emitting stacks ST2 and ST3. The first charge generation layer CGL1 may include a N-type charge generation layers 291 and a P-type charge generation layer 292. The second charge generation layer CGL2 may include a N-type charge generation layer 293 and a P-type charge generation layer 294. At least one of the first light-emitting layer 261, the second light-emitting layer 262, and the third light-emitting layer 263 may contain the organometallic compound represented by the Chemical Formula 1 according to the present disclosure as the dopant. For example, as illustrated in FIG. 3, the second light-emitting layer 262 of the second light-emitting stack ST2 may contain the host material 262″, and the dopant 262′ made of or include the organometallic compound represented by the Chemical Formula 1 doped into the host material. Although not illustrated in FIG. 3, each of the first, second and third light-emitting stacks ST1, ST2 and ST3 may further include an additional light-emitting layer, in addition to each of the first light-emitting layer 261, the second light-emitting layer 262 and the third light-emitting layer 263. The descriptions as set forth above with respect to the hole transport layer 150 illustrated in the example embodiment in FIG. 1 may be applied in the same or similar manner to each of the first hole transport layer 251, the second hole transport layer 252, and the third hole transport layer 253 illustrated in the example embodiment in FIG. 3. Moreover, the descriptions as set forth above with respect to the electron transport layer 170 illustrated in the example embodiment in FIG. 1 may be applied in the same or similar manner to each of the first electron transport layer 271, the second electron transport layer 272, and the third electron transport layer 273 illustrated in the example embodiment in FIG. 3.

Furthermore, an organic light-emitting diode according to an embodiment of the present disclosure may include a tandem structure including four or more light-emitting stacks and three or more charge generating layers disposed between the first electrode and the second electrode.

The organic light-emitting diode according to the present disclosure may be used as a light-emitting element of each of an organic light-emitting display device and a lighting device. In an example embodiment, FIG. 4 is a cross-sectional view schematically illustrating an organic light-emitting display device including the organic light-emitting diode according to some embodiments of the present disclosure as a light-emitting element thereof.

As illustrated in FIG. 4, an organic light-emitting display device 3000 includes a substrate 3010, an organic light-emitting diode 4000, and an encapsulation film 3900 covering the organic light-emitting diode 4000. A driving thin-film transistor Td as a driving element, and the organic light-emitting diode 4000 connected to the driving thin-film transistor Td are positioned on the substrate 3010.

Although not illustrated explicitly in FIG. 4, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed or disposed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 may be formed or disposed on the substrate 3010 and may be made of or include an oxide semiconductor material or polycrystalline silicon. When the semiconductor layer 3100 is made of or include an oxide semiconductor material, a light-shielding pattern (not illustrated) may be formed or disposed under the semiconductor layer 3100. The light-shielding pattern may prevent or reduce the chances of light from being incident into the semiconductor layer 3100 to prevent or reduce the chances of the semiconductor layer 3100 from being deteriorated due to the light. In some embodiments, the semiconductor layer 3100 may be made of or include polycrystalline silicon. In an example embodiment, both edges of the semiconductor layer 3100 may be doped with impurities.

The gate insulating layer 3200 made of or include an insulating material is formed or disposed over an entirety of a surface of the substrate 3010 and on the semiconductor layer 3100. The gate insulating layer 3200 may be made of or include an inorganic insulating material such as silicon oxide or silicon nitride.

The gate electrode 3300 made of or include a conductive material such as a metal is formed or disposed on the gate insulating layer 3200 and corresponds to a center of the semiconductor layer 3100. The gate electrode 3300 is connected to the switching thin film transistor.

The interlayer insulating layer 3400 made of or include an insulating material is formed or disposed over the entirety of the surface of the substrate 3010 and on the gate electrode 3300. The interlayer insulating layer 3400 may be made of or include an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of or include a conductive material such as metal are formed or disposed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line (not illustrated).

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

In some embodiments, the driving thin-film transistor Td may have an inverted staggered structure in which the gate electrode is disposed under the semiconductor layer while the source electrode and the drain electrode are disposed above the semiconductor layer. In an example embodiment, the semiconductor layer may be made of or include amorphous silicon. In an example, the switching thin-film transistor (not illustrated) may have substantially the same structure as that of the driving thin-film transistor (Td).

In an example, the organic light-emitting display device 3000 may include a color filter 3600 absorbing the light generated from the electroluminescent element (light-emitting diode) 4000. For example, the color filter 3600 may absorb red (R), green (G), blue (B), and white (W) light. In an example embodiment, red, green, and blue color filter patterns that absorb light may be formed or disposed separately in different pixel areas. Each of these color filter patterns may be disposed to overlap each organic layer 4300 of the organic light-emitting diode 4000 to emit light of a wavelength band corresponding to each color filter. Adopting the color filter 3600 may allow the organic light-emitting display device 3000 to realize full-color.

For example, when the organic light-emitting display device 3000 is of a bottom emission type, the color filter 3600 absorbing light may be positioned on a portion of the interlayer insulating layer 3400 corresponding to the organic light-emitting diode 4000. In some embodiments, when the organic light-emitting display device 3000 is of a top emission type, the color filter may be positioned on top of the organic light-emitting diode 4000, that is, on top of a second electrode 4200. For example, the color filter 3600 may be formed to have a thickness of 2 to 5 m.

In an example, a planarization layer 3700 having a drain contact hole 3720 defined therein exposing the drain electrode 3540 of the driving thin-film transistor Td is formed or disposed to cover the driving thin-film transistor Td.

On the planarization layer 3700, each first electrode 4100 connected to the drain electrode 3540 of the driving thin-film transistor Td via the drain contact hole 3720 is formed or disposed individually in each pixel area.

The first electrode 4100 may act as a positive electrode (anode), and may be made of or include a conductive material having a relatively large work function value. For example, the first electrode 4100 may be made of or include a transparent conductive material such as ITO, IZO or ZnO.

In an example, when the organic light-emitting display device 3000 is of a top-emission type, a reflective electrode or a reflective layer may be further formed or disposed under the first electrode 4100. For example, the reflective electrode or the reflective layer may be made of or include one of aluminum (Al), silver (Ag), nickel (Ni), and an aluminum-palladium-copper (APC) alloy.

A bank layer 3800 covering an edge of the first electrode 4100 is formed or disposed on the planarization layer 3700. The bank layer 3800 exposes a center of the first electrode 4100 corresponding to the pixel area.

An organic layer 4300 is formed or disposed on the first electrode 4100. In some embodiments, the organic light-emitting diode 4000 may have a tandem structure, as illustrated in the example embodiments in FIG. 2 to FIG. 4.

The second electrode 4200 is formed or disposed on the substrate 3010 on which the organic layer 4300 has been formed. The second electrode 4200 is disposed over the entirety of the surface of the display area and is made of or include a conductive material having a relatively small work function value and may be used as a negative electrode (a cathode). For example, the second electrode 4200 may be made of or include one of aluminum (Al), magnesium (Mg), and an aluminum-magnesium alloy (Al—Mg).

The first electrode 4100, the organic layer 4300, and the second electrode 4200 constitute the organic light-emitting diode 4000.

An encapsulation film 3900 is formed or disposed on the second electrode 4200 to prevent or reduce external moisture from penetrating into the organic light-emitting diode 4000. Although not illustrated explicitly in FIG. 4, the encapsulation film 3900 may have a triple-layer structure in which a first inorganic layer, an organic layer, and an inorganic layer are sequentially stacked. However, the present disclosure is not limited thereto.

Hereinafter, Synthesis Examples and Present Examples of the present disclosure will be described. However, the following Examples are examples of the present disclosure. The present disclosure is not limited thereto.

### Synthesis Examples

### Preparation of Ligand A-3

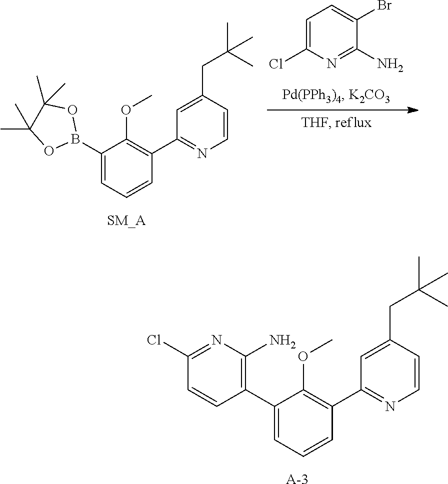

SM_A (11.44 g, 30 mmol), 3-bromo-6-chloropyridin-2-amine (6.22 g, 30 mmol), potassium carbonate (8.02 g, 58 mmol), and Pd(PPh₃)₄ (0.69 g, 0.6 mmol) were dissolved in tetrahydrofuran (300 ml) to produce a solution which in turn was stirred under reflux for 6 hours. A resulting crude mixture was filtered through celite and silica gel to obtain a solid which in turn was dissolved in dichloromethane, and methanol was added thereto little by little such that a solid was precipitated to obtain 9.28 g (81%) of a target compound A-3.

### Preparation of Ligand A-2

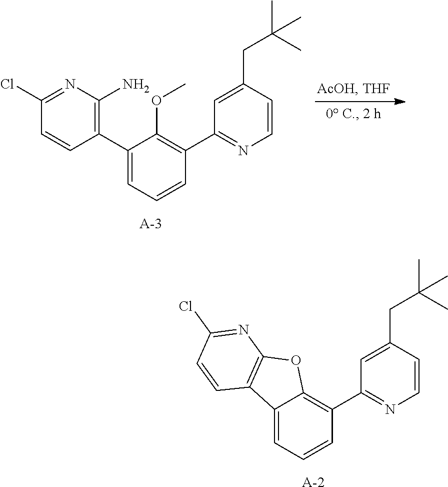

A-3 (9.17 g, 24 mmol) was dissolved in acetic acid (200 ml) and tetrahydrofuran (100 ml), followed by stirring at 0 degrees Celsius for 2 hours. Then, a reaction product was heated to room temperature. The reaction mixture was mixed with ethyl acetate and water. The organic phase was isolated, washed with aqueous sodium bicarbonate and brine, dried with sodium sulfate, filtered, and evaporated to remove solvent. After the evaporation of the solvent, the residue was purified by silica gel-based column chromatography using 30% dichloromethane in hexane to obtain 6.15 g (73%) of a target compound A-2.

### Preparation of Ligand A-1

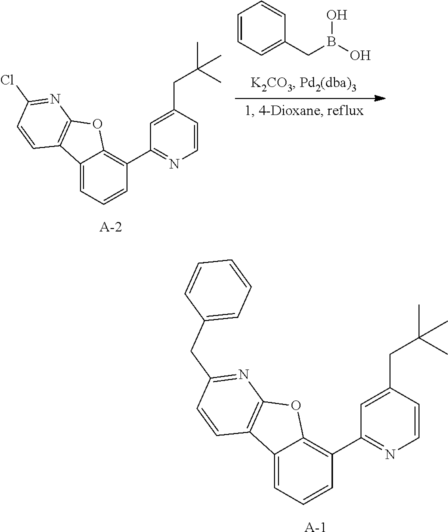

A mixed solution in which A-2 (5.96 g, 17 mmol), benzylboronic acid (2.31 g, 17 mmol), Pd₂(dba)₃ (0.30 g, 0.33 mmol), and potassium carbonate (4.70 g, 34 mmol) were dissolved in 1,4-dioxane (150 ml) was refluxed overnight. The solution was subjected to evaporation. The residue was mixed with dichloromethane and water. An organic phase was isolated, dried on sodium sulfate, filtered, and evaporated to remove the solvent. After the evaporation of the solvent, a crude mixture was purified by silica gel-based column chromatography using 30 to 40% dichloromethane in hexane to obtain 4.77 g (69%) of a target compound A-1.

### Preparation of Ligand A

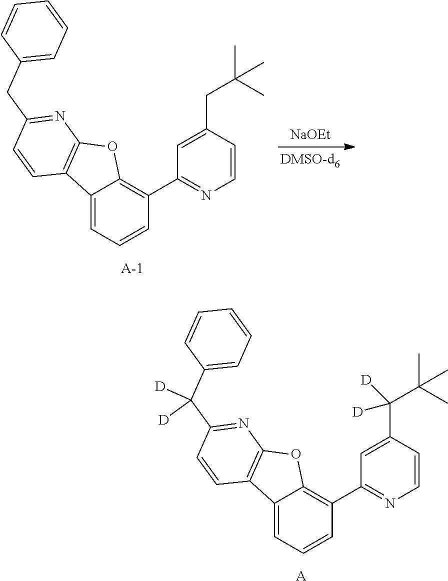

A mixed solution in which A-1 (4.47 g, 11 mmol) and sodium ethoxide (4.08 g, 60 mmol) were dissolved in DMSO-d6 (100 ml) was refluxed for 60 hours. The solution was subjected to evaporation. The residue was mixed with dichloromethane and water. An organic phase was isolated, dried on sodium sulfate, filtered, and evaporated to remove the solvent. After the evaporation of the solvent, a crude mixture was purified by silica gel-based column chromatography using 40 to 50% hexane in dichloromethane to obtain 3.66 g (81%) of a target compound A.

### Preparation of Ligand B-1

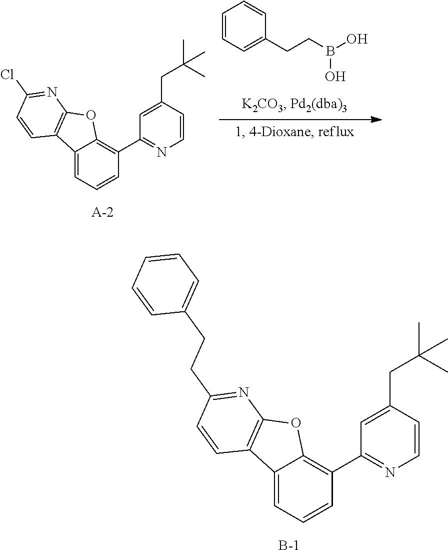

A mixed solution in which A-2 (7.72 g, 22 mmol), phenylethylboronic acid (3.30 g, 22 mmol), Pd₂(dba)₃ (0.40 g, 0.44 mmol), and sodium carbonate (6.08 g, 44 mmol) were dissolved in 1,4-dioxane (180 ml) was refluxed overnight. The solution was subjected to evaporation. The residue was mixed with dichloromethane and water. An organic phase was isolated, dried on sodium sulfate, filtered, and evaporated to remove the solvent. After the evaporation of the solvent, a crude mixture was purified by silica gel-based column chromatography using 30 to 40% dichloromethane in hexane to obtain 6.75 g (73%) of a target compound B-1.

### Preparation of Ligand B

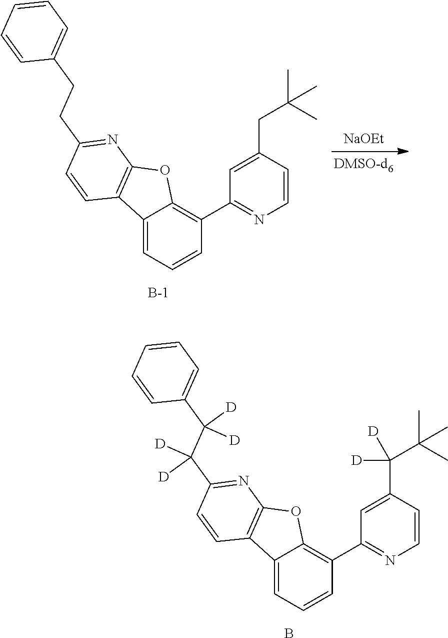

A mixed solution in which B-1 (6.31 g, 15 mmol) and sodium ethoxide (10.21 g, 150 mmol) were dissolved in DMSO-d6 (150 ml) was refluxed for 60 hours. The solution was subjected to evaporation. The residue was mixed with dichloromethane and water. An organic phase was isolated, dried on sodium sulfate, filtered, and evaporated to remove the solvent. After the evaporation of the solvent, a crude mixture was purified by silica gel-based column chromatography using 40 to 50% hexane in dichloromethane to obtain 4.99 g (78%) of a target compound B.

### Preparation of Ligand C-3

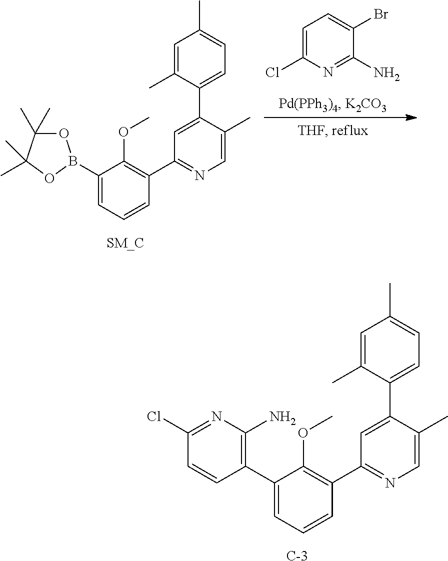

SM_C (21.47 g, 50 mmol), 3-bromo-6-chloropyridin-2-amine (10.37 g, 50 mmol), sodium carbonate (13.13 g, 95 mmol) and Pd(PPh₃)₄ (1.16 g, 1.0 mmol) were dissolved in tetrahydrofuran (600 ml) to produce a solution which in turn was stirred under reflux for 8 hours. A resulting crude mixture was filtered through celite and silica gel to obtain a solid which in turn was dissolved in dichloromethane, and methanol was added thereto little by little such that a solid was precipitated to obtain 15.26 g (71%) of a target compound C-3.

### Preparation of Ligand C-2

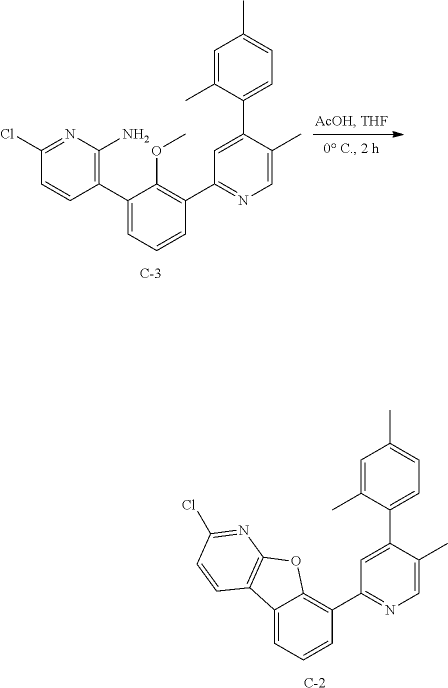

C-3 (15.05 g, 35 mmol) was dissolved in acetic acid (300 ml) and tetrahydrofuran (150 ml), followed by stirring at 0 degrees Celsius for 2 hours. Then, a reaction product was heated to room temperature. The reaction mixture was mixed with ethyl acetate and water. The organic phase was isolated, washed with aqueous sodium bicarbonate and brine, dried under sodium sulfate, filtered, and evaporated to remove the solvent. After the evaporation of the solvent, the residue was purified by silica gel-based column chromatography using 30% dichloromethane in hexane to obtain 9.21 g (66%) of a target compound C-2.

### Preparation of Ligand C-1

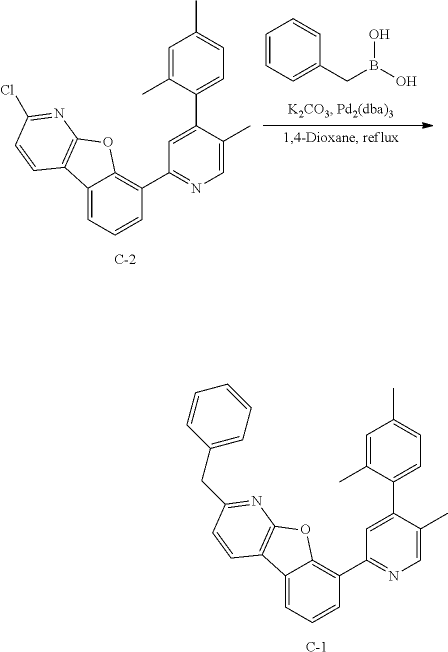

A mixed solution in which C-2 (9.17 g, 23 mmol), benzylboronic acid (3.13 g, 23 mmol), Pd₂(dba)₃ (0.53 g, 0.46 mmol), and sodium carbonate (6.36 g, 46 mmol) were dissolved in 1,4-dioxane (200 ml) was refluxed overnight. The solution was subjected to evaporation. The residue was mixed with dichloromethane and water. An organic phase was isolated, dried on sodium sulfate, filtered, and evaporated to remove the solvent. After the evaporation of the solvent, a crude mixture was purified by silica gel-based column chromatography using 30 to 40% dichloromethane in hexane to obtain 7.32 g (70%) of a target compound C-1.

### Preparation of Ligand C

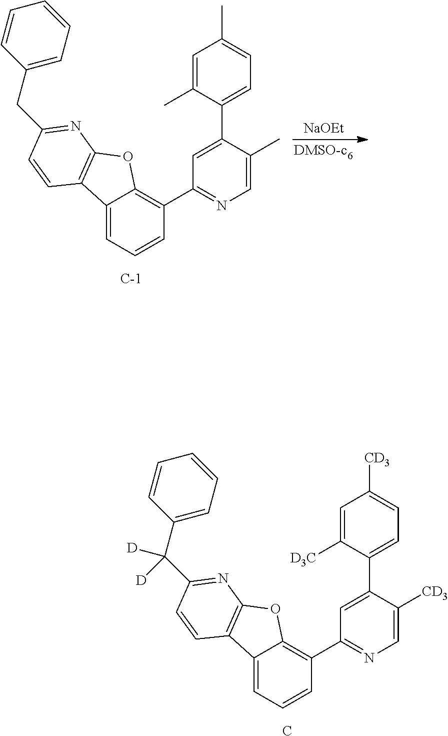

A mixed solution in which C-1 (7.27 g, 16 mmol) and sodium ethoxide (16.33 g, 240 mmol) were dissolved in DMSO-d6 (320 ml) was refluxed for 72 hours. The solution was subjected to evaporation. The residue was mixed with dichloromethane and water. An organic phase was isolated, dried on sodium sulfate, filtered, and evaporated to remove the solvent. After the evaporation of the solvent, a crude mixture was purified by silica gel-based column chromatography using 40 to 50% hexane in dichloromethane. Further, the above process was repeated to obtain 4.62 g (62%) of a target compound C.

### Preparation of Ligand D-1

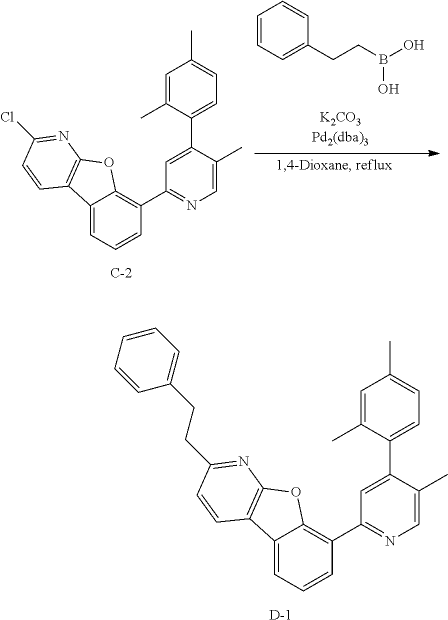

A mixed solution in which C-2 (11.97 g, 30 mmol), phenylethylboronic acid (4.50 g, 30 mmol), Pd₂(dba)₃ (0.69 g, 0.60 mmol), and sodium carbonate (8.29 g, 60 mmol) were dissolved in 1,4-dioxane (300 ml) was refluxed overnight. The solution was subjected to evaporation. The residue was mixed with dichloromethane and water. An organic phase was isolated, dried on sodium sulfate, filtered, and evaporated to remove the solvent. After the evaporation of the solvent, a crude mixture was purified by silica gel-based column chromatography using 30 to 40% dichloromethane in hexane to obtain 10.68 g (76%) of a target compound D-1.

### Preparation of Ligand D

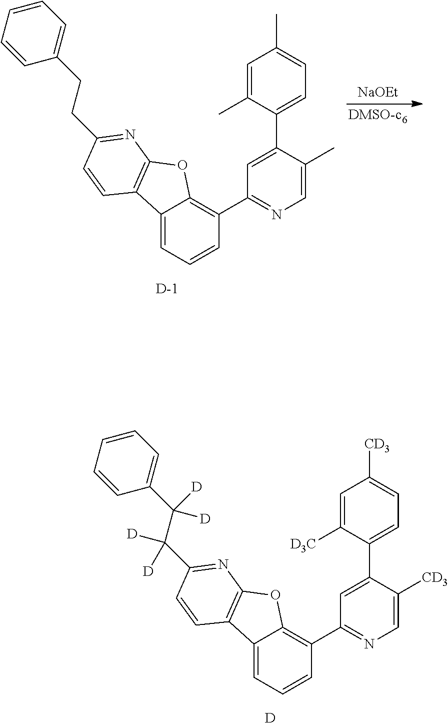

A mixed solution in which D-1 (10.31 g, 22 mmol) and sodium ethoxide (29.94 g, 440 mmol) were dissolved in DMSO-d6 (400 ml) was refluxed for 72 hours. The solution was subjected to evaporation. The residue was mixed with dichloromethane and water. An organic phase was isolated, dried on sodium sulfate, filtered, and evaporated to remove the solvent. After the evaporation of the solvent, a crude mixture was purified by silica gel-based column chromatography using 40 to 50% hexane in dichloromethane. Further, the above process was repeated to obtain 6.78 g (64%) of a target compound D.

### Preparation of Compound EE

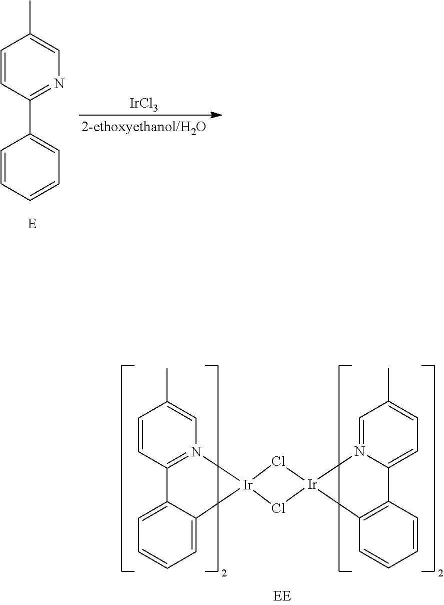

A solution in which E (6.77 g, 40 mmol) and IrCl₃ (4.78 g, 16 mmol) were dissolved in ethoxyethanol (100 ml), and distilled water (30 ml) was stirred under reflux for 24 hours. Thereafter, a temperature was lowered to room temperature, and a resulting solid was separated via filtration under reduced pressure. The solid was sufficiently washed with water and cold methanol and then filtered under reduced pressure. This process was repeated several times to obtain 8.39 g (93%) of a target compound EE.

### Preparation of Compound FF

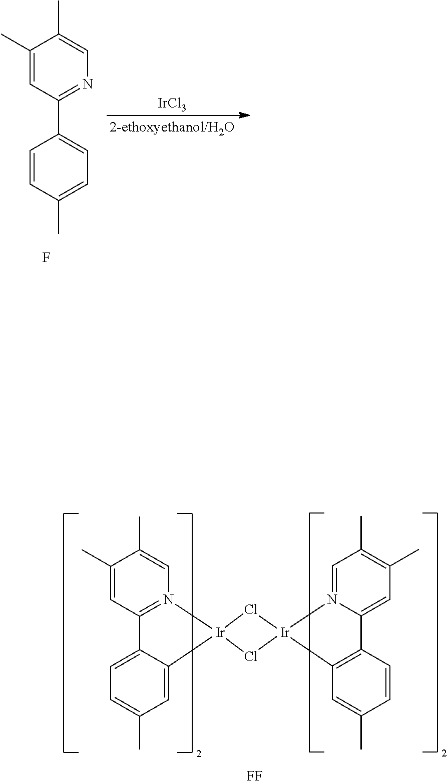

A solution in which F (7.89 g, 40 mmol) and IrCl₃ (4.78 g, 16 mmol) were dissolved in ethoxyethanol (100 ml), and distilled water (30 ml) was stirred under reflux for 24 hours. Thereafter, a temperature was lowered to room temperature, and a resulting solid was separated via filtration under reduced pressure. The solid was sufficiently washed with water and cold methanol and then filtered under reduced pressure. This process was repeated several times to obtain 8.93 g (90%) of a target compound FF.

### Preparation of Compound GG

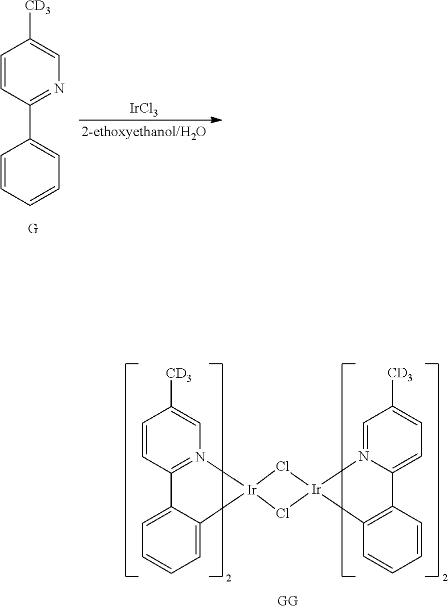

A solution in which G (6.89 g, 40 mmol) and IrCl₃ (4.78 g, 16 mmol) were dissolved in ethoxyethanol (100 ml), and distilled water (30 ml) was stirred under reflux for 24 hours. Thereafter, a temperature was lowered to room temperature, and a resulting solid was separated via filtration under reduced pressure. The solid was sufficiently washed with water and cold methanol and then filtered under reduced pressure. This process was repeated several times to obtain 8.48 g (93%) of a target compound GG.

### Preparation of Compound HH

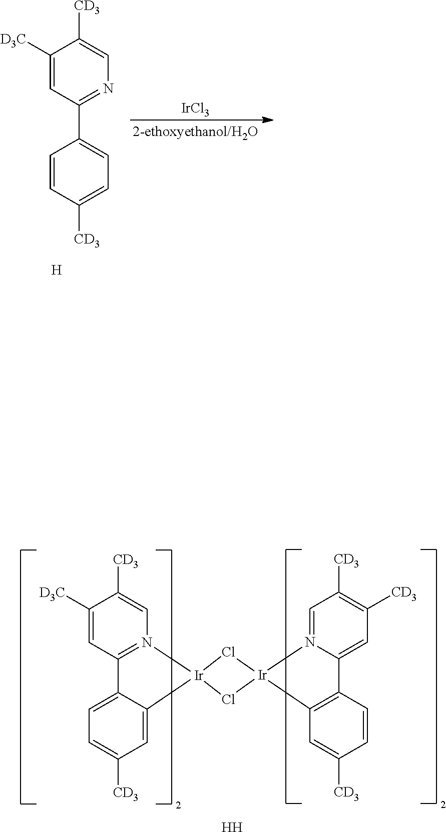

A solution in which H (8.25 g, 40 mmol) and IrCl₃ (4.78 g, 16 mmol) were dissolved in ethoxyethanol (100 ml), and distilled water (30 ml) was stirred under reflux for 24 hours. Thereafter, a temperature was lowered to room temperature, and a resulting solid was separated via filtration under reduced pressure. The solid was sufficiently washed with water and cold methanol and then filtered under reduced pressure. This process was repeated several times to obtain 9.29 g (91%) of a target compound HH.

### Preparation of Compound EEE

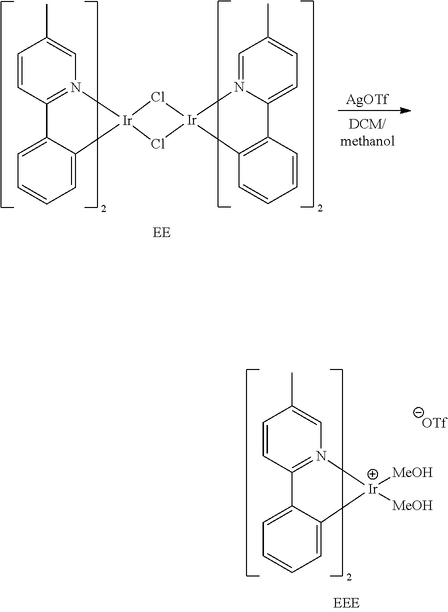

A solution in which EE (6.77 g, 6 mmol) and silver trifluoromethanesulfonate (4.54 g, 18 mmol) were dissolved in dichloromethane (100 ml), and methanol (100 ml) was stirred overnight at room temperature. After completion of a reaction, a reaction solution was filtered with Celite to remove solid precipitates therefrom. The solvent was removed from the filtrate under reduced pressure, and the resulting solid (target compound EEE) obtained therefrom was washed three times with hexane. 8.46 g (95%) of the target compound EEE was obtained.

### Preparation of Compound FFF

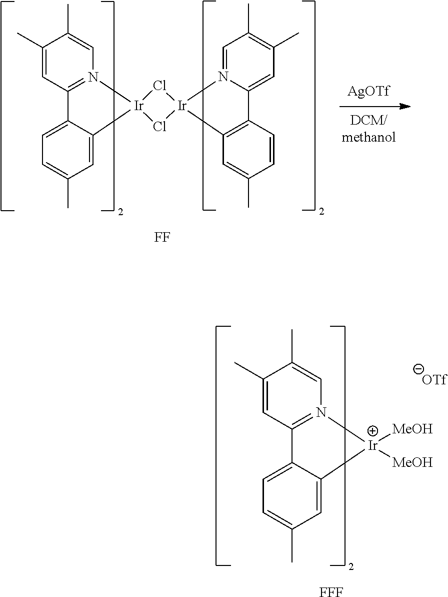

A solution in which FF (7.44 g, 6 mmol) and silver trifluoromethanesulfonate (4.54 g, 18 mmol) were dissolved in dichloromethane (100 ml), and methanol (100 ml) was stirred overnight at room temperature. After completion of a reaction, a reaction solution was filtered with Celite to remove solid precipitates therefrom. The solvent was removed from the filtrate under reduced pressure, and the resulting solid (target compound FFF) obtained therefrom was washed three times with hexane. 8.81 g (92%) of the target compound FFF was obtained.

### Preparation of Compound GGG

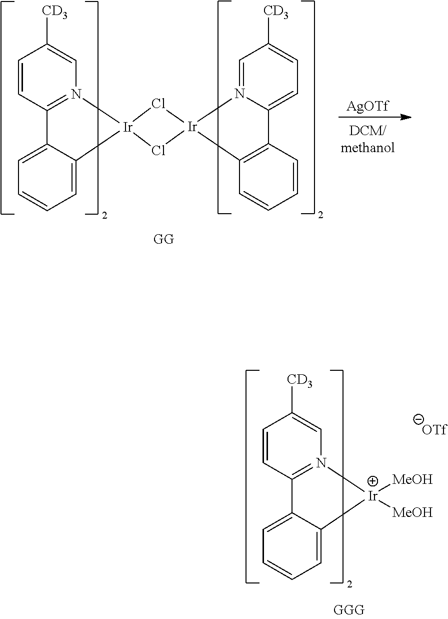

A solution in which GG (6.84 g, 6 mmol) and silver trifluoromethanesulfonate (4.54 g, 18 mmol) were dissolved in dichloromethane (100 ml), and methanol (100 ml) was stirred overnight at room temperature. After completion of a reaction, a reaction solution was filtered with Celite to remove solid precipitates therefrom. The solvent was removed from the filtrate under reduced pressure, and the resulting solid (target compound GGG) obtained therefrom was washed three times with hexane. 8.53 g (95%) of the target compound GGG was obtained.

### Preparation of Compound HHH

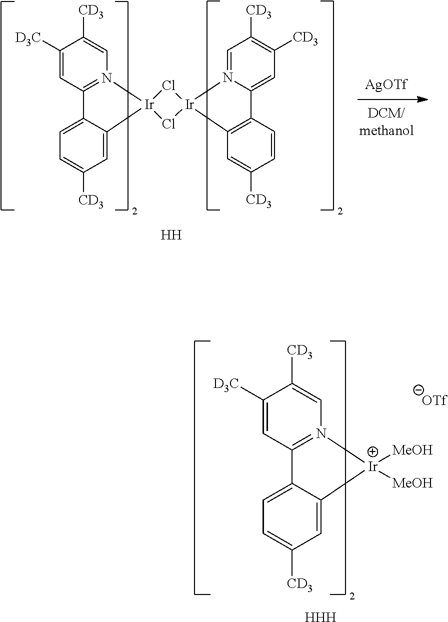

A solution in which HH (7.66 g, 6 mmol) and silver trifluoromethanesulfonate (4.54 g, 18 mmol) were dissolved in dichloromethane (100 ml), and methanol (100 ml) was stirred overnight at room temperature. After completion of a reaction, a reaction solution was filtered with Celite to remove solid precipitates therefrom. The solvent was removed from the filtrate under reduced pressure, and the resulting solid (target compound HHH) obtained therefrom was washed three times with hexane. 9.20 g (94%) of the target compound HHH was obtained.

### Preparation of Iridium Compound 105

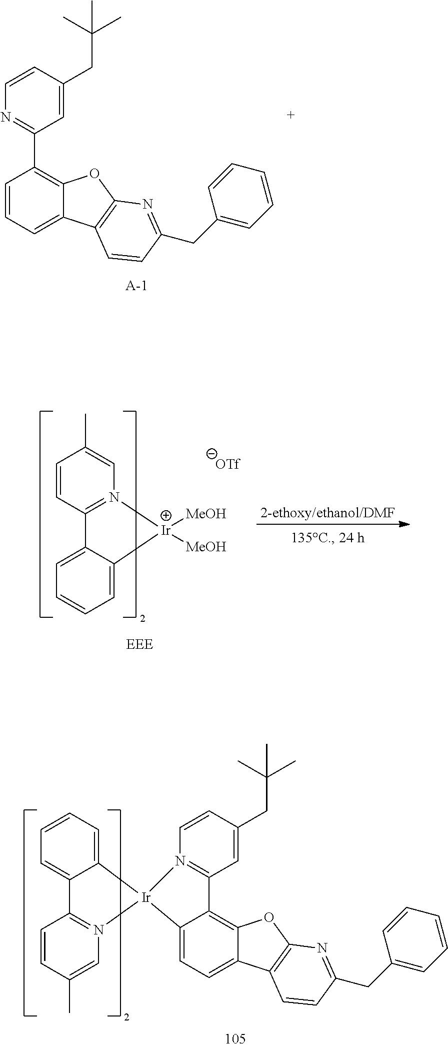

A solution in which A-1 (2.03 g, 5 mmol) and EEE (4.45 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.36 g (72%) of a target iridium compound 105.

### Preparation of Iridium Compound 153

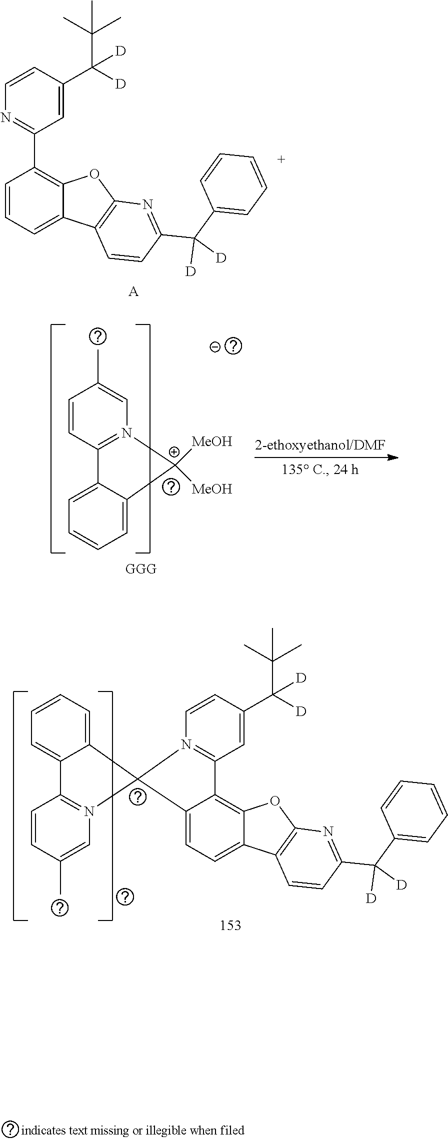

A solution in which A (2.05 g, 5 mmol) and GGG (4.49 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.64 g (77%) of a target iridium compound 153.

### Preparation of Iridium Compound 201

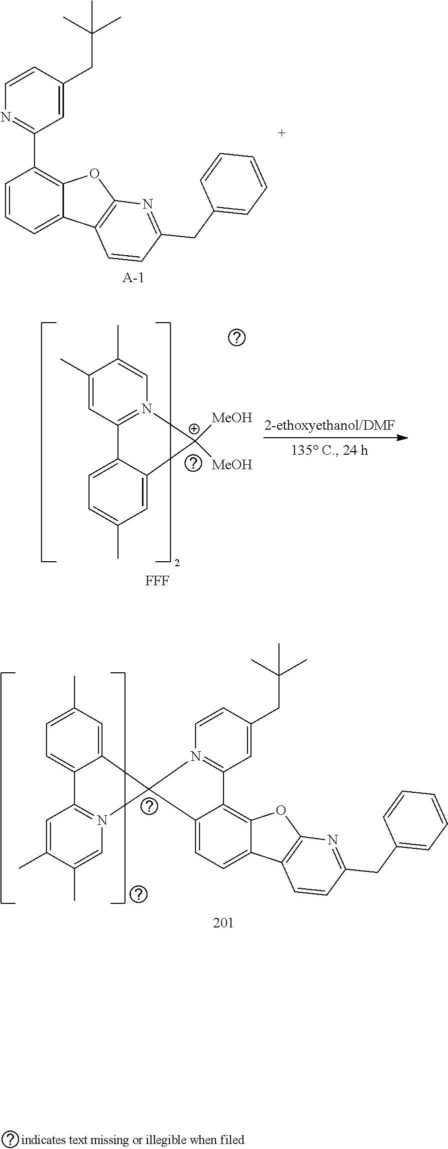

A solution in which A-1 (2.03 g, 5 mmol) and FFF (4.79 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.96 g (80%) of a target iridium compound 201.

### Preparation of Iridium Compound 249

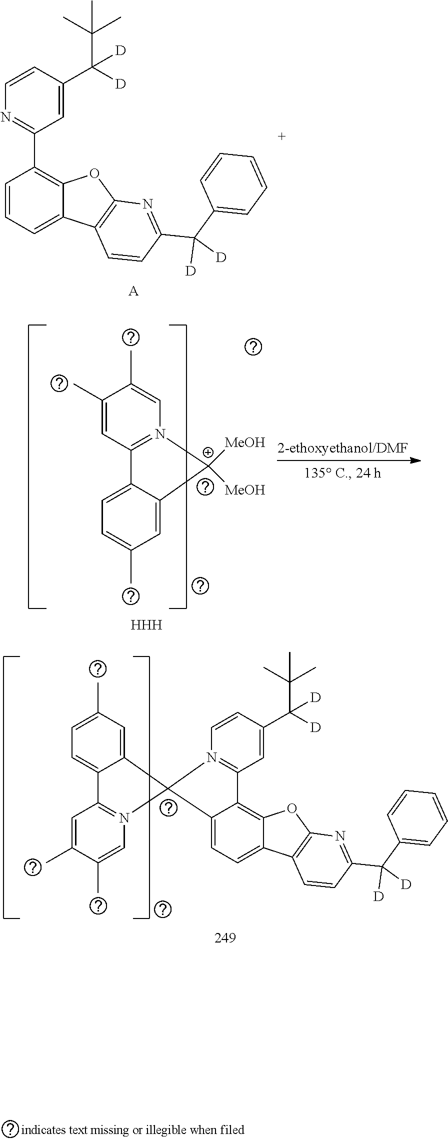

A solution in which A (2.05 g, 5 mmol) and HHH (4.90 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 4.15 g (82%) of a target iridium compound 249.

### Preparation of Iridium Compound 129

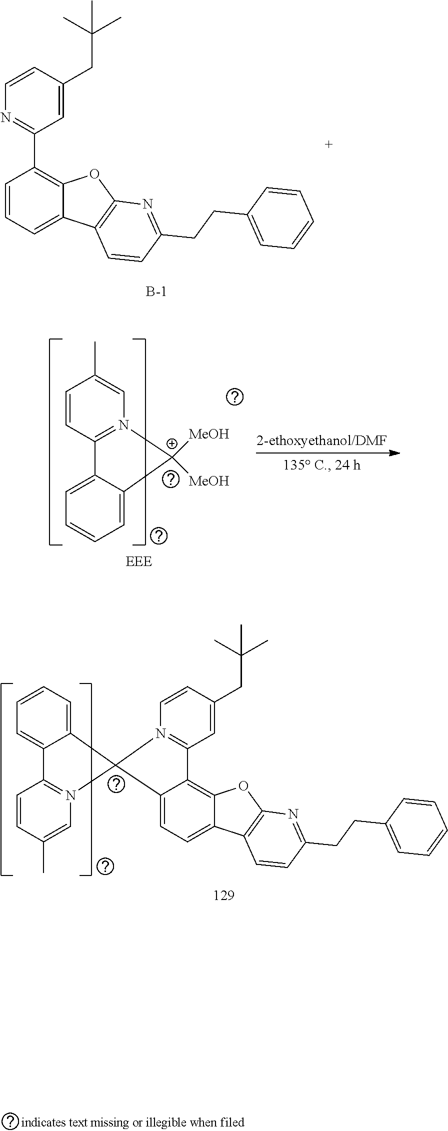

A solution in which B-1 (2.10 g, 5 mmol) and EEE (4.45 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.32 g (70%) of a target iridium compound 129.

### Preparation of Iridium Compound 177

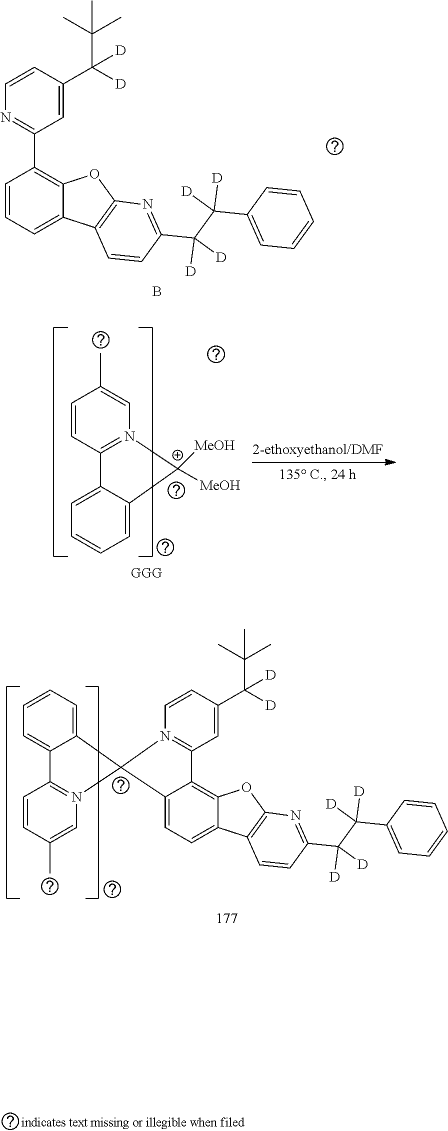

A solution in which B (2.13 g, 5 mmol) and GGG (4.49 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.51 g (73%) of a target iridium compound 177.

### Preparation of Iridium Compound 225

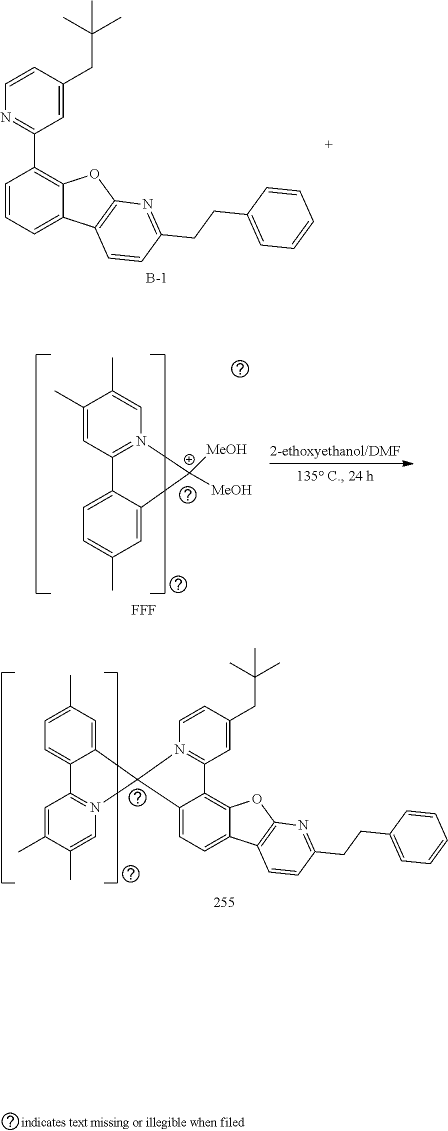

A solution in which B-1 (2.10 g, 5 mmol) and FFF (4.79 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 4.17 g (83%) of a target iridium compound 225.

### Preparation of Iridium Compound 273

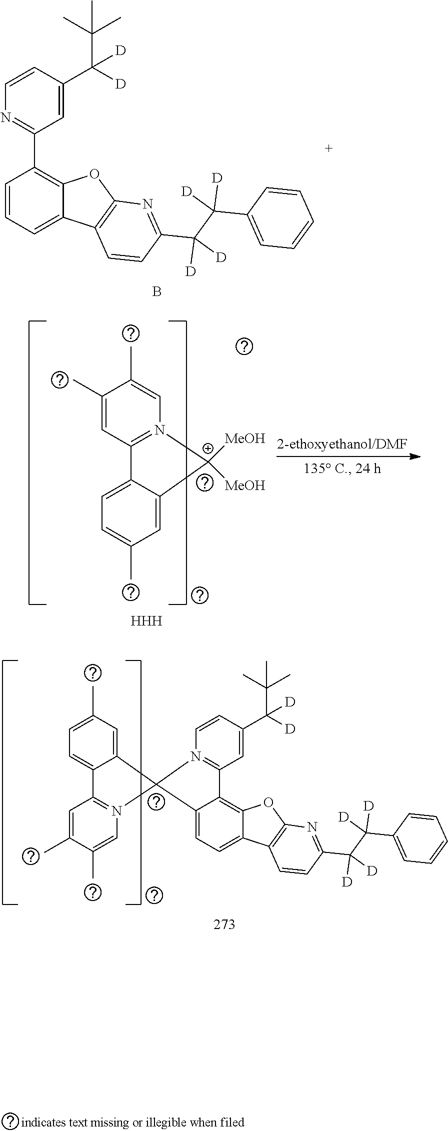

A solution in which B (2.13 g, 5 mmol) and HHH (4.90 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 4.42 g (86%) of a target iridium compound 273.

### Preparation of Iridium Compound 119

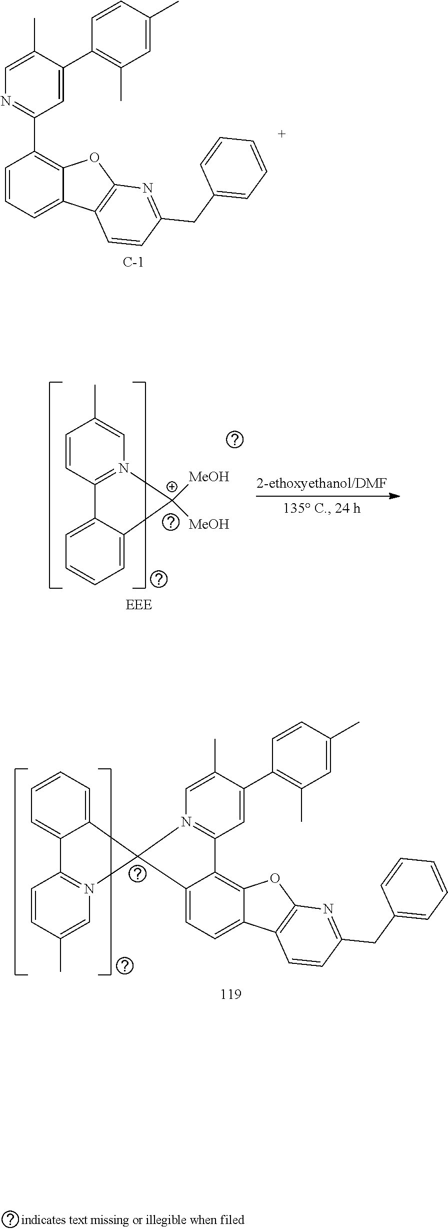

A solution in which C-1 (2.27 g, 5 mmol) and EEE (4.45 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.39 g (69%) of a target iridium compound 119.

### Preparation of Iridium Compound 167

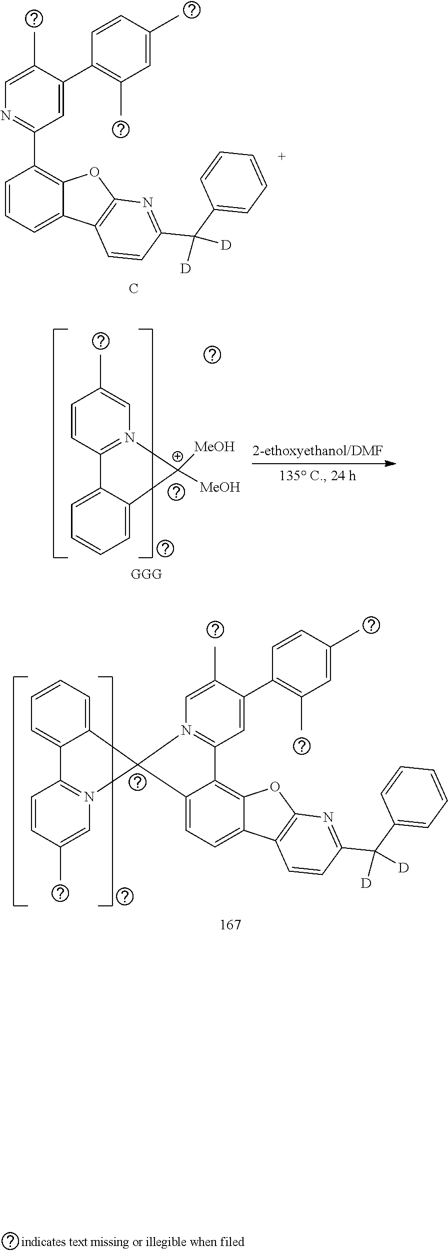

A solution in which C (2.33 g, 5 mmol) and GGG (4.49 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.60 g (72%) of a target iridium compound 167.

### Preparation of Iridium Compound 215

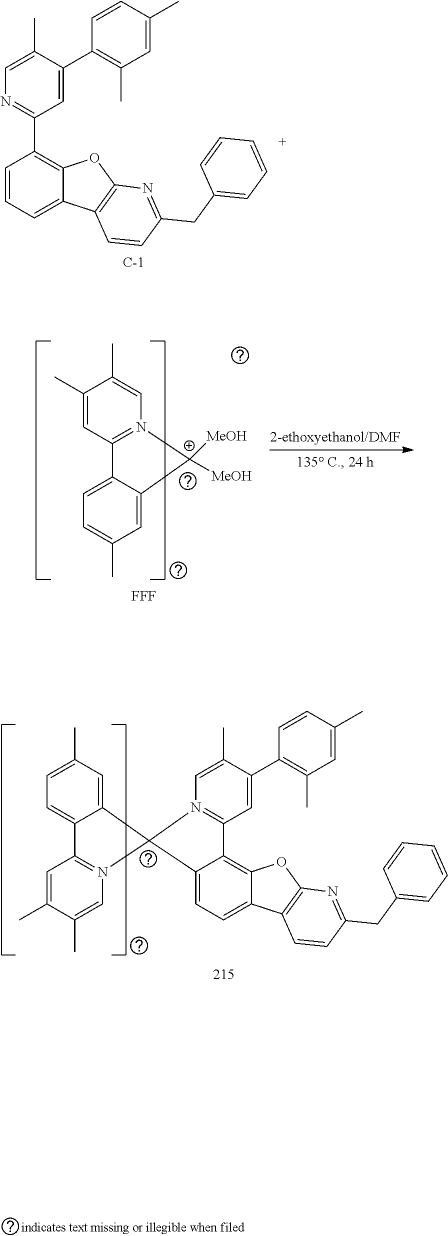

A solution in which C-1 (2.27 g, 5 mmol) and FFF (4.79 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.89 g (75%) of a target iridium compound 215.

### Preparation of Iridium Compound 263

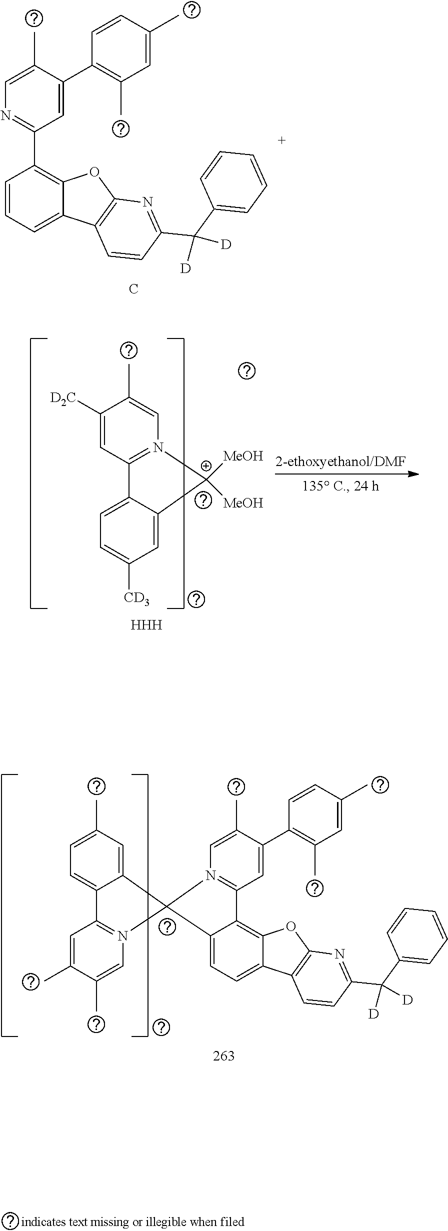

A solution in which C (2.33 g, 5 mmol) and HHH (4.90 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.79 g (71%) of a target iridium compound 263.

### Preparation of Iridium Compound 143

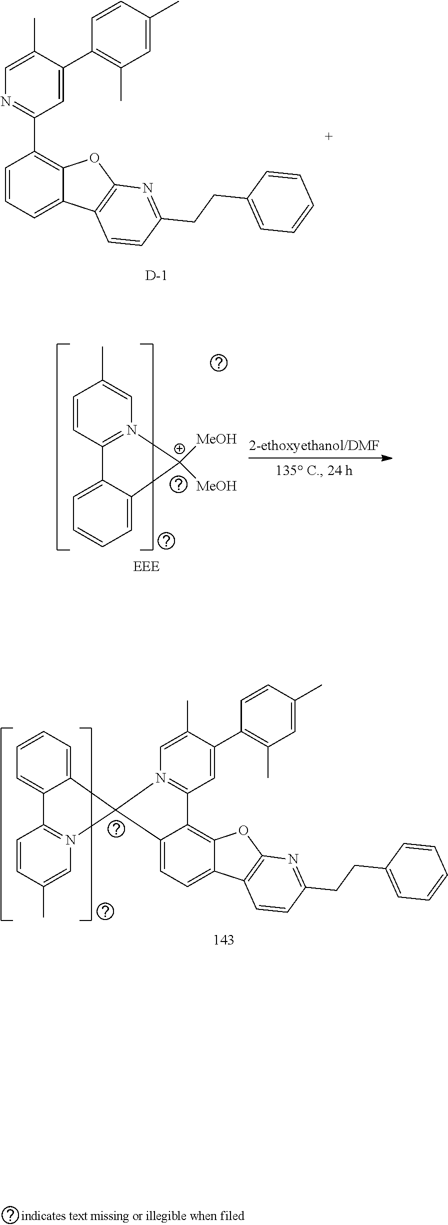

A solution in which D-1 (2.34 g, 5 mmol) and EEE (4.45 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.09 g (62%) of a target iridium compound 143.

### Preparation of Iridium Compound 191

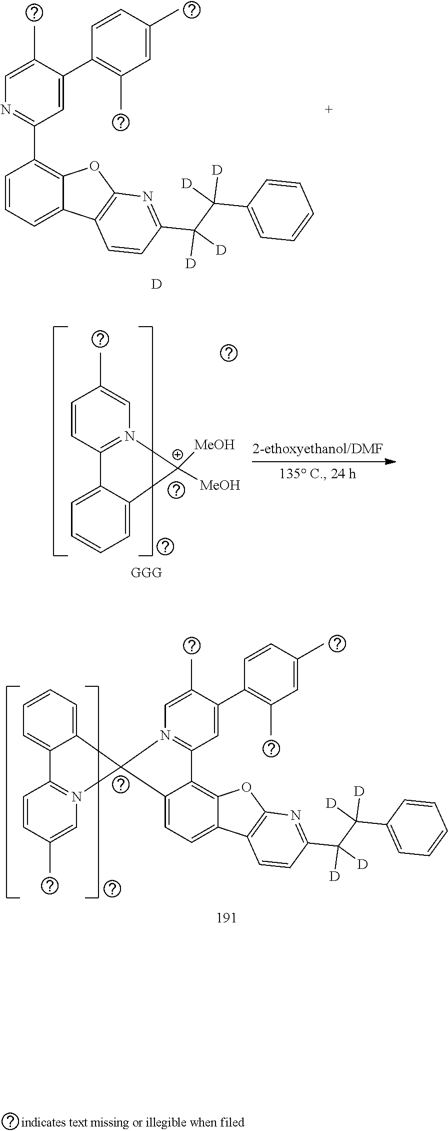

A solution in which D (2.41 g, 5 mmol) and GGG (4.49 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.40 g (67%) of a target iridium compound 191.

### Preparation of Iridium Compound 239

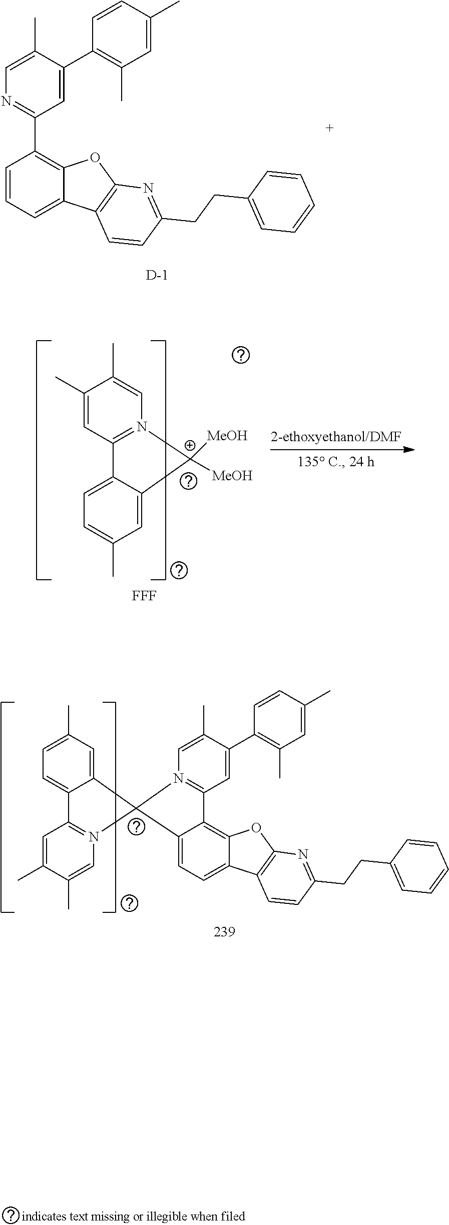

A solution in which D-1 (2.34 g, 5 mmol) and FFF (4.79 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 3.68 g (70%) of a target iridium compound 239.

### Preparation of Iridium Compound 287

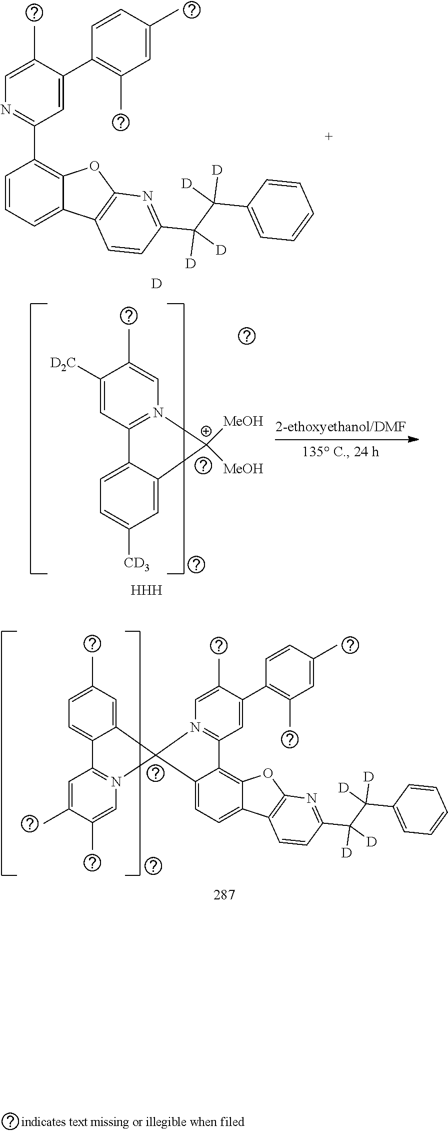

A solution in which D (2.41 g, 5 mmol) and HHH (4.90 g, 6 mmol) were dissolved in 2-ethoxyethanol (100 ml) and DMF (100 ml) was stirred at 135° C. for 24 hours. After completion of a reaction, a temperature was lowered to room temperature, and an organic phase was isolated using dichloromethane and distilled water, and anhydrous magnesium sulfate was added to the organic phase to remove water. A solution was obtained through filtration, and was depressurized to obtain a residue. The residue was purified by silica gel-based column chromatography using 25% ethyl acetate in hexane to obtain 4.01 g (74%) of a target iridium compound 287.

### Present Example 1

A glass substrate having a thin film of ITO (indium tin oxide) having a thickness of 1,000 Å coated thereon was washed, followed by ultrasonic cleaning with a solvent such as isopropyl alcohol, acetone, or methanol. Then, the glass substrate was dried. Thus, an ITO transparent electrode was formed. HI-1 as a hole injection material was deposited on the ITO transparent electrode via thermal vacuum deposition. Thus, a hole injection layer having a thickness of 60 nm was formed. Then, NPB as a hole transport material was deposited on the hole injection layer via thermal vacuum deposition. Thus, a hole transport layer having a thickness of 80 nm was formed. Then, CBP as a host material of a light-emitting layer was deposited on the hole transport layer via thermal vacuum deposition. The compound 105 as a dopant was doped into the host material at a doping concentration of 5%. Thus, the light-emitting layer of a thickness of 30 nm was formed. ET-1:Liq (1:1) (30 nm) as materials for an electron transport layer and an electron injection layer, respectively, were deposited on the light-emitting layer. Then, 100 nm thick aluminum was deposited thereon to form a negative electrode. In this way, an organic light-emitting diode was manufactured. The materials used in Present Example 1 are as follows.

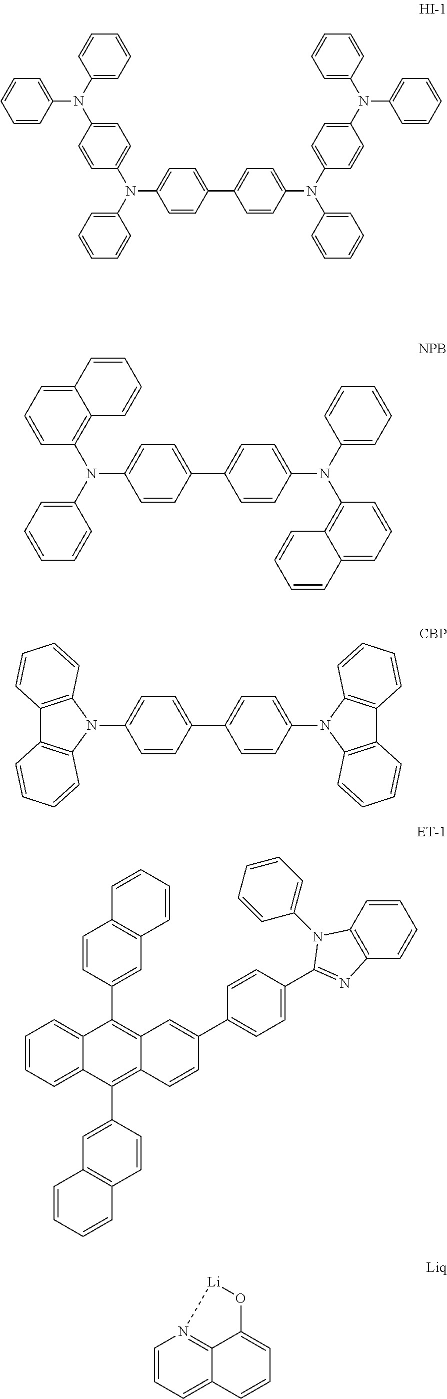

HI-1 is NPNPB, and ET-1 is ZADN.

### Present Examples 2 to 16

An organic light-emitting diode of each of Present Examples 2 to 16 was manufactured in the same manner as in Present Example 1, except that the compound as indicated in the following Table 1 was used instead of the compound 105 as in Present Example 1.

### Comparative Examples 1 to 3

An organic light-emitting diode of each of Comparative Examples 1 to 3 was manufactured in the same manner as in Present Example 1, except that compounds Ref1 to Ref3, as indicated in the following Table 1, were used instead of the compound 105 as in Present Example 1:

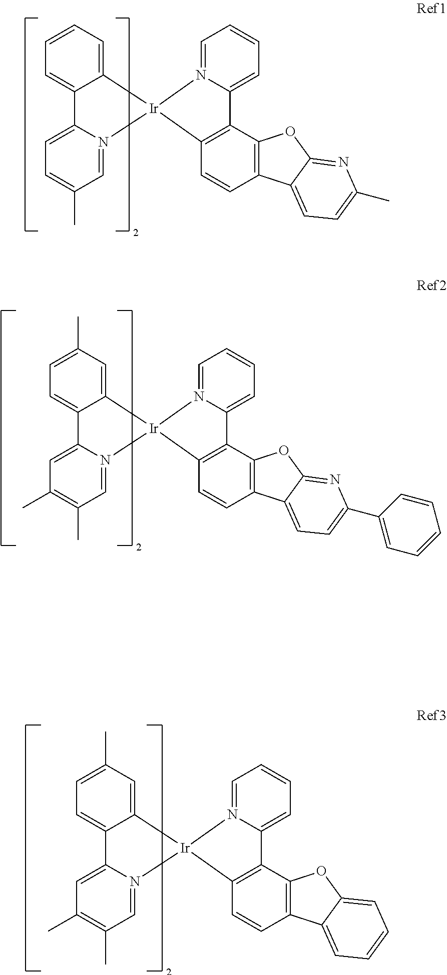

### Experimental Example

The organic light-emitting diode as manufactured in each of Present Examples 1 to 16 and Comparative Examples 1 to 3 was connected to an external power source, and characteristics of the organic light-emitting diode were evaluated at room temperature using a current source and a photometer.

Specifically, operation voltage (V), external quantum efficiency (EQE; 0, relative value), and lifetime characteristics (LT95; %, relative value) were measured at a current density of 10 mA/cm², and were calculated as relative values to those of Comparative Example 1, and the results are summarized in the following Table 1.

LT95 lifetime refers to a time it takes for the display element to lose 5% of its initial brightness. LT95 is the customer specification that may be the most difficult to meet. Whether or not image burn-in occurs on the display may be determined based on the LT95.

TABLE 1

| | | Operation | EQE | LT95 |
|---|---|---|---|---|
| | | voltage | (%, relative | (%, relative |
| | Dopant | (V) | value) | value) |
| Comparative | Ref1 | 4.34 | 100 | 100 |
| Example 1 | | | | |
| Comparative | Ref2 | 4.41 | 108 | 114 |
| Example 2 | | | | |
| Comparative | Ref3 | 4.39 | 89 | 125 |
| Example 3 | | | | |
| Present | Compound 105 | 4.30 | 113 | 139 |
| Example 1 | | | | |
| Present | Compound 153 | 4.27 | 112 | 173 |
| Example 2 | | | | |
| Present | Compound 201 | 4.41 | 117 | 147 |
| Example 3 | | | | |
| Present | Compound 249 | 4.36 | 117 | 183 |
| Example 4 | | | | |
| Present | Compound 129 | 4.33 | 116 | 133 |
| Example 5 | | | | |
| Present | Compound 177 | 4.33 | 116 | 164 |
| Example 6 | | | | |
| Present | Compound 225 | 4.37 | 119 | 136 |
| Example 7 | | | | |
| Present | Compound 273 | 4.44 | 118 | 173 |
| Example 8 | | | | |
| Present | Compound 119 | 4.28 | 121 | 126 |
| Example 9 | | | | |
| Present | Compound 167 | 4.29 | 120 | 158 |
| Example 10 | | | | |
| Present | Compound 215 | 4.34 | 123 | 130 |
| Example 11 | | | | |
| Present | Compound 263 | 4.39 | 123 | 167 |
| Example 12 | | | | |
| Present | Compound 143 | 4.32 | 125 | 124 |
| Example 13 | | | | |
| Present | Compound 191 | 4.21 | 125 | 157 |
| Example 14 | | | | |
| Present | Compound 239 | 4.24 | 129 | 128 |
| Example 15 | | | | |
| Present | Compound 287 | 4.20 | 127 | 163 |
| Example 16 | | | | |

Each dopant of the light-emitting layer in the Present Examples of the present disclosure is different from each dopant of the light-emitting layer in Comparative Examples 1 to 3 in that each of Ref1 to Ref3 (dopants in Comparative Examples 1 to 3) has a structure in which the arylalkyl moiety is not introduced thereto.

From the results of the Table 1, the organic light-emitting diode of each of Present Examples 1 to 16 of the present disclosure including the organometallic compound having an arylalkyl moiety as a dopant in the light-emitting layer has lowered operation voltage, improved external quantum efficiency (EQE), and improved lifetime (LT95) compared to those in the organic light-emitting diode of each of Comparative Examples 1 to 3.

Although the embodiments of the present disclosure have been described in more detail with reference to the accompanying drawings, the present disclosure is not limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all aspects.

What is claimed is:

1. An organometallic compound represented by Chemical Formula 1: 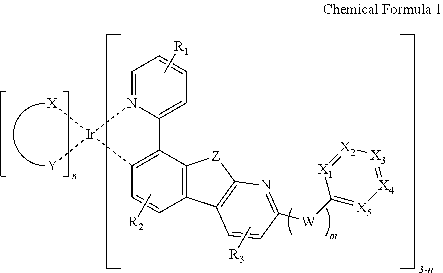
wherein in the Chemical Formula 1,
Z represents one of O (oxygen), S (sulfur) or Se (selenium),
each W independently represents C(R₄)₂,
m is an integer of 1 to 5,
each of X₁, X₂, X₃, X₄, and X₅ independently represents N or CR₅.
R₁, when present, represents mono-substitution, di-substitution, tri-substitution or tetra-substitution,
R₂, when present, and R₃, when present, each independently represents mono-substitution, or di-substitution,
each of R₁ to R₃ independently represents one selected from the group consisting of deuterium, halogen, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, and phosphino,
each R₄ independently represents one selected from the group consisting of hydrogen, deuterium, halogen, and a C1 to C20 linear or branched alkyl group,
each R₅ independently represents one selected from the group consisting of hydrogen, deuterium, halogen, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, and phosphino,
two adjacent R₁ groups, when present, optionally bind to each other to form a cycloalkyl, cycloalkenyl, aryl or arylalkyl,
two adjacent R₂ groups, when present, optionally bind to each other to form a cycloalkyl, cycloalkenyl, aryl or arylalkyl,
two adjacent R₃ groups, when present, optionally bind to each other to form a cycloalkyl, cycloalkenyl, aryl or arylalkyl,
two adjacent R₅ groups, when present, optionally bind to each other to form a cycloalkyl, cycloalkenyl, aryl or arylalkyl,
n is an integer from 0 to 2, and 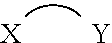
is a bidentate ligand.

2. The organometallic compound of claim 1, wherein 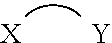
has a structure represented by one of Chemical Formula 2 or Chemical Formula 3: 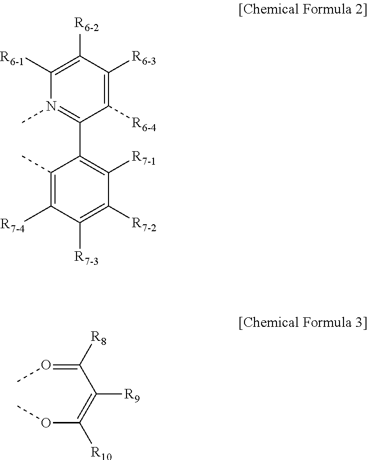
wherein in the Chemical Formula 2, each of R₆₋₁, R₆₋₂, R₆₋₃, R₆₋₄, R₇₋₁, R₇₋₂, R₇₋₃, and R₇₋₄ independently represents one selected from the group consisting of hydrogen, deuterium, a C1 to C5 linear alkyl group, a C1 to C5 branched alkyl group, a C6 to C20 aryl group, and a C7 to C30 arylalkyl group,
at least one hydrogen of the C1 to C5 linear alkyl group, the C1 to C5 branched alkyl group, the C6 to C20 aryl group, or the C7 to C30 arylalkyl group is optionally substituted by deuterium or halogen,
two adjacent groups among R₆₋₁, R₆₋₂, R₆₋₃, and R₆₋₄ optionally bind to each other to form a ring structure,
two adjacent groups among R₇₋₁, R₇₋₂, R₇₋₃, and R₇₋₄ optionally bind to each other to form a ring structure,
wherein in the Chemical Formula 3, each of R₈, R₉, and R₁₀ independently represents one selected from the group consisting of hydrogen, deuterium, a C1 to C5 linear alkyl group and a C1 to C6 branched alkyl group,
at least one hydrogen of the C1 to C5 linear alkyl group or the C1 to C5 branched alkyl group is optionally substituted by deuterium or a halogen,
two adjacent groups among R₈, R₉, and R₁₀ optionally bind to each other to form a ring structure.

3. The organometallic compound of claim 1, wherein n in the Chemical Formula 1 is 0.

4. The organometallic compound of claim 1, wherein n in the Chemical Formula 1 is 1.

5. The organometallic compound of claim 1, wherein n in the Chemical Formula 1 is 2.

6. The organometallic compound of claim 1, wherein Z is O (oxygen).

7. The organometallic compound of claim 1, wherein the organometallic compound represented by the Chemical Formula 1 includes at least one selected from the group consisting of following compounds 1 to 372:

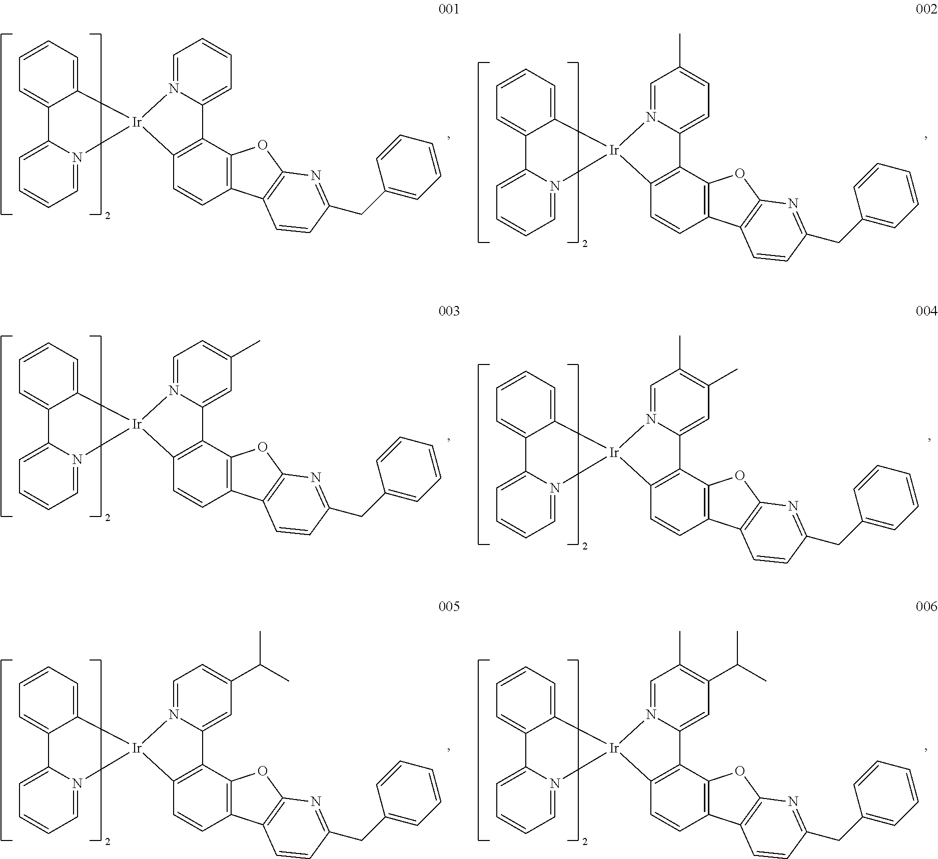

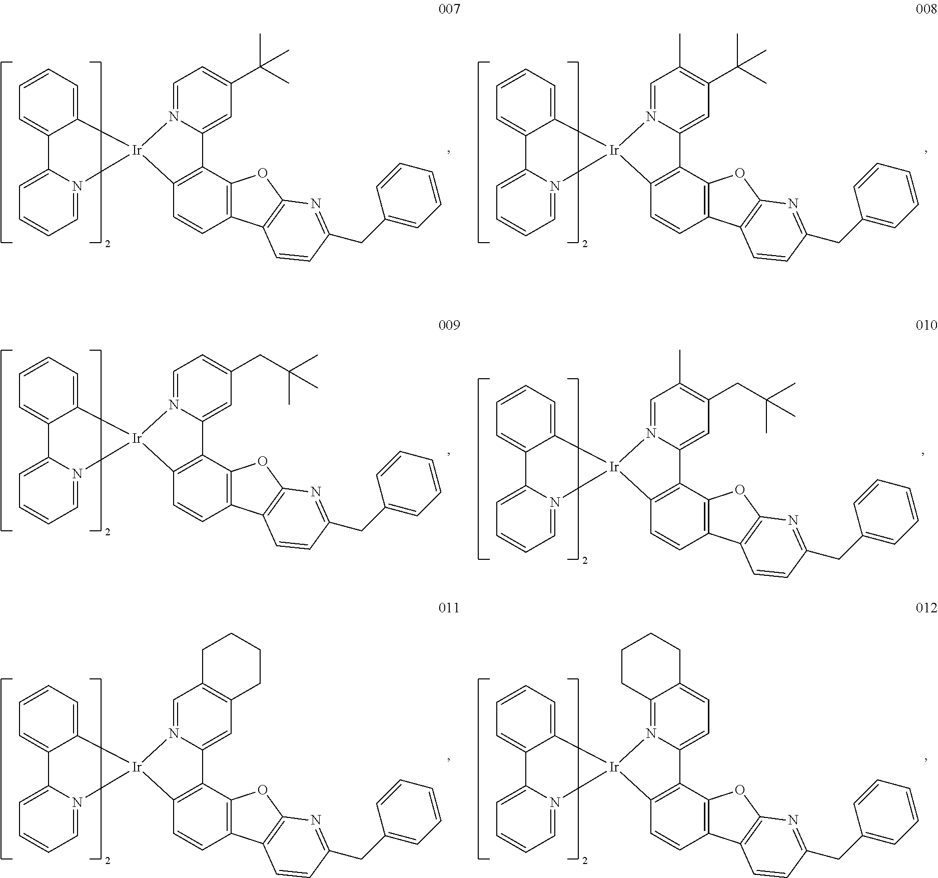

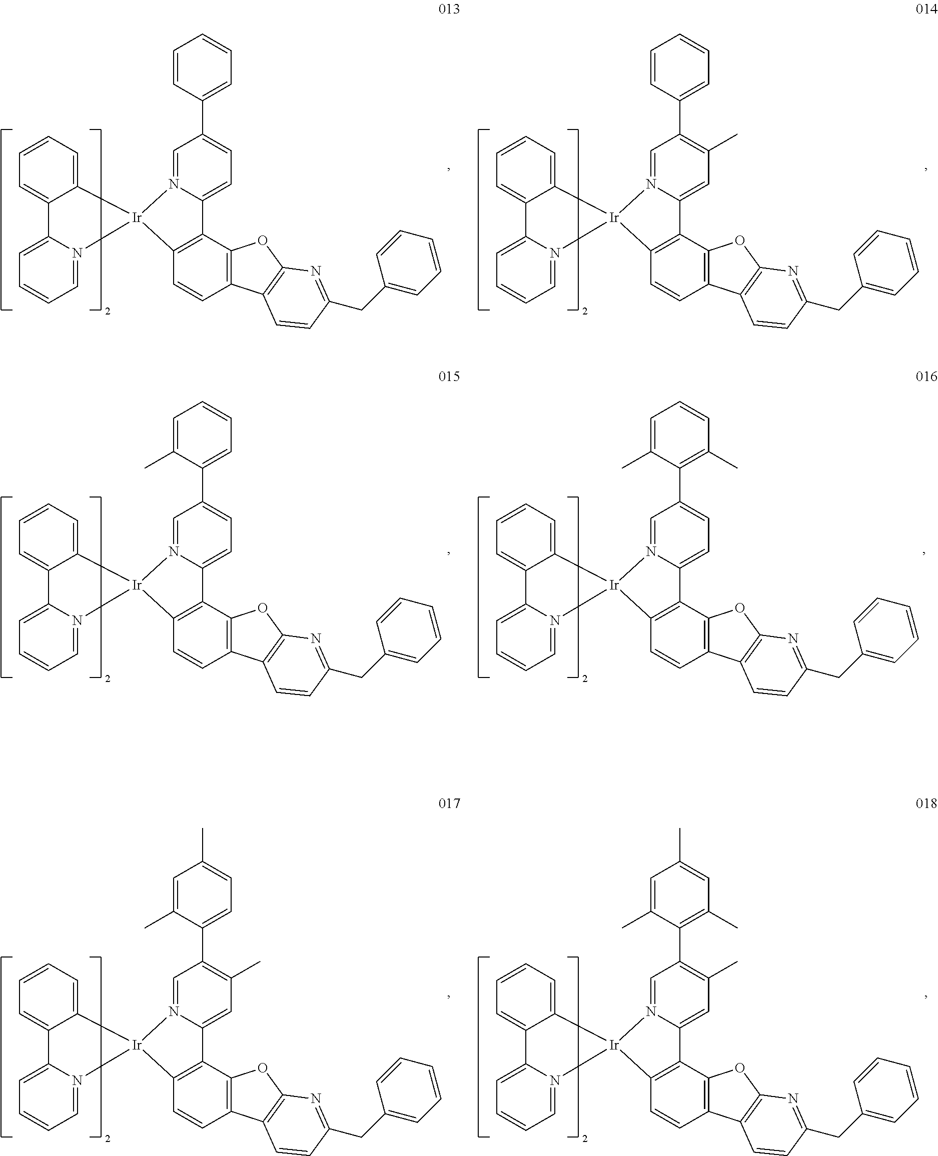

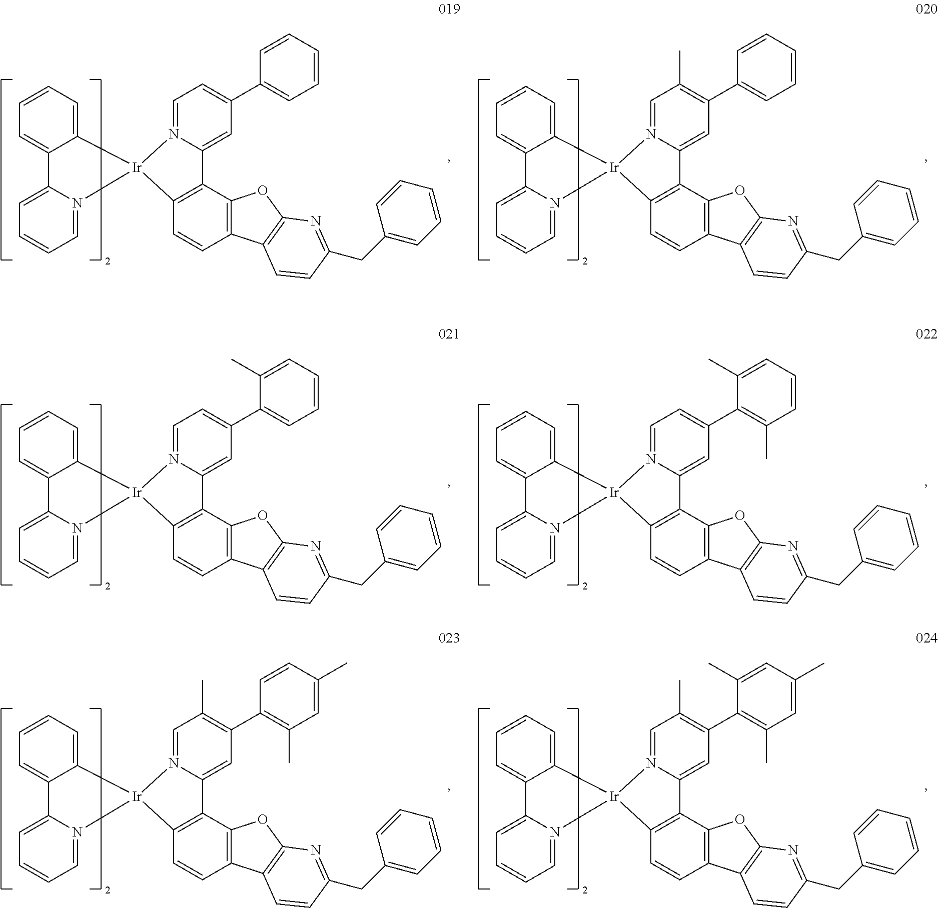

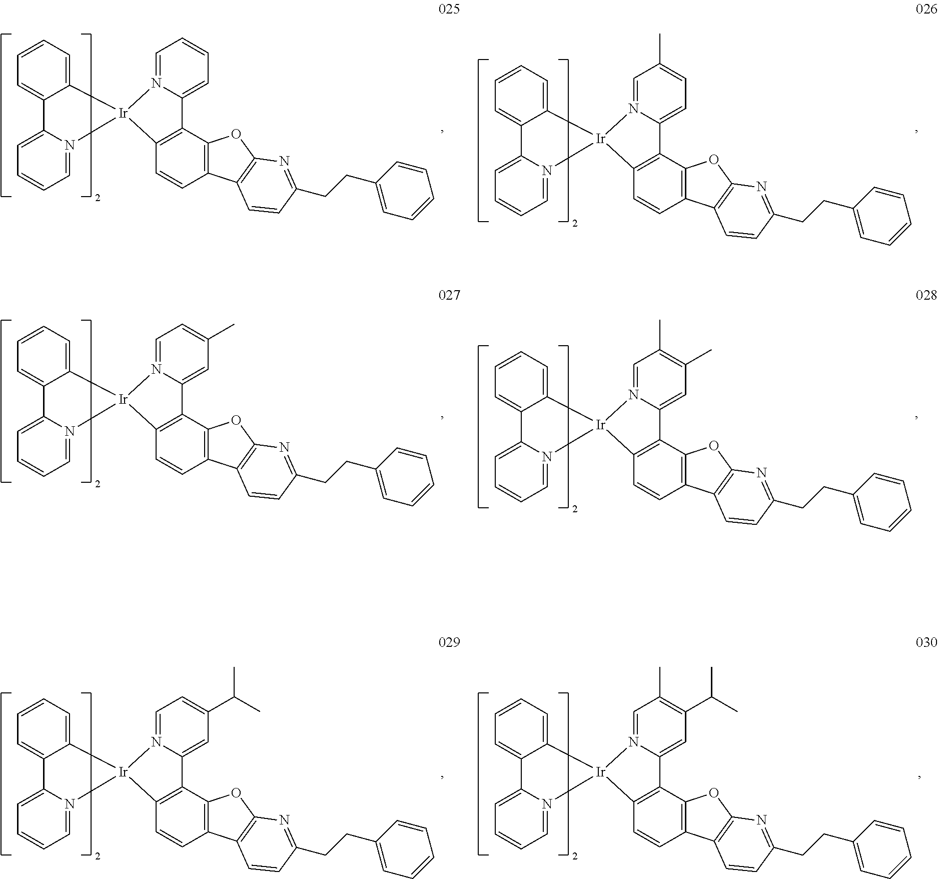

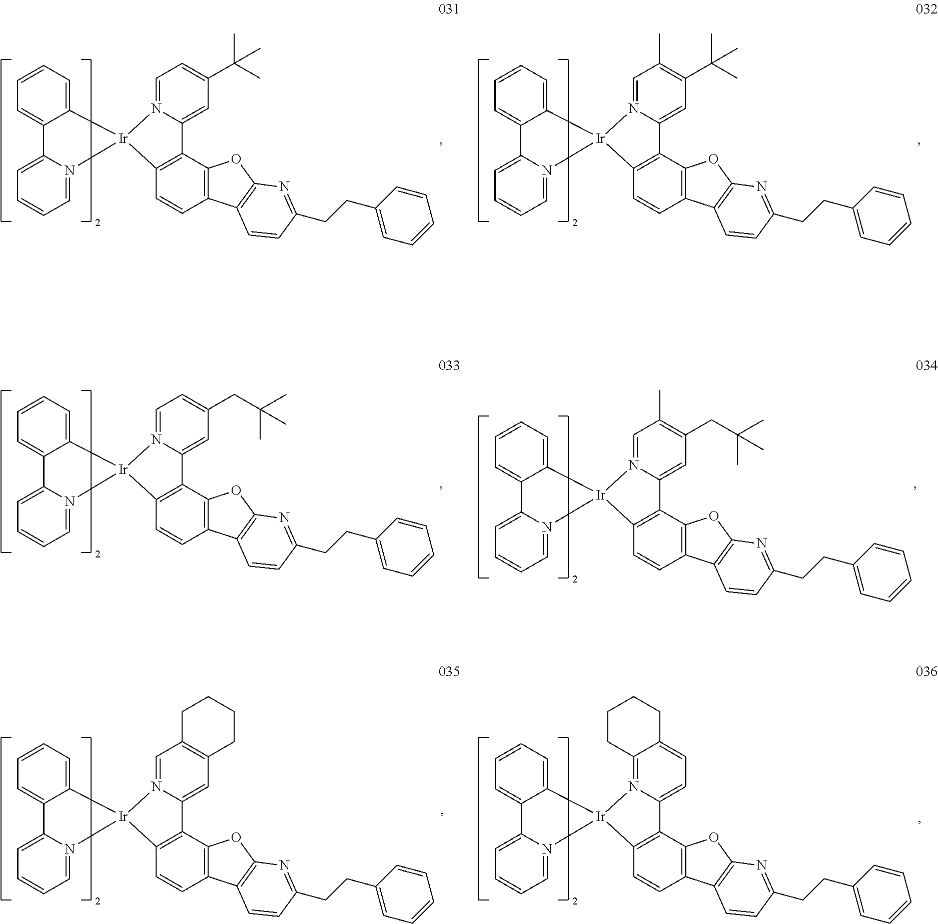

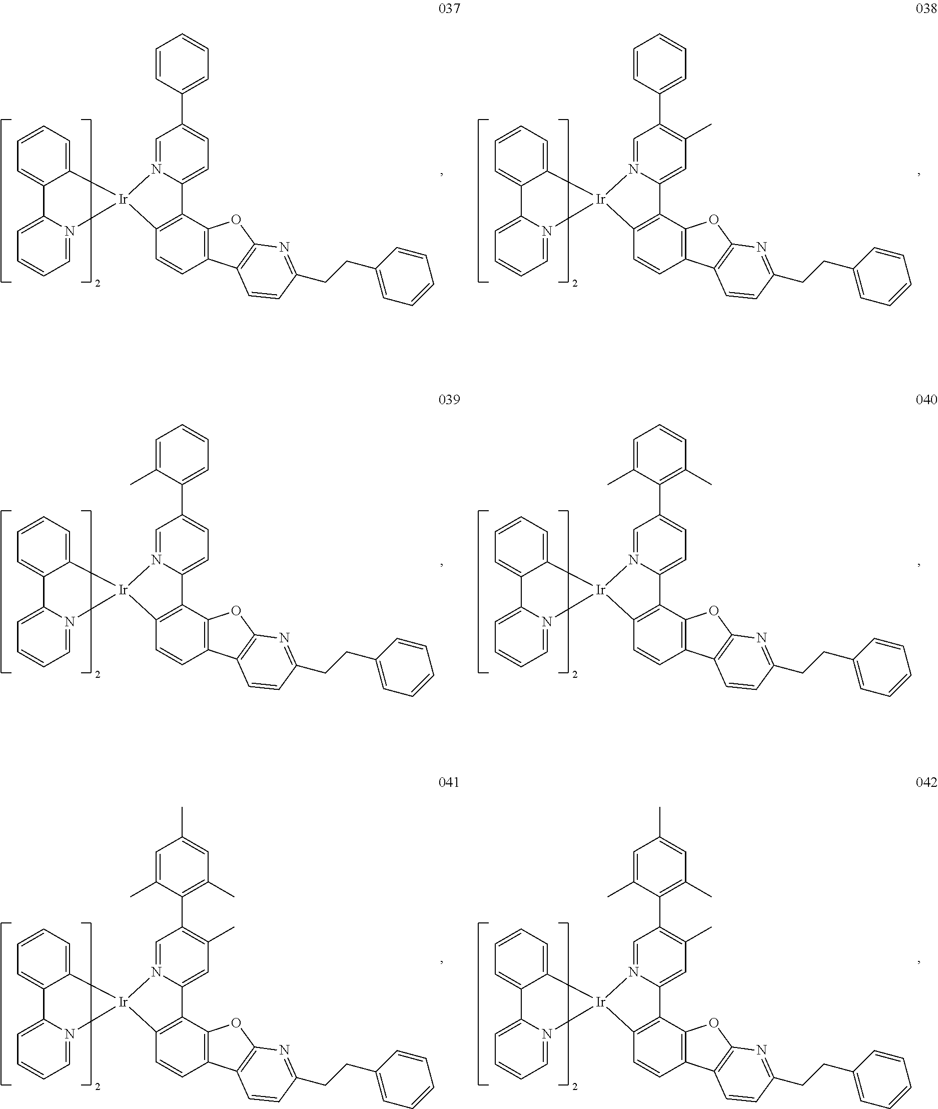

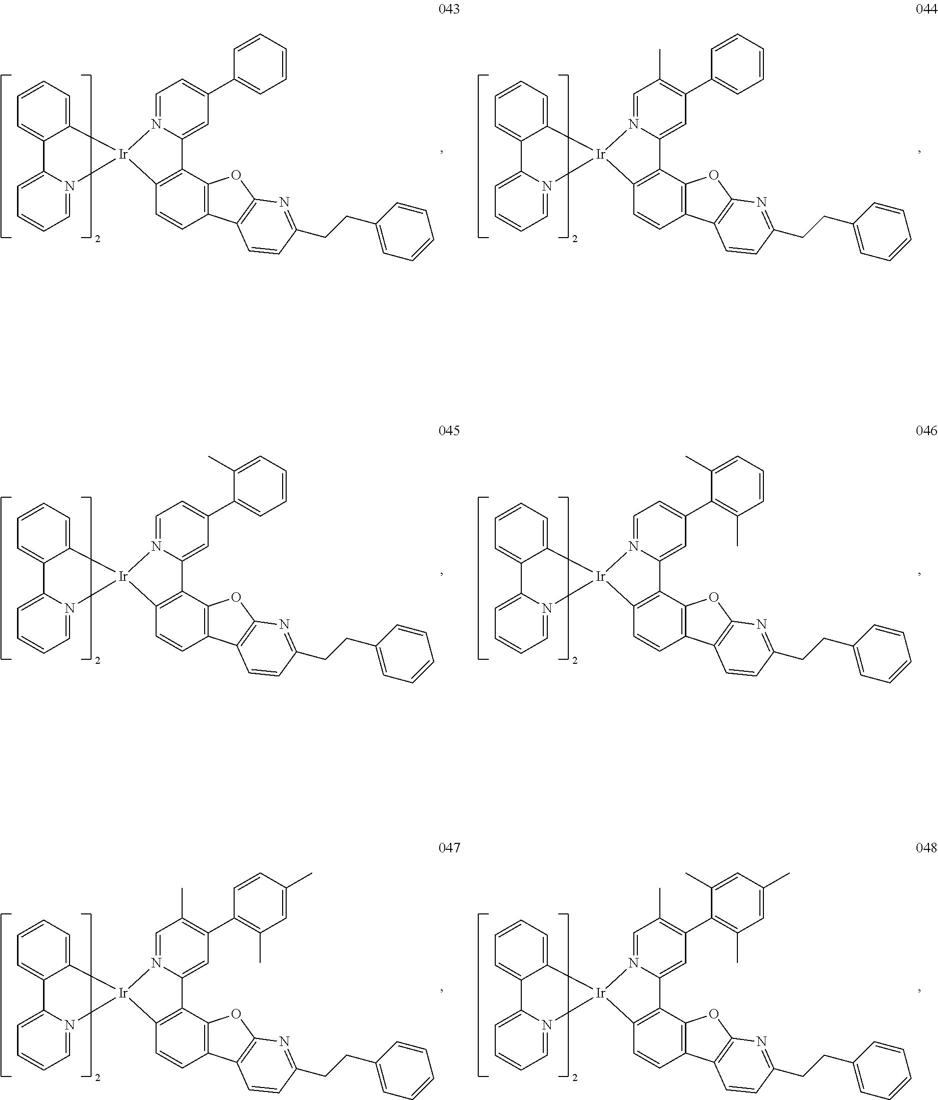

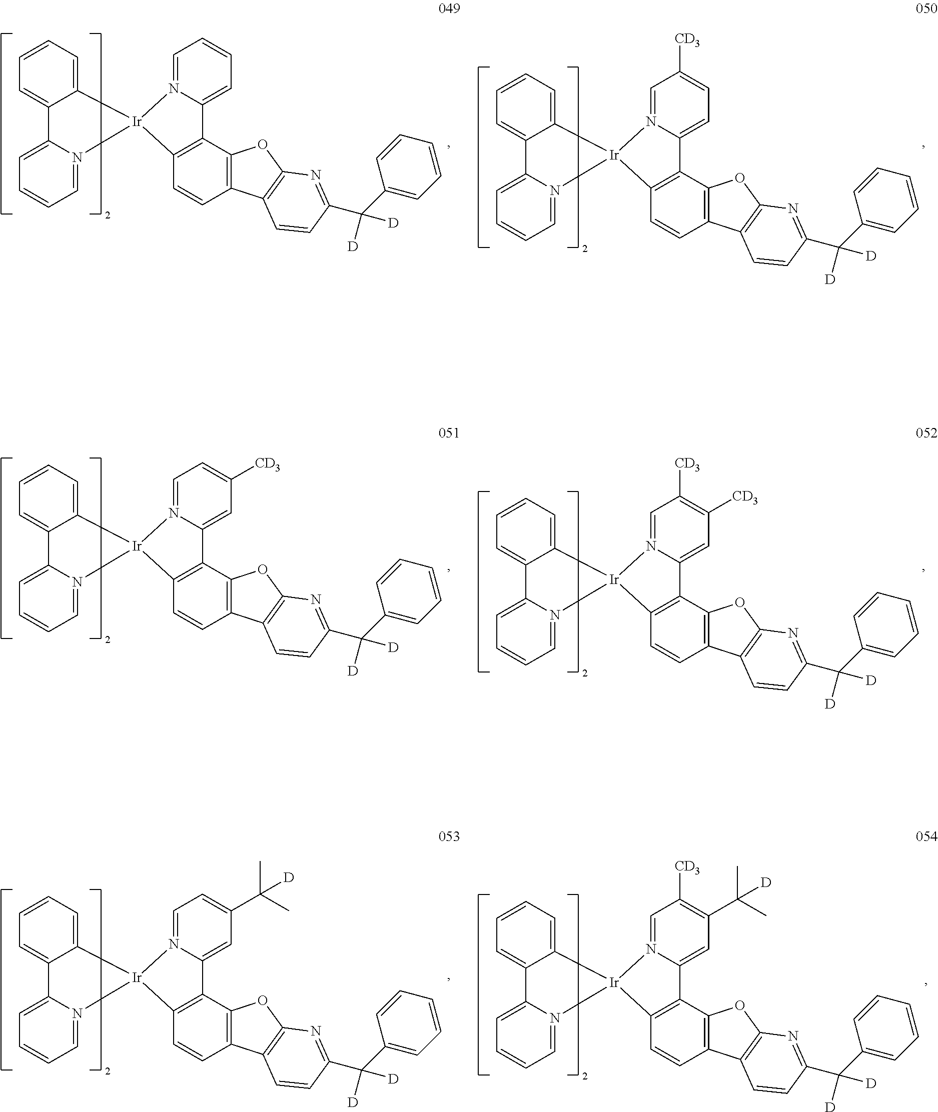

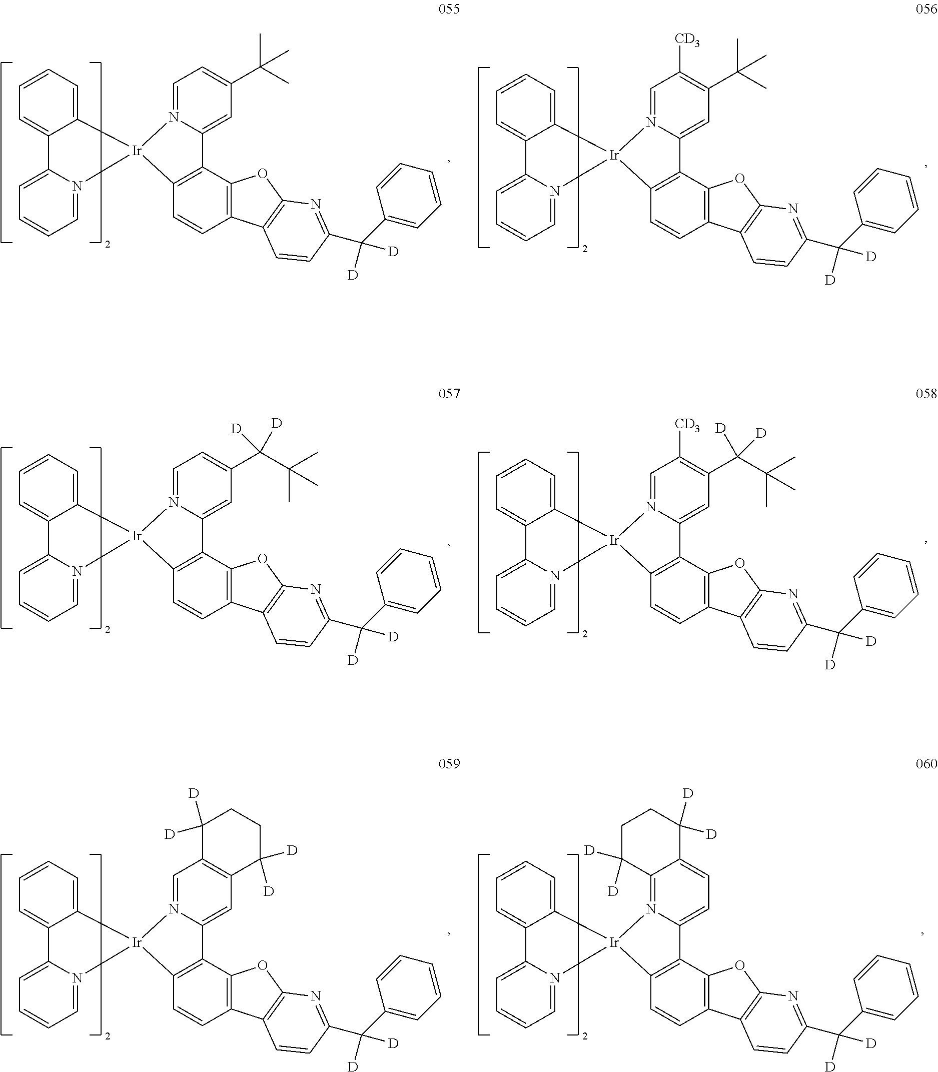

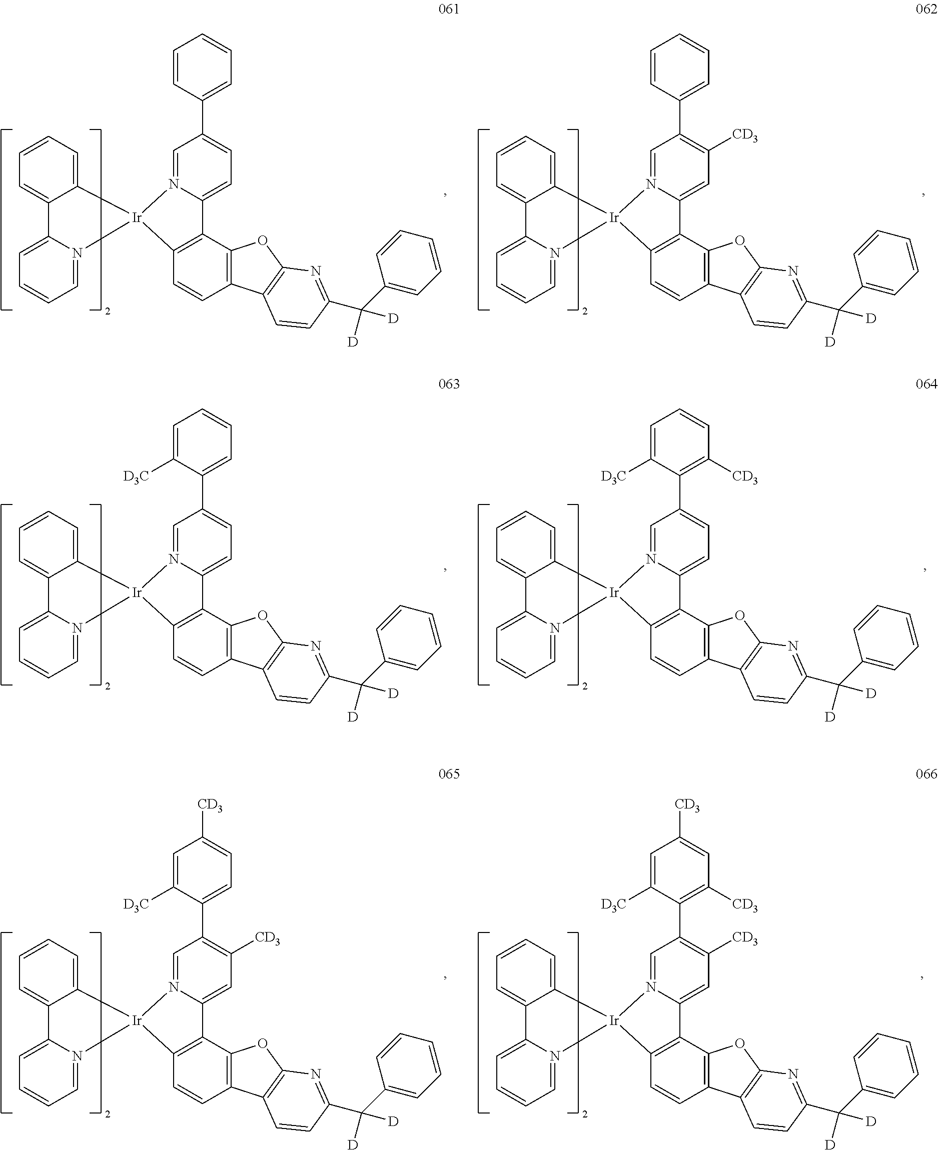

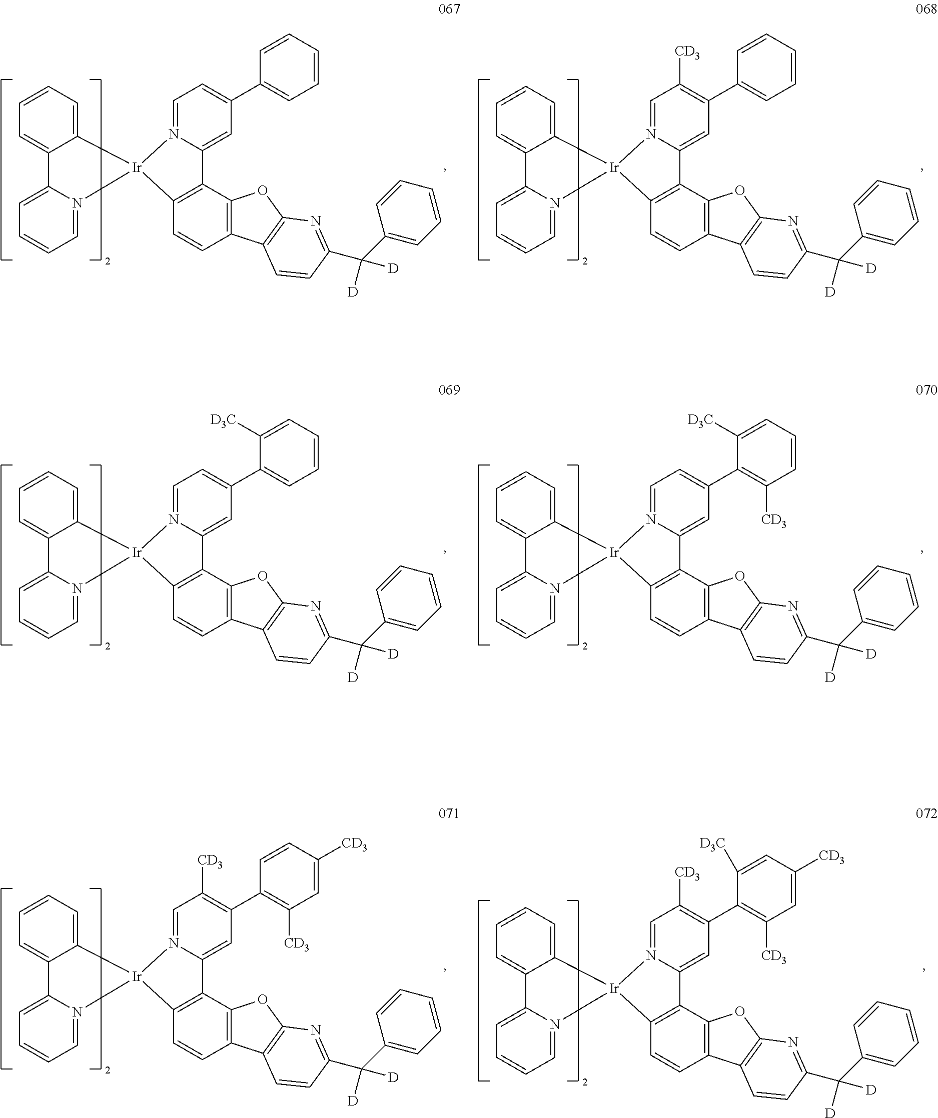

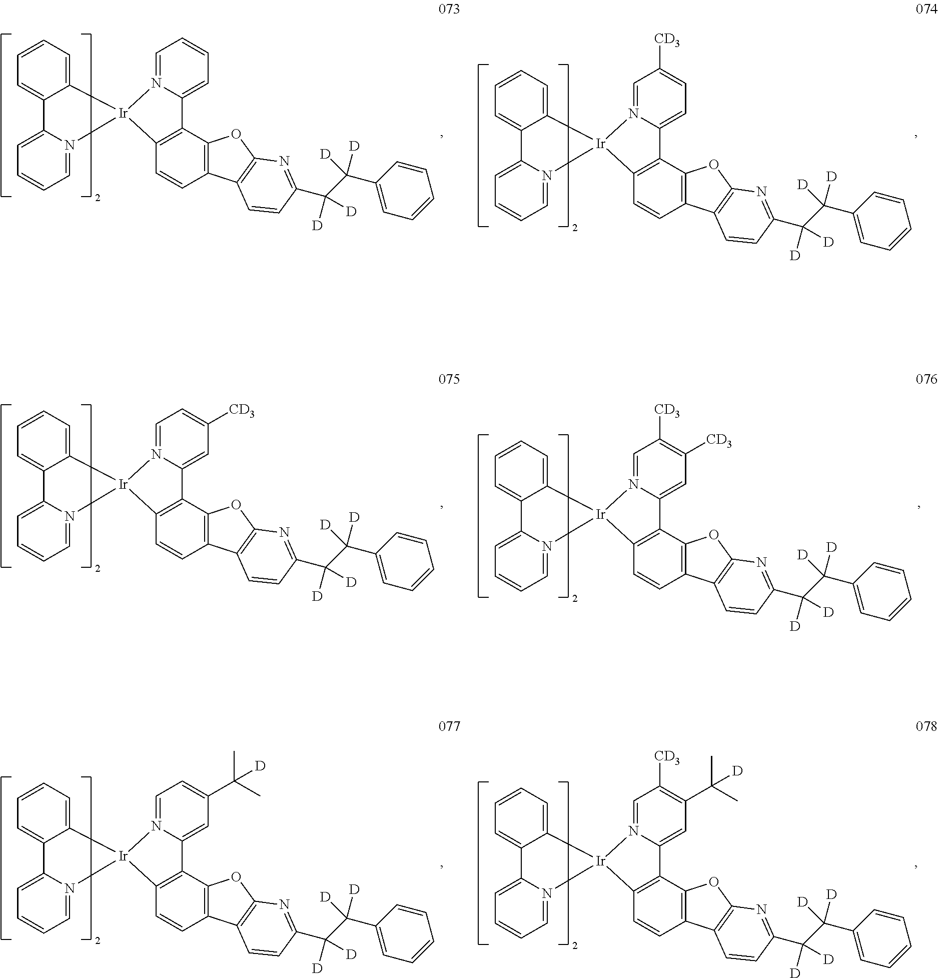

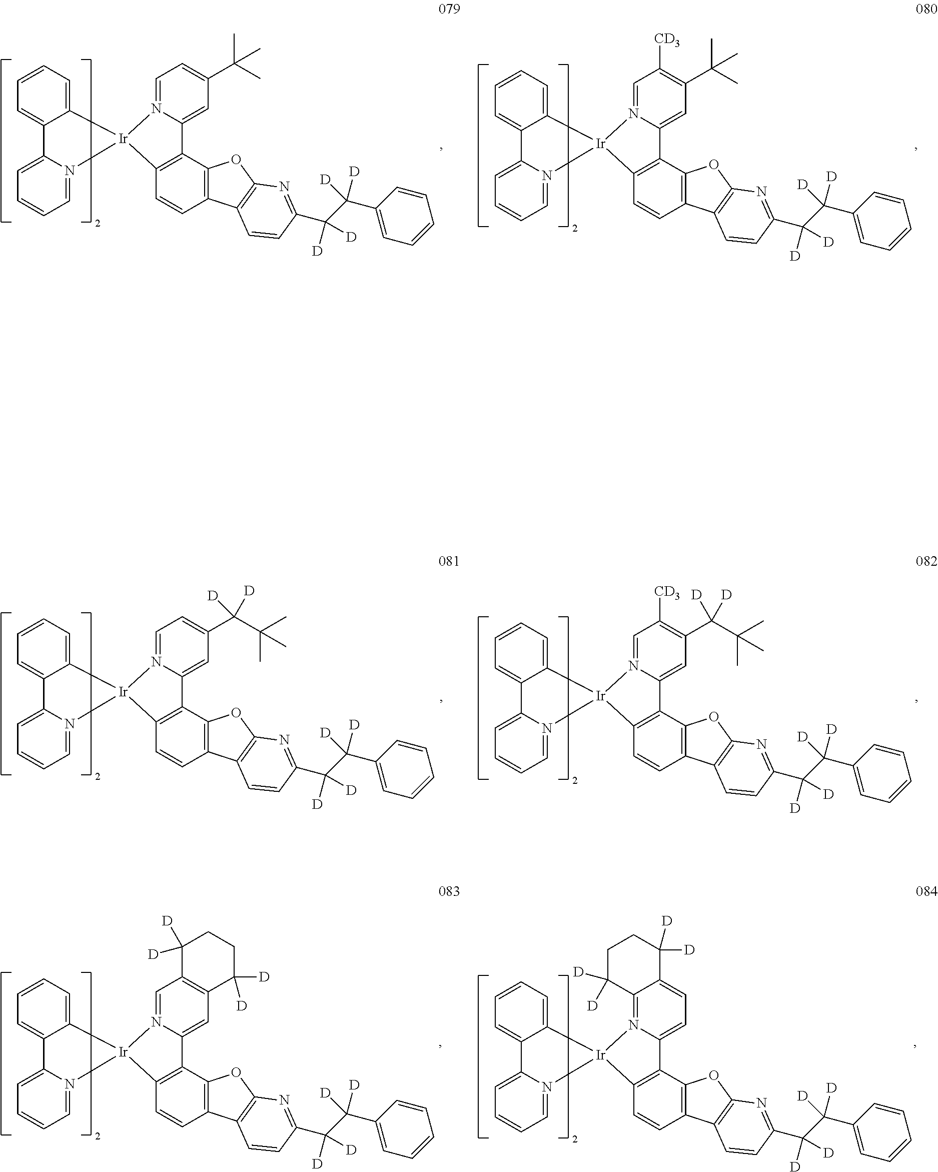

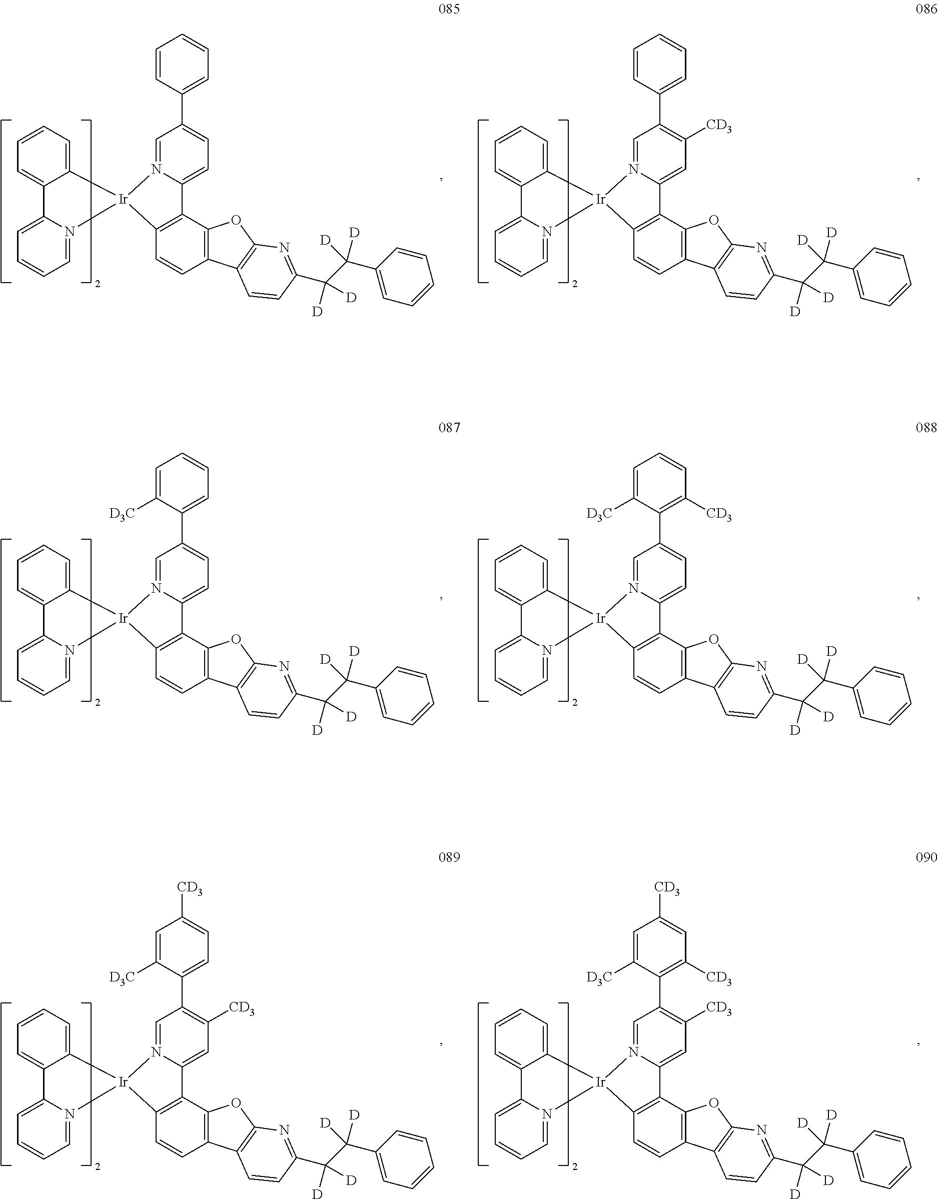

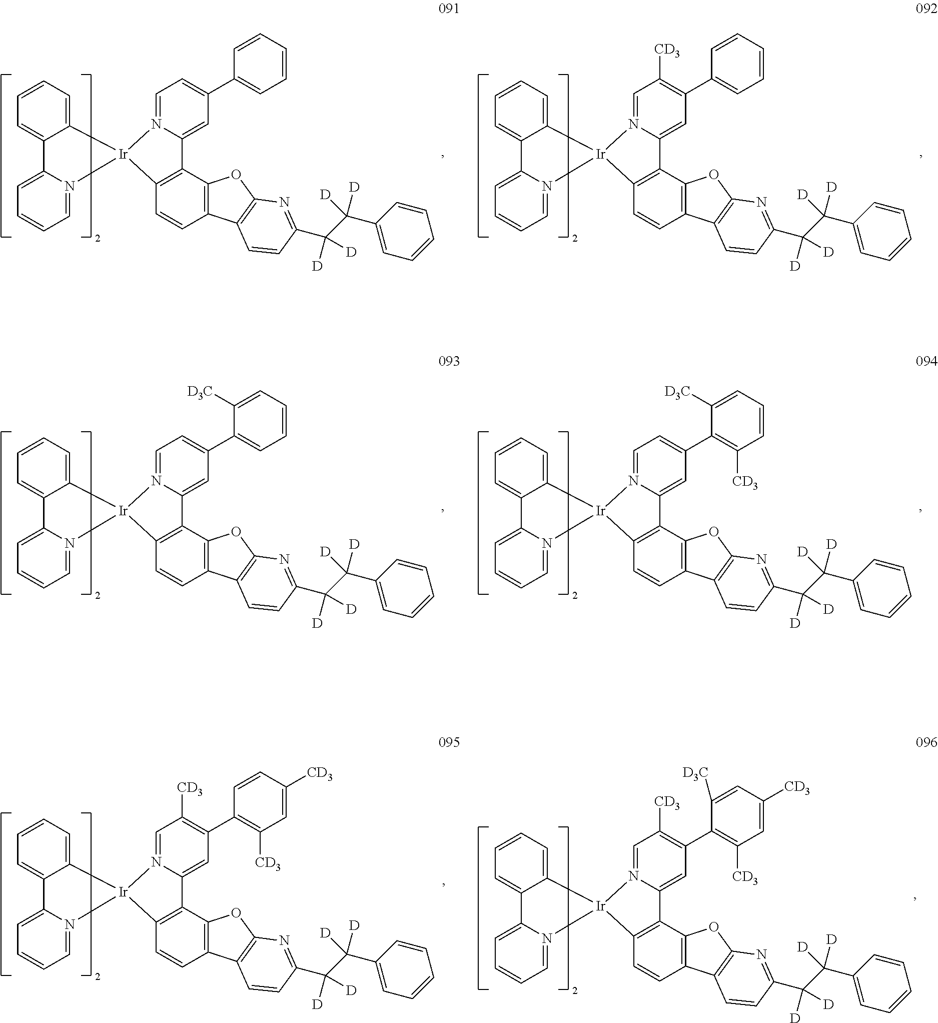

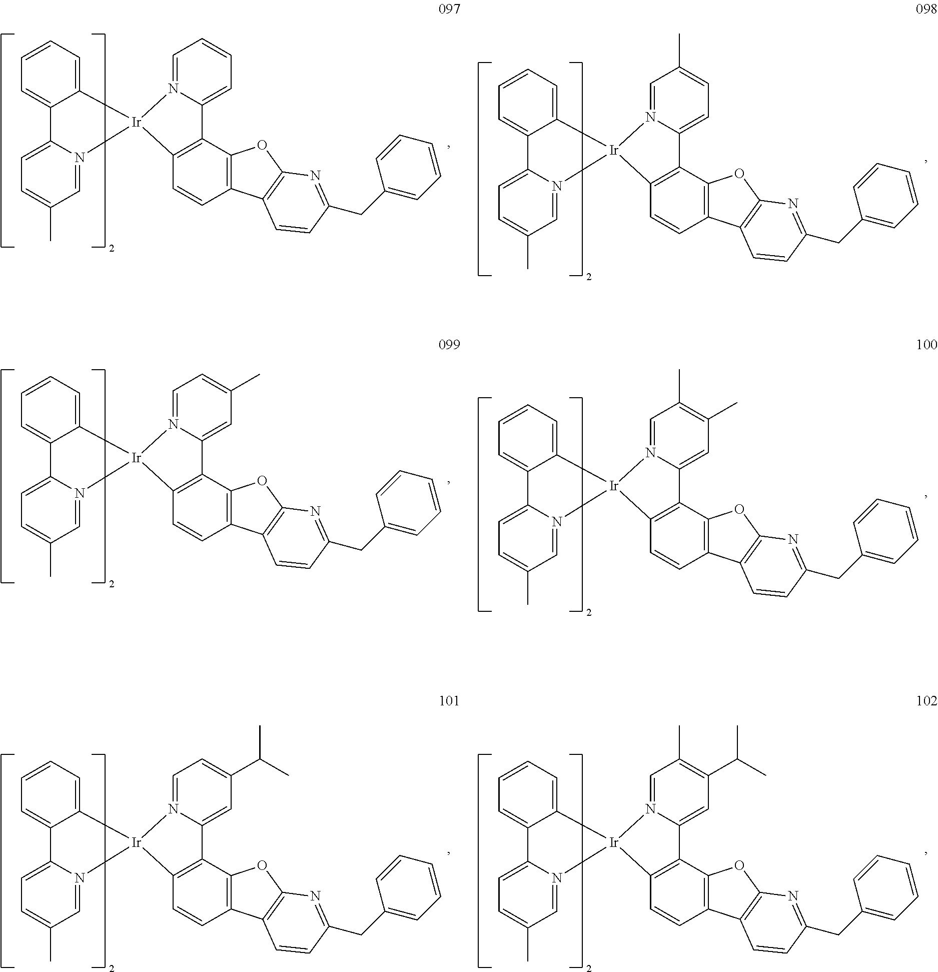

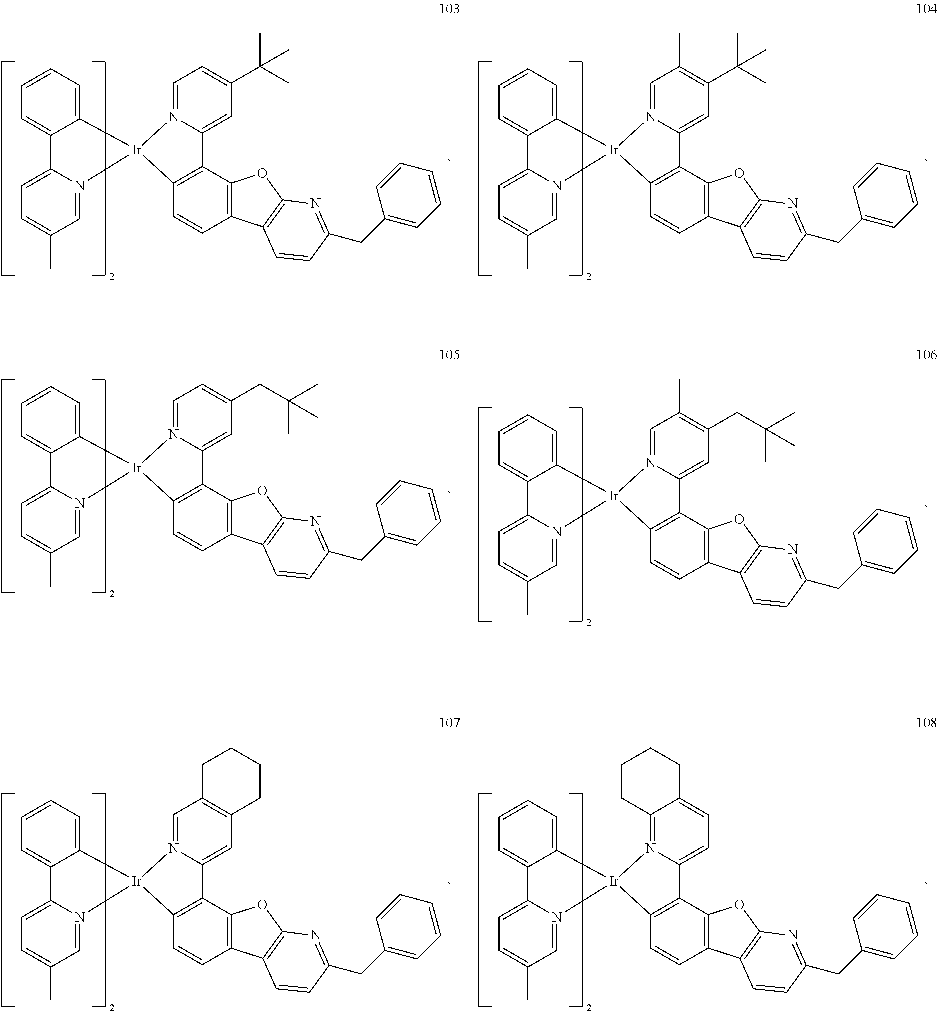

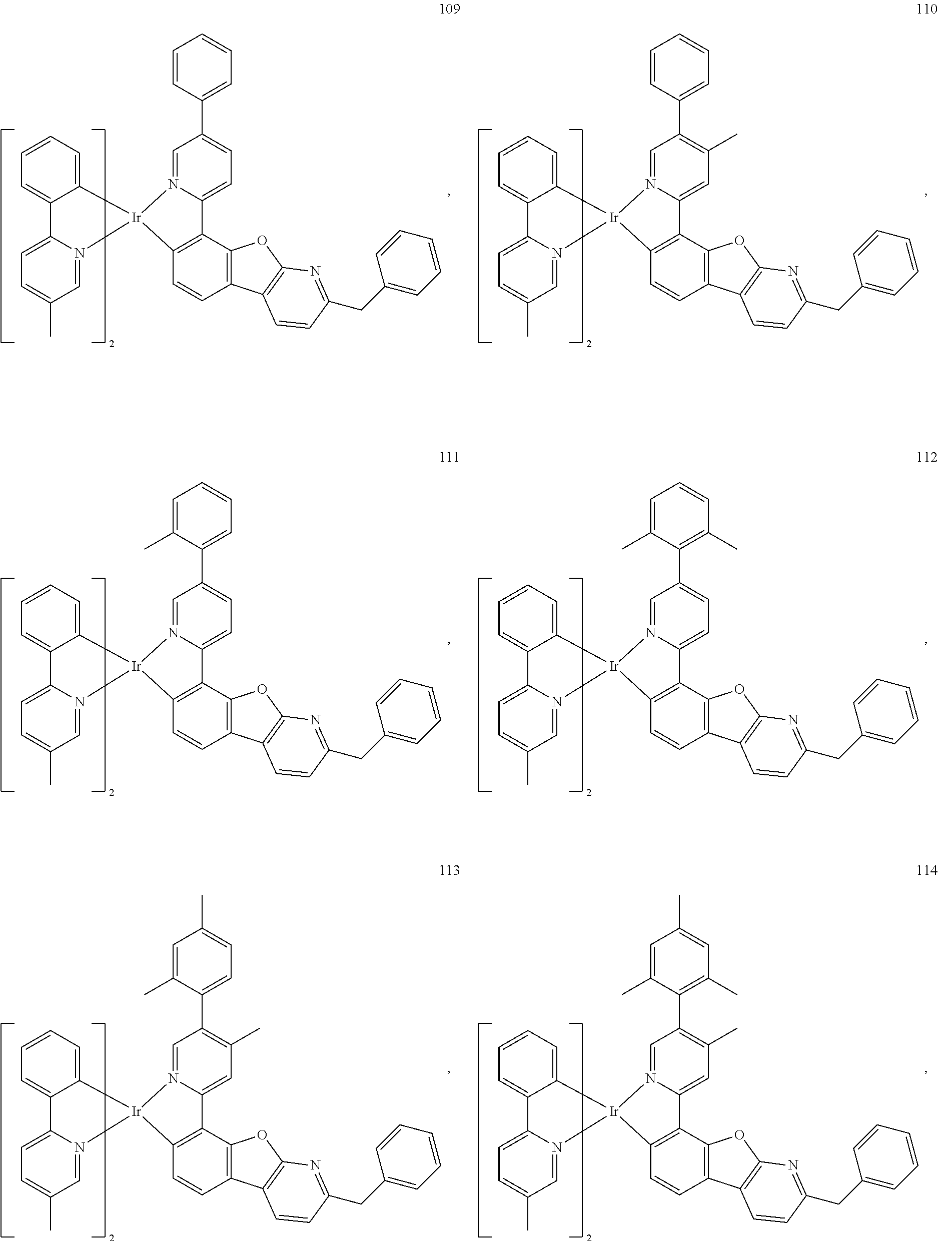

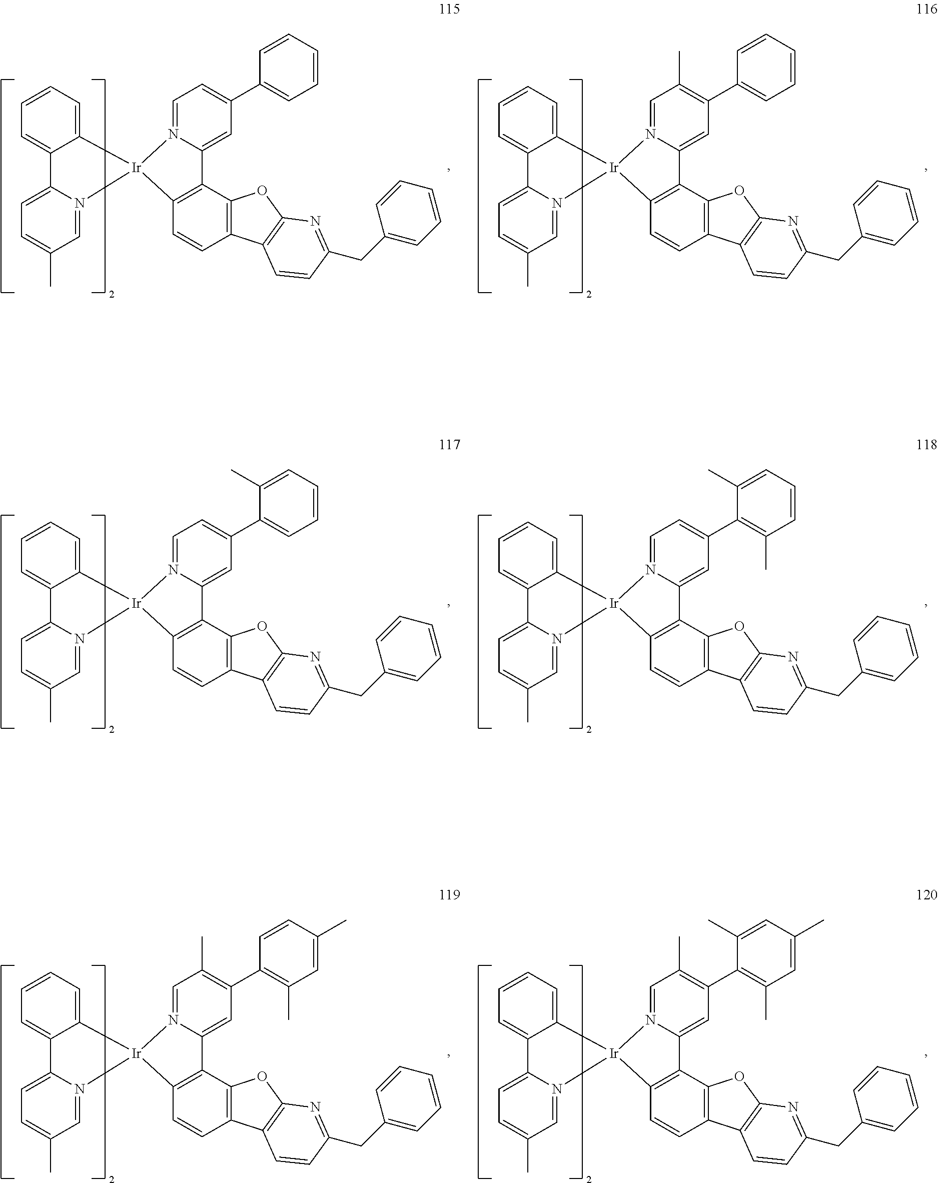

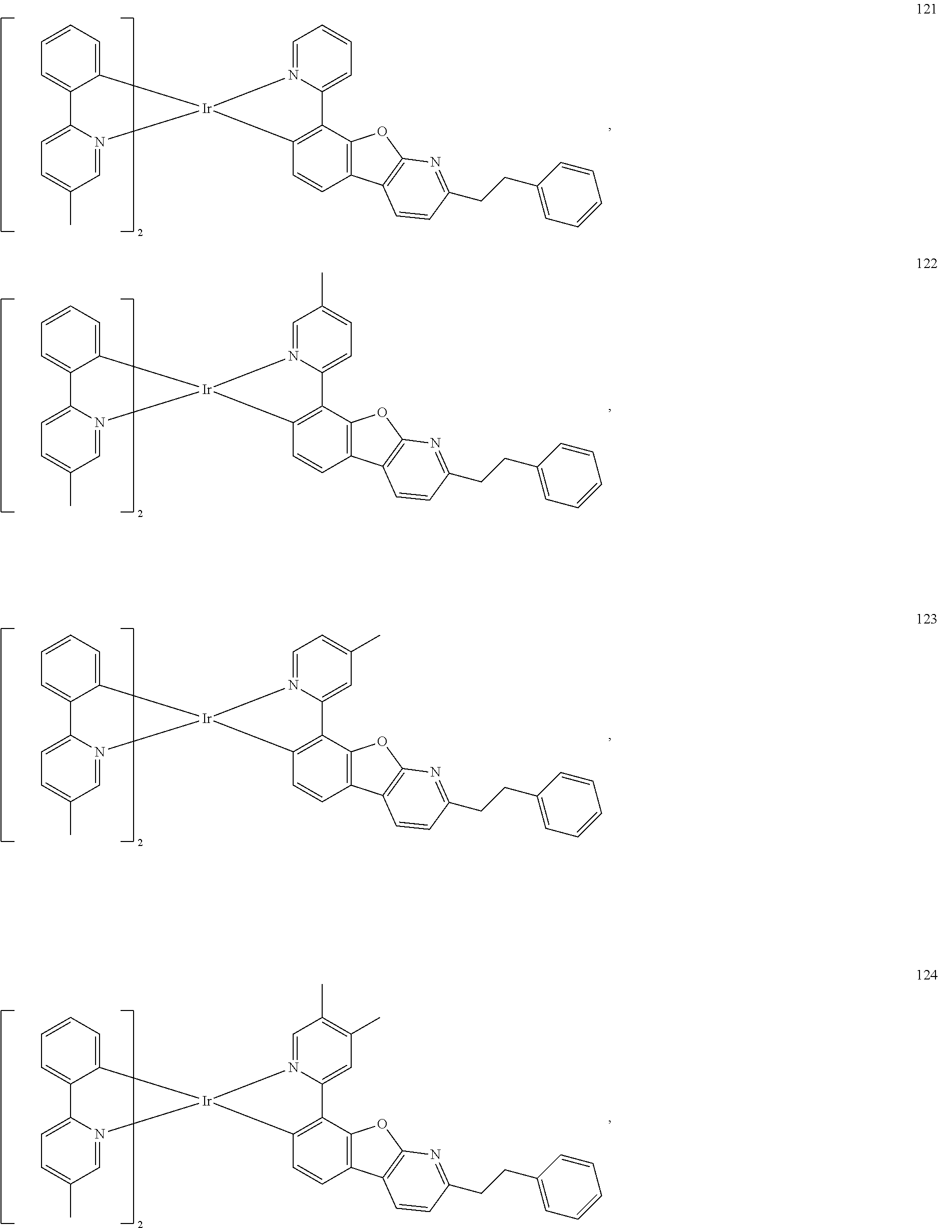

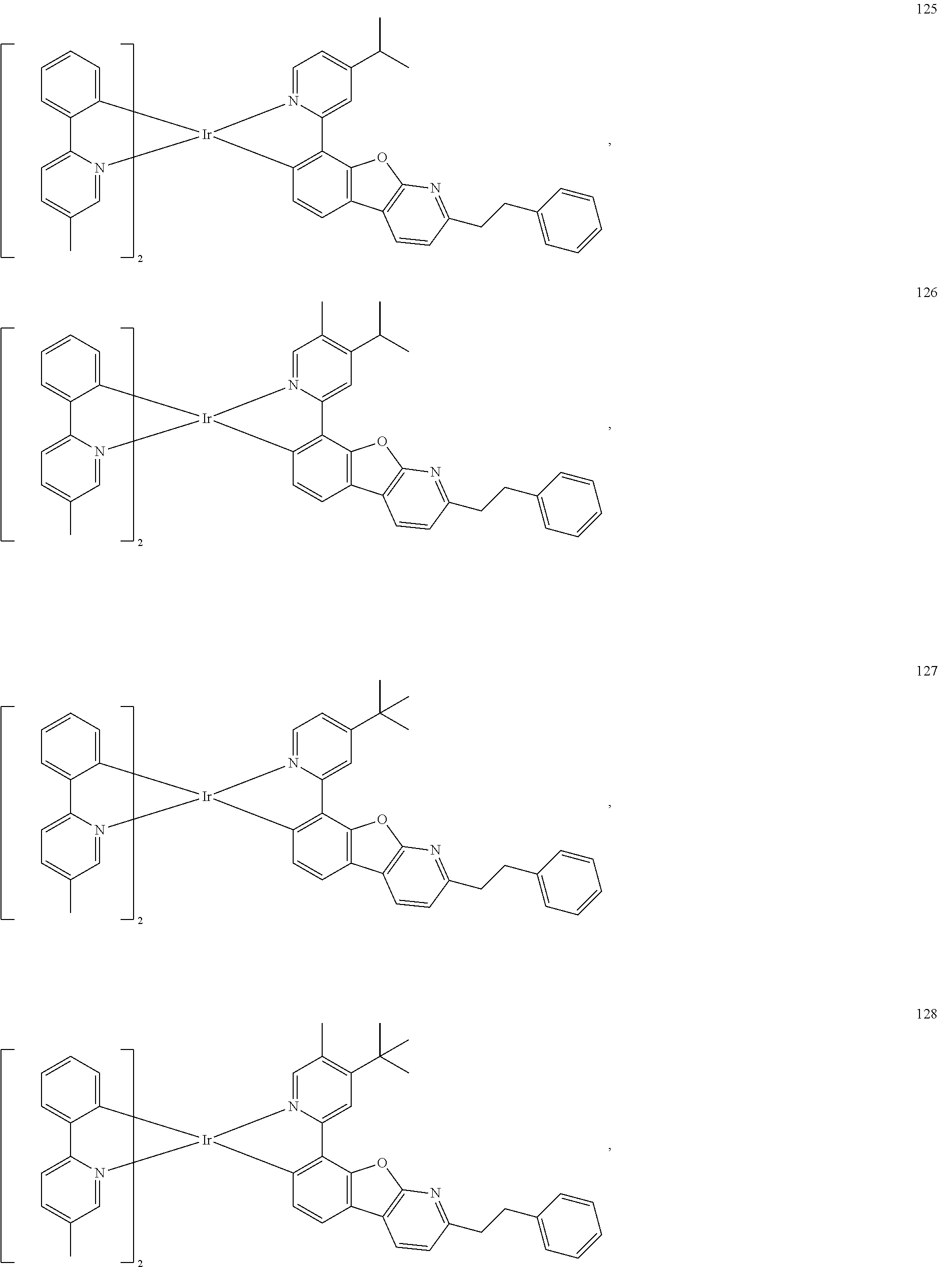

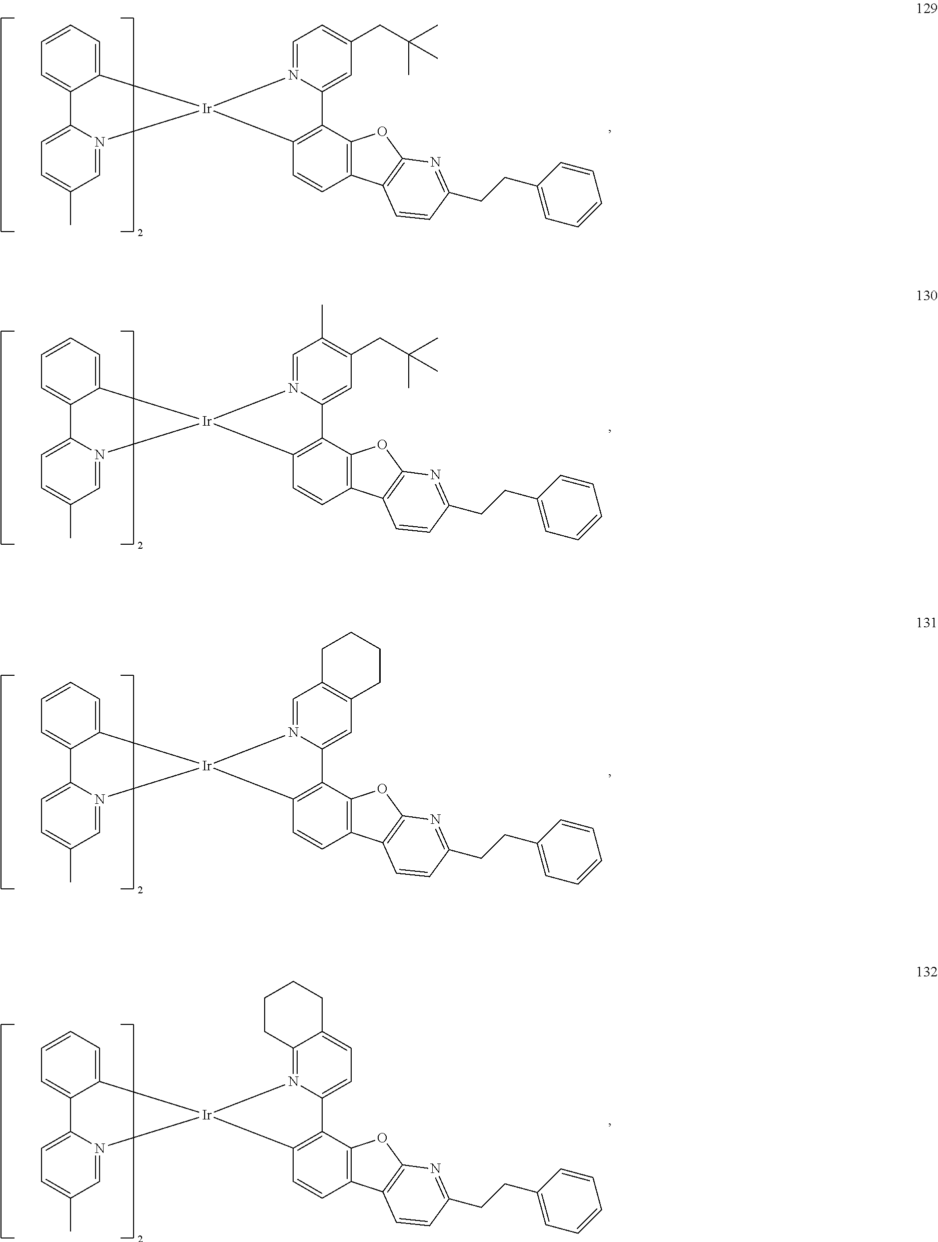

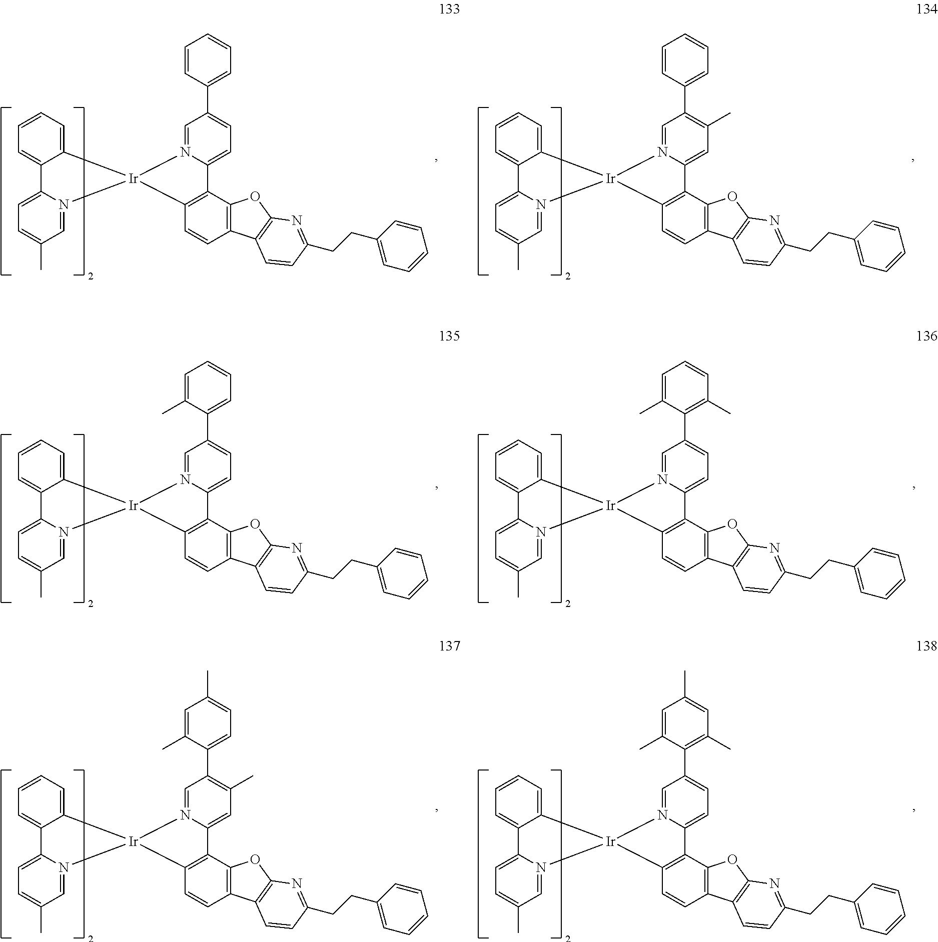

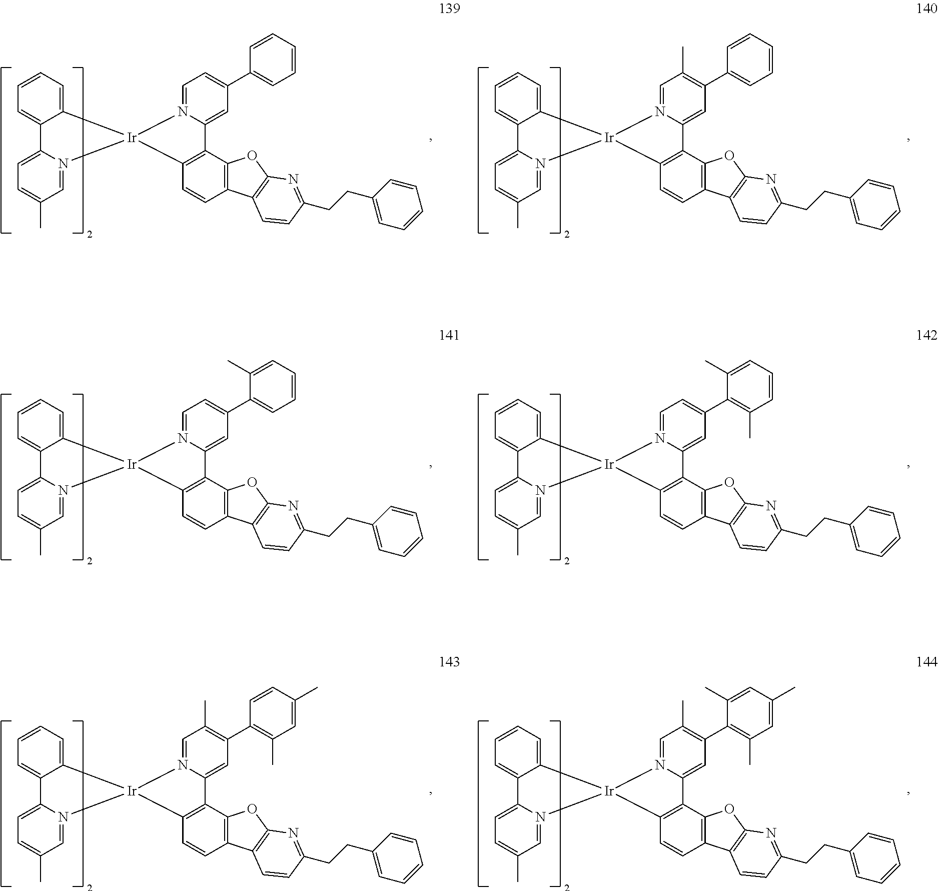

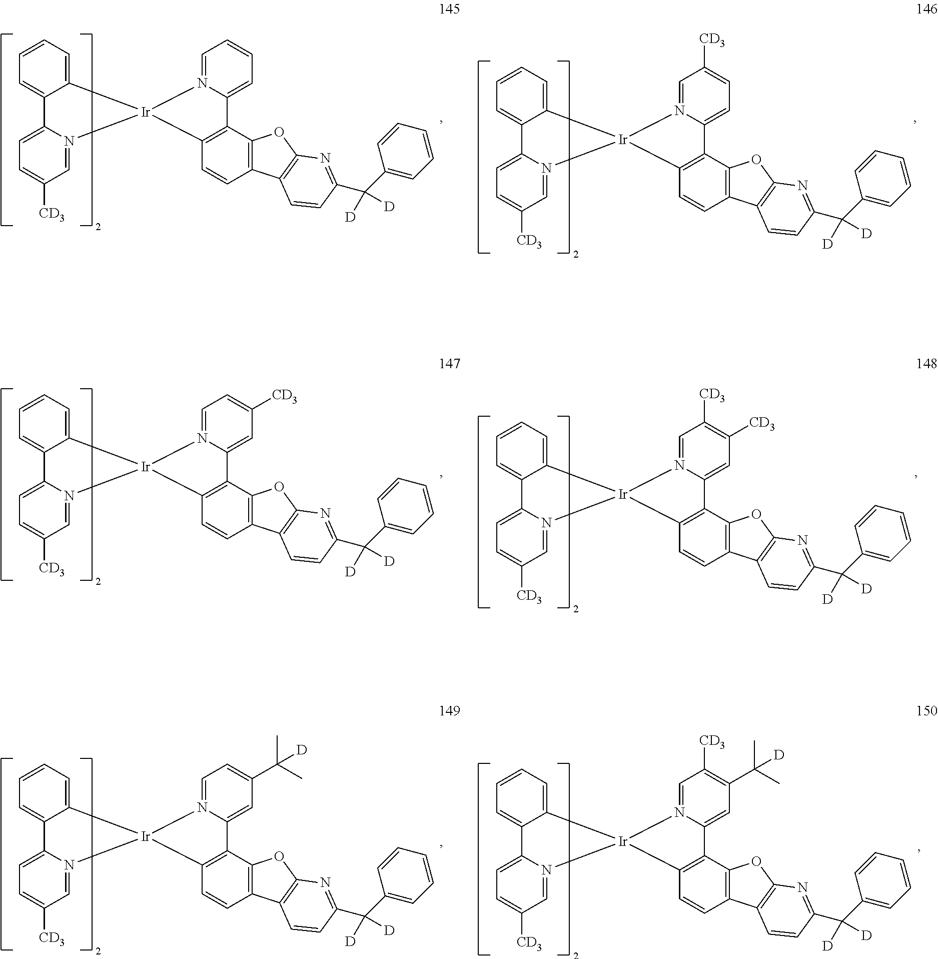

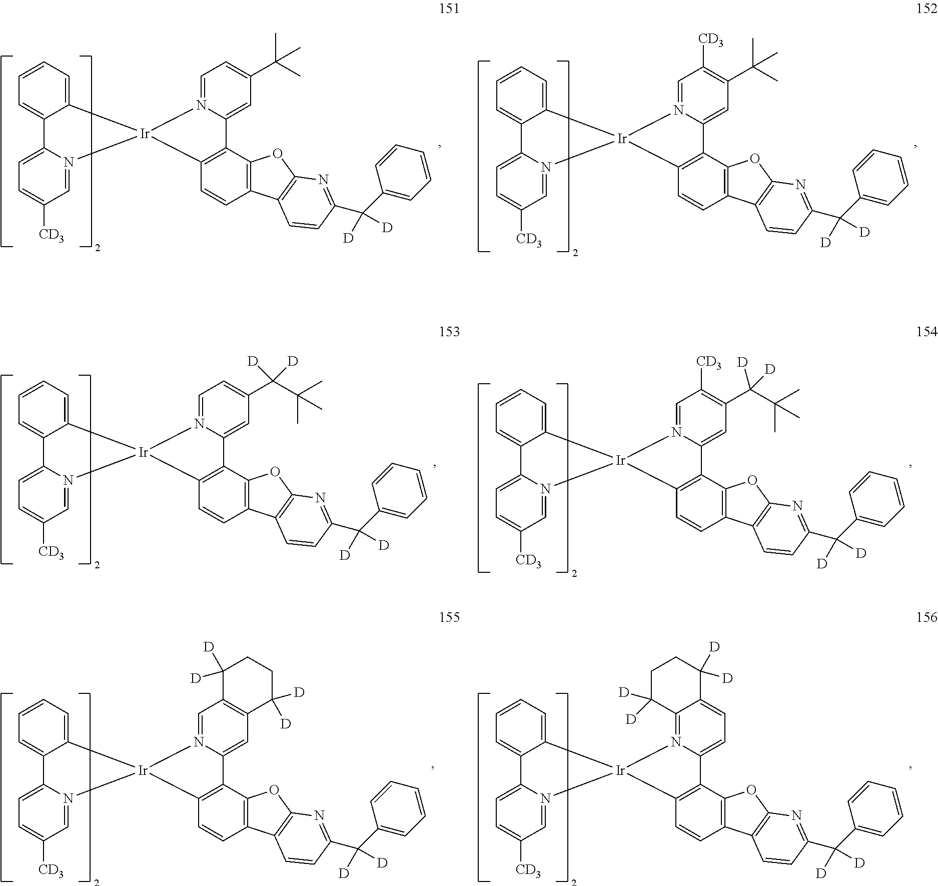

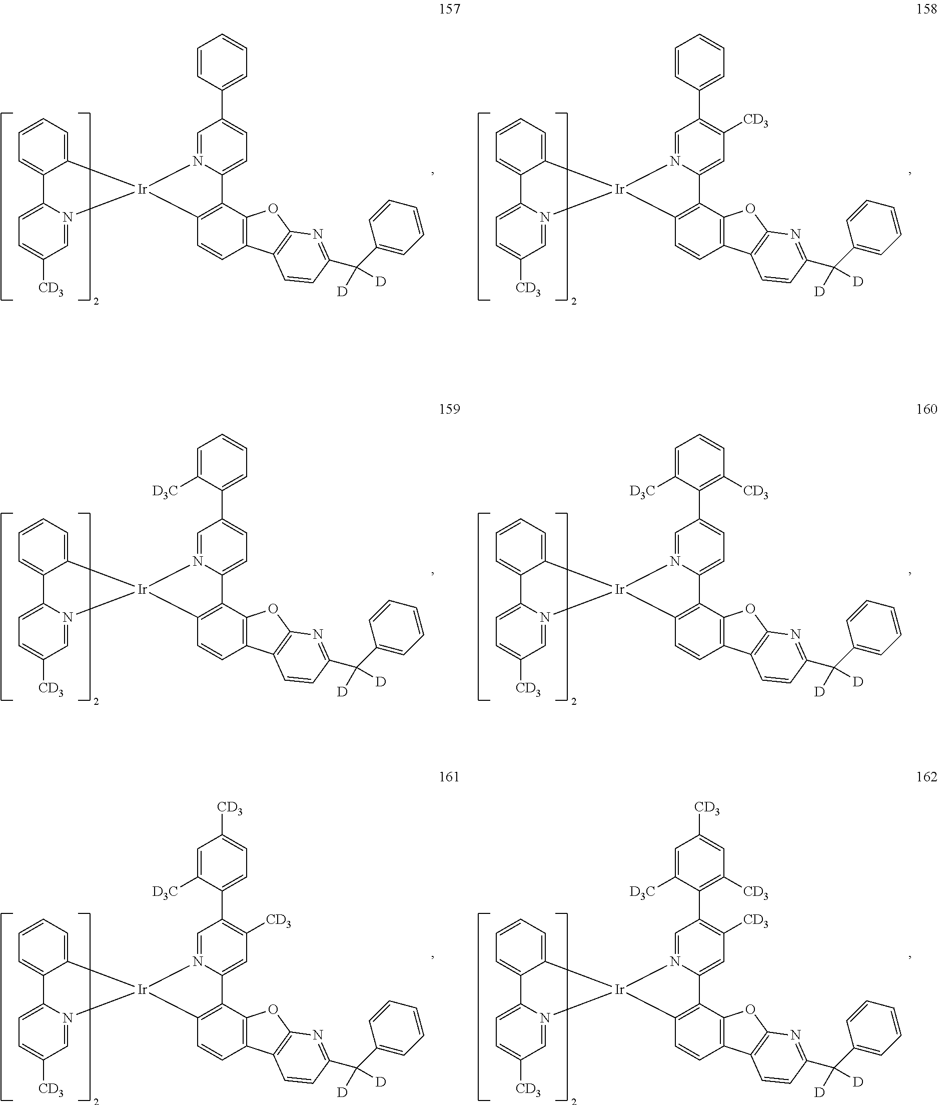

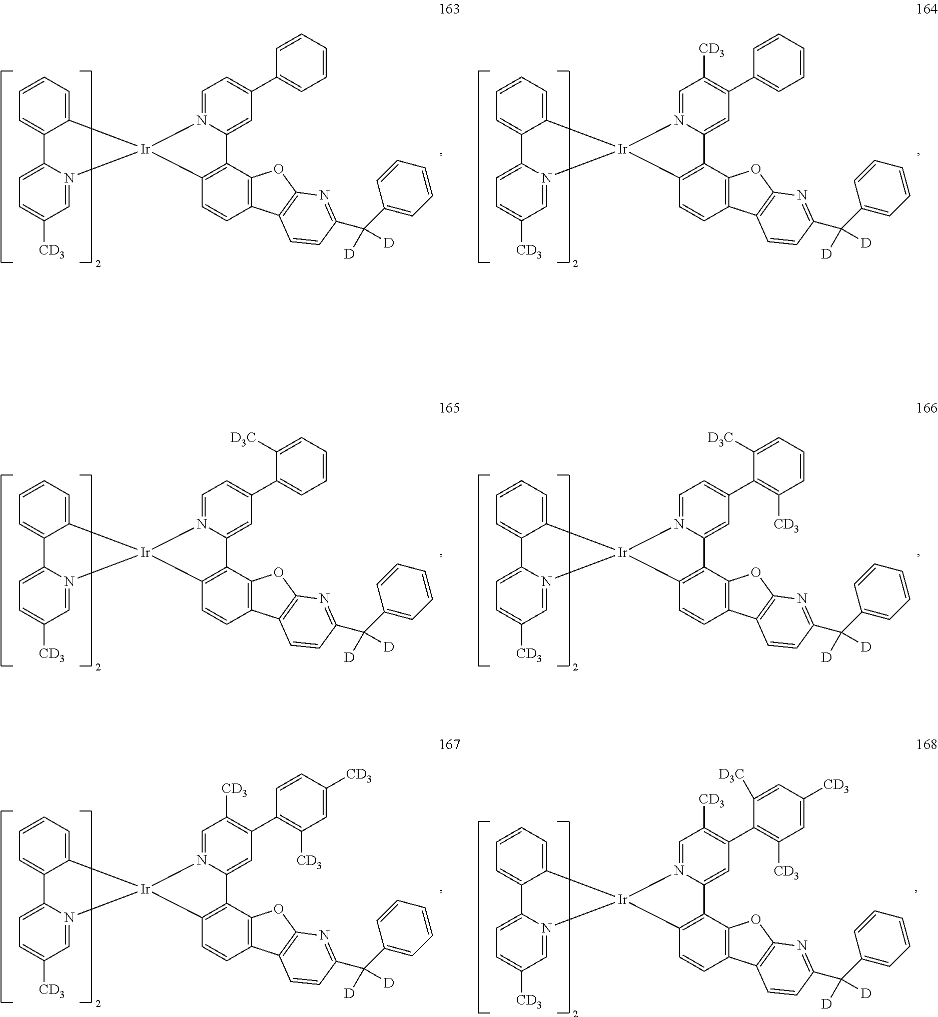

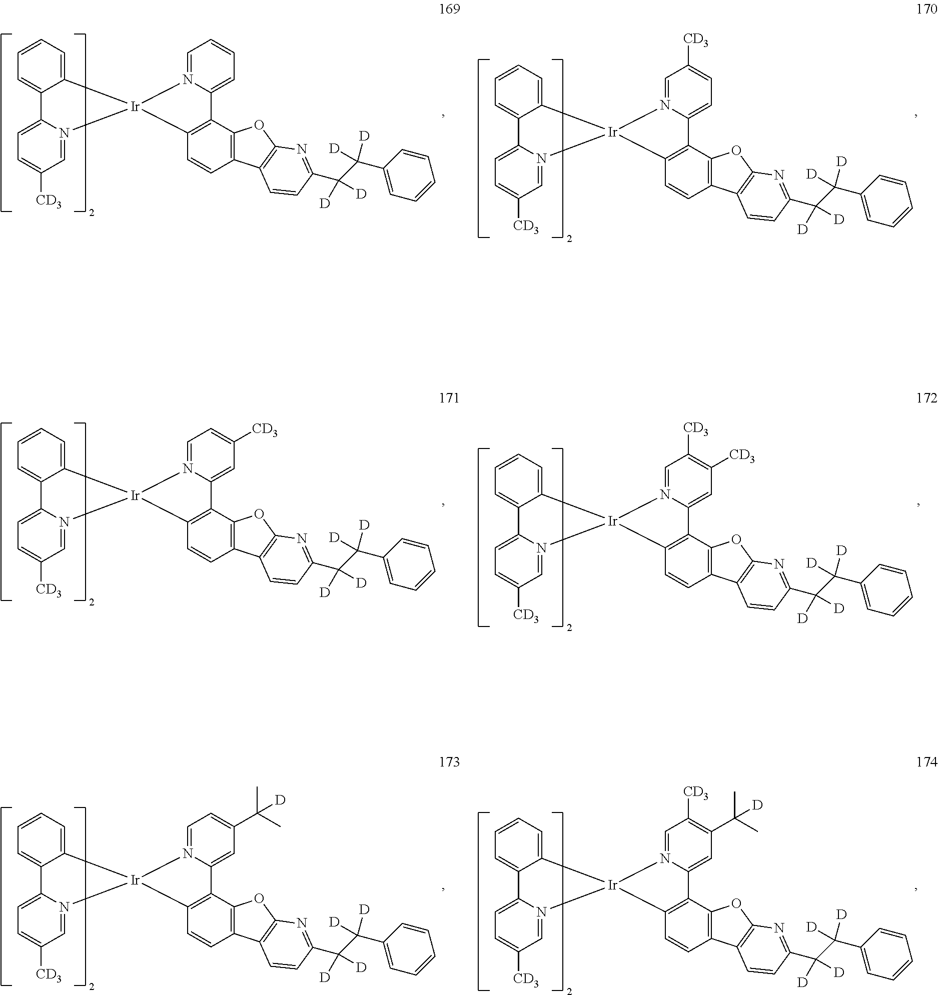

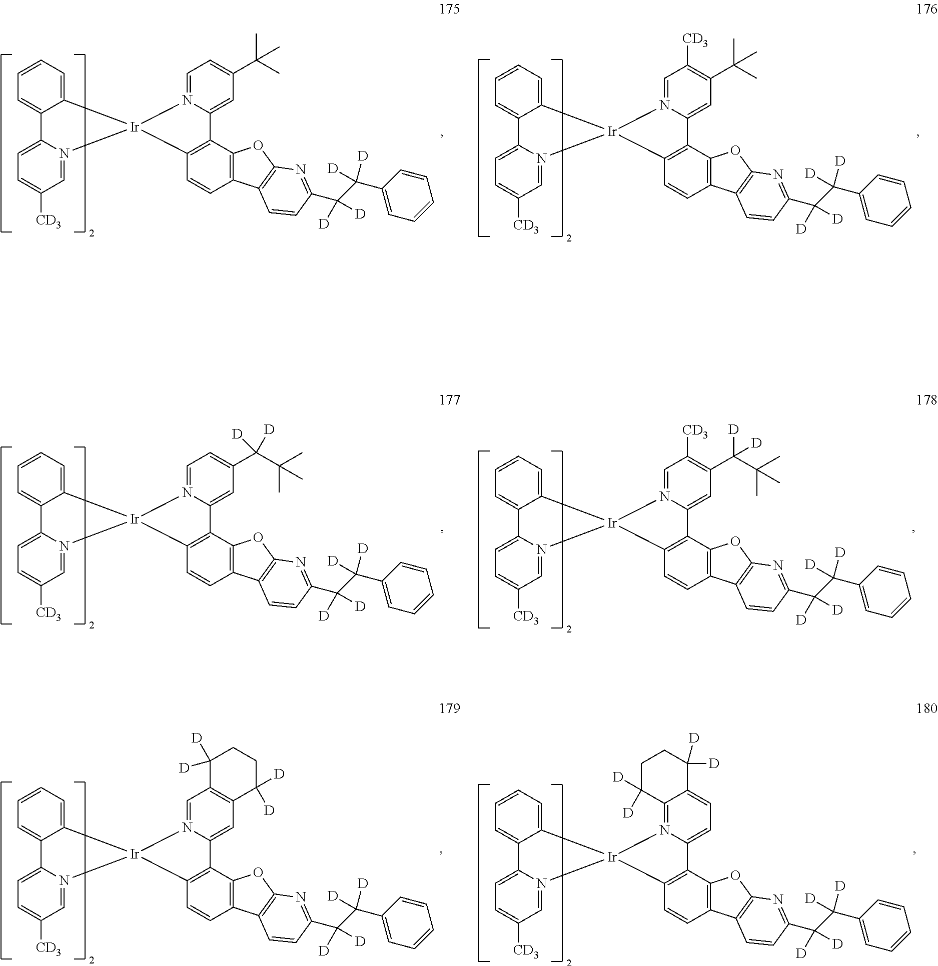

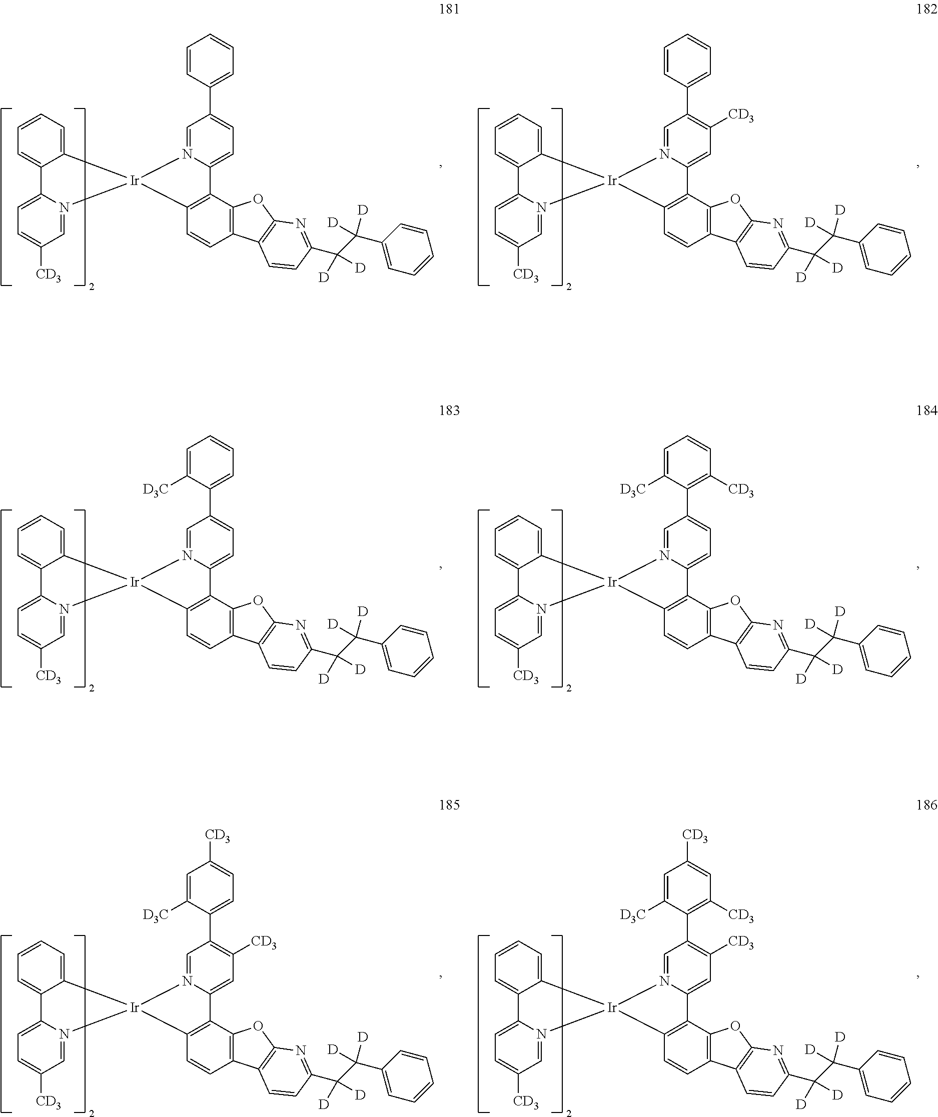

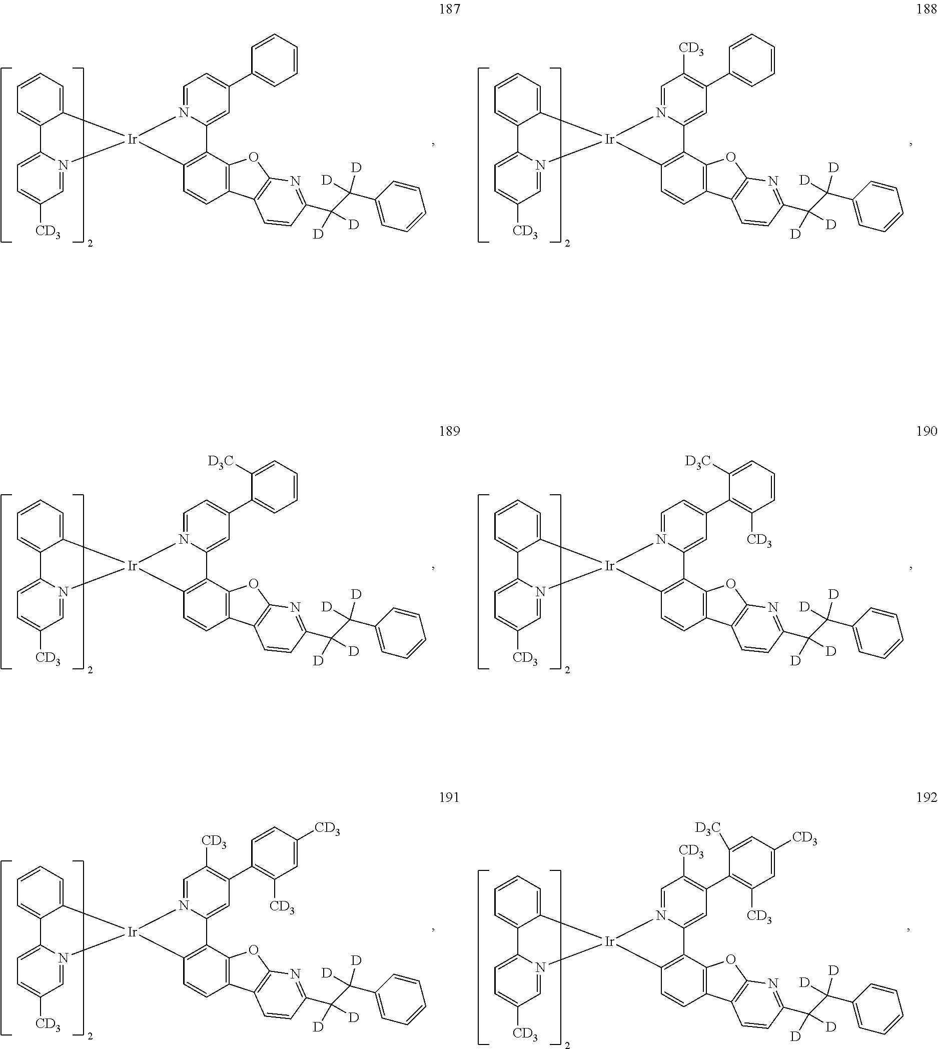

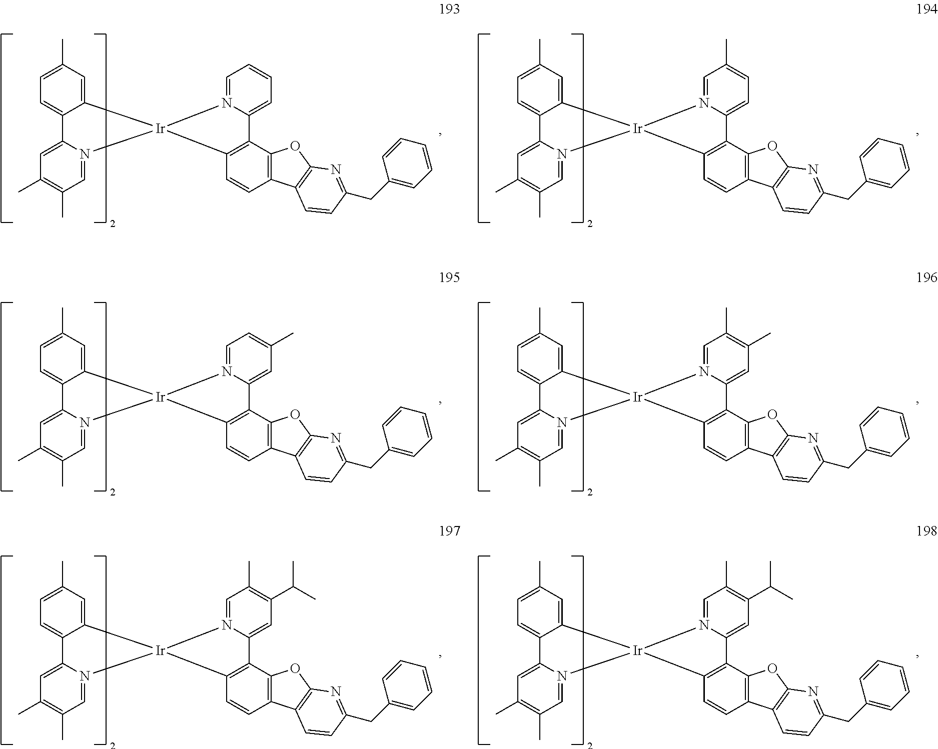

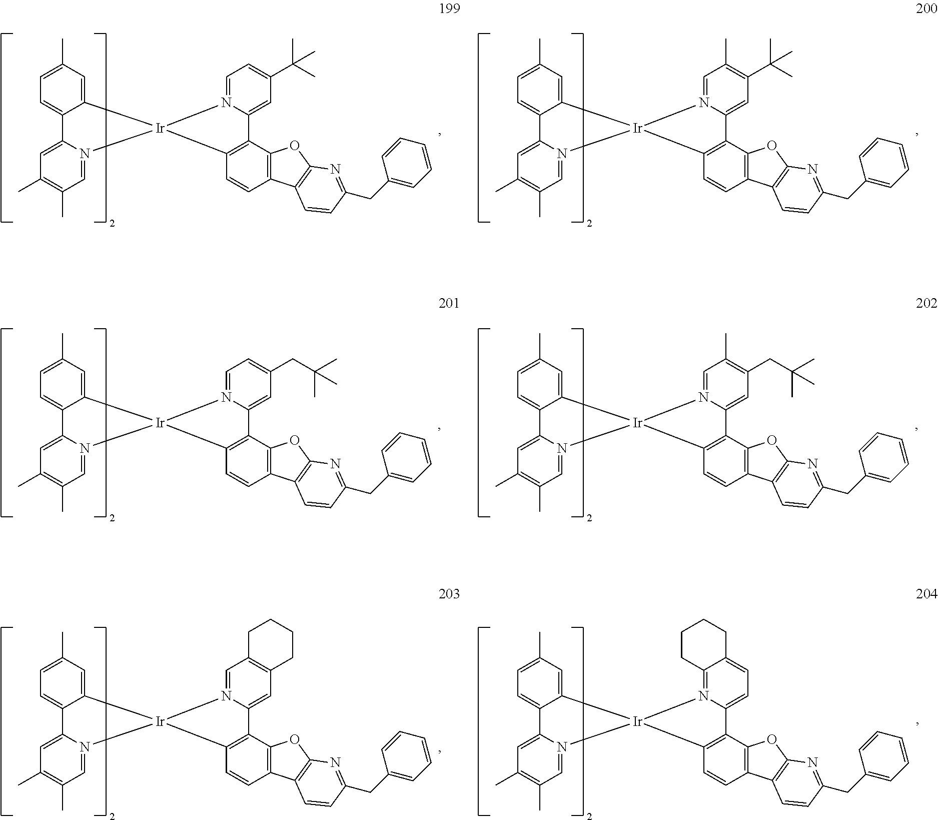

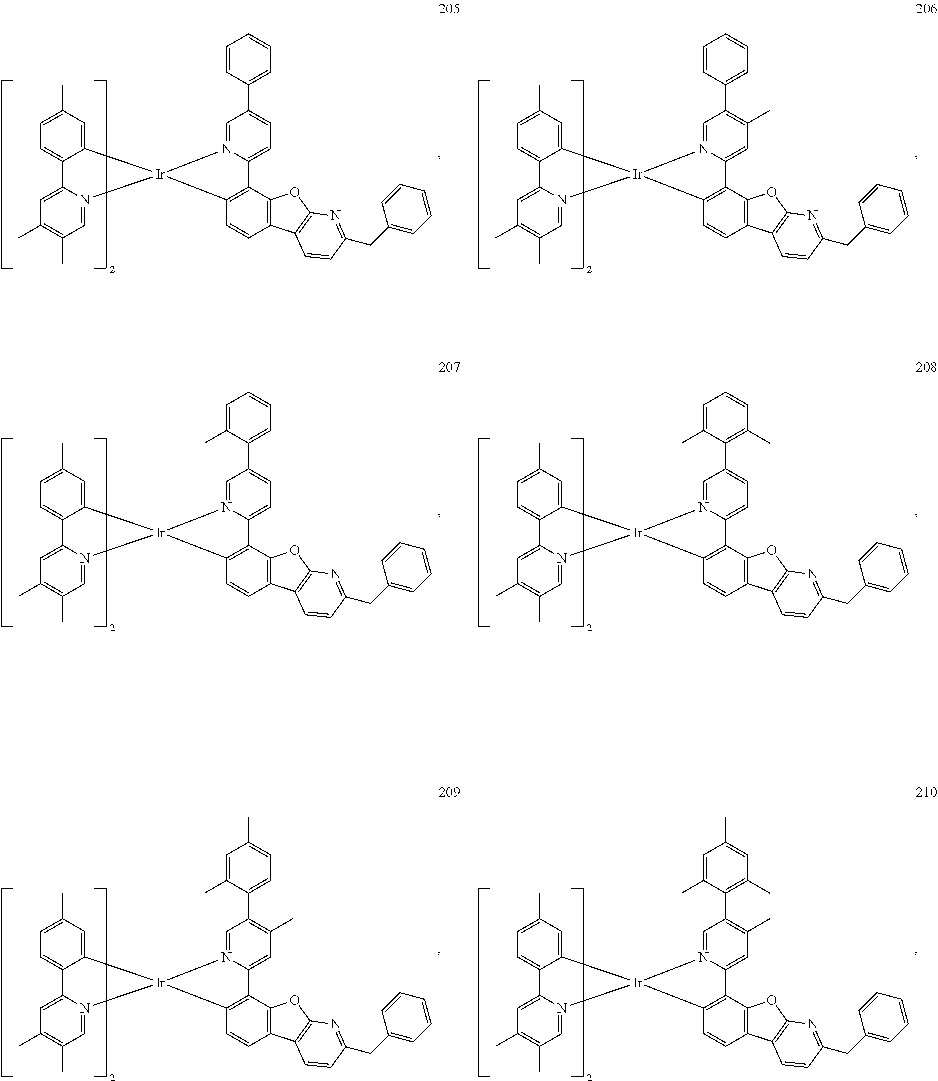

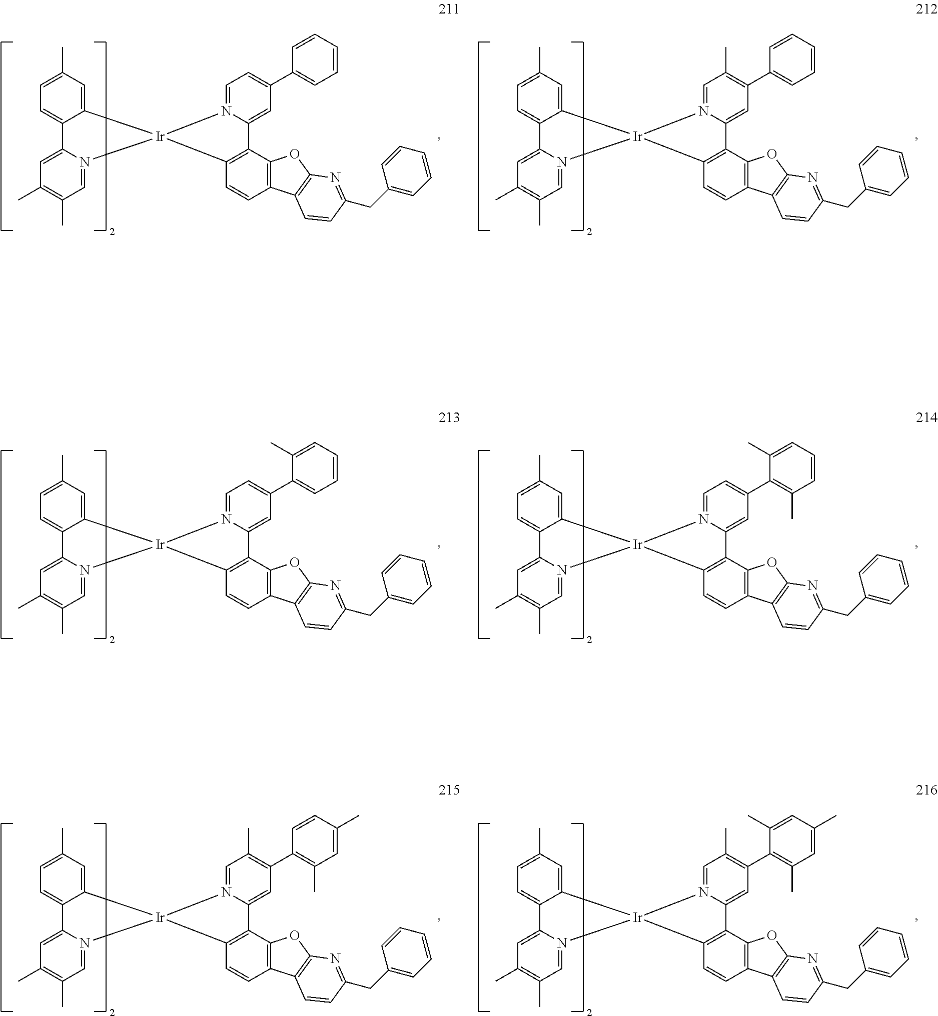

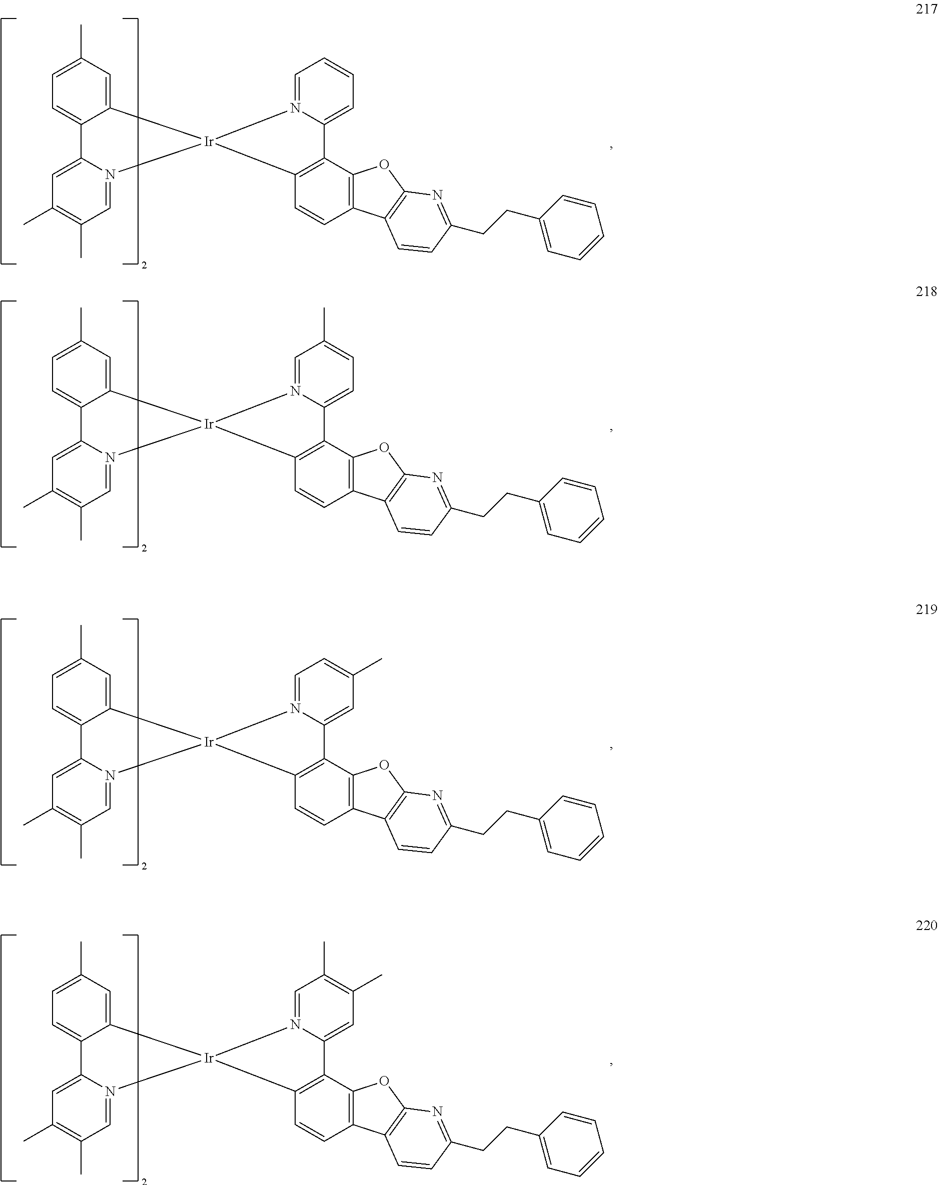

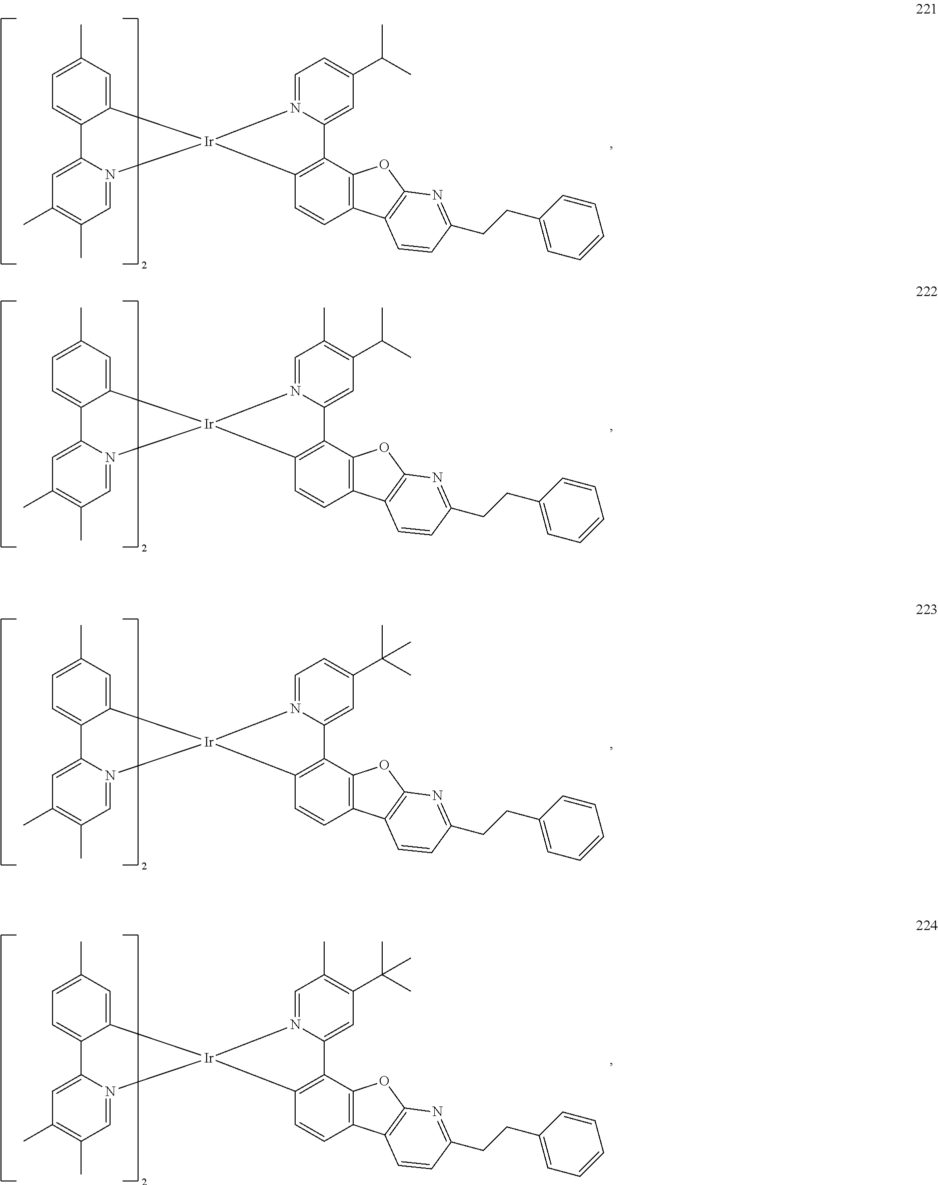

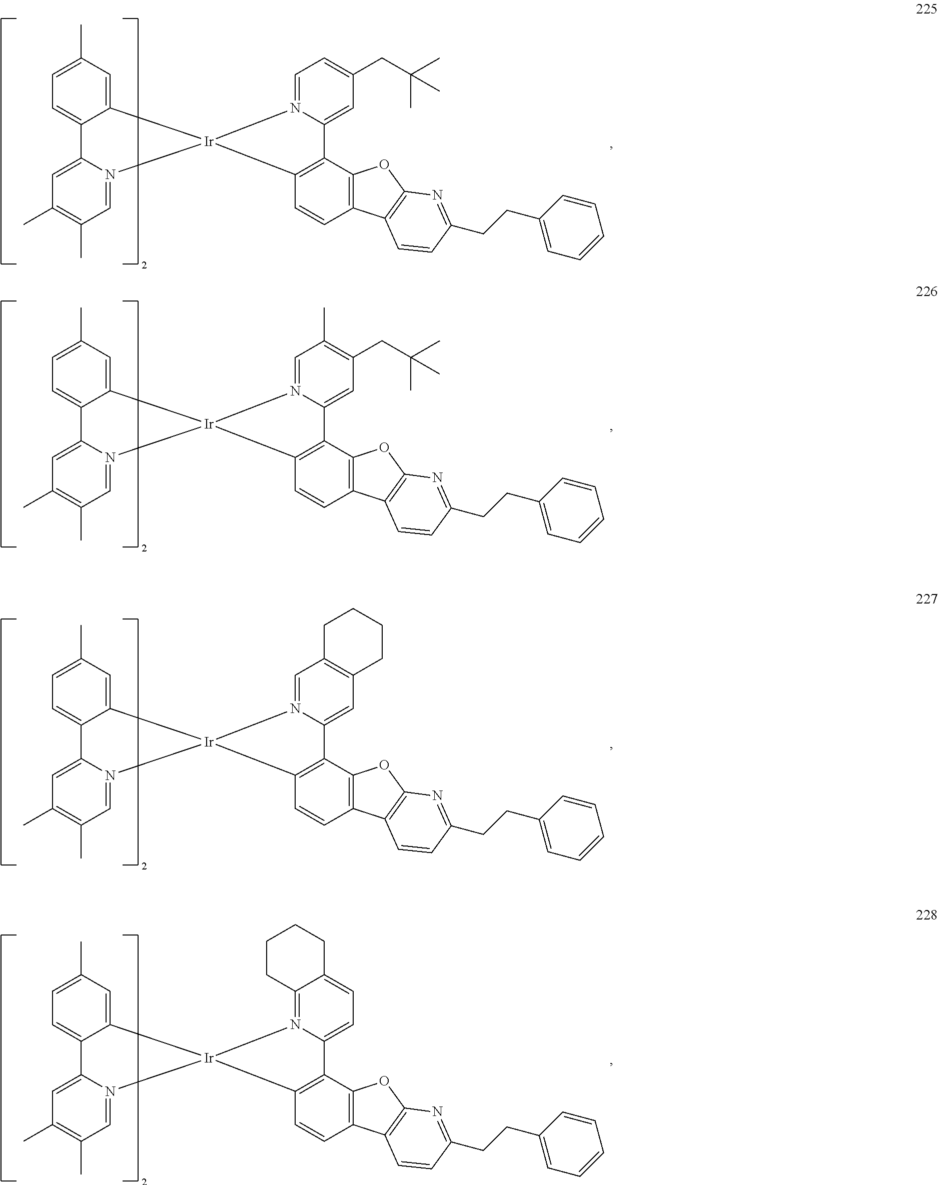

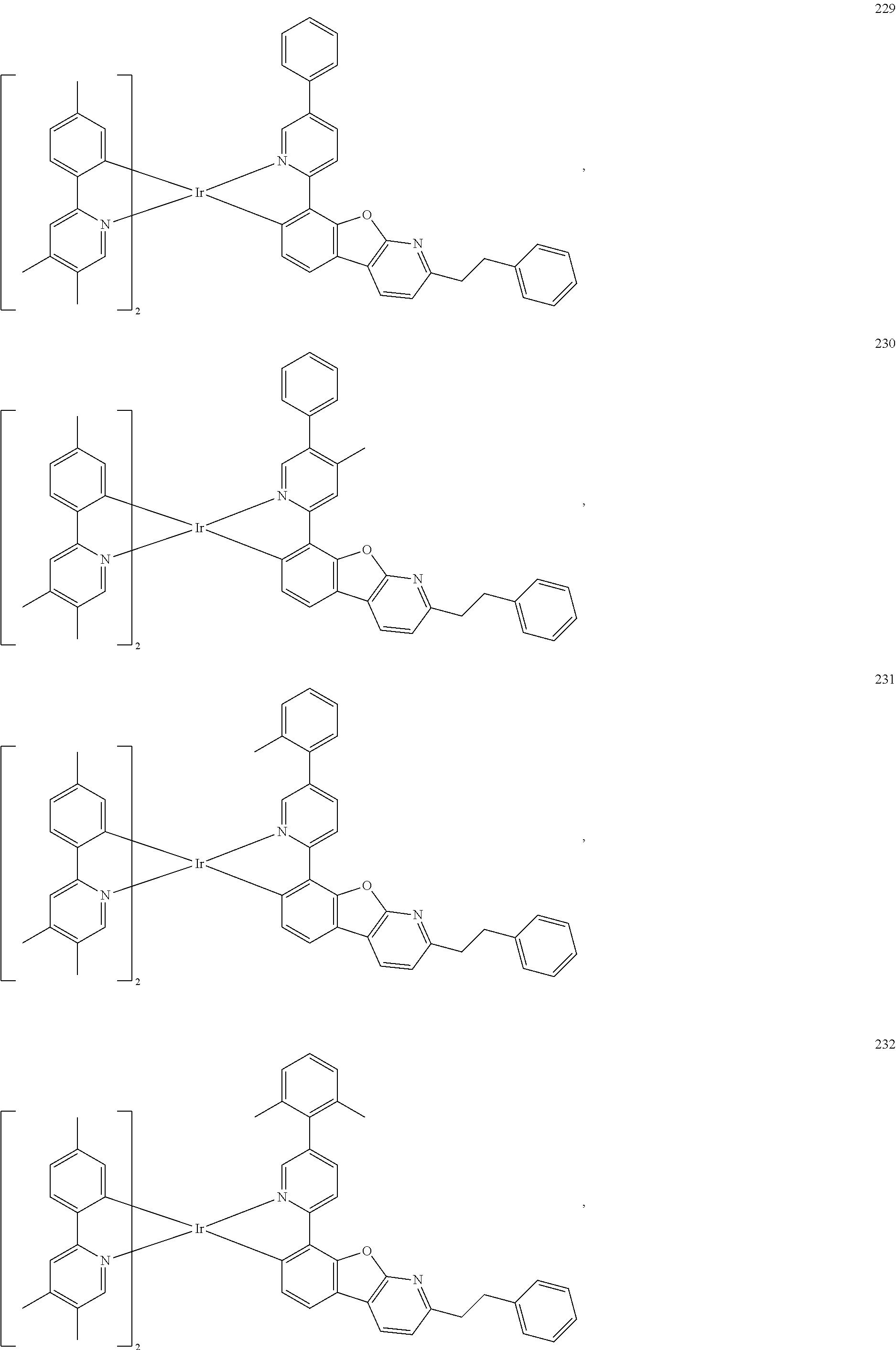

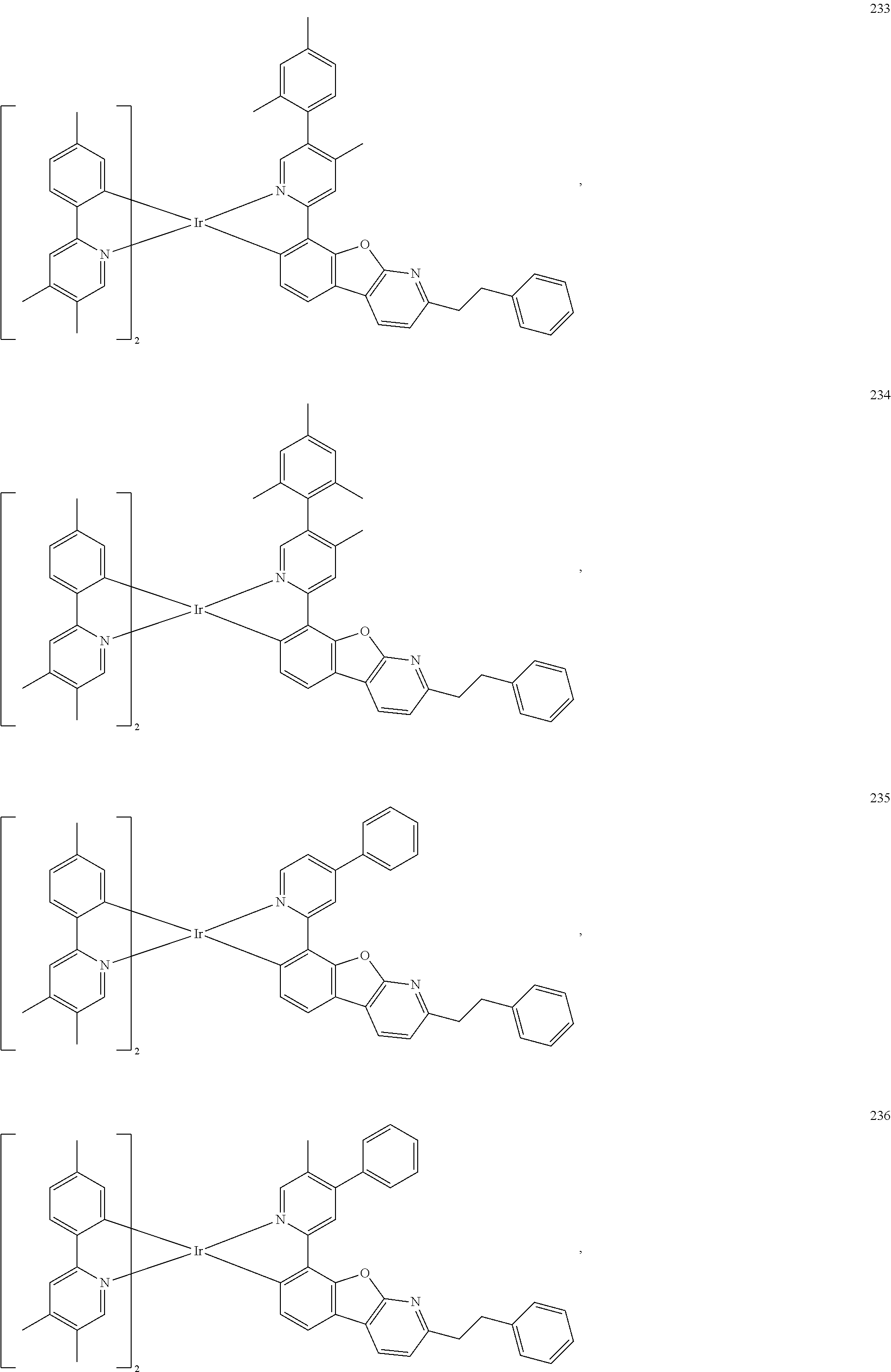

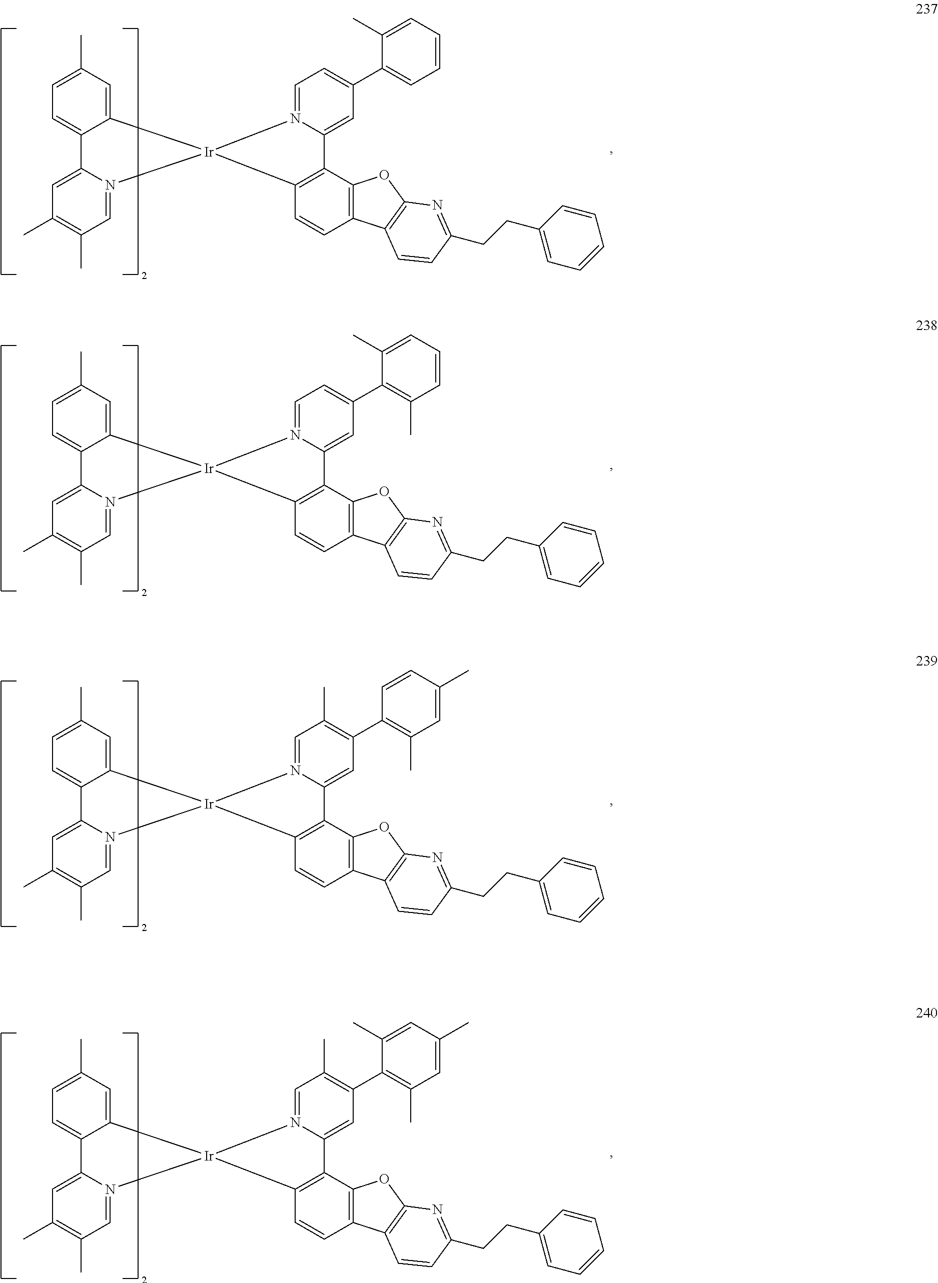

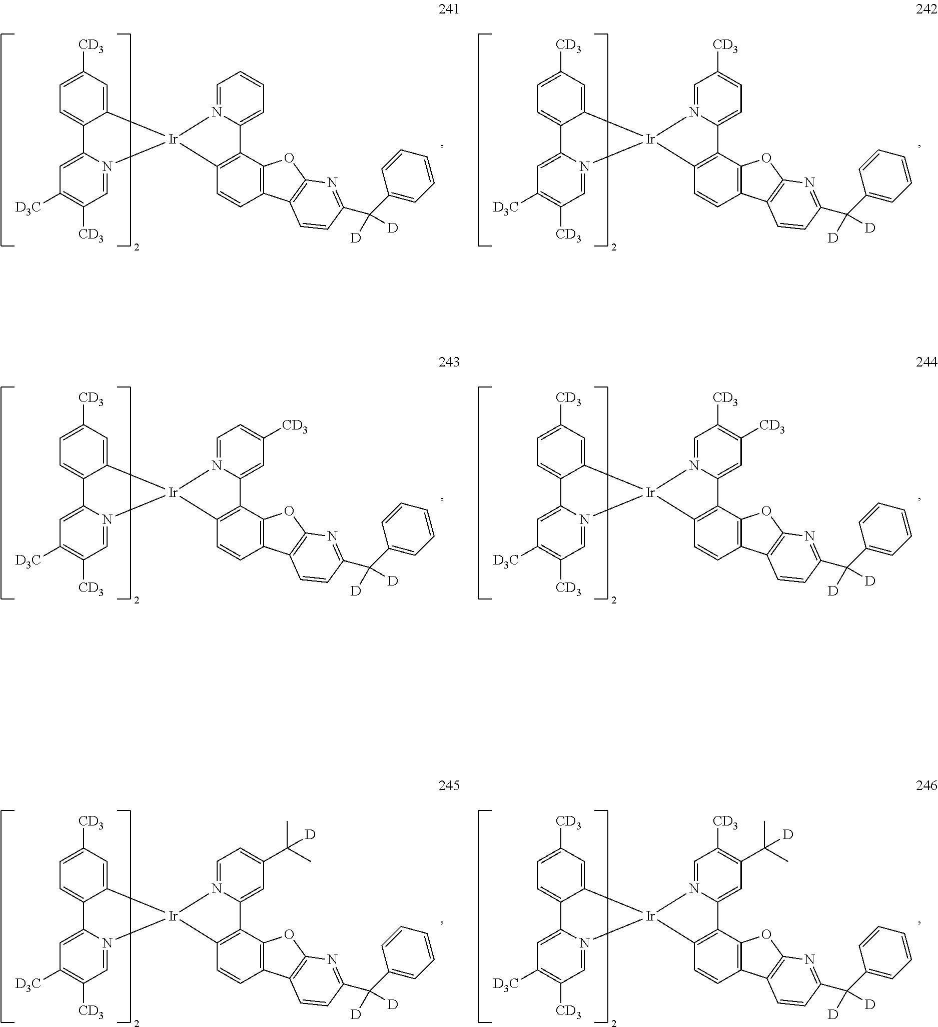

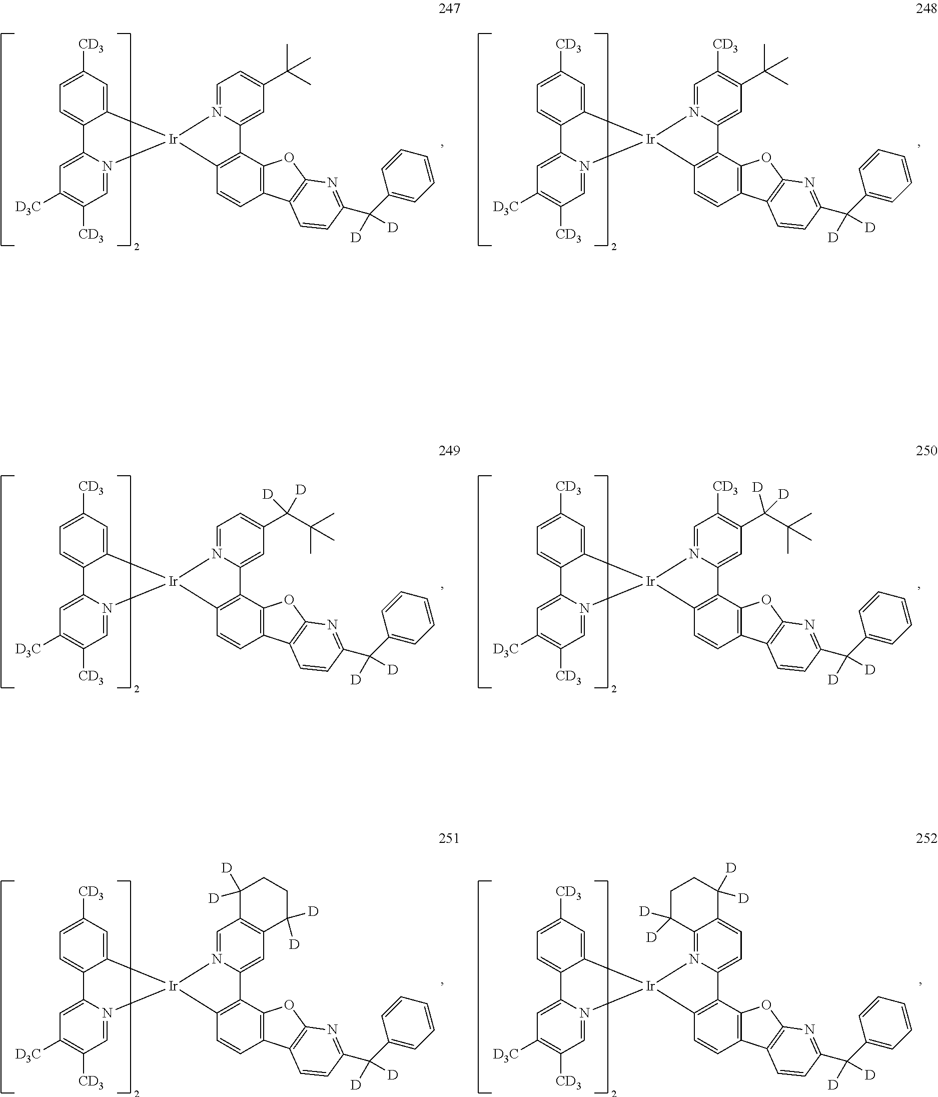

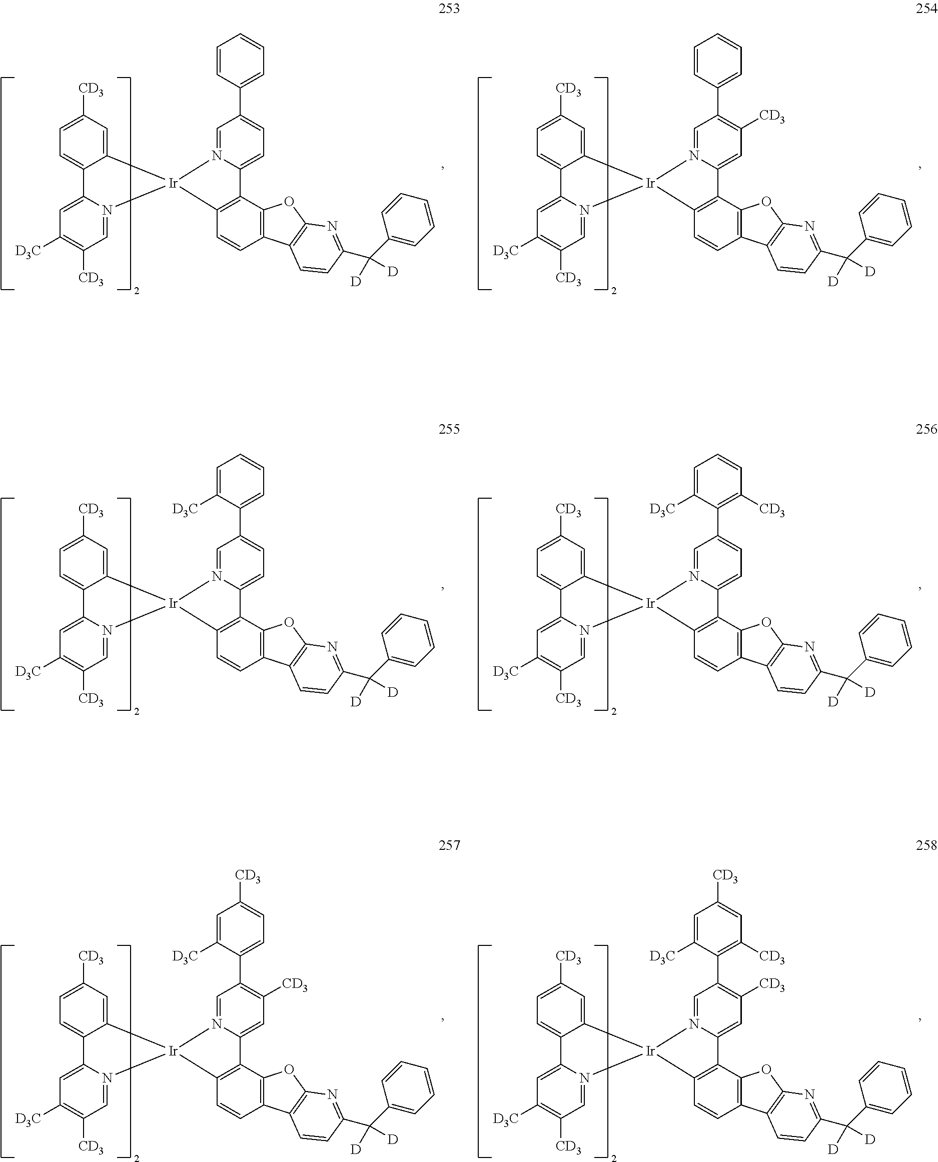

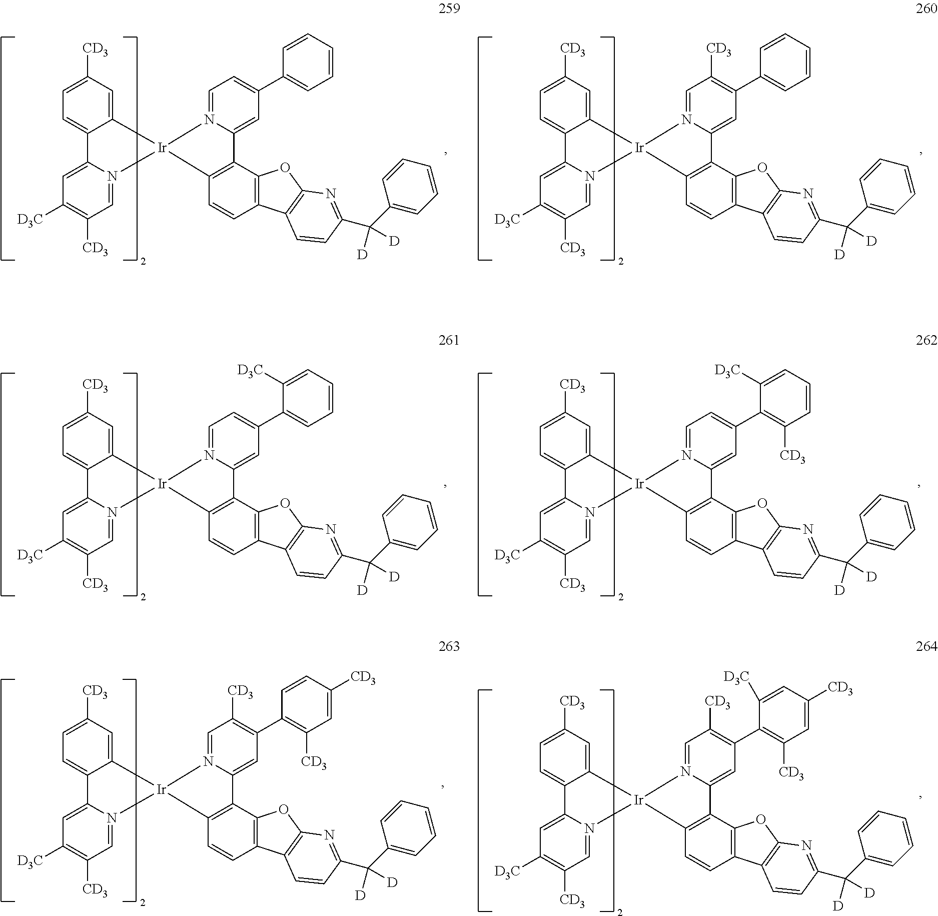

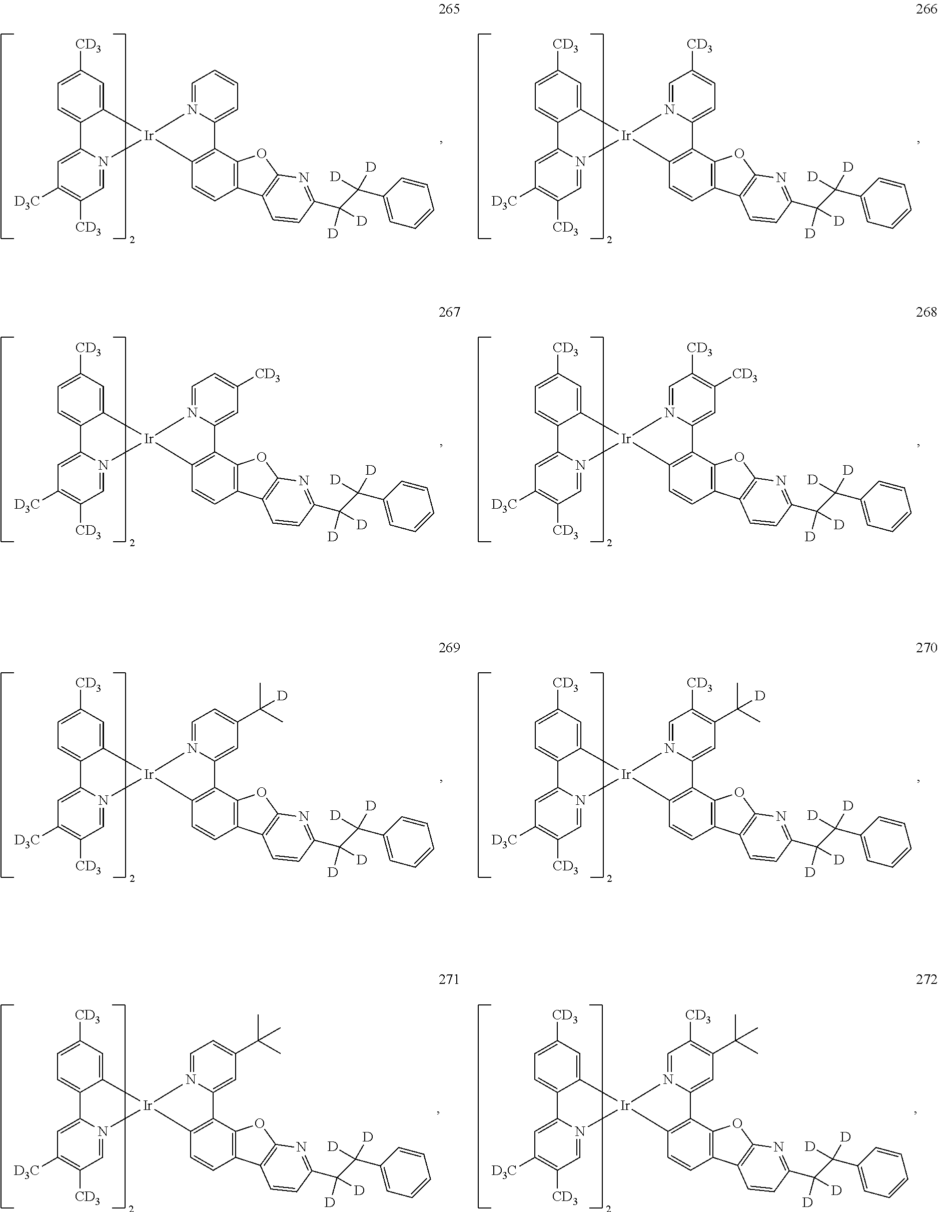

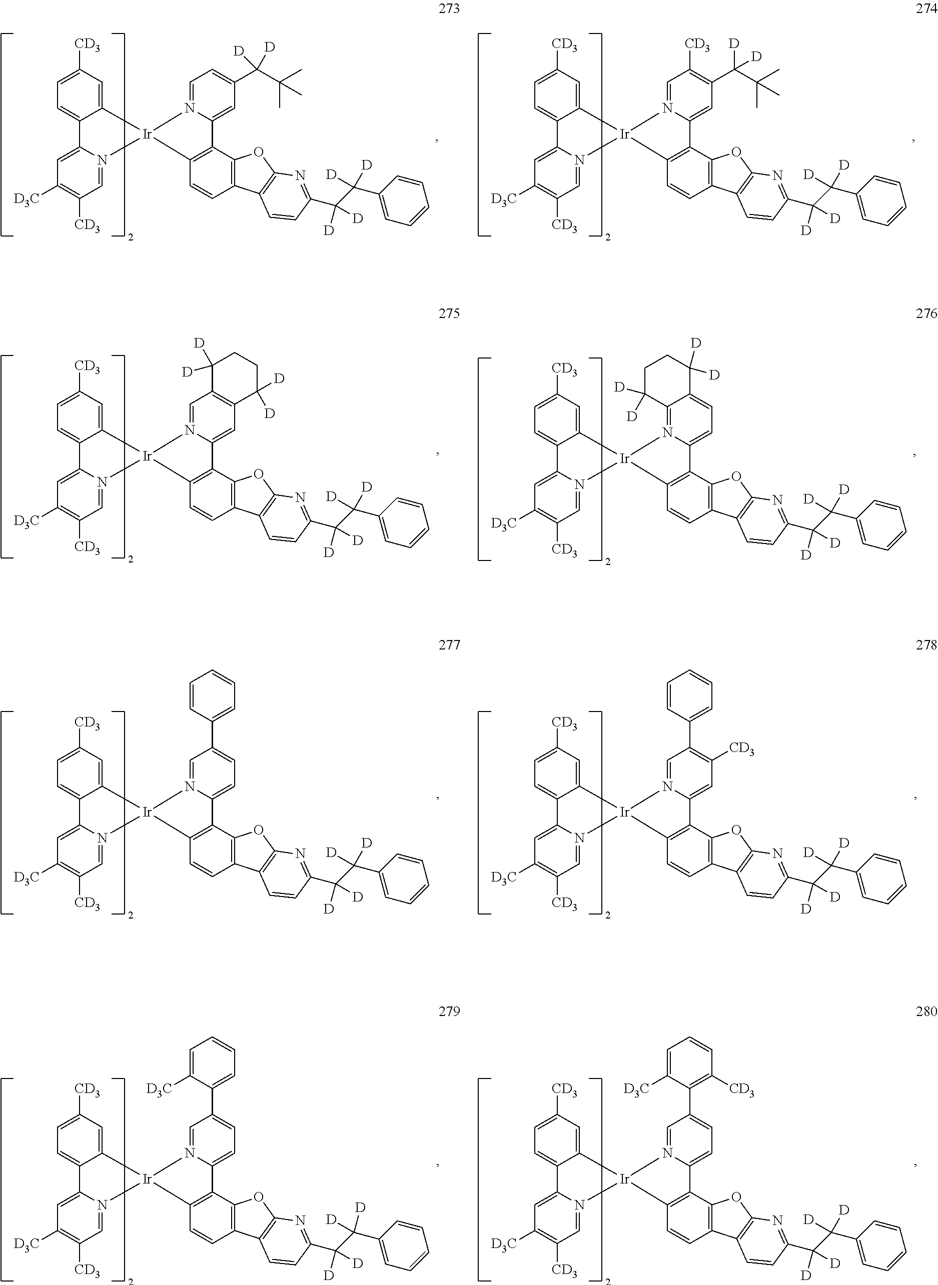

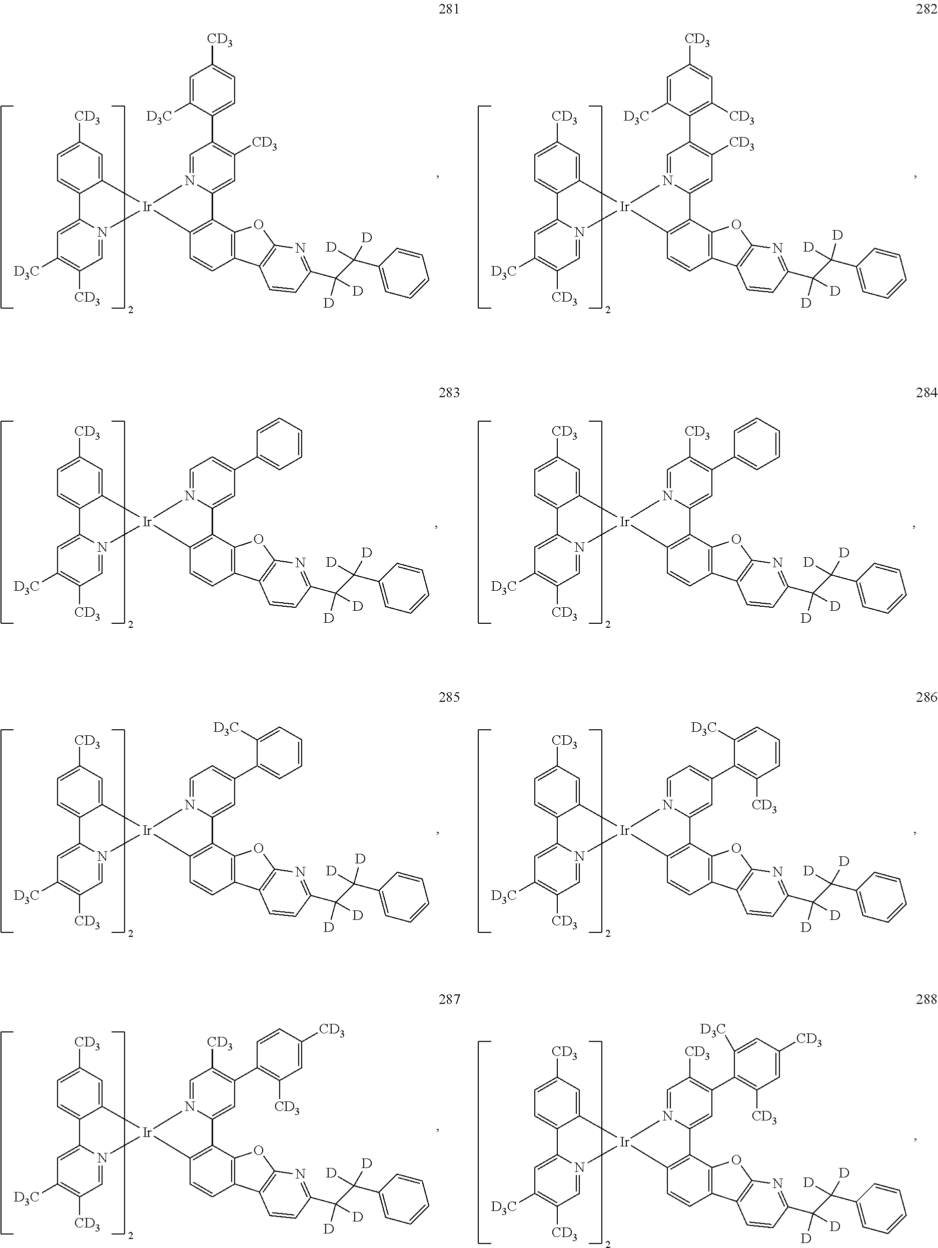

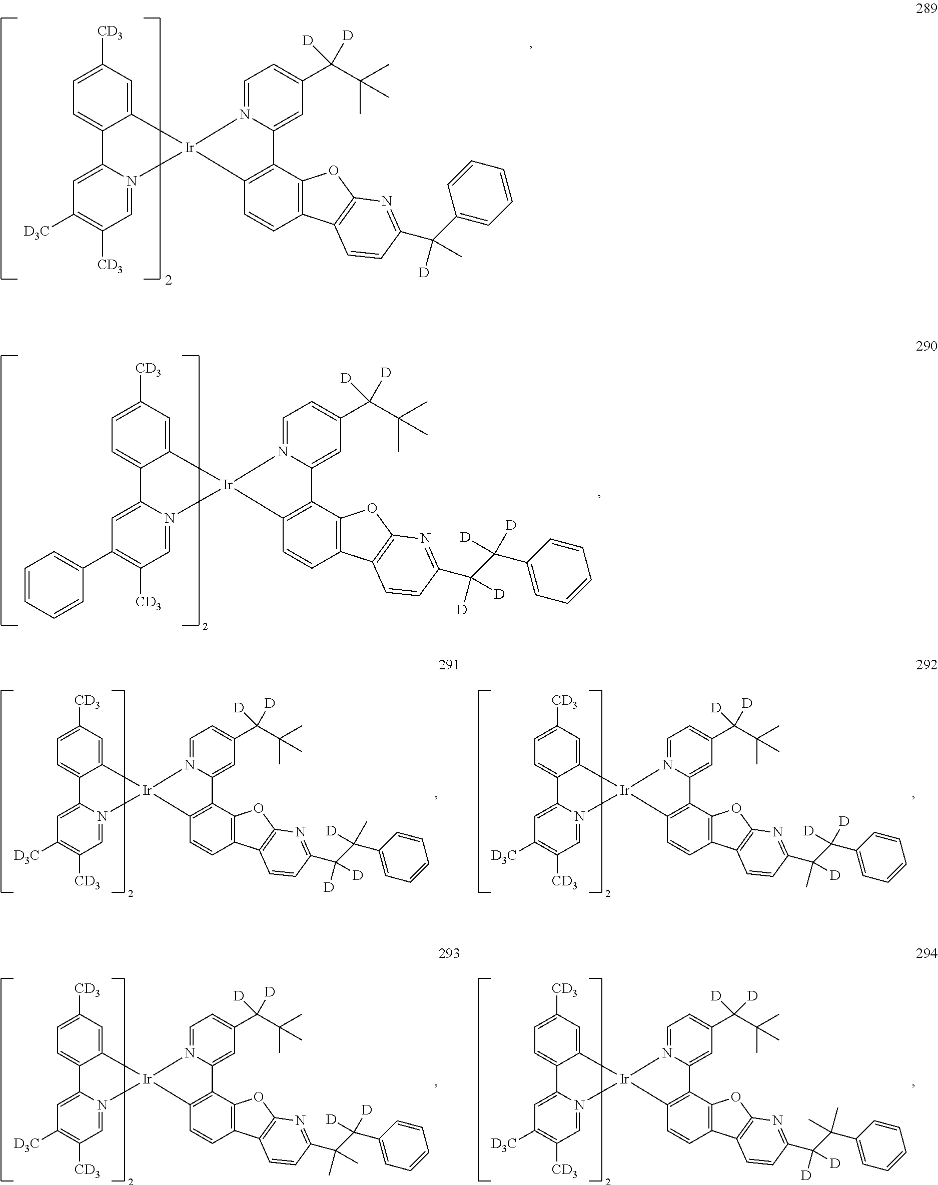

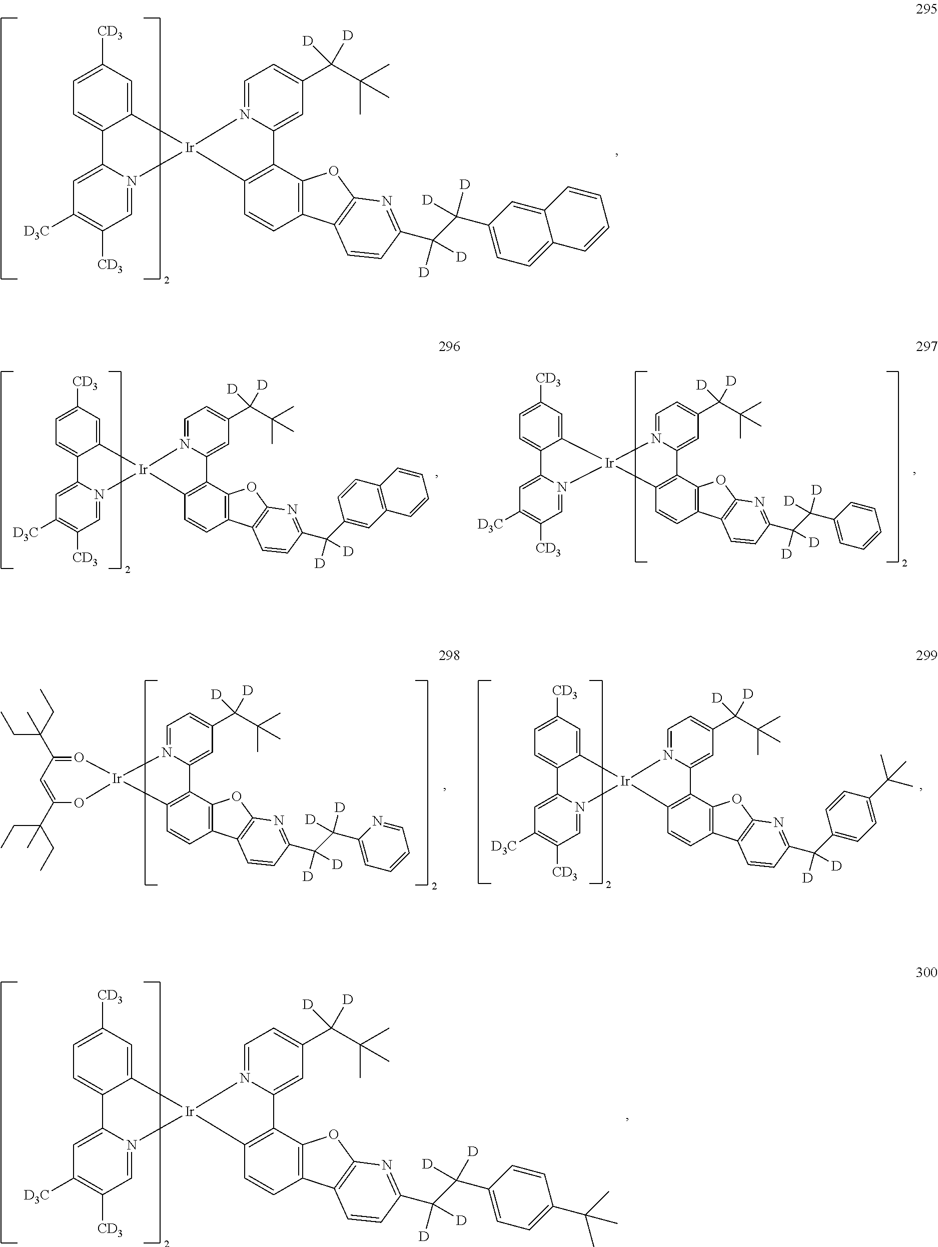

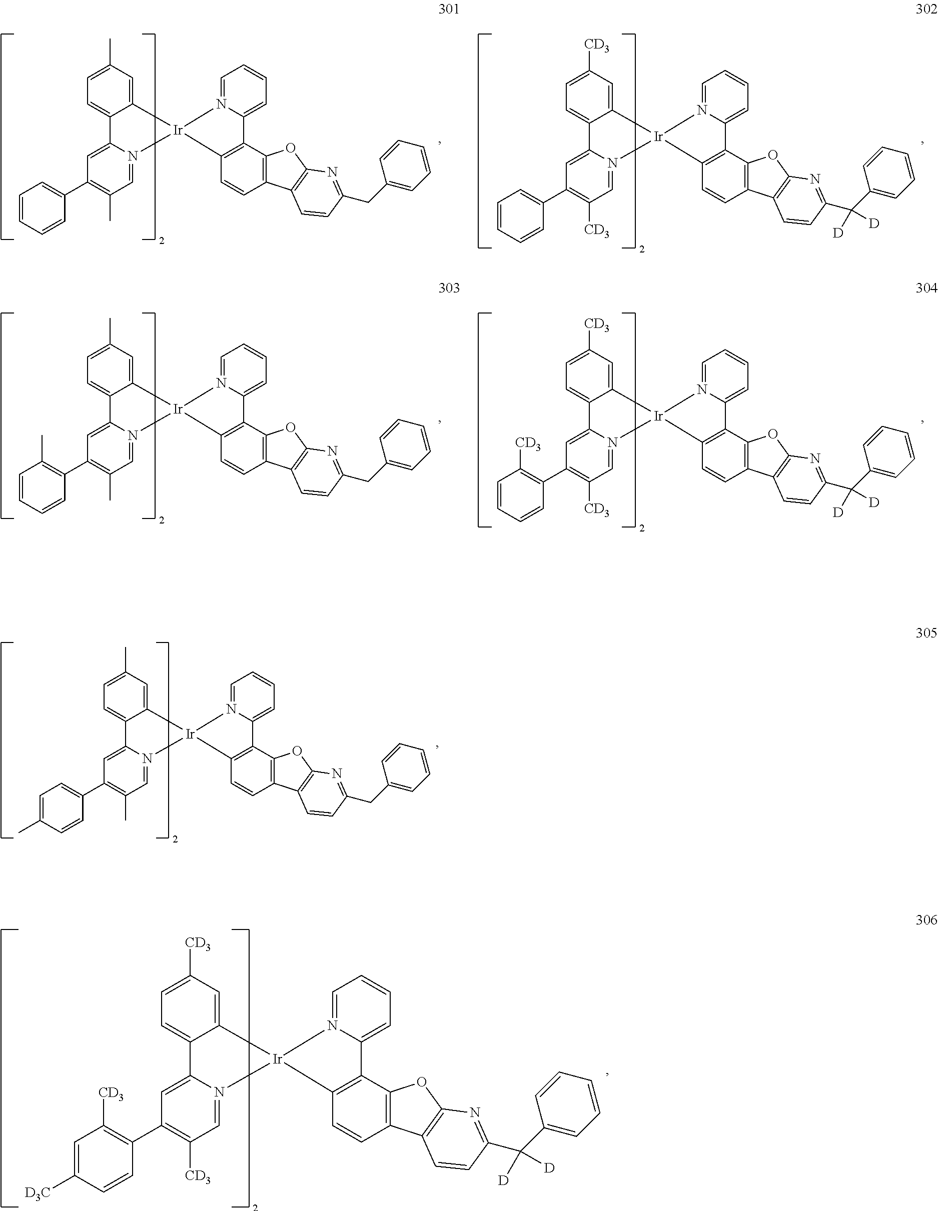

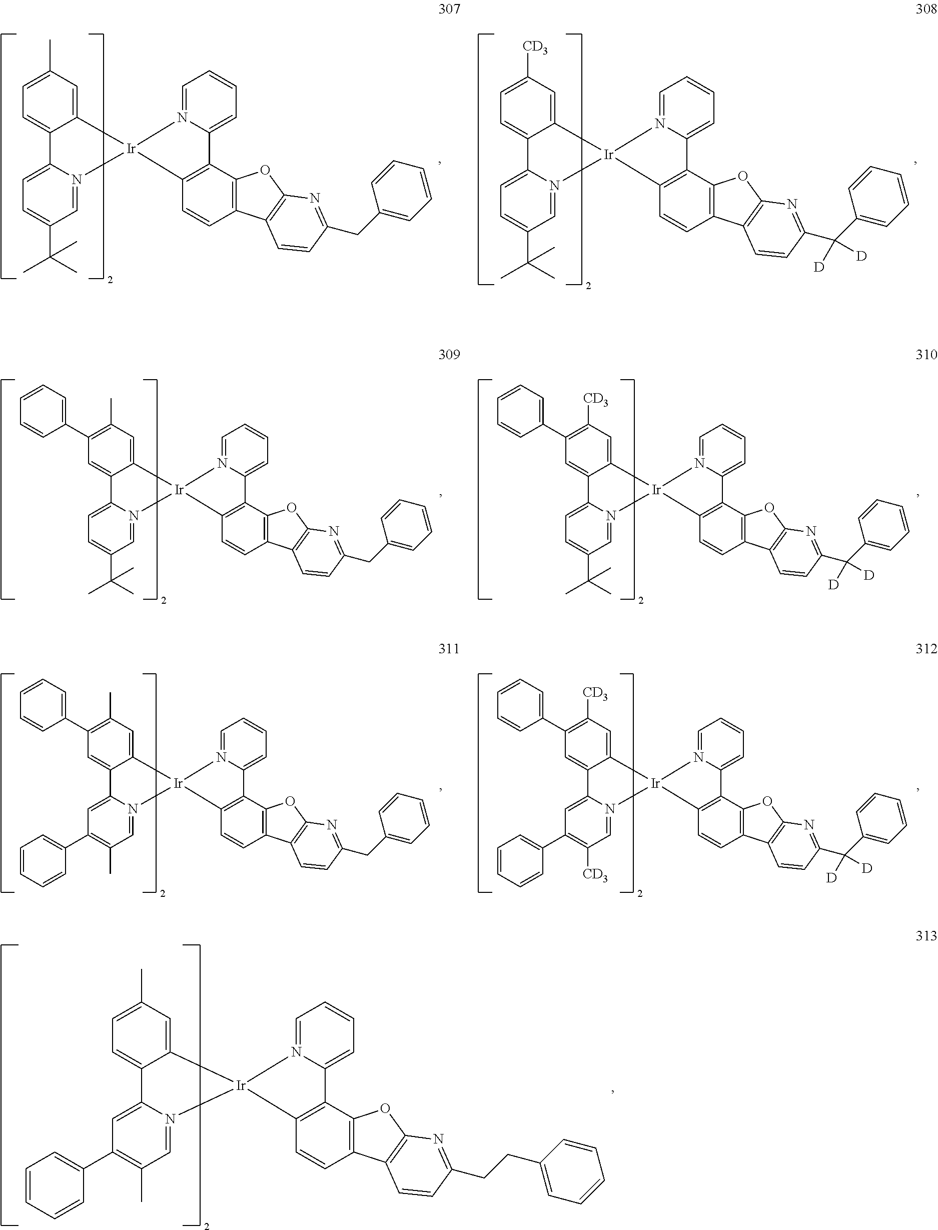

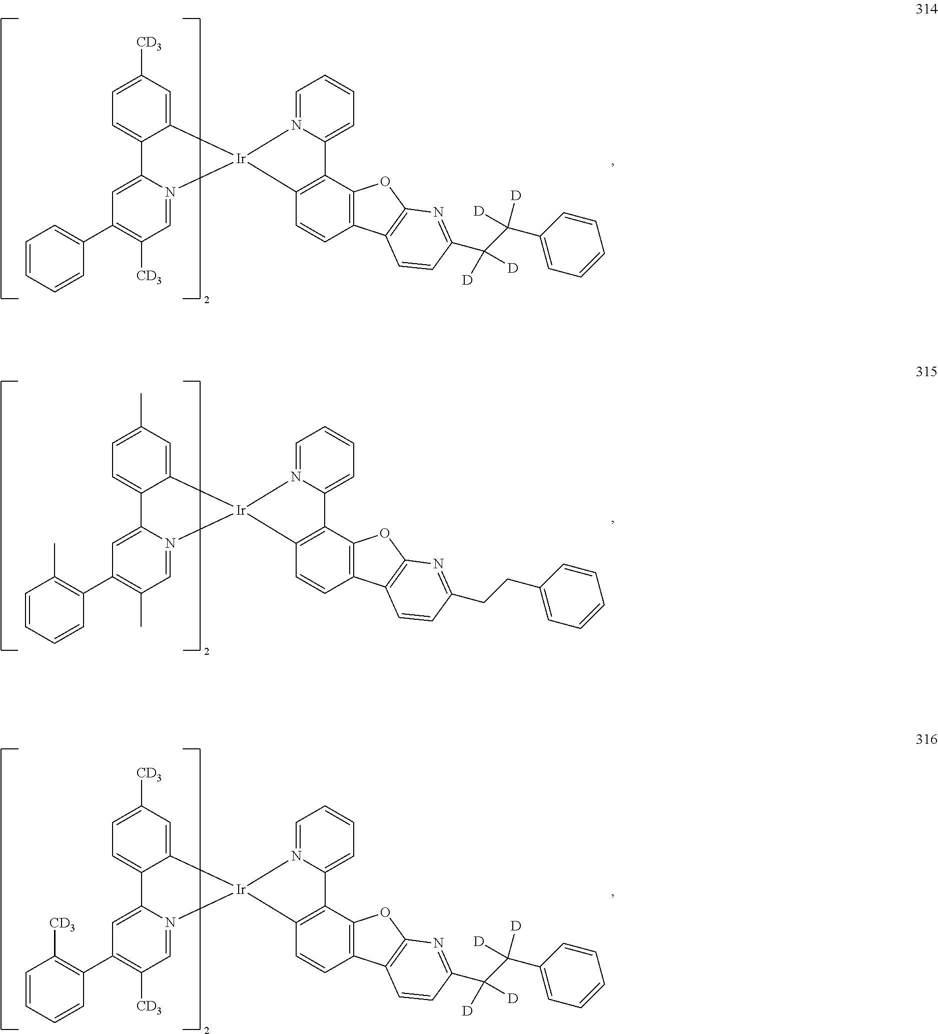

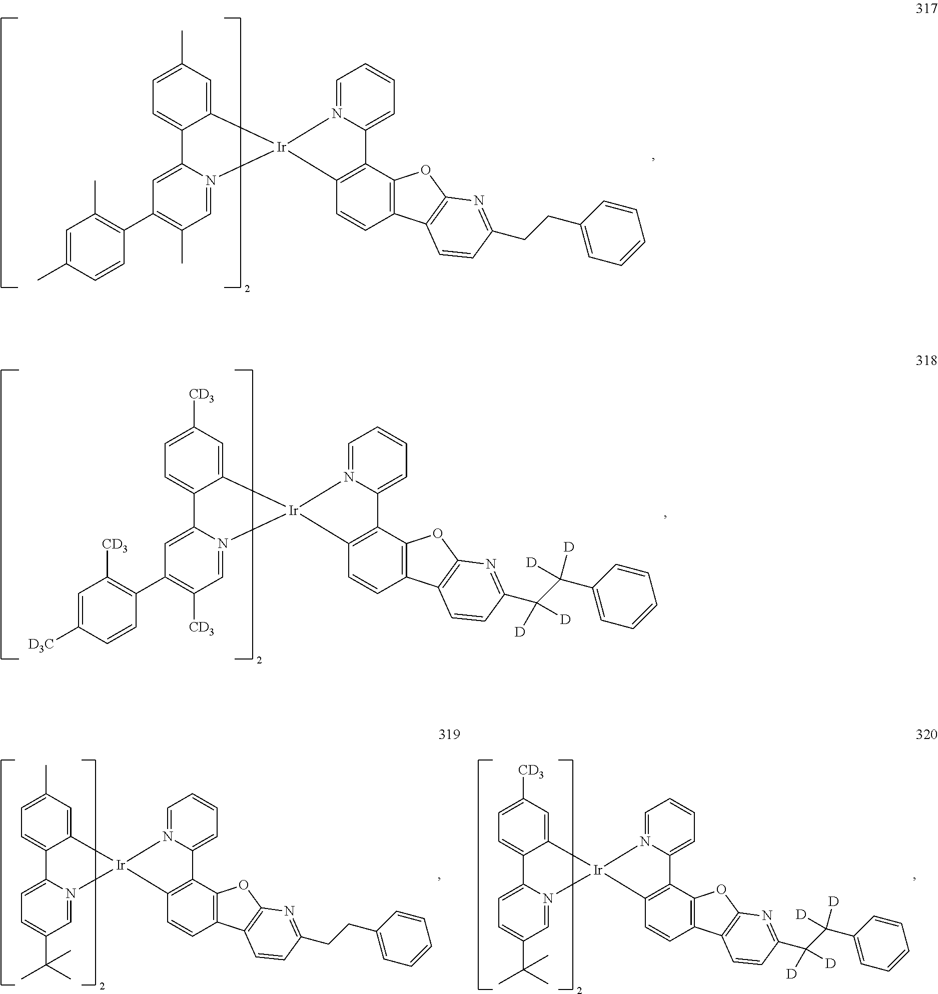

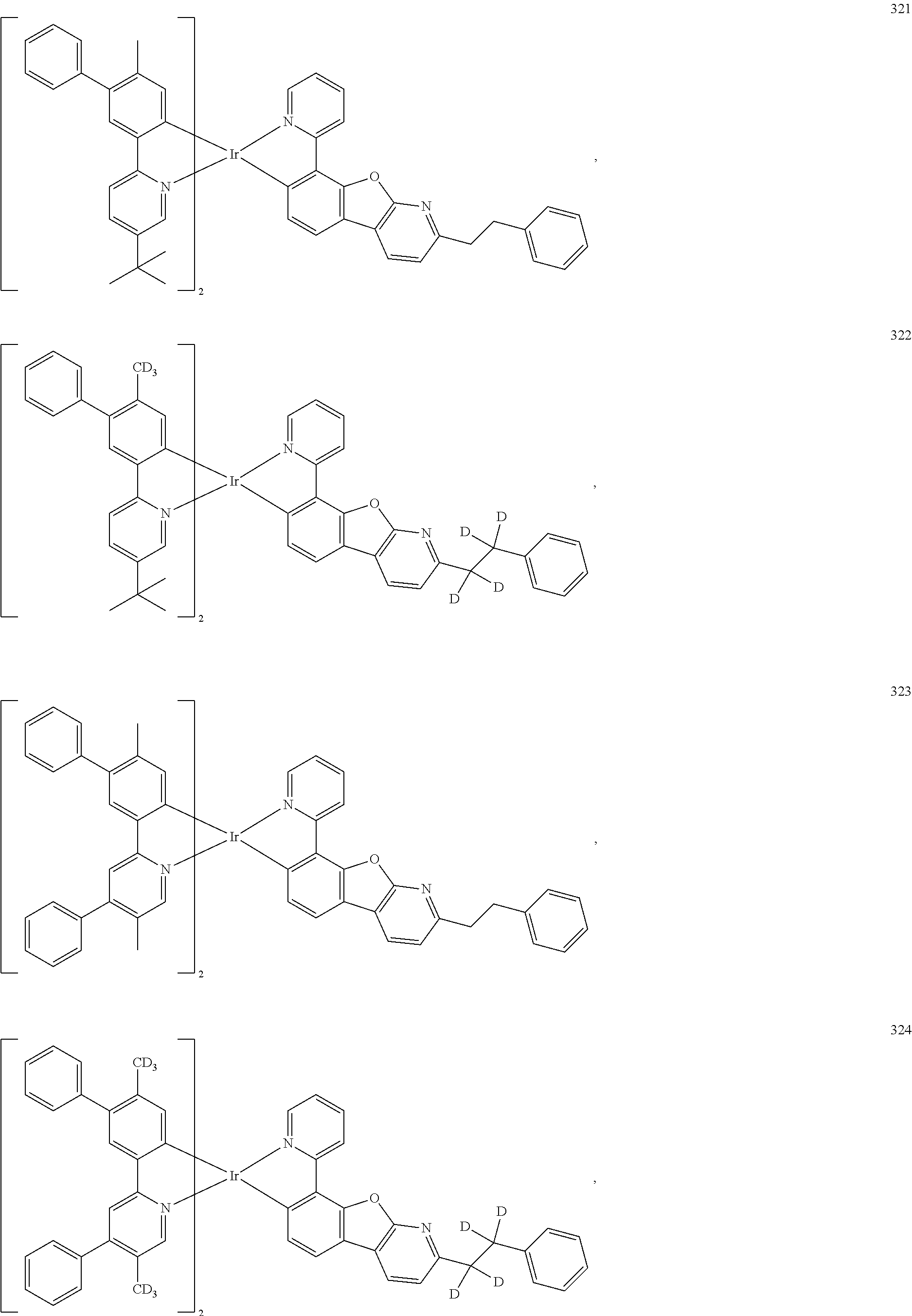

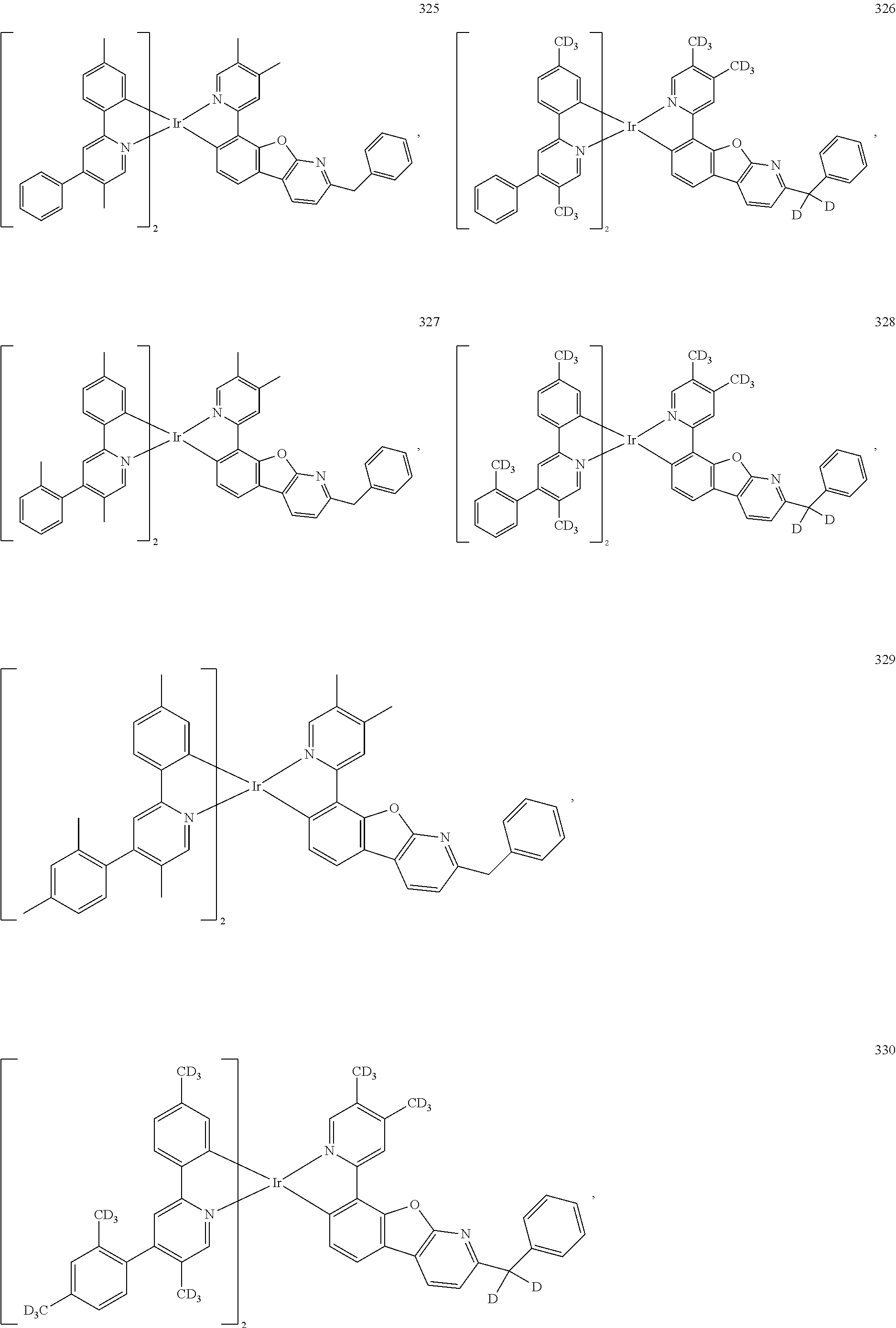

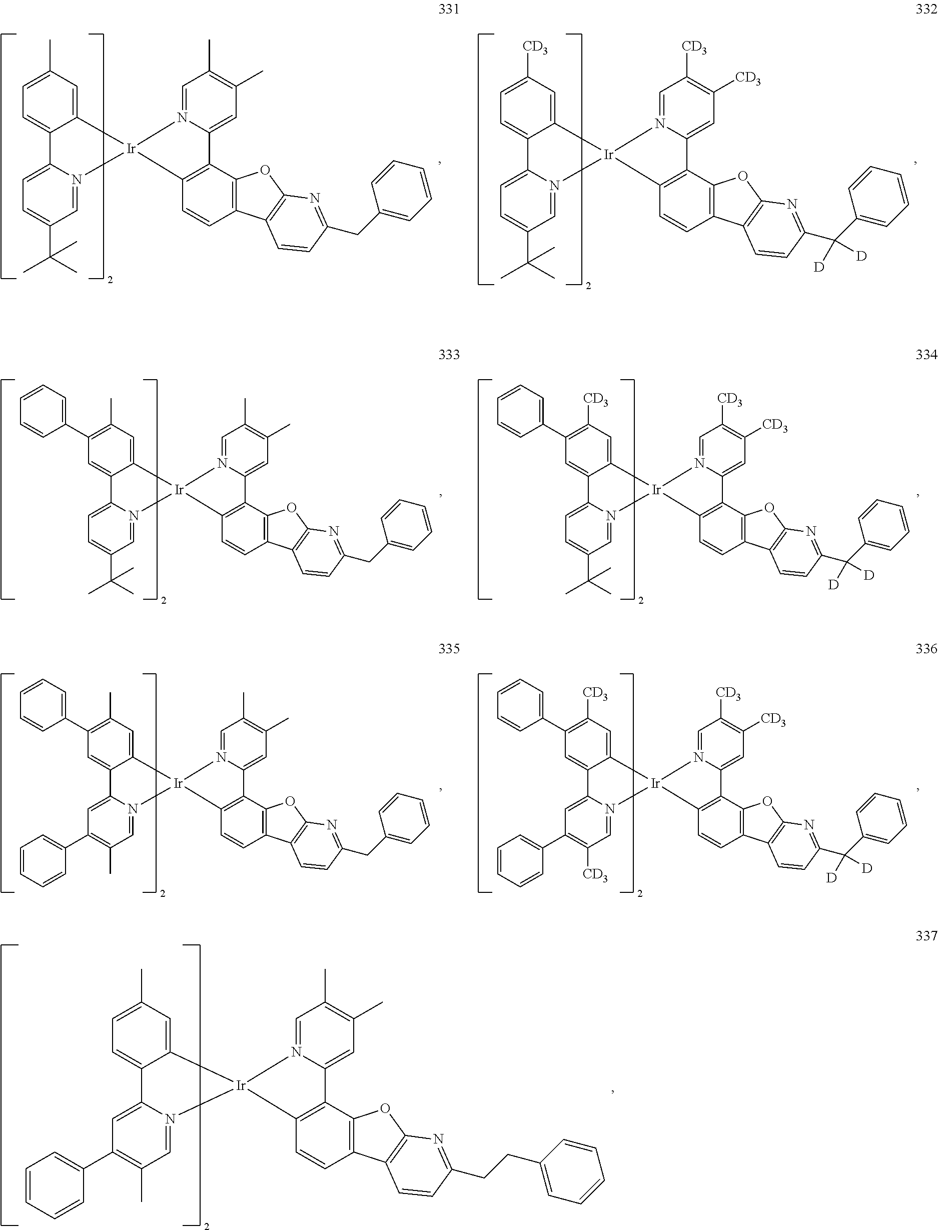

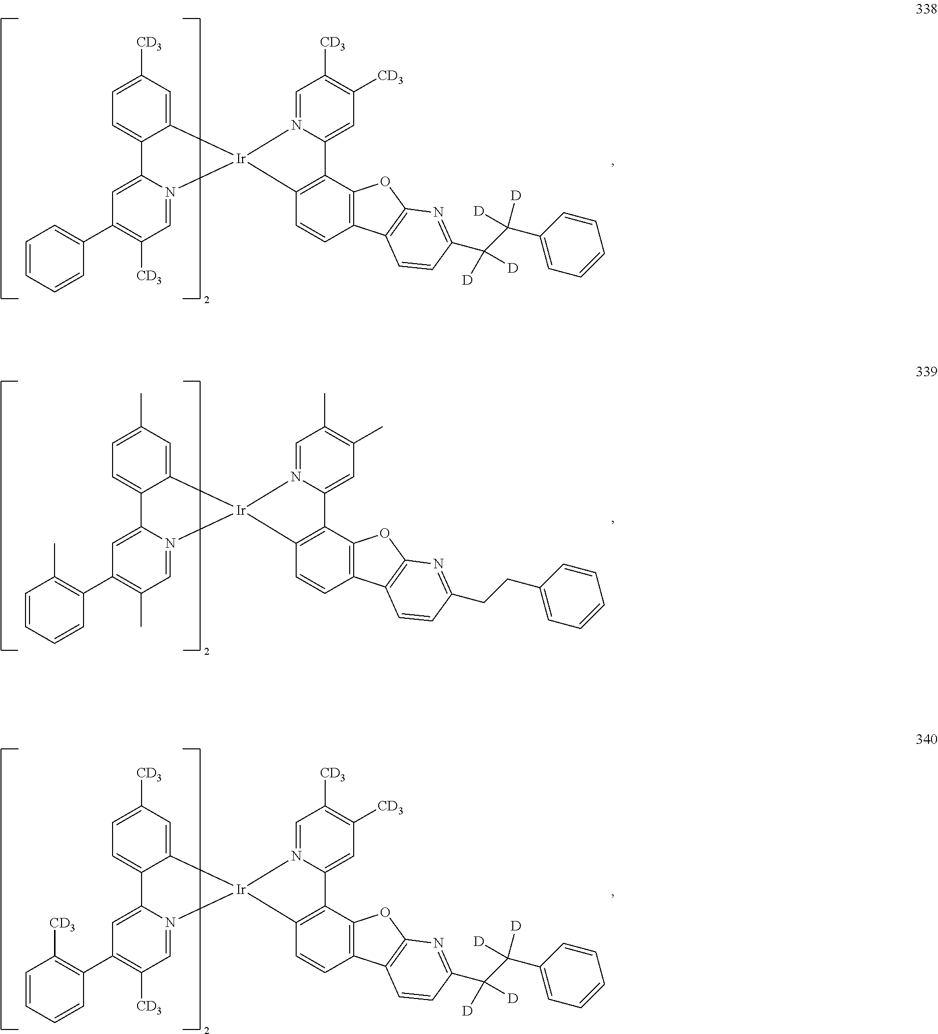

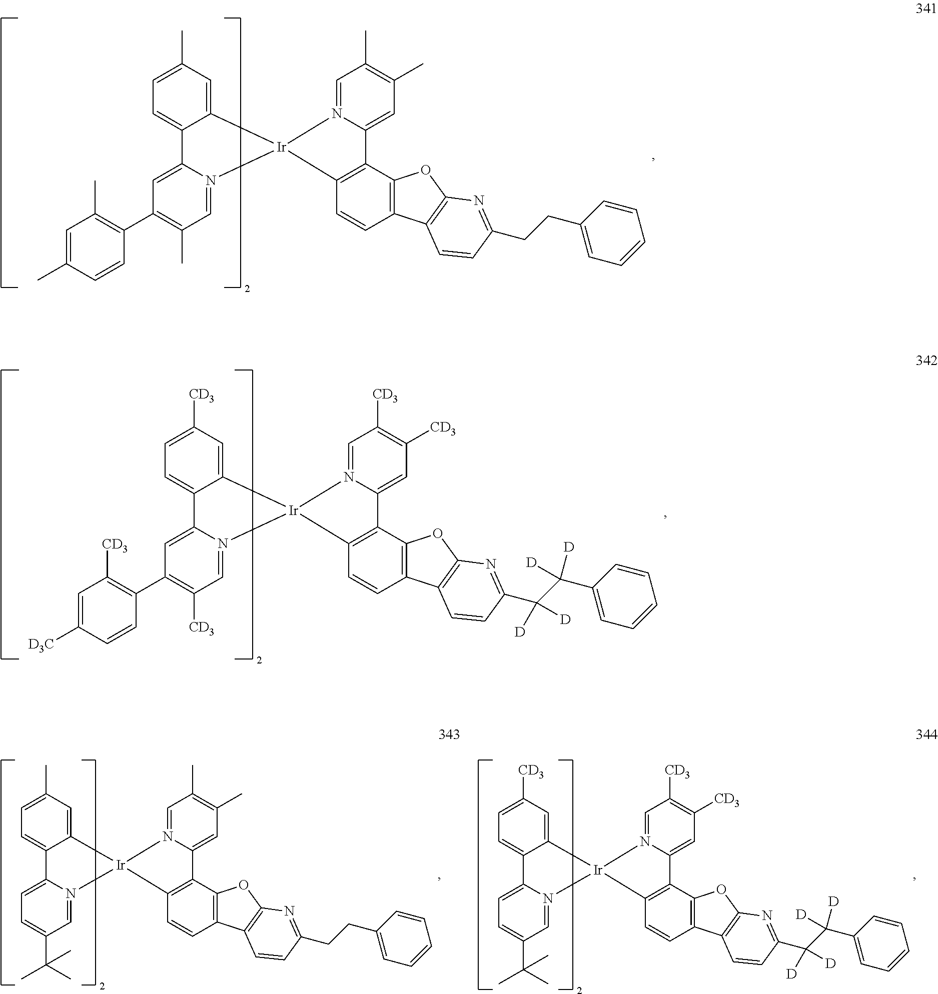

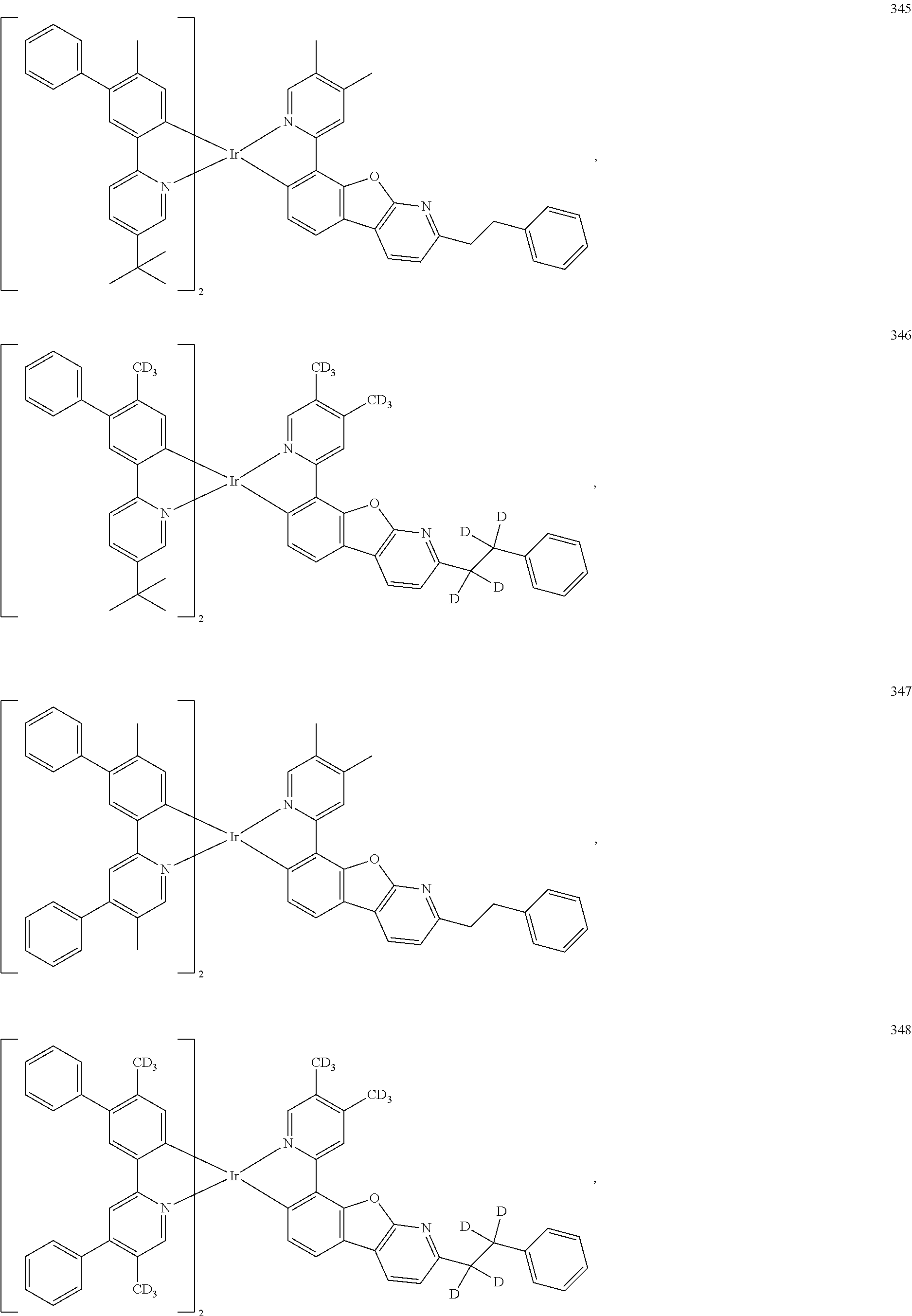

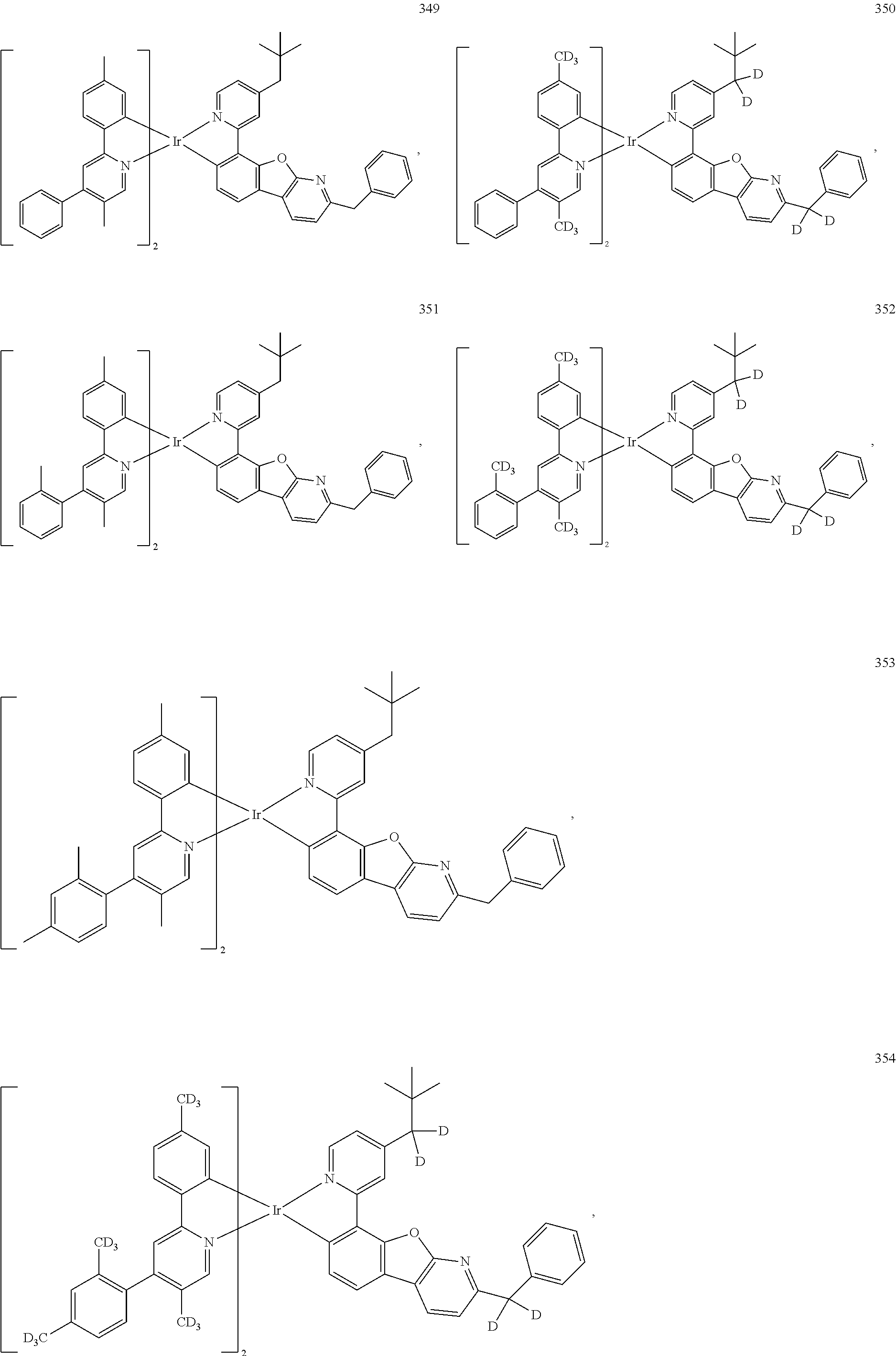

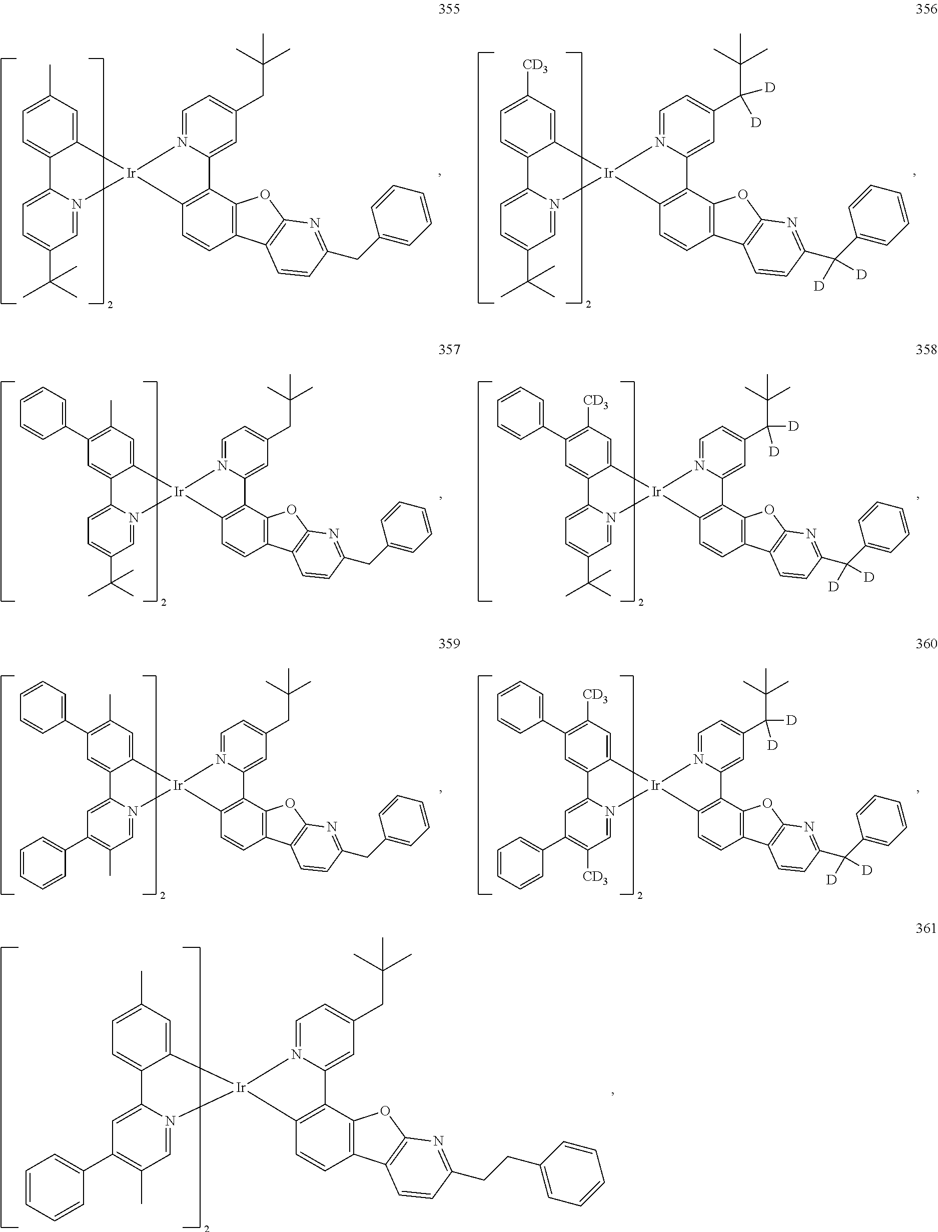

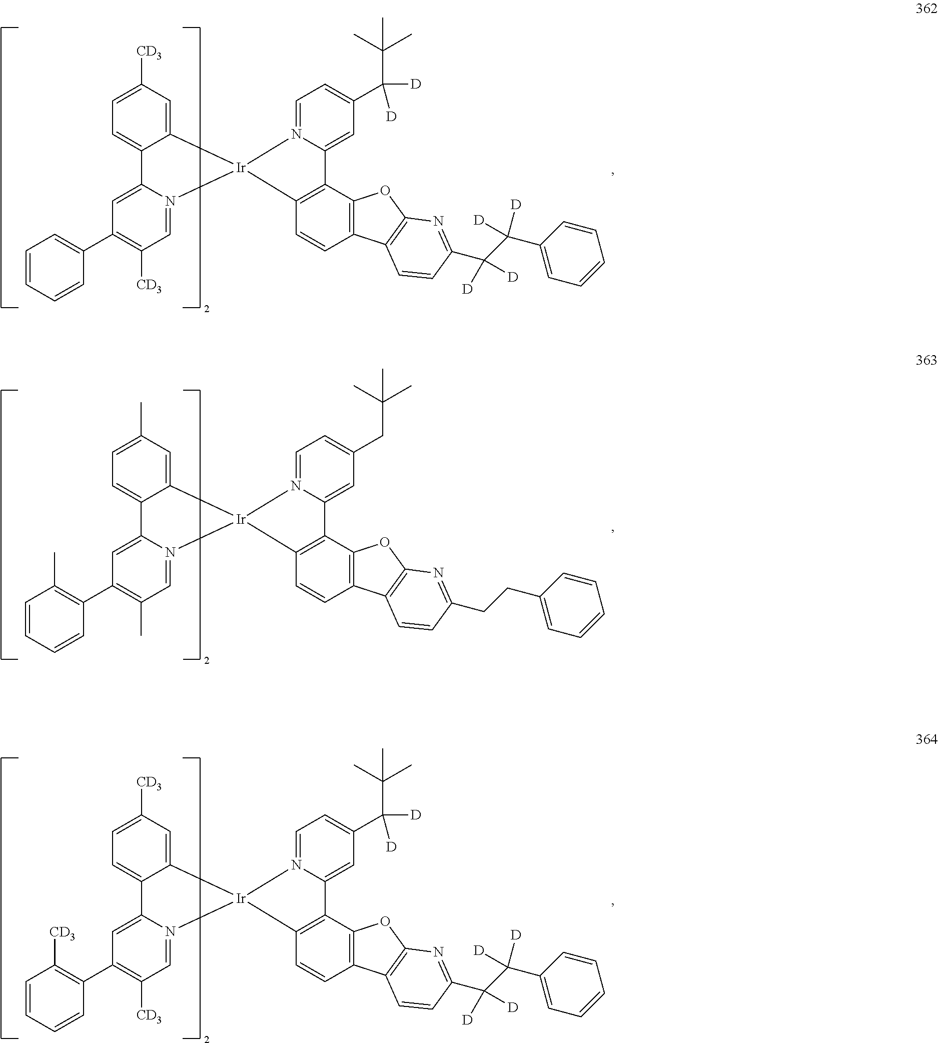

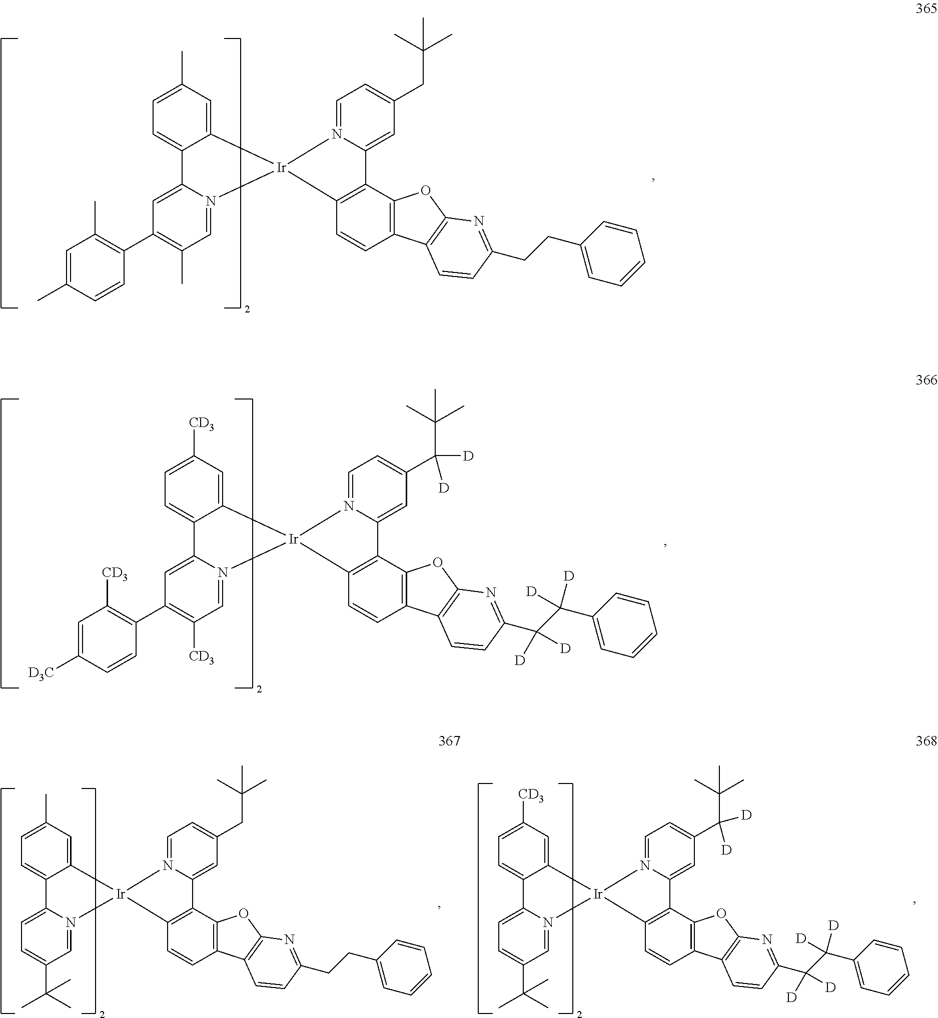

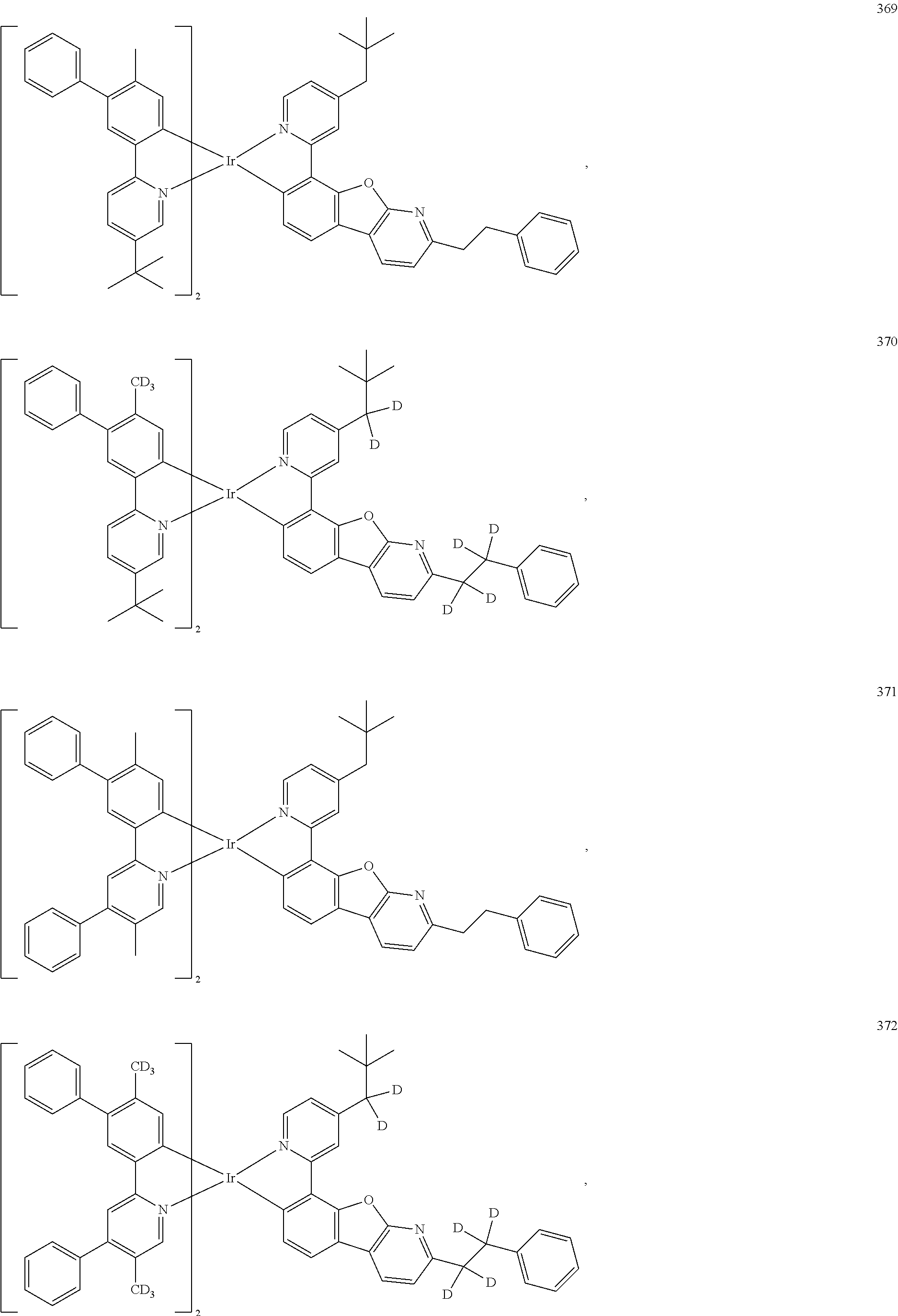

8. The organometallic compound of claim 1, wherein the organometallic compound represented by the Chemical Formula 1 is a green phosphorescent material.

9. An organic light-emitting diode comprising:
a first electrode;
a second electrode facing the first electrode; and
an organic layer including a light-emitting layer that includes the organometallic compound according to claim 1, wherein the organic layer is between the first electrode and the second electrode.

10. The organic light-emitting diode of claim 9, wherein the organometallic compound represented by the Chemical Formula 1 is a green phosphorescent material.

11. The organic light-emitting diode of claim 9, wherein the organic layer further includes at least one selected from the group consisting of a hole injection layer, a hole transport layer, an electron transport layer, and an electron injection layer.

12. An organic light-emitting display device comprising:
a substrate;
a driving element positioned on the substrate; and
the organic light-emitting diode according to claim 9, wherein the organic light-emitting diode is on the substrate and connected to the driving element.
